(19) United States
(12) Patent Application Publication
(10) Pub. No.: US 2026/0149237 A1
(43) Pub. Date: May 28, 2026

(54) SEMICONDUCTOR LIGHT-EMITTING DEVICE

(71) Applicant: ROHM CO., LTD., Kyoto (JP)

(72) Inventor: Koki SAKAMOTO, Kyoto-shi (JP)

(73) Assignee: ROHM CO., LTD., Kyoto (JP)

(21) Appl. No.: 19/453,896

(22) Filed: Jan. 20, 2026

Related U.S. Application Data
(63) Continuation of application No. PCT/JP2024/024683, filed on Jul. 9, 2024.

(30) Foreign Application Priority Data
Jul. 28, 2023 (JP) 2023-123646

(51) Int. Cl. H01S 5/062; H01S 5/40

(52) U.S. Cl. CPC H01S 5/06233; H01S 5/4031

(57) ABSTRACT

A semiconductor light-emitting device includes: a substrate; front-surface electrodes; back-surface electrodes; a semiconductor light-emitting element; a first drive circuit; and a second drive circuit. The substrate includes a substrate front surface, and a substrate back surface. The front-surface electrodes are formed on the substrate front surface. The back-surface electrodes are formed on the substrate back surface and configured for mounting the semiconductor light-emitting device. The semiconductor light-emitting element includes a first light emitter and a second light emitter. The first drive circuit is configured to drive the first light emitter. The second drive circuit is configured to drive the second light emitter. The semiconductor light-emitting element, the first drive circuit, and the second drive circuit are mounted on the front-surface electrodes.

### CROSS-REFERENCE TO RELATED APPLICATIONS

This application is a continuation of, and claims the benefit of priority from International Application No. PCT/JP2024/024683, filed on Jul. 9, 2024, which claims the benefit of priority from Japanese Patent Application No. 2023-123646, filed on Jul. 28, 2023, the entire contents of each of which are incorporated herein by reference.

### BACKGROUND

### 1. Field

The following description relates to a semiconductor light-emitting device.

### 2. Description of Related Art

A typical example of a semiconductor light-emitting device is a semiconductor laser device that includes a semiconductor light-emitting element as a source of laser beam (for example, refer to JP2016-29718A). The semiconductor laser device of JP2016-29718A includes rod-shaped leads. These leads serve as terminals for mounting the semiconductor laser device on an electronic device or the like.

### BRIEF DESCRIPTION OF THE DRAWINGS

FIG. 1 is a schematic plan view of a semiconductor light-emitting device in accordance with a first embodiment.

FIG. 2 is a schematic bottom view of the semiconductor light-emitting device shown in FIG. 1.

FIG. 3 is a schematic cross-sectional view of the semiconductor light-emitting device taken along line F3-F3 shown in FIG. 1.

FIG. 4 is a schematic cross-sectional view of the semiconductor light-emitting device taken along line F4-F4 shown in FIG. 3.

FIG. 5 is a schematic circuit diagram of a light-emitting system including the semiconductor light-emitting device of the first embodiment.

FIG. 6 is a schematic cross-sectional view of the semiconductor light-emitting device shown in FIG. 3 mounted on a circuit board.

FIG. 7 is a schematic cross-sectional view illustrating a current path in the semiconductor light-emitting device.

FIG. 8 is a schematic plan view of a semiconductor light-emitting device in accordance with a second embodiment.

FIG. 9 is a schematic bottom view of the semiconductor light-emitting device shown in FIG. 8.

FIG. 10 is a schematic plan view of a front-surface intermediate electrode of the semiconductor light-emitting device shown in FIG. 8.

FIG. 11 is a schematic circuit diagram of a light-emitting system including the semiconductor light-emitting device of the second embodiment.

FIG. 12 is a schematic plan view of a semiconductor light-emitting device in accordance with a third embodiment.

FIG. 13 is a schematic bottom view of the semiconductor light-emitting device shown in FIG. 12.

FIG. 14 is a schematic cross-sectional view of the semiconductor light-emitting device taken along line F14-F14 shown in FIG. 12.

FIG. 15 is a schematic cross-sectional view of the semiconductor light-emitting device taken along line F15-F15 shown in FIG. 12.

FIG. 16 is a schematic plan view of a semiconductor light-emitting device in accordance with a fourth embodiment.

FIG. 17 is a schematic bottom view of the semiconductor light-emitting device shown in FIG. 16.

FIG. 18 is a schematic plan view enlarging part of the semiconductor light-emitting device shown in FIG. 16.

FIG. 19 is a schematic plan view enlarging another part of the semiconductor light-emitting device shown in FIG. 16.

FIG. 20 is a schematic circuit diagram of a light-emitting system including a semiconductor light-emitting device in accordance with a fifth embodiment.

FIG. 21 is a schematic plan view of the semiconductor light-emitting device illustrated in FIG. 20.

FIG. 22 is a schematic bottom view of the semiconductor light-emitting device shown in FIG. 21.

FIG. 23 is a schematic plan view of a front-surface intermediate electrode of the semiconductor light-emitting device shown in FIG. 21.

FIG. 24 is a schematic plan view enlarging part of the semiconductor light-emitting device illustrated in FIG. 20.

FIG. 25 is a schematic plan view enlarging another part of the semiconductor light-emitting device illustrated in FIG. 20.

FIG. 26 is a schematic plan view enlarging another part of the semiconductor light-emitting device illustrated in FIG. 20.

FIG. 27 is a schematic circuit diagram of a light-emitting system including a semiconductor light-emitting device in accordance with a sixth embodiment.

FIG. 28 is a schematic plan view of the semiconductor light-emitting device illustrated in FIG. 27.

FIG. 29 is a schematic bottom view of the semiconductor light-emitting device shown in FIG. 28.

FIG. 30 is a schematic plan view of a front-surface intermediate electrode of the semiconductor light-emitting device shown in FIG. 28.

FIG. 31 is a schematic plan view of a back-surface intermediate electrode of the semiconductor light-emitting device shown in FIG. 28.

FIG. 32 is a schematic plan view enlarging part of the semiconductor light-emitting device shown in FIG. 28.

FIG. 33 is a schematic plan view enlarging another part of the semiconductor light-emitting device shown in FIG. 28.

FIG. 34 is a schematic plan view enlarging another part of the semiconductor light-emitting device shown in FIG. 28.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Several embodiments of a semiconductor light-emitting device will now be described with reference to the accompanying drawings. Elements in the drawings are illustrated for simplicity and clarity and are not necessarily drawn to scale. In the cross-sectional drawings, hatching lines may not be shown in order to facilitate understanding. The accompanying drawings merely illustrate exemplary embodiments of the present disclosure and are not intended to limit the present disclosure.

This detailed description includes exemplary embodiments of devices, systems, and methods in accordance with the present disclosure. Further, this detailed description is illustrative and is not intended to limit embodiments of the present disclosure or the application and use of the embodiments.

### First Embodiment

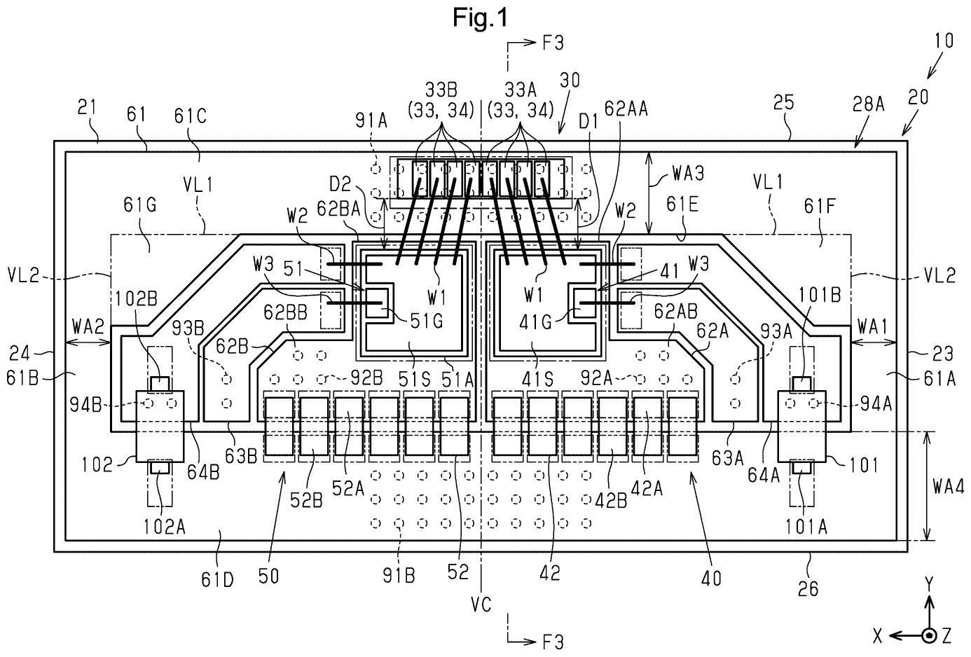

A semiconductor light-emitting device 10 in accordance with a first embodiment will now be described with reference to FIGS. 1 to 7.

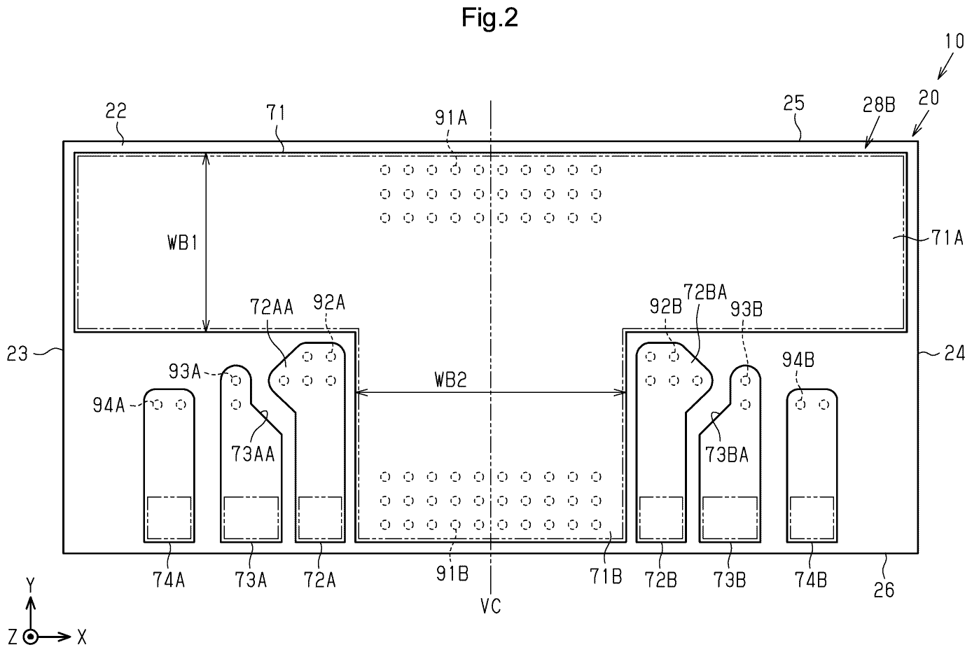

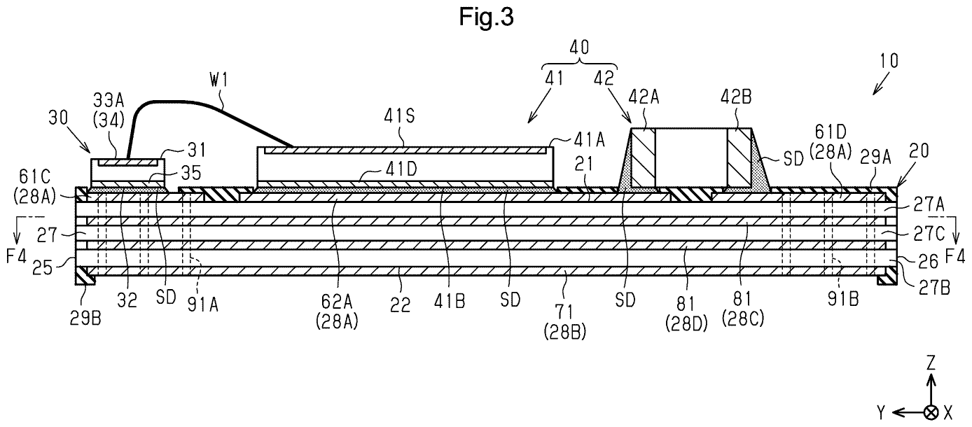

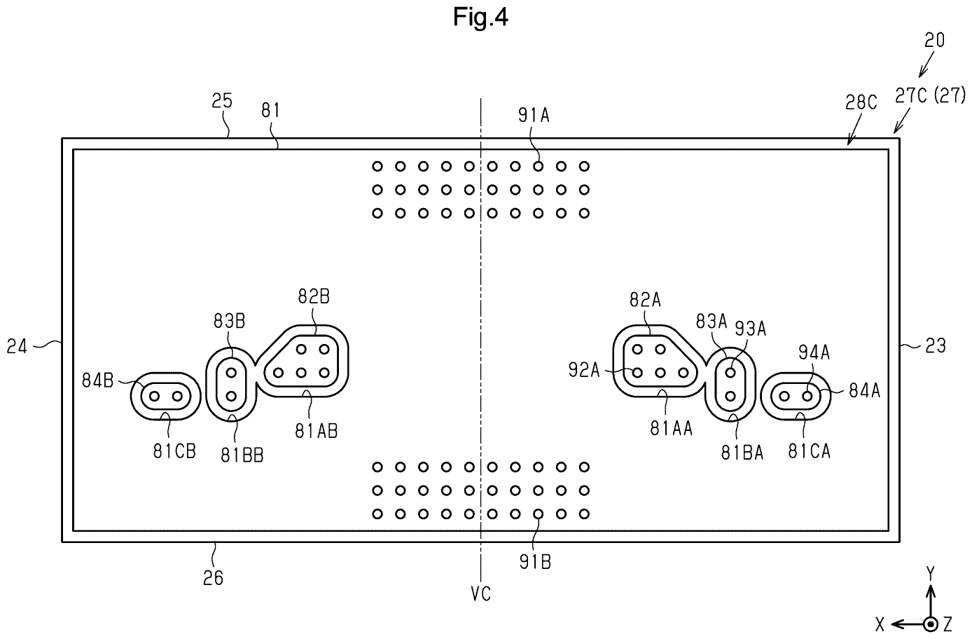

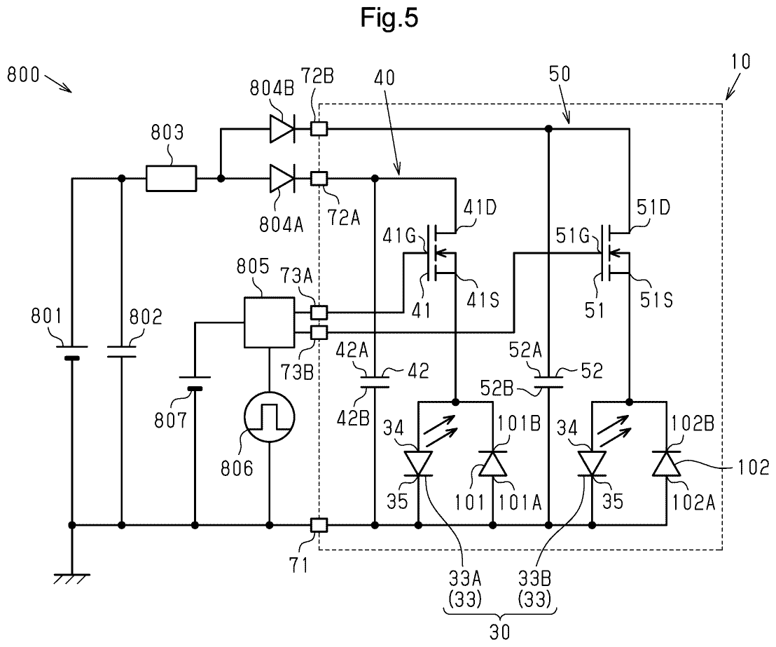

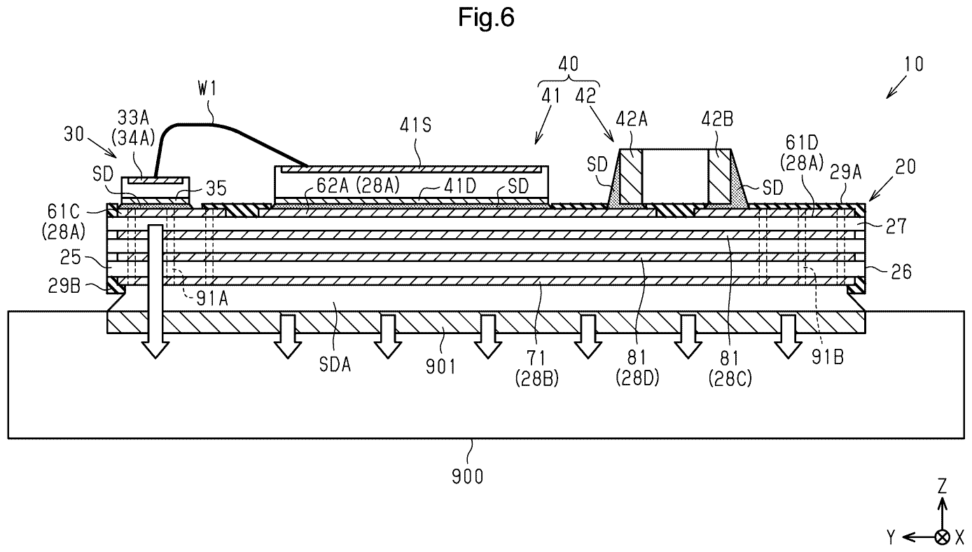

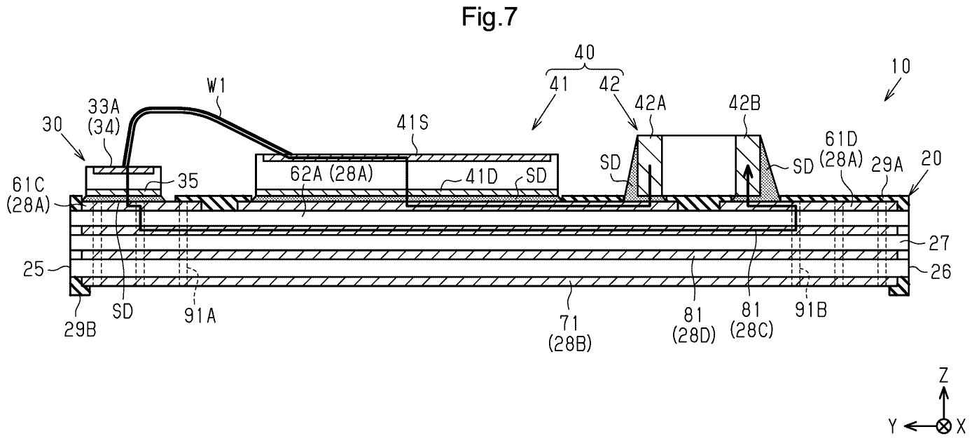

FIG. 1 shows a schematic planar structure of the semiconductor light-emitting device 10. FIG. 2 shows a schematic bottom structure of the semiconductor light-emitting device 10. FIG. 3 shows a schematic cross-sectional structure of the semiconductor light-emitting device 10 taken along line F3-F3 shown in FIG. 1. FIG. 4 shows a schematic cross-sectional structure of the semiconductor light-emitting device 10 taken along line F4-F4 shown in FIG. 3. FIG. 5 shows a schematic circuit diagram of a light-emitting system 800 including the semiconductor light-emitting device 10. FIG. 6 shows a schematic cross-sectional structure of the semiconductor light-emitting device 10 mounted on a circuit board 900. FIG. 7 shows a diagram illustrating a current flow in the semiconductor light-emitting device 10. To facilitate understanding, hatching lines are not shown in FIG. 4. In this disclosure, X-axis, Y-axis, and Z-axis are orthogonal to one another as shown in FIG. 1. The term “plan view” as used in this disclosure refers to a view of the semiconductor light-emitting device 10 taken in the Z-direction. In the first embodiment, the X-direction is an example of “second direction”, and the Y-direction is an example of “first direction”.

### Overall Configuration of Semiconductor Light-Emitting Device

As shown in FIG. 1, the semiconductor light-emitting device 10 includes a substrate 20, a semiconductor light-emitting element 30, a first drive circuit 40, and a second drive circuit 50. The semiconductor light-emitting element 30, the first drive circuit 40, and the second drive circuit 50 are arranged on the substrate 20. The semiconductor light-emitting element 30, the first drive circuit 40, and the second drive circuit 50 are spaced apart from one another on the substrate 20.

The substrate 20 is a component configured to support the semiconductor light-emitting element 30, the first drive circuit 40, and the second drive circuit 50. The substrate 20 has a shape of a rectangular flat plate having a thickness-wise direction parallel to the Z-direction. In the description hereafter, the phrase “in plan view” is synonymous with “as viewed in the thickness-wise direction of the substrate”.

The substrate 20 is rectangular in plan view, with long sides extending in the X-direction and short sides extending in the Y-direction. The substrate 20 includes a substrate front surface 21, a substrate back surface 22 facing away from the substrate front surface 21 in the Z-direction, and first to fourth substrate side surfaces 23 to 26 connecting the substrate front surface 21 and the substrate back surface 22. The first substrate side surface 23 and the second substrate side surface 24 define two end surfaces of the substrate 20 in the X-direction. The third substrate side surface 25 and the fourth substrate side surface 26 define two end surfaces of the substrate 20 in the Y-direction. The planar shape of the substrate 20 may be changed.

As shown in FIG. 3, the substrate 20 is a multilayer substrate. In the example shown in FIG. 3, the substrate 20 is a four-layer substrate. Specifically, the substrate 20 includes front-surface electrodes 28A, back-surface electrodes 28B, front-surface intermediate electrodes 28C, and back-surface intermediate electrodes 28D that are included in a base member 27. The front-surface electrodes 28A, the back-surface electrodes 28B, the front-surface intermediate electrodes 28C, and the back-surface intermediate electrodes 28D are formed from, for example, a material containing one or more selected from titanium (Ti), titanium nitride (TiN), gold (Au), silver (Ag), copper (Cu), aluminum (Al), and tungsten (W).

The base member 27 is formed from, for example, an insulative material. The insulative material may be, for example, a material containing an epoxy resin. In an example, the base member 27 may be formed from glass epoxy resin. Alternatively, the insulative material may be, for example, a material containing ceramic. Examples of the material containing ceramic may include aluminum nitride (AlN), alumina (Al₂O₃), and the like. When the base member 27 is formed from the material containing ceramic, the base member 27 has improved heat dissipation performance. Therefore, the temperature of the semiconductor light-emitting device 10 will not become excessively high. The substrate front surface 21, the substrate back surface 22, and the first to fourth substrate side surfaces 23 to 26 respectively correspond to a base-member front surface, a base-member back surface, and first to fourth base-member side surfaces of the base member 27. More specifically, the base member 27 includes three base members, namely, a front-surface base member 27A, a back-surface base member 27B, and an intermediate base member 27C. The substrate front surface 21 of the substrate 20 is defined by a base-member front surface of the front-surface base member 27A. The substrate back surface 22 of the substrate 20 is defined by a base-member back surface of the back-surface base member 27B. The first to fourth base-member side surfaces of the substrate 20 are defined by first to fourth base-member side surfaces of the front-surface base member 27A, the back-surface base member 27B, and the intermediate base member 27C. In the first to fourth substrate side surfaces 23 to 26 (FIG. 3 shows third substrate side surface 25 and fourth substrate side surface 26), the base members 27A, 27B, and 27C cover ends of the front-surface intermediate electrode 28C and ends of the back-surface intermediate electrode 28D. In FIG. 3, to facilitate understanding, solid lines are drawn to demarcate the base members 27A, 27B, and 27C and the portions in which the ends of the front-surface intermediate electrode 28C and the ends of the back-surface intermediate electrode 28D are covered by the base members 27A, 27B, and 27C. Nonetheless, the interfaces between the base members 27A, 27B, and 27C may not be well-defined.

As shown in FIG. 1, the front-surface electrodes 28A are formed in the substrate front surface 21. The front-surface electrodes 28A include a first front-surface electrode 61, second front-surface electrodes 62A and 62B, third front-surface electrodes 63A and 63B, and fourth front-surface electrodes 64A and 64B that are spaced apart from one another.

The first front-surface electrode 61 has substantially a shape of a rectangular frame extending along edges of the substrate front surface 21. The first front-surface electrode 61 is symmetric with respect to an imaginary centerline VC. The imaginary centerline VC extends in the Y-direction through the center of the substrate front surface 21 in the X-direction. The first front-surface electrode 61 includes first to fourth wiring portions 61A to 61D and an open portion 61E. The first to fourth wiring portions 61A to 61D each define a corresponding side of the rectangular frame. The open portion 61E is surrounded by the first to fourth wiring portions 61A to 61D.

The first wiring portion 61A extends in the Y-direction and is adjacent to the first substrate side surface 23 in the X-direction. The second wiring portion 61B extends in the Y-direction and is adjacent to the second substrate side surface 24 in the X-direction. The third wiring portion 61C extends in the X-direction and is adjacent to the third substrate side surface 25 in the Y-direction. The fourth wiring portion 61D extends in the X-direction and is adjacent to the fourth substrate side surface 26 in the Y-direction.

A width WA3 of the third wiring portion 61C is greater than a width WA1 of the first wiring portion 61A. The width WA3 is greater than a width WA2 of the second wiring portion 61B. The width WA3 is less than a width WA4 of the fourth wiring portion 61D. The width WA3 of the third wiring portion 61C is a dimension of the third wiring portion 61C in a direction (Y-direction) orthogonal to the direction (X-direction) in which the third wiring portion 61C extends in plan view. The width WA1 of the first wiring portion 61A and the width WA2 of the second wiring portion 61B are a dimension of the first wiring portion 61A and a dimension of the second wiring portion 61B in a direction (X-direction) orthogonal to the direction in which the first wiring portion 61A and the second wiring portion 61B extend (Y-direction) in plan view. The width WA4 of the fourth wiring portion 61D is a dimension of the fourth wiring portion 61D in a direction (Y-direction) orthogonal to the direction in which the fourth wiring portion 61D extends (X-direction) in plan view.

An extension region 61F is formed between the first wiring portion 61A and the third wiring portion 61C, and an extension region 61G is formed between the second wiring portion 61B and the third wiring portion 61C. The extension region 61F is a region that increases the area of the first front-surface electrode 61 between the first wiring portion 61A and the third wiring portion 61C. The extension region 61G is a region that increases the area of the first front-surface electrode 61 between the second wiring portion 61B and the third wiring portion 61C. In the example shown in FIG. 1, the extension regions 61F and 61G each have a shape of a right trapezoid. In a hypothetical example in which the extension regions 61F and 61G are not included, imaginary lines VL1 and VL2 indicated by double-dashed lines shown in FIG. 1 define part of the first wiring portion 61A, the second wiring portion 61B, and the third wiring portion 61C.

In plan view, the second front-surface electrodes 62A and 62B, the third front-surface electrodes 63A and 63B, and the fourth front-surface electrodes 64A and 64B are arranged in the open portion 61E of the first front-surface electrode 61 included in the substrate front surface 21. The second front-surface electrode 62A, the third front-surface electrode 63A, and the fourth front-surface electrode 64A are located closer to the first substrate side surface 23 than the imaginary centerline VC is. The second front-surface electrode 62B, the third front-surface electrode 63B, and the fourth front-surface electrode 64B are located closer to the second substrate side surface 24 than the imaginary centerline VC is. In the example shown in FIG. 1, the second front-surface electrode 62A, the third front-surface electrode 63A, the fourth front-surface electrode 64A, the second front-surface electrode 62B, the third front-surface electrode 63B, and the fourth front-surface electrode 64B are symmetric with respect to the imaginary centerline VC. Hereinafter, the second front-surface electrode 62A, the third front-surface electrode 63A, and the fourth front-surface electrode 64A will be described, and description of the second front-surface electrode 62B, the third front-surface electrode 63B, and the fourth front-surface electrode 64B will be omitted.

The second front-surface electrode 62A is substantially L-shaped in plan view. The second front-surface electrode 62A is located closer to the imaginary centerline VC than the third front-surface electrode 63A and the fourth front-surface electrode 64A are. The second front-surface electrode 62A includes a narrow section 62AA and a wide section 62AB. The narrow section 62AA is part of the second front-surface electrode 62A that has a smaller dimension in the X-direction. The wide section 62AB is part of the second front-surface electrode 62A that has a larger dimension in the X-direction. The narrow section 62AA and the wide section 62AB are arranged next to each other in the Y-direction. In an example, the narrow section 62AA and the wide section 62AB are integrated with each other. The narrow section 62AA is located relatively close to the third wiring portion 61C of the first front-surface electrode 61. The wide section 62AB is located relatively close to the fourth wiring portion 61D of the first front-surface electrode 61. The second front-surface electrode 62B includes a narrow section 62BA and a wide section 62BB in the same manner as the second front-surface electrode 62A.

The third front-surface electrode 63A surrounds the wide section 62AB of the second front-surface electrode 62A from a side in the X-direction and a side in the Y-direction. The third front-surface electrode 63A includes a first opposing section, a second opposing section, and a joining section. The first opposing section and the second opposing section define two opposite ends of the third front-surface electrode 63A in a direction in which the third front-surface electrode 63A extends.

The first opposing section is located closer to the third wiring portion 61C than the wide section 62AB is. The first opposing section opposes the narrow section 62AA in the X-direction. The first opposing section is adjacent to the narrow section 62AA in the X-direction. The second opposing section is located closer to the first wiring portion 61A than the wide section 62AB is. The second opposing section opposes the fourth wiring portion 61D in the Y-direction. The joining section joins the first opposing section and the second opposing section. As the joining section becomes closer to the first wiring portion 61A, the joining section diagonally extends toward the fourth wiring portion 61D. In the example shown in FIG. 1, the third front-surface electrode 63A includes wiring having a constant width.

The fourth front-surface electrode 64A surrounds the third front-surface electrode 63A from a side in the X-direction and a side in the Y-direction. The fourth front-surface electrode 64A includes a first opposing section, a second opposing section, and a joining section. The first opposing section and the second opposing section define two opposite ends of the fourth front-surface electrode 64A in a direction in which the fourth front-surface electrode 64A extends.

The first opposing section is located closer to the third wiring portion 61C than the first opposing section of the third front-surface electrode 63A is. The first opposing section opposes the narrow section 62AA in the X-direction. The first opposing section is adjacent to the narrow section 62AA in the X-direction. The first opposing section of the fourth front-surface electrode 64A is arranged next to the first opposing section of the third front-surface electrode 63A in the Y-direction. The second opposing section of the fourth front-surface electrode 64A is located closer to the first wiring portion 61A than the second opposing section of the third front-surface electrode 63A is. The second opposing portion of the fourth front-surface electrode 64A opposes the fourth wiring portion 61D in the Y-direction. The joining section of the fourth front-surface electrode 64A joins the first opposing section and the second opposing section of the fourth front-surface electrode 64A. This joining section is located closer to the extension region 61F than the joining section of the third front-surface electrode 63A is. In the example shown in FIG. 1, a width (dimension in X-direction) of the second opposing section of the fourth front-surface electrode 64A is greater than a width (dimension in the Y-direction) of the first opposing section of the fourth front-surface electrode 64A.

In the example shown in FIG. 1, in plan view, the first front-surface electrode 61 has a greater area than each of the second front-surface electrodes 62A and 62B, the third front-surface electrodes 63A and 63B, or the fourth front-surface electrodes 64A and 64B. In an example, the area of the first front-surface electrode 61 is greater than the combined total area of the second front-surface electrodes 62A and 62B, the third front-surface electrodes 63A and 63B, and the fourth front-surface electrodes 64A and 64B.

As shown in FIG. 2, the back-surface electrodes 28B are formed in the substrate back surface 22. The back-surface electrodes 28B include a first back-surface electrode 71, second back-surface electrodes 72A and 72B, third back-surface electrodes 73A and 73B, and fourth back-surface electrodes 74A and 74B that are spaced apart from one another.

The first back-surface electrode 71 is electrically connected to the first front-surface electrode 61 (refer to FIG. 1). The first back-surface electrode 71 is formed to overlap the first front-surface electrode 61 in plan view. The first back-surface electrode 71 is formed to overlap at least the first wiring portion 61A and the fourth wiring portion 61D in plan view. The first back-surface electrode 71 is T-shaped in plan view. In an example, the first back-surface electrode 71 is symmetric with respect to the imaginary centerline VC. The first back-surface electrode 71 includes a wide section 71A and a narrow section 71B. In an example, the wide section 71A and the narrow section 71B are integrated with each other.

The wide section 71A is located closer to the third substrate side surface 25 than the center of the substrate back surface 22 in the Y-direction is. The wide section 71A is formed across substantially the entire substrate back surface 22 in the X-direction. In an example, a dimension WB1 of the wide section 71A in the Y-direction is greater than one-third of the dimension of the substrate back surface 22 in the Y-direction and is less than one-half of the dimension of the substrate back surface 22 in the Y-direction.

The narrow section 71B is located closer to the fourth substrate side surface 26 than the wide section 71A is. The narrow section 71B is disposed in a central part of the substrate back surface 22 in the X-direction. In plan view, the distal end of the narrow section 71B is adjacent to the fourth substrate side surface 26 in the Y-direction. In an example, a width WB2 of the narrow section 71B is greater than the dimension WB1 of the wide section 71A in the Y-direction.

The second back-surface electrodes 72A and 72B are separately disposed at opposite sides of the narrow section 71B of the first back-surface electrode 71 in the X-direction. The third back-surface electrodes 73A and 73B are separately disposed at opposite sides of the narrow section 71B of the first back-surface electrode 71 in the X-direction. The fourth back-surface electrodes 74A and 74B are separately disposed at opposite sides of the narrow section 71B of the first back-surface electrode 71 in the X-direction. The second back-surface electrode 72A, the third back-surface electrode 73B, and the fourth back-surface electrode 74A are located closer to the first substrate side surface 23 than the narrow section 71B is. The second back-surface electrode 72B, the third back-surface electrode 73B, and the fourth back-surface electrode 74B are located closer to the second substrate side surface 24 than the narrow section 71B is.

The second back-surface electrode 72A and the second back-surface electrode 72B are symmetric with respect to the imaginary centerline VC. The fourth back-surface electrode 74A and the fourth back-surface electrode 74B are symmetric with respect to the imaginary centerline VC. Hereinafter, the second back-surface electrode 72A, the third back-surface electrode 73A, and the fourth back-surface electrode 74A will be described, and description of the second back-surface electrode 72B, the third back-surface electrode 73B, and the fourth back-surface electrode 74B will be omitted.

The second back-surface electrode 72A is electrically connected to the second front-surface electrode 62A (refer to FIG. 1). The second back-surface electrode 72A includes a portion that overlaps the wide section 62AB of the second front-surface electrode 62A (refer to FIG. 1) in plan view. The second back-surface electrode 72A is adjacent to the narrow section 71B in the X-direction. The second back-surface electrode 72A extends in the Y-direction. One of two opposite ends of the second back-surface electrode 72A in the Y-direction that is located closer to the third substrate side surface 25 is adjacent to the wide section 71A in the Y-direction. The other one of the two opposite ends of the second back-surface electrode 72A in the Y-direction that is located closer to the fourth substrate side surface 26 is adjacent to the fourth substrate side surface 26 in the Y-direction. The end of the second back-surface electrode 72A that is adjacent to the wide section 71A in the Y-direction includes a projection 72AA projecting away from the narrow section 71B in the X-direction. The projection 72AA is triangular in plan view. In the same manner as the second back-surface electrode 72A, the second back-surface electrode 72B includes a projection 72BA.

The third back-surface electrode 73A is electrically connected to the third front-surface electrode 63A (refer to FIG. 1). The third back-surface electrode 73A includes a portion that overlaps the second opposing section of the third front-surface electrode 63A in plan view. The third back-surface electrode 73A is located at a side of the second back-surface electrode 72A opposite to the narrow section 71B in the X-direction. The third back-surface electrode 73A extends in the Y-direction. The third back-surface electrode 73A is smaller than the second back-surface electrode 72A in the Y-direction. One of two opposite ends of the third back-surface electrode 73A in the Y-direction that is located closer to the fourth substrate side surface 26 is adjacent to the fourth substrate side surface 26 in the Y-direction. Thus, the distance between the third back-surface electrode 73A and the wide section 71A in the Y-direction is greater than the distance between the second back-surface electrode 72A and the wide section 71A in the Y-direction. The end of the second back-surface electrode 72A that is located closer to the wide section 71A in the Y-direction includes a cutout 73AA to avoid the projection 72AA. In the same manner as the third back-surface electrode 73A, the third back-surface electrode 73B includes a cutout 73BA to avoid the projection 72BA.

The fourth back-surface electrode 74A is electrically connected to the fourth front-surface electrode 64A (refer to FIG. 1). The fourth back-surface electrode 74A is located at a side of the third back-surface electrode 73A opposite to the second back-surface electrode 72A in the X-direction. The fourth back-surface electrode 74A extends in the Y-direction. The fourth back-surface electrode 74A is smaller than the third back-surface electrode 73A in the Y-direction. One of two opposite ends of the fourth back-surface electrode 74A in the Y-direction that is located closer to the fourth substrate side surface 26 is adjacent to the fourth substrate side surface 26 in the Y-direction. Thus, the distance between the fourth back-surface electrode 74A and the wide section 71A in the Y-direction is greater than the distance between the third back-surface electrode 73A and the wide section 71A in the Y-direction.

In the example shown in FIG. 2, in plan view, the first back-surface electrode 71 has a greater area than each of the second back-surface electrodes 72A and 72B, the third back-surface electrodes 73A and 73B, or the fourth back-surface electrodes 74A and 74B. In an example, the area of the first back-surface electrode 71 is greater than the combined total area of the second back-surface electrodes 72A and 72B, the third back-surface electrodes 73A and 73B, and the fourth back-surface electrodes 74A and 74B. In an example, the area of the first back-surface electrode 71 is greater than two times the combined total area of the second back-surface electrodes 72A and 72B, the third back-surface electrodes 73A and 73B, and the fourth back-surface electrodes 74A and 74B. In an example, the area of the first back-surface electrode 71 is greater than three times the combined total area of the second back-surface electrodes 72A and 72B, the third back-surface electrodes 73A and 73B, and the fourth back-surface electrodes 74A and 74B. In an example, the area of the first back-surface electrode 71 is greater than one-half of the area of the substrate back surface 22.

As shown in FIG. 4, the front-surface intermediate electrodes 28C are formed in the base member 27. More specifically, the front-surface intermediate electrodes 28C are sandwiched between the front-surface base member 27A and the intermediate base member 27C (refer to FIG. 3). The front-surface intermediate electrodes 28C include a first intermediate electrode 81, second intermediate electrodes 82A and 82B, third intermediate electrodes 83A and 83B, and fourth intermediate electrodes 84A and 84B that are spaced apart from one another.

The first intermediate electrode 81 is electrically connected to both the first front-surface electrode 61 (refer to FIG. 1) and the first back-surface electrode 71 (refer to FIG. 2). In plan view, the first intermediate electrode 81 has a greater area than each of the second intermediate electrodes 82A and 82B, the third intermediate electrodes 83A and 83B, or the fourth intermediate electrodes 84A and 84B. In plan view, the area of the first intermediate electrode 81 is greater than the combined total area of the second intermediate electrodes 82A and 82B, the third intermediate electrodes 83A and 83B, and the fourth intermediate electrodes 84A and 84B. In plan view, the area of the first intermediate electrode 81 is greater than one-half of the area of the base-member front surface of the intermediate base member 27C. In plan view, the area of the first intermediate electrode 81 is greater than two-thirds of the area of the base-member front surface of the intermediate base member 27C. In an example, the first intermediate electrode 81 is formed across substantially the entire base-member front surface of the intermediate base member 27C in plan view.

The first intermediate electrode 81 includes two first openings 81AA and 81AB, two second openings 81BA and 81BB, and two third openings 81CA and 81CB. The first openings 81AA and 81AB are symmetric with respect to the imaginary centerline VC. The second openings 81BA and 81BB are symmetric with respect to the imaginary centerline VC. The third openings 81CA and 81CB are symmetric with respect to the imaginary centerline VC. The first opening 81AA, the second opening 81BA, and the third opening 81CA are located closer to the first substrate side surface 23 than the imaginary centerline VC is. The first opening 81AB, the second opening 81BB, and the third opening 81CB are located closer to the second substrate side surface 24 than the imaginary centerline VC is.

The first openings 81AA and 81AB are located closer to the imaginary centerline VC than the second openings 81BA and 81BB and the third openings 81CA and 81CB are. As viewed in the X-direction, the second opening 81BA is located at a position that overlaps the first opening 81AA. The second opening 81BA is continuous with an end of the first opening 81AA in the X-direction that is located relatively close to the first substrate side surface 23. The third opening 81CA is located at a side of the second opening 81BA opposite to the first opening 81AA in the X-direction. The third opening 81CA is spaced apart from the first opening 81AA and the second opening 81BA. As viewed in the X-direction, the third opening 81CA is located at a position that overlaps the second opening 81BA. As viewed in the X-direction, the second opening 81BB is located at a position that overlaps the first opening 81AB. The second opening 81BB is continuous with an end of the second opening 81BA in the X-direction that is located relatively close to the second substrate side surface 24. The third opening 81CB is located at a side of the second opening 81BB opposite to the first opening 81AB in the X-direction. The third opening 81CB is spaced apart from the first opening 81AB and the second opening 81BB. As viewed in the X-direction, the third opening 81CB is located at a position that overlaps the second opening 81BB.

In plan view, the second intermediate electrode 82A is disposed in the first opening 81AA. In plan view, the second intermediate electrode 82B is disposed in the first opening 81AB. In plan view, the third intermediate electrode 83A is disposed in the second opening 81BA. In plan view, the third intermediate electrode 83B is disposed in the second opening 81BB. In plan view, the fourth intermediate electrode 84A is disposed in the third opening 81CA. In plan view, the fourth intermediate electrode 84B is disposed in the third opening 81CB.

The first openings 81AA and 81AB each have substantially a shape of a right trapezoid. Corners of the first openings 81AA and 81AB are curved. The second openings 81BA and 81BB are each elliptic and elongated in the Y-direction. As viewed in the X-direction, the second openings 81BA and 81BB each include a portion extending beyond a corresponding one of the first openings 81AA and 81AB toward the fourth substrate side surface 26. The third openings 81CA and 81CB are each elliptic and elongated in the X-direction.

The second intermediate electrode 82A and the second intermediate electrode 82B are symmetric with respect to the imaginary centerline VC. The third intermediate electrode 83A and the third intermediate electrode 83B are symmetric with respect to the imaginary centerline VC. The fourth intermediate electrode 84A and the fourth intermediate electrode 84B are symmetric with respect to the imaginary centerline VC. Hereinafter, the second intermediate electrode 82A, the third intermediate electrode 83A, and the fourth intermediate electrode 84A will be described, and description of the second intermediate electrode 82B, the third intermediate electrode 83B, and the fourth intermediate electrode 84B will be omitted.

The second intermediate electrode 82A has substantially a shape of a right trapezoid in plan view. The second intermediate electrode 82A is slightly smaller than the first opening 81AA. The third intermediate electrode 83A is elliptic in plan view, with major axis extending in the Y-direction and minor axis extending in the X-direction. The third intermediate electrode 83A is slightly smaller than the second opening 81BA. The fourth intermediate electrode 84A is elliptic in plan view, with major axis extending in the X-direction and minor axis extending in the Y-direction. The fourth intermediate electrode 84A is slightly smaller than the third opening 81CA. The back-surface intermediate electrodes 28D have the same configuration as the front-surface intermediate electrodes 28C. Hence, the back-surface intermediate electrodes 28D will not be described in detail.

As shown in FIGS. 1 to 4, the substrate 20 includes first vias 91A and 91B, second vias 92A and 92B, third vias 93A and 93B, and fourth vias 94A and 94B. The first vias 91A and 91B, the second vias 92A and 92B, the third vias 93A and 93B, and the fourth vias 94A and 94B extend through the base members 27A, 27B, and 27C, the front-surface intermediate electrodes 28C, and the back-surface intermediate electrodes 28D in the Z-direction. The first vias 91A and 91B, the second vias 92A and 92B, the third vias 93A and 93B, and the fourth vias 94A and 94B may extend through the front-surface electrodes 28A and the back-surface electrodes 28B in the Z-direction. The first vias 91A and 91B, the second vias 92A and 92B, the third vias 93A and 93B, and the fourth vias 94A and 94B are formed from, for example, a material containing one or more selected from Ti, TiN, Au, Ag, Cu, Al, and W.

Multiple first vias 91A and multiple first vias 91B are provided. The first vias 91A and the first vias 91B are electrically connected to the first front-surface electrode 61, the first intermediate electrode 81 of the front-surface intermediate electrode 28C, the first intermediate electrode 81 of the back-surface intermediate electrode 28D, and the first back-surface electrode 71. Therefore, the first front-surface electrode 61, the first intermediate electrode 81 of the front-surface intermediate electrode 28C, the first intermediate electrode 81 of the back-surface intermediate electrode 28D, and the first back-surface electrode 71 are electrically connected to each other.

As shown in FIG. 1, the first vias 91A are arranged in the third wiring portion 61C of the first front-surface electrode 61. More specifically, the first vias 91A are disposed in a central part of the third wiring portion 61C in the X-direction. Accordingly, in plan view, the first vias 91A are located at a position of the third wiring portion 61C that overlaps the semiconductor light-emitting element 30. The first vias 91A are aligned with and spaced apart from one another in the X-direction and the Y-direction. A greater number of first vias 91A are aligned in the X-direction than in the Y-direction. In plan view, the first vias 91A are formed in a region that is larger than the area of the semiconductor light-emitting element 30. Therefore, some of the first vias 91A are located outside the semiconductor light-emitting element 30 in plan view.

As shown in FIG. 1, the first vias 91B are arranged in the fourth wiring portion 61D of the first front-surface electrode 61. More specifically, the first vias 91B are disposed in a central part of the fourth wiring portion 61D in the X-direction. In the example shown in FIG. 1, the first vias 91B are arranged in the fourth wiring portion 61D and are located relatively close to the fourth substrate side surface 26. In other words, the first vias 91B are not arranged in one of two opposite ends of the fourth wiring portion 61D in the Y-direction that is located closer to the second front-surface electrodes 62A and 62B. The first vias 91B are aligned with and spaced apart from one another in the X-direction and the Y-direction. The quantity and layout of the first vias 91B are identical to those of the first vias 91A. In the example shown in FIG. 1, the first vias 91B are located at the same position as the first vias 91A in the X-direction.

As shown in FIGS. 1 to 4, multiple second vias 92A and multiple second vias 92B are provided. The second vias 92A and the second via 92B are less in number than the first via 91A and the first via 91B. The second vias 92A are electrically connected to the second front-surface electrode 62A, the second intermediate electrode 82A of the front-surface intermediate electrode 28C, the second intermediate electrode 82A of the back-surface intermediate electrode 28D, and the second back-surface electrode 72A. Therefore, the second front-surface electrode 62A, the second intermediate electrode 82A of the front-surface intermediate electrode 28C, the second intermediate electrode 82A of the back-surface intermediate electrode 28D, and the second back-surface electrode 72A are electrically connected to each other. The second via 92B is electrically connected to the second front-surface electrode 62B, the second intermediate electrode 82B of the front-surface intermediate electrode 28C, the second intermediate electrode 82B of the back-surface intermediate electrode 28D, and the second back-surface electrode 72B. Therefore, the second front-surface electrode 62B, the second intermediate electrode 82B of the front-surface intermediate electrode 28C, the second intermediate electrode 82B of the back-surface intermediate electrode 28D, and the second back-surface electrode 72B are electrically connected to each other.

As shown in FIG. 1, the second vias 92A are arranged in a portion of the wide section 62AB of the second front-surface electrode 62A that is located relatively close to the first substrate side surface 23. As shown in FIG. 2, the second vias 92A are arranged in one of the two opposite ends of the second back-surface electrode 72A in the Y-direction that is located closer to the wide section 71A of the first back-surface electrode 71. Some of the second vias 92A are disposed in the projection 72AA of the second back-surface electrode 72A.

As shown in FIG. 1, the second vias 92B are arranged in a portion of the wide section 62BB of the second front-surface electrode 62B that is located relatively close to the second substrate side surface 24. As shown in FIG. 2, the second vias 92B are arranged in one of two opposite ends of the second back-surface electrode 72B in the Y-direction that is located closer to the wide section 71A of the first back-surface electrode 71. Some of the second vias 92B are disposed in the projection 72BA of the second back-surface electrode 72B.

As shown in FIGS. 1 to 4, multiple third vias 93A and multiple third vias 93B are provided. The third via 93A and the third via 93B are less in number than the second via 92A and the second via 92B. The third vias 93A are electrically connected to the third front-surface electrode 63A, the third intermediate electrode 83A of the front-surface intermediate electrode 28C, the third intermediate electrode 83A of the back-surface intermediate electrode 28D, and the third back-surface electrode 73A. Therefore, the third front-surface electrode 63A, the third intermediate electrode 83A of the front-surface intermediate electrode 28C, the third intermediate electrode 83A of the back-surface intermediate electrode 28D, and the third back-surface electrode 73A are electrically connected to each other. The third vias 93B are electrically connected to the third front-surface electrode 63B, the third intermediate electrode 83B of the front-surface intermediate electrode 28C, the third intermediate electrode 83B of the back-surface intermediate electrode 28D, and the third back-surface electrode 73B. Therefore, the third front-surface electrode 63B, the third intermediate electrode 83B of the front-surface intermediate electrode 28C, the third intermediate electrode 83B of the back-surface intermediate electrode 28D, and the third back-surface electrode 73B are electrically connected to each other.

As shown in FIG. 1, the third vias 93A are arranged in the second opposing section of the third front-surface electrode 63A. The third vias 93A are located at the same position in the X-direction and are spaced apart from each other in the Y-direction. As shown in FIG. 2, the third vias 93A are arranged in one of the two opposite ends of the third back-surface electrode 73A in the Y-direction that is located closer to the wide section 71A of the first back-surface electrode 71. That is, the third vias 93A are arranged in the third back-surface electrode 73A and adjacent to the cutout 73AA in the X-direction.

As shown in FIG. 1, the third vias 93B are arranged in the second opposing section of the third front-surface electrode 63B. The third vias 93B are located at the same position in the X-direction and are spaced apart from each other in the Y-direction. As shown in FIG. 2, the third vias 93B are arranged in one of two opposite ends of the third back-surface electrode 73B in the Y-direction that is located closer to the wide section 71A of the first back-surface electrode 71. That is, the third vias 93B are located in the third back-surface electrode 73B and adjacent to the cutout 73BA in the X-direction.

As shown in FIGS. 1 to 4, multiple fourth vias 94A and multiple fourth vias 94B are provided. The fourth via 94A and the fourth via 94B are less in number than the second via 92A and the second via 92B. In an example, the fourth vias 94A and the fourth vias 94B are equal in number to the third vias 93A and the third vias 93B. The fourth vias 94A are electrically connected to the fourth front-surface electrode 64A, the fourth intermediate electrode 84A of the front-surface intermediate electrode 28C, the fourth intermediate electrode 84A of the back-surface intermediate electrode 28D, and the fourth back-surface electrode 74A. Therefore, the fourth front-surface electrode 64A, the fourth intermediate electrode 84A of the front-surface intermediate electrode 28C, the fourth intermediate electrode 84A of the back-surface intermediate electrode 28D, and the fourth back-surface electrode 74A are electrically connected to each other. The fourth vias 94B are electrically connected to the fourth front-surface electrode 64B, the fourth intermediate electrode 84B of the front-surface intermediate electrode 28C, the fourth intermediate electrode 84B of the back-surface intermediate electrode 28D, and the fourth back-surface electrode 74B. Therefore, the fourth front-surface electrode 64B, the fourth intermediate electrode 84B of the front-surface intermediate electrode 28C, the fourth intermediate electrode 84B of the back-surface intermediate electrode 28D, and the fourth back-surface electrode 74B are electrically connected to each other.

As shown in FIG. 1, the fourth vias 94A are arranged in the second opposing section of the fourth front-surface electrode 64A. The fourth vias 94A are located at the same position in the Y-direction and are spaced apart from each other in the X-direction. As shown in FIG. 2, the fourth vias 94A are arranged in one of the two opposite ends of the fourth back-surface electrode 74A in the Y-direction that is located closer to the wide section 71A of the first back-surface electrode 71.

As shown in FIG. 1, the fourth vias 94B are arranged in the second opposing section of the fourth front-surface electrode 64B. The fourth vias 94B are located at the same position in the Y-direction and are spaced apart from each other in the X-direction. As shown in FIG. 2, the fourth vias 94B are arranged in one of two opposite ends of the fourth back-surface electrode 74B in the Y-direction that is located closer to the wide section 71A of the first back-surface electrode 71.

As shown in FIG. 3, the substrate front surface 21 of the substrate 20 may be covered by a front surface resist 29A. Further, the substrate back surface 22 of the substrate 20 may be covered by a back surface resist 29B. The front surface resist 29A and the back surface resist 29B are formed from an insulative material. The insulative material for the front surface resist 29A and the back surface resist 29B may include insulative resin, such as an epoxy resin, a polyimide resin, or the like. Also, the front surface resist 29A and the back surface resist 29B may contain a filler, such as silica, alumina, or the like.

The front surface resist 29A has openings that expose parts of the front-surface electrodes 28A. The semiconductor light-emitting element 30, components of the first drive circuit 40, and components of the second drive circuit 50 are mounted on the front-surface electrode 28A exposed in the openings of the front surface resist 29A. In FIG. 1, the openings of the front surface resist 29A are indicated by double-dashed lines.

The back surface resist 29B has openings that expose parts of the back-surface electrodes 28B. The semiconductor light-emitting device 10 is mounted on the circuit board 900 shown in FIG. 6 by the back-surface electrode 28B exposed in the openings of the back surface resist 29B. In other words, the semiconductor light-emitting device 10 is a surface-mount type device configured to be mounted on a surface of the circuit board 900. In FIG. 2, the openings of the back surface resist 29B are indicated by double-dashed lines.

### Configuration and Layout of Semiconductor Light-Emitting Element, First Drive Circuit, and Second Drive Circuit

As shown in FIG. 1, the semiconductor light-emitting element 30, the first drive circuit 40, and the second drive circuit 50 are mounted on the front-surface electrodes 28A. The configuration and arrangement of the semiconductor light-emitting element 30, the first drive circuit 40, and the second drive circuit 50 will now be described in detail.

As shown in FIGS. 1 and 3, the semiconductor light-emitting element 30 is mounted on the third wiring portion 61C of the first front-surface electrode 61. More specifically, as shown in FIG. 3, the semiconductor light-emitting element 30 is bonded to the third wiring portion 61C by a conductive bonding material SD. The conductive bonding material SD may be solder paste, silver paste, gold paste, or copper paste.

As shown in FIG. 1, the semiconductor light-emitting element 30 is disposed in a central part of the third wiring portion 61C in the X-direction. The semiconductor light-emitting element 30 is shifted toward the third substrate side surface 25 with respect to the center of the third wiring portion 61C in the Y-direction.

The semiconductor light-emitting element 30 has a shape of a rectangular flat plate having a thickness-wise direction parallel to the Z-direction. The semiconductor light-emitting element 30 is rectangular in plan view, with long sides extending in the X-direction and short sides extending in the Y-direction. In an example, the dimension of the semiconductor light-emitting element 30 in the Y-direction is approximately one-half of the width WA3 of the third wiring portion 61C.

The semiconductor light-emitting element 30 is a laser diode configured to output a laser beam of a predetermined wavelength band. The semiconductor light-emitting element 30 serves as a light source of the semiconductor light-emitting device 10. The semiconductor light-emitting element 30 is, for example, an edge-emitting laser (EEL) element. The semiconductor light-emitting element 30 includes multiple (in the first embodiment, eight) light emitters 33. Each light emitter 33 is configured to emit a laser beam of a predetermined wavelength band. That is, the semiconductor light-emitting element 30 is a multi-array edge-emitting laser element. The laser beam may be a visible light ray. Alternatively, the laser beam may be a light ray having a longer wavelength than a visible light ray, such as an infrared ray or the like. The light emitters 33 are aligned in the X-direction.

As shown in FIG. 3, the semiconductor light-emitting element 30 includes an element front surface 31 and an element back surface 32 facing away from each other in the Z-direction.

As shown in FIG. 1, the element front surface 31 includes multiple (in the first embodiment, eight) element front-surface electrodes 34. The number of element front-surface electrodes 34 is determined in accordance with the number of light emitters 33. Specifically, the element front-surface electrodes 34 are respectively provided for the light emitters 33. The element front-surface electrodes 34 are separately electrically connected to the light emitters 33. The element front-surface electrodes 34 are located at the same position in the Y-direction and are spaced apart from each other in the X-direction. In an example, the element front-surface electrodes 34 define anode electrodes of the light emitters 33.

As shown in FIG. 3, an element back-surface electrode 35 is formed in the element back surface 32. In an example, the element back-surface electrode 35 is formed across the entire element back surface 32. The element back-surface electrode 35 is electrically connected to the light emitters 33. That is, the element back-surface electrode 35 serves as a common electrode of the light emitters 33. In an example, the element back-surface electrode 35 defines a common cathode electrode of the light emitters 33.

As shown in FIG. 1, the first drive circuit 40 is configured to drive four of the eight light emitters 33 that are located relatively close to the first substrate side surface 23. In the first embodiment, the four light emitters 33 driven by the first drive circuit 40 will be referred to as “first light emitter 33A”.

The second drive circuit 50 is configured to drive four of the eight light emitters 33 that are located relatively close to the second substrate side surface 24. In the first embodiment, the four light emitters 33 driven by the second drive circuit 50 will be referred to as “second light emitter 33B”.

Hereinafter, the element front-surface electrode 34 provided for the first light emitter 33A will be referred to as “first element front-surface electrode 34A”, and the element front-surface electrode 34 provided for the second light emitter 33B will be referred to as “second element front-surface electrode 34B”. In the first embodiment, the first element front-surface electrode 34A includes four element front-surface electrodes 34, and the second element front-surface electrode 34B includes the other four element front-surface electrodes 34. The first element front-surface electrode 34A defines “first anode electrode”, and the second element front-surface electrode 34B defines “second anode electrode”.

The first drive circuit 40 includes a first switching element 41 configured to control driving of the first light emitter 33A, and a first capacitor 42 configured to supply electric current to the first light emitter 33A. The first switching element 41 and the first capacitor 42 are spaced apart from the semiconductor light-emitting element 30.

The first switching element 41 is mounted on the second front-surface electrode 62A. More specifically, as shown in FIG. 3, the first switching element 41 is bonded to the second front-surface electrode 62A by the conductive bonding material SD.

As shown in FIG. 1, a main part of the first switching element 41 is mounted on the narrow section 62AA of the second front-surface electrode 62A. The first switching element 41 partially extends into the wide section 62AB of the second front-surface electrode 62A. That is, the first switching element 41 is arranged in the second front-surface electrode 62A and is located relatively close to the semiconductor light-emitting element 30. More specifically, the first switching element 41 is located at a position of the second front-surface electrode 62A that is relatively close to the first light emitter 33A of the semiconductor light-emitting element 30. As viewed in the Y-direction, the first switching element 41 is located at a position that overlaps the first light emitter 33A.

The first switching element 41 includes, for example, a vertical transistor. The first switching element 41 may include a transistor, such as a metal-oxide-semiconductor field-effect transistor (MOSFET), an insulated-gate bipolar transistor (IGBT), or the like. In the first embodiment, the first switching element 41 is a MOSFET.

The first switching element 41 has a shape of a rectangular flat plate having a thickness-wise direction parallel to the Z-direction. The first switching element 41 is square in plan view. The planar shape of the first switching element 41 may be changed.

As shown in FIG. 3, the first switching element 41 includes a second element front surface 41A and a second element back surface 41B facing away from each other in the Z-direction. The second element front surface 41A faces the same direction as the substrate front surface 21, and the second element back surface 41B faces the same direction as the substrate back surface 22. That is, the second element back surface 41B faces the second front-surface electrode 62A. The second element front surface 41A is an example of “the element front surface of the first switching element 41”, and the second element back surface 41B is an example of “the element back surface of the first switching element 41”.

As shown in FIG. 1, a source electrode 41S and a gate electrode 41G are formed in the second element front surface 41A. The source electrode 41S is formed in most of the second element front surface 41A. The gate electrode 41G is formed in an end of the second element front surface 41A in the X-direction that is located relatively close to the first substrate side surface 23. Further, the gate electrode 41G is disposed in a central part of the second element front surface 41A in the Y-direction. In an example, the gate electrode 41G is located in a recess formed by the source electrode 41S. In plan view, the gate electrode 41G opposes the first opposing section of the third front-surface electrode 63A in the X-direction. In plan view, the source electrode 41S includes a portion that opposes the first opposing section of the fourth front-surface electrode 64A in the X-direction.

As shown in FIG. 3, a drain electrode 41D is formed in the second element back surface 41B. The drain electrode 41D is formed across the entire second element back surface 41B. The drain electrode 41D is bonded to the second front-surface electrode 62A by the conductive bonding material SD. In other words, the drain electrode 41D of the first switching element 41 is mounted on the second front-surface electrode 62A.

As shown in FIG. 1, the source electrode 41S of the first switching element 41 is electrically connected to the first element front-surface electrodes 34A by separate wires W1. The source electrode 41S of the first switching element 41 is electrically connected to the fourth front-surface electrode 64A by a wire W2. The gate electrode 41G of the first switching element 41 is electrically connected to the third front-surface electrode 63A by a wire W3. The wires W1 to W3 are bonding wires formed by a wire bonder. The wires W1 to W3 are formed from a conductor containing, for example, Au, Al, Cu, or the like.

As shown in FIG. 1, in plan view, the semiconductor light-emitting element 30 is spaced apart from the first capacitor 42 in the Y-direction. The first capacitor 42 is located at a side of the first switching element 41 opposite to the semiconductor light-emitting element 30 in the Y-direction. In other words, in plan view, the first switching element 41 is arranged between the semiconductor light-emitting element 30 and the first capacitor 42 in the Y-direction.

Multiple (in the first embodiment, six) first capacitors 42 are provided. The first capacitors 42 are aligned with and spaced apart from each other in the X-direction. Each of the first capacitors 42 extends over the second front-surface electrode 62A and the fourth wiring portion 61D of the first front-surface electrode 61 in the Y-direction. The first capacitor 42 is mounted on the second front-surface electrode 62A and the fourth wiring portion 61D. More specifically, the first capacitor 42 is separately bonded to the second front-surface electrode 62A and the fourth wiring portion 61D by the conductive bonding material SD.

The first capacitor 42 includes a first electrode 42A and a second electrode 42B. The first capacitor 42 is arranged so that the first electrode 42A and the second electrode 42B are located at the same position in the X-direction and are spaced apart from each other in the Y-direction. In the example shown in FIG. 1, the first electrode 42A is bonded to the second front-surface electrode 62A by the conductive bonding material SD. Therefore, the first electrode 42A is electrically connected to the second front-surface electrode 62A. The second electrode 42B is bonded to the fourth wiring portion 61D by the conductive bonding material SD. Therefore, the second electrode 42B is electrically connected to the fourth wiring portion 61D (first front-surface electrode 61).

The first electrode 42A of the first capacitor 42 is disposed in the wide section 62AB of the second front-surface electrode 62A. In the example shown in FIG. 1, the first electrode 42A is disposed in an end of the wide section 62AB that is located relatively close to the fourth wiring portion 61D in the Y-direction. The first capacitors 42 are arranged side by side in the X-direction and are disposed across the entire wide section 62AB in the X-direction. In other words, the dimension of the wide section 62AB in the X-direction is set to allow for the side-by-side arrangement of the first capacitors 42 in the X-direction.

The second electrode 42B of the first capacitor 42 is disposed in one of two opposite ends of the fourth wiring portion 61D in the Y-direction that is located closer to the second front-surface electrode 62A. That is, the second electrode 42B of the first capacitor 42 is located closer to the second front-surface electrode 62A than the first vias 91B are in the Y-direction. As viewed in the Y-direction, some of the first capacitors 42 are located closer to the first substrate side surface 23 than the first switching element 41 is.

The second drive circuit 50 includes a second switching element 51 configured to control driving of the second light emitter 33B, and a second capacitor 52 configured to supply electric current to the second light emitter 33B.

The second switching element 51 is mounted on the narrow section 62BA of the second front-surface electrode 62B. The second switching element 51 is arranged on the second front-surface electrode 62B in the same manner as the first switching element 41 on the second front-surface electrode 62A. Therefore, in plan view, a distance D1 between the semiconductor light-emitting element 30 and the first switching element 41 in the Y-direction is equal to a distance D2 between the semiconductor light-emitting element 30 and the second switching element 51 in the Y-direction. The distance D1 and the distance D2 may be considered to be the same as long as a difference of the distance D1 and the distance D2 is, for example, within 10% of the distance D1.

The second switching element 51 includes a vertical transistor. The second switching element 51 includes a second element front surface 51A and a second element back surface (not shown) facing away from each other in the Z-direction. A source electrode 51S and a gate electrode 51G are formed in the second element front surface 51A. A drain electrode 51D (refer to FIG. 5) is formed in the second element back surface. The drain electrode 51D is mounted on the second front-surface electrode 62B. The second switching element 51 has the same configuration as the first switching element 41. Hence, the components of the second switching element 51 will not be described in detail. The second element front surface 51A is an example of “the element front surface of the second switching element 41”, and the second element back surface is an example of “the element back surface of the second switching element 41”.

As shown in FIG. 1, the source electrode 51S of the second switching element 51 is electrically connected to the second element front-surface electrodes 34B by separate wires W1. The source electrode 51S of the second switching element 51 is electrically connected to the third front-surface electrode 63B by a wire W2. The gate electrode 51G is electrically connected to the second front-surface electrode 62B by a wire W3.

In plan view, the source electrode 41S of the first switching element 41 includes a portion that opposes the first light emitter 33A in the Y-direction. The wires W1 separately connected to the four first element front-surface electrodes 34A are connected to one of two opposite ends of the source electrode 41S of the first switching element 41 in the Y-direction that is located closer to the first light emitter 33A. In plan view, the source electrode 51S of the second switching element 51 includes a portion that opposes the second light emitter 33B in the Y-direction. The wires W1 separately connected to the four second element front-surface electrodes 34B are connected to one of two opposite ends of the source electrode 51S of the second switching element 51 in the Y-direction that is located closer to the second light emitter 33B.

In an example, the four wires W1 separately connected to the four first element front-surface electrodes 34A have the same length. In an example, the four wires W1 separately connected to the four second element front-surface electrodes 34B have the same length. The number of wires W1 connected to each of the first element front-surface electrodes 34A may be changed. In an example, four wires W1 may be connected to each of the first element front-surface electrodes 34A. In this case, sixteen wires W1 are connected to the first light emitter 33A, and sixteen wires W1 are connected to the second light emitter 33B.

The distance D1 between the semiconductor light-emitting element 30 and the first switching element 41 in the Y-direction is equal to the distance D2 between the semiconductor light-emitting element 30 and the second switching element 51 in the Y-direction. Therefore, in plan view, the total length of the four wires W1 separately connected to the four first element front-surface electrodes 34A may be adjusted to be identical to the total length of the four wires W1 separately connected to the four second element front-surface electrodes 34B.

As shown in FIG. 1, in plan view, the semiconductor light-emitting element 30 is spaced apart from the second capacitor 52 in the Y-direction. The second capacitor 52 is located at a side of the second switching element 51 opposite to the semiconductor light-emitting element 30 in the Y-direction. In other words, in plan view, the second switching element 51 is arranged between the semiconductor light-emitting element 30 and the second capacitor 52 in the Y-direction.

Multiple (in the first embodiment, six) second capacitors 52 are provided. The second capacitors 52 are aligned with and spaced apart from each other in the X-direction. Each of the second capacitors 52 extends over the second front-surface electrode 62B and the fourth wiring portion 61D of the first front-surface electrode 61 in the Y-direction. The second capacitor 52 is mounted on the second front-surface electrode 62B and the fourth wiring portion 61D. More specifically, the second capacitor 52 includes a first electrode 52A and a second electrode 52B. Although not shown in the drawings, the first electrode 52A is bonded to the second front-surface electrode 62B by the conductive bonding material SD. Therefore, the first electrode 52A is electrically connected to the second front-surface electrode 62B. The second electrode 52B is bonded to the fourth wiring portion 61D by the conductive bonding material SD. Therefore, the second electrode 52B is electrically connected to the fourth wiring portion 61D (first front-surface electrode 61). The second capacitors 52 are arranged in the same manner as the first capacitors 42. Hence, the layout of the second capacitors 52 will not be described in detail.

The semiconductor light-emitting device 10 further includes a first protection diode 101 and a second protection diode 102.

The first protection diode 101 is configured to protect the first light emitter 33A of the semiconductor light-emitting element 30. The first protection diode 101 is located closer to the first substrate side surface 23 than the semiconductor light-emitting element 30, the first switching element 41, and the first capacitors 42 are in the X-direction. The first protection diode 101 is located at a side of the first switching element 41 opposite to the semiconductor light-emitting element 30 in the Y-direction. The first protection diode 101 is located at the same position as the first capacitors 42 in the Y-direction. The first protection diode 101 extends over the fourth front-surface electrode 64A and the fourth wiring portion 61D of the first front-surface electrode 61 in the Y-direction. The first protection diode 101 is mounted on the fourth front-surface electrode 64A and the first front-surface electrode 61. More specifically, the first protection diode 101 is separately bonded to the fourth front-surface electrode 64A and the first front-surface electrode 61 by the conductive bonding material SD.

The first protection diode 101 is connected in antiparallel to the first light emitter 33A. More specifically, the first protection diode 101 includes a first anode electrode 101A and a first cathode electrode 101B. The first protection diode 101 is arranged so that the first anode electrode 101A and the first cathode electrode 101B are located at the same position in the X-direction and are spaced apart from each other in the Y-direction. The first anode electrode 101A is bonded to the first front-surface electrode 61 by the conductive bonding material SD (not shown). The first anode electrode 101A is disposed in the fourth wiring portion 61D of the first front-surface electrode 61. Therefore, the first anode electrode 101A is electrically connected to the element back-surface electrode 35 of the semiconductor light-emitting element 30 through the first front-surface electrode 61. The first cathode electrode 101B is bonded to the fourth front-surface electrode 64A by the conductive bonding material SD (not shown). The first cathode electrode 101B is disposed in the second opposing section of the fourth front-surface electrode 64A. Therefore, the first cathode electrode 101B is electrically connected to the first element front-surface electrodes 34A, which correspond to the first light emitter 33A of the semiconductor light-emitting element 30, through the wire W2, the source electrode 41S of the first switching element 41, and the wires W1.

The second protection diode 102 is configured to protect the second light emitter 33B of the semiconductor light-emitting element 30. The second protection diode 102 is located closer to the second substrate side surface 24 than the semiconductor light-emitting element 30, the second switching element 51, and the second capacitors 52 are in the X-direction. The second protection diode 102 is located at a side of the second switching element 51 opposite to the semiconductor light-emitting element 30 in the Y-direction. The second protection diode 102 is located at the same position as the second capacitors 52 in the Y-direction. The second protection diode 102 extends over the fourth front-surface electrode 64B and the fourth wiring portion 61D of the first front-surface electrode 61 in the Y-direction. The second protection diode 102 is mounted on the fourth front-surface electrode 64B and the first front-surface electrode 61. The second protection diode 102 is arranged in the same manner as the first protection diode 101.

The second protection diode 102 is connected in antiparallel to the second light emitter 33B. More specifically, the second protection diode 102 includes a second anode electrode 102A and a second cathode electrode 102B. The second anode electrode 102A is bonded to the fourth wiring portion 61D of the first front-surface electrode 61 by the conductive bonding material SD. Therefore, the second anode electrode 102A is electrically connected to the element back-surface electrode 35 of the semiconductor light-emitting element 30 through the first front-surface electrode 61. The second cathode electrode 102B is bonded to the second opposing section of the fourth front-surface electrode 64B by the conductive bonding material SD. Therefore, the second cathode electrode 102B is electrically connected to the second element front-surface electrodes 34B, which correspond to the second light emitter 33B of the semiconductor light-emitting element 30, through the wire W2, the source electrode 51S of the second switching element 51, and the wires W1.

### Circuitry of Semiconductor Light-Emitting Device

As shown in FIG. 5, the light-emitting system 800 including the semiconductor light-emitting device 10 includes a DC power supply 801, a capacitor 802 connected in parallel to the DC power supply 801, a current limiting resistor 803, reverse current protection diodes 804A and 804B, a gate driver integrated circuit (IC) 805, a pulse generator 806, and a control power supply 807.

The current limiting resistor 803 includes a first terminal electrically connected to the positive electrode of the DC power supply 801. Further, the current limiting resistor 803 includes a second terminal electrically connected to the anodes of the reverse current protection diodes 804A and 804B. The cathode of the reverse current protection diode 804A is electrically connected to the second back-surface electrode 72A, and the cathode of the reverse current protection diode 804B is electrically connected to the second back-surface electrode 72B.

The gate driver IC 805 is separately electrically connected to the gate electrode 41G of the first switching element 41 and the gate electrode 51G of the second switching element 51. That is, the gate driver IC 805 can control the first switching element 41 and the second switching element 51 separately. In the first embodiment, the gate driver IC 805 includes an isolated gate driver. The gate driver IC 805 is separately electrically connected to the third back-surface electrodes 73A and 73B.

The pulse generator 806 and the control power supply 807 are electrically connected to the gate driver IC 805. The pulse generator 806 is configured to output a pulse signal for controlling the first switching element 41 and the second switching element 51 to the gate driver IC 805. The control power supply 807 is for operating the gate driver IC 805. The control power supply 807 is configured to apply operation voltage to the gate driver IC 805.

The negative electrode of the DC power supply 801, the capacitor 802, the pulse generator 806, and the negative electrode of the control power supply 807 are each electrically connected to the first back-surface electrode 71. Further, the negative electrode of the DC power supply 801, the capacitor 802, the pulse generator 806, and the negative electrode of the control power supply 807 are each grounded. Accordingly, the first back-surface electrode 71 is grounded.

In the semiconductor light-emitting device 10, the cathode of the reverse current protection diode 804A is electrically connected to both the drain electrode 41D of the first switching element 41 and the first electrode 42A of the first capacitor 42 through the second back-surface electrode 72A. The cathode of the reverse current protection diode 804B is electrically connected to both the drain electrode 51D of the second switching element 51 and the first electrode 52A of the second capacitor 52 through the second back-surface electrode 72B.

The source electrode 41S of the first switching element 41 is electrically connected to the first element front-surface electrode 34A (first anode electrode), which corresponds to the first light emitter 33A of the semiconductor light-emitting element 30, and the first cathode electrode 101B of the first protection diode 101. The second electrode 42B of the first capacitor 42, the element back-surface electrode 35 (cathode), which corresponds to the first light emitter 33A of the semiconductor light-emitting element 30, and the first anode electrode 101A of the first protection diode 101 are each electrically connected to the first back-surface electrode 71 through the first front-surface electrode 61.

The source electrode 51S of the second switching element 51 is electrically connected to the second element front-surface electrode 34B (second anode electrode), which corresponds to the second light emitter 33B of the semiconductor light-emitting element 30, and the second cathode electrode 102B of the second protection diode 102. The second electrode 52B of the second capacitor 52, the element back-surface electrode 35 (cathode), which corresponds to the second light emitter 33B of the semiconductor light-emitting element 30, and the second anode electrode 102A of the second protection diode 102 are each electrically connected to the first back-surface electrode 71 through the first front-surface electrode 61. In this manner, the first front-surface electrode 61 serves as ground wiring. The first back-surface electrode 71 electrically connected to the first front-surface electrode 61 serves as a ground terminal.

With the semiconductor light-emitting device 10, when the first switching element 41 is off, the first capacitor 42 is charged by the DC power supply 801. When the first switching element 41 is shifted from an off-state to an on-state, electric current flows from the first capacitor 42 through the first switching element 41 to the first light emitter 33A of the semiconductor light-emitting element 30. As a result, the first light emitter 33A emits laser in pulses. When the second switching element 51 is off, the second capacitor 52 is charged by the DC power supply 801. When the second switching element 51 is shifted from an off-state to an on-state, electric current flows from the second capacitor 52 through the second switching element 51 to the second light emitter 33B of the semiconductor light-emitting element 30. As a result, the second light emitter 33B emits laser in pulses. In this manner, the first drive circuit 40 including the first switching element 41 and the first capacitor 42 controls driving of the first light emitter 33A, and the second drive circuit 50 including the second switching element 51 and the second capacitor 52 controls driving of the second light emitter 33B. That is, the first drive circuit 40 and the second drive circuit 50 control the first light emitter 33A and the second light emitter 33B separately.

In an example, the first drive circuit 40 and the second drive circuit 50 sequentially drive the first light emitter 33A and the second light emitter 33B. In this case, pulsed light emission by the first light emitter 33A and the second light emitter 33B may be adjusted to shorten a pulse interval of the semiconductor light-emitting element 30 as compared to a semiconductor light-emitting device including, for example, a single light emitter. Therefore, the number of pulses per unit time is increased. In addition, the first light emitter 33A and the second light emitter 33B alternately emit light. This reduces generation of heat in the semiconductor light-emitting element 30 as compared to a semiconductor light-emitting device including a single light emitter.

Furthermore, the first light emitter 33A and the second light emitter 33B each include multiple (in the first embodiment, four) light emitters 33. This increases average output power of the laser beam as compared to a semiconductor light-emitting device including a single light emitter.

### Operation

The operation of the semiconductor light-emitting device 10 in accordance with the first embodiment will now be described.

The semiconductor light-emitting device 10 includes the semiconductor light-emitting element 30 having multiple (in the first embodiment, eight) light emitters 33 in order to increase output of the semiconductor light-emitting element. As the output of the semiconductor light-emitting element 30 increases, an amount of heat generated in the semiconductor light-emitting element 30 also increases. Accordingly, there is a need for a structure that dissipates heat of the semiconductor light-emitting element 30 to be included in the semiconductor light-emitting device 10.

The semiconductor light-emitting device 10 of the first embodiment includes the semiconductor light-emitting element 30 mounted on the first front-surface electrode 61 that is formed in the substrate front surface 21. In addition, the back-surface electrodes 28B are formed in the substrate back surface 22 and configured for mounting the semiconductor light-emitting device 10. As shown in FIG. 6, when the semiconductor light-emitting device 10 is mounted on the circuit board 900, the back-surface electrodes 28B are bonded to wiring 901 of the circuit board 900 by, for example, a conductive bonding material SDA. The conductive bonding material SDA may be any one of solder paste, copper paste, gold paste, or silver paste.

In particular, as shown in FIG. 6, the first back-surface electrode 71, which is formed in most of the substrate back surface 22, is bonded to the wiring 901 of the circuit board 900 by the conductive bonding material SDA. Accordingly, the heat of the semiconductor light-emitting element 30 is transferred through the conductive bonding material SD bonded to the element back-surface electrode 35, the first front-surface electrode 61, the first vias 91A, the first back-surface electrode 71, and the conductive bonding material SDA to the wiring 901. The first back-surface electrode 71, the conductive bonding material SDA, and the wiring 901 are bonded to each other over a relatively large area as compared to a configuration in which a CAN type package semiconductor laser device is mounted on a circuit board by multiple leads. This facilitates transfer of heat from the semiconductor light-emitting element 30 to the circuit board 900.

The semiconductor light-emitting device 10 may be used in a laser system for three-dimensional distance measurement, such as LiDAR (“light detection and ranging”, or “laser imaging detection and ranging”). The semiconductor light-emitting device 10 may also be used in a laser system for two-dimensional distance measurement.

In LiDAR, it is desired that the field of view is increased and the resolution is improved for measurements of longer ranges. In response to such a need, a drive circuit may be provided to separately drive the first light emitter 33A and the second light emitter 33B, which serve as channels. Specifically, the first light emitter 33A and the second light emitter 33B are controlled to emit light at different times. This shortens the pulse interval of the laser beam emitted from the semiconductor light-emitting element 30, and increases the number of laser beam emissions of the semiconductor light-emitting element 30 per unit time.

If such a drive circuit is arranged outside the semiconductor light-emitting device 10, the drive circuit and the first light emitter 33A may form a looped first current path that is relatively long, and the drive circuit and the second light emitter 33B may form a looped second current path that is relatively long. As a result, the inductance caused by these current paths may be increased. In this case, it is difficult to further shorten the pulse interval of the laser beam emitted from the first light emitter 33A and the second light emitter 33B. In addition, when the first current path and the second current path are relatively long, a difference in length between the first current path and the second current path may be relatively large. As a result, the pulse width of laser beam emitted from the first light emitter 33A may vary from the pulse width of laser beam emitted from the second light emitter 33B.

The semiconductor light-emitting device 10 includes the first drive circuit 40 and the second drive circuit 50 configured to drive the first light emitter 33A and the second light emitter 33B separately. In other words, the semiconductor light-emitting device 10 incorporates the first drive circuit 40 and the second drive circuit 50. As shown in FIG. 7, electric current flows through the first electrode 42A of the first capacitor 42, the second front-surface electrode 62A, the drain electrode 41D of the first switching element 41, the source electrode 41S, the wire W1, the first element front-surface electrode 34A, the element back-surface electrode 35, the first front-surface electrode 61, the first intermediate electrode 81 of the front-surface intermediate electrode 28C, and the second electrode 42B of the first capacitor 42 in this order. That is, the first light emitter 33A and the first drive circuit 40 form the looped first current path. Although not shown in the drawings, the second light emitter 33B and the second drive circuit 50 form the looped second conductive path in the same manner as the first current path. The looped first current path formed by the first light emitter 33A and the first drive circuit 40 and the looped second current path formed by the second light emitter 33B and the second drive circuit 50 are shorter as compared to a configuration in which the drive circuits are arranged outside the semiconductor light-emitting device 10. Therefore, the inductance caused by the lengths of the first current path and the second current path is reduced. In addition, the lengths of the first current path and the second current path are both relatively short. Therefore, a difference in inductance caused by the difference in length between the first current path and the second current path is relatively small. This shortens the pulse width of laser beam emitted from the first light emitter 33A and the pulse width of laser beam emitted from the second light emitter 33B, and reduces the difference in pulse width between the laser beam emitted from the first light emitter 33A and the laser beam emitted from the second light emitter 33B. In an example, the pulse width of the laser beam emitted from the first light emitter 33A and the pulse width of the laser beam emitted from the second light emitter 33B are each 4 ns or less. In an example, an absolute value of the difference in pulse width between the laser beam emitted from the first light emitter 33A and the laser beam emitted from the second light emitter 33B is 10% or less.

### Advantages

The semiconductor light-emitting device 10 of the first embodiment has the following advantages.

(1-1) The semiconductor light-emitting device 10 includes the substrate 20, the front-surface electrodes 28A, the back-surface electrodes 28B, the semiconductor light-emitting element 30, the first drive circuit 40, and the second drive circuit 50. The substrate 20 includes the substrate front surface 21 and the substrate back surface 22 facing away from the substrate front surface 21. The front-surface electrodes 28A are formed in the substrate front surface 21. The back-surface electrodes 28B are formed in the substrate back surface 22 and are configured for mounting the semiconductor light-emitting device 10. The semiconductor light-emitting element 30 includes the first light emitter 33A, the second light emitter 33B, the first element front-surface electrode 34A electrically connected to the first light emitter 33A, the second element front-surface electrode 34B electrically connected to the second light emitter, and the element back-surface electrode 35 electrically connected to both the first light emitter 33A and the second light emitter 33B. The first drive circuit 40 is electrically connected to the first element front-surface electrode 34A and is configured to drive the first light emitter 33A. The second drive circuit 50 is electrically connected to the second element front-surface electrode 34B and is configured to drive the second light emitter 33B. The element back-surface electrode 35 of the semiconductor light-emitting element 30, the first drive circuit 40, and the second drive circuit 50 are mounted on the front-surface electrodes 28A.

With this configuration, the semiconductor light-emitting element 30 is mounted on the front-surface electrode 28A, and the back-surface electrode 28B is formed in the substrate back surface 22. This facilitates transfer of heat from the semiconductor light-emitting element 30 through the front-surface electrode 28A and the back-surface electrode 28B to the outside of the semiconductor light-emitting device 10. Accordingly, the temperature of the semiconductor light-emitting element 30 will not become excessively high. In addition, the semiconductor light-emitting device 10 includes the first drive circuit 40 and the second drive circuit 50. Therefore, the first current path between the semiconductor light-emitting element 30 and the first drive circuit 40 and the second current path between the semiconductor light-emitting element 30 and the second drive circuit 50 are shorter as compared to a configuration in which the first drive circuit 40 and the second drive circuit 50 are arranged outside the semiconductor light-emitting device 10. This decreases the inductance caused by the lengths of these current paths, and reduces the difference in inductance between the first current path and the second current path. As a result, the pulse width of laser beam emitted from the first light emitter 33A and the pulse width of laser beam emitted from the second light emitter 33B are shortened, and the difference in pulse width between the laser beam emitted from the first light emitter 33A and the laser beam emitted from the second light emitter 33B is reduced.

(1-2) The first drive circuit 40 includes the first switching element 41 configured to control driving of the first light emitter 33A, and the first capacitor 42 configured to supply electric current to the first light emitter 33A. The second drive circuit 50 includes the second switching element 51 configured to control driving of the second light emitter 33B, and the second capacitor 52 configured to supply electric current to the second light emitter 33B.

With this configuration, the first light emitter 33A of the semiconductor light-emitting element 30, the first switching element 41, and the first capacitor 42 form the looped first current path inside the semiconductor light-emitting device 10. In this case, the first current path is shorter than when the first switching element 41 and the first capacitor 42 are both arranged outside the semiconductor light-emitting device 10, thereby reducing the inductance caused by the length of the first current path. Further, the second light emitter 33B of the semiconductor light-emitting element 30, the second switching element 51, and the second capacitor 52 form the looped second current path inside the semiconductor light-emitting device 10. In this case, the second current path is shorter than when the second switching element 51 and the second capacitor 52 are both arranged outside the semiconductor light-emitting device 10, thereby reducing the inductance caused by the length of the second current path. Since the first current path and the second current path are both relatively short, a difference in length between the first current path and the second current path may be decreased. This reduces a difference in inductance between the first current path and the second current path.

(1-3) In plan view, the semiconductor light-emitting element 30 and the first capacitor 42 are spaced apart from each other in the Y-direction. In plan view, the first switching element 41 is arranged between the semiconductor light-emitting element 30 and the first capacitor 42 in the Y-direction. In plan view, the semiconductor light-emitting element 30 and the second capacitor 52 are spaced apart from each other in the Y-direction. In plan view, the second switching element 51 is arranged between the semiconductor light-emitting element 30 and the second capacitor 52 in the Y-direction.

With this configuration, the looped first current path formed by the first light emitter 33A of the semiconductor light-emitting element 30, the first switching element 41, and the first capacitor 42 is shorter as compared to a configuration in which the first switching element 41 is located at a side of the first capacitor 42 opposite to the semiconductor light-emitting element 30 in the Y-direction. Further, the looped second current path formed by the second light emitter 33B of the semiconductor light-emitting element 30, the second switching element 51, and the second capacitor 52 is shorter as compared to a configuration in which the second switching element 51 is located at a side of the second capacitor 52 opposite to the semiconductor light-emitting element 30 in the Y-direction.

(1-4) The distance D1 between the semiconductor light-emitting element 30 and the first switching element 41 in the Y-direction is equal to the distance D2 between the semiconductor light-emitting element 30 and the second switching element 51 in the Y-direction.

With this configuration, the current path between the semiconductor light-emitting element 30 and the first switching element 41 is equal in length to the current path between the semiconductor light-emitting element 30 and the second switching element 51. This reduces a difference in length between the looped first current path formed by the first light emitter 33A of the semiconductor light-emitting element 30, the first switching element 41, and the first capacitor 42 and the looped second current path formed by the second light emitter 33B of the semiconductor light-emitting element 30, the second switching element 51, and the second capacitor 52.

(1-5) The first capacitor 42 is one of first capacitors 42, and the second capacitor 52 is one of second capacitors 52. The first capacitors 42 are connected in parallel to each other. The second capacitors 52 are connected in parallel to each other.

With this configuration, the first capacitors 42 are connected in parallel to each other, so that the total inductance of the first capacitors 42 is less than the inductance of each of the first capacitors 42. Further, the second capacitors 52 are connected in parallel to each other, so that the total inductance of the second capacitors 52 is less than the inductance of each of the second capacitors 52.

(1-6) The first capacitors 42 are aligned with and spaced apart from each other in the X-direction. The second capacitors 52 are aligned with and spaced apart from each other in the X-direction.

With this configuration, in plan view, the first capacitors 42 are aligned in a direction (X-direction) orthogonal to the direction (Y-direction) in which the semiconductor light-emitting element 30, the first switching element 41, and the first capacitor 42 are arranged. Therefore, the looped first current path formed by the first light emitter 33A of the semiconductor light-emitting element 30, the first switching element 41, and the first capacitor 42 is relatively short. In plan view, the second capacitors 52 are aligned in a direction (X-direction) orthogonal to the direction (Y-direction) in which the semiconductor light-emitting element 30, the second switching element 51, and the second capacitor 52 are arranged. Therefore, the looped second current path formed by the second light emitter 33B of the semiconductor light-emitting element 30, the second switching element 51, and the second capacitor 52 is relatively short.

(1-7) The semiconductor light-emitting device 10 further includes the first protection diode 101 connected in antiparallel to the first light emitter 33A, and the second protection diode 102 connected in antiparallel to the second light emitter 33B.

With this configuration, the first protection diode 101 and the second protection diode 102 suppress an excessive reverse bias caused by a resonant current from being applied to the first light emitter 33A and the second light emitter 33B. As a result of such suppression, a peak light output of the semiconductor light-emitting element 30 may be increased.

(1-8) The first protection diode 101 is located at a side of the first switching element 41 opposite to the semiconductor light-emitting element 30 in the Y-direction. The second protection diode 102 is located at a side of the second switching element 51 opposite to the semiconductor light-emitting element 30 in the Y-direction. The first protection diode 101 is spaced apart from the first capacitor 42 in the X-direction. The second protection diode 102 is spaced apart from the second capacitor 52 in the X-direction.

With this configuration, the looped first current path formed by the semiconductor light-emitting element 30, the first switching element 41, and the first capacitor 42 is shorter as compared to a configuration in which the first protection diode 101 is arranged between the semiconductor light-emitting element 30 and the first switching element 41 or between the first switching element 41 and the first capacitor 42. Further, the looped second current path formed by the semiconductor light-emitting element 30, the second switching element 51, and the second capacitor 52 is shorter as compared to a configuration in which the second protection diode 102 is arranged between the semiconductor light-emitting element 30 and the second switching element 51 or between the second switching element 51 and the second capacitor 52.

(1-9) In plan view, the first front-surface electrode 61 has a greater area than each of the second front-surface electrodes 62A and 62B, the third front-surface electrodes 63A and 63B, or the fourth front-surface electrodes 64A and 64B.

This configuration facilitates transfer of heat from the semiconductor light-emitting element 30, which is mounted on the first front-surface electrode 61, to the first front-surface electrode 61. Accordingly, the temperature of the semiconductor light-emitting element 30 will not become excessively high.

(1-10) In plan view, the area of the first front-surface electrode 61 is greater than the combined total area of the second front-surface electrodes 62A and 62B, the third front-surface electrodes 63A and 63B, and the fourth front-surface electrodes 64A and 64B.

This configuration further facilitates transfer of heat from the semiconductor light-emitting element 30, which is mounted on the first front-surface electrode 61, to the first front-surface electrode 61. Accordingly, the temperature of the semiconductor light-emitting element 30 will not become excessively high.

(1-11) In plan view, the first back-surface electrode 71 has a greater area than each of the second back-surface electrodes 72A and 72B, the third back-surface electrodes 73A and 73B, or the fourth back-surface electrodes 74A and 74B.

With this configuration, the first back-surface electrode 71 has a relatively large heat capacity. Therefore, the heat of the semiconductor light-emitting element 30 is readily transferred to the first back-surface electrode 71. In addition, when the semiconductor light-emitting device 10 is mounted on the circuit board 900, the first back-surface electrode 71 and the circuit board 900 are bonded to each other over a relatively large area, so that the heat of the semiconductor light-emitting element 30 is readily transferred through the first back-surface electrode 71 to the circuit board 900. As a result, the temperature of the semiconductor light-emitting element 30 will not become excessively high.

(1-12) In plan view, the area of the first back-surface electrode 71 is greater than the combined total area of the second back-surface electrodes 72A and 72B, the third back-surface electrodes 73A and 73B, and the fourth back-surface electrodes 74A and 74B.

This configuration increases the heat capacity of the first back-surface electrode 71, thereby further facilitating transfer of heat from the semiconductor light-emitting element 30 to the first back-surface electrode 71. In addition, when the semiconductor light-emitting device 10 is mounted on the circuit board 900, the first back-surface electrode 71 and the circuit board 900 are bonded to each other over a relatively large area, so that the heat of the semiconductor light-emitting element 30 is more readily transferred through the first back-surface electrode 71 to the circuit board 900. As a result, the temperature of the semiconductor light-emitting element 30 will not become excessively high.

(1-13) In plan view, the first intermediate electrode 81 has a greater area than each of the second intermediate electrodes 82A and 82B, the third intermediate electrodes 83A and 83B, or the fourth intermediate electrodes 84A and 84B.

With this configuration, the first intermediate electrode 81 has a relatively large heat capacity. Therefore, the heat of the semiconductor light-emitting element 30 is readily transferred to the first intermediate electrode 81. Accordingly, the temperature of the semiconductor light-emitting element 30 will not become excessively high.

(1-14) In plan view, the area of the first intermediate electrode 81 is greater than the combined total area of the second intermediate electrodes 82A and 82B, the third intermediate electrodes 83A and 83B, and the fourth intermediate electrodes 84A and 84B.

This configuration increases the heat capacity of the first intermediate electrode 81, thereby further facilitating transfer of heat from the semiconductor light-emitting element 30 to the first intermediate electrode 81. Accordingly, the temperature of the semiconductor light-emitting element 30 will not become excessively high.

(1-15) The element back-surface electrode 35 of the semiconductor light-emitting element 30 is electrically connected to the first front-surface electrode 61. The drain electrode 41D of the first switching element 41 is electrically connected to the second front-surface electrode 62A. The source electrode 41S of the first switching element 41 is electrically connected to the first element front-surface electrode 34A. The first electrode 42A of the first capacitor 42 is electrically connected to the second front-surface electrode 62A. The second electrode 42B of the first capacitor 42 is electrically connected to the first front-surface electrode 61. The drain electrode 51D of the second switching element 51 is electrically connected to the second front-surface electrode 62B. The source electrode 51S of the second switching element 51 is electrically connected to the second element front-surface electrode 34B. The first electrode 52A of the second capacitor 52 is electrically connected to the second front-surface electrode 62B. The second electrode 52B of the second capacitor 52 is electrically connected to the first front-surface electrode 61. The first intermediate electrode 81 is electrically connected to the first front-surface electrode 61.

With this configuration, the first intermediate electrode 81 forms part of the loop of the first current path, in which electric current flows through the first electrode 42A of the first capacitor 42, the drain electrode 41D of the first switching element 41, the source electrode 41S, the first element front-surface electrode 34A of the semiconductor light-emitting element 30, the element back-surface electrode 35, and the second electrode 42B of the first capacitor 42 in this order. This decreases the area of the loop of the first current path, thereby reducing the inductance of the first current path. Further, the first intermediate electrode 81 forms part of the loop of the second current path, in which electric current flows through the first electrode 52A of the second capacitor 52, the drain electrode 51D of the second switching element 51, the source electrode 51S, the second element front-surface electrode 34B of the semiconductor light-emitting element 30, the element back-surface electrode 35, and the second electrode 52B of the second capacitor 52 in this order. This decreases the area of the loop of the second current path, thereby reducing the inductance of the second current path.

(1-16) In plan view, the first vias 91A are located at a position that overlaps the semiconductor light-emitting element 30.

With this configuration, the heat of the semiconductor light-emitting element 30 is readily transferred to the first intermediate electrode 81 and the first back-surface electrode 71. Accordingly, the temperature of the semiconductor light-emitting element 30 will not become excessively high.

(1-17) As viewed in the Y-direction, the first vias 91B are formed in a region that overlaps the region in which the first vias 91A are formed.

With this configuration, the first intermediate electrode 81 forms part of the loop of the first current path, in which electric current flows through the first electrode 42A of the first capacitor 42, the drain electrode 41D of the first switching element 41, the source electrode 41S, the first element front-surface electrode 34A of the semiconductor light-emitting element 30, the element back-surface electrode 35, and the second electrode 42B of the first capacitor 42 in this order. The part of the first current path formed by the first intermediate electrode 81 extends in the Y-direction. This decreases the area of the loop of the first current path, thereby reducing the inductance of the first current path. Further, the first intermediate electrode 81 forms part of the loop of the second current path, in which electric current flows through the first electrode 52A of the second capacitor 52, the drain electrode 51D of the second switching element 51, the source electrode 51S, the second element front-surface electrode 34B of the semiconductor light-emitting element 30, the element back-surface electrode 35, and the second electrode 52B of the second capacitor 52 in this order. The part of the loop of the second current path formed by the first intermediate electrode 81 extends in the Y-direction. This decreases the area of the loop of the second current path, thereby reducing the inductance of the second current path.

(1-18) The second front-surface electrode 62A includes the narrow section 62AA and the wide section 62AB. The first switching element 41 is mounted on the narrow section 62AA. The third front-surface electrode 63A and the fourth front-surface electrode 64A each have a portion adjacent to the narrow section 62AA of the second front-surface electrode 62A in the X-direction. The second front-surface electrode 62B includes the narrow section 62BA and the wide section 62BB. The second switching element 51 is mounted on the narrow section 62BA. The third front-surface electrode 63B and the fourth front-surface electrode 64B each have a portion adjacent to the narrow section 62BA of the second front-surface electrode 62B in the X-direction.

With this configuration, the wire W2 connecting the source electrode 41S of the first switching element 41 to the fourth front-surface electrode 64A, and the wire W3 connecting the gate electrode 41G of the first switching element 41 to the third front-surface electrode 63A are both relatively short. Further, the wire W2 connecting the source electrode 51S of the second switching element 51 to the fourth front-surface electrode 64B, and the wire W3 connecting the gate electrode 51G of the second switching element 51 to the third front-surface electrode 63B are both relatively short.

(1-19) The first switching element 41 is located at a position that overlaps the first light emitter 33A of the semiconductor light-emitting element 30 as viewed in the Y-direction. The second switching element 51 is located at a position that overlaps the second light emitter 33B of the semiconductor light-emitting element 30 as viewed in the Y-direction.

With this configuration, the distance between the first switching element 41 and the semiconductor light-emitting element 30 is shorter as compared to a configuration in which the first switching element 41 is shifted from the semiconductor light-emitting element 30 in the X-direction. Therefore, when the source electrode 41S of the first switching element 41 is connected to the first element front-surface electrode 34A of the semiconductor light-emitting element 30 by the wires W1, the wires W1 are relatively short. The distance between the second switching element 51 and the semiconductor light-emitting element 30 is shorter as compared to a configuration in which the second switching element 51 is shifted from the semiconductor light-emitting element 30 in the X-direction. Therefore, when the source electrode 51S of the second switching element 51 is connected to the second element front-surface electrode 34B of the semiconductor light-emitting element 30 by the wires W1, the wires W1 are relatively short.

(1-20) The first switching element 41 and the second switching element 51 include vertical transistors having the same configuration.

With this configuration, the semiconductor light-emitting device 10 includes a single type of switching element. This reduces the manufacturing costs of the semiconductor light-emitting device 10 as compared to when two types of switching elements are included.

### Second Embodiment

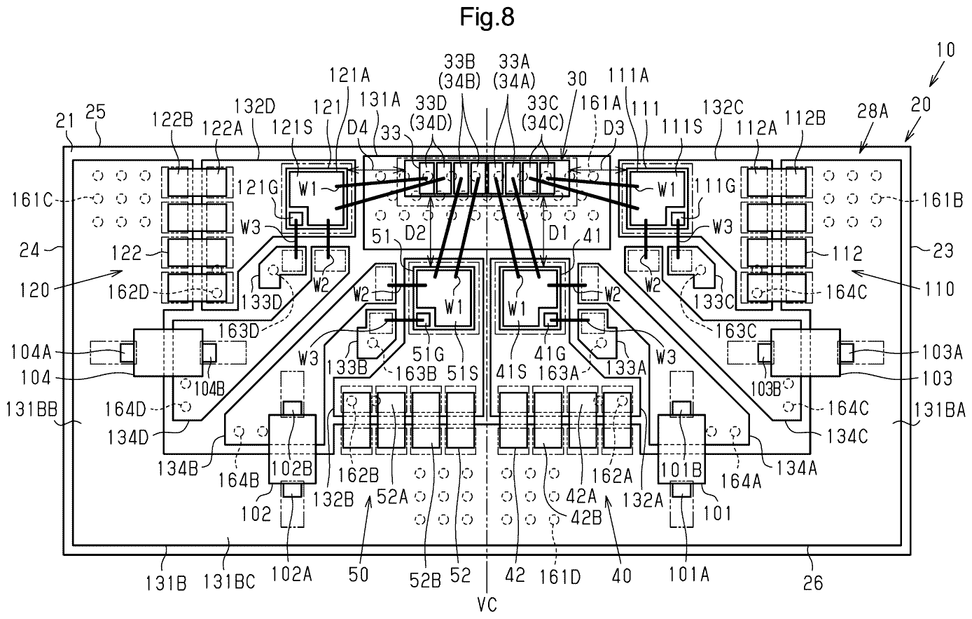

A semiconductor light-emitting device 10 in accordance with a second embodiment will now be described with reference to FIGS. 8 to 11. The semiconductor light-emitting device 10 of the second embodiment differs from the semiconductor light-emitting device 10 of the first embodiment in the number of light emitters that are separately controlled. Hereinafter, the description will focus on the differences from the first embodiment. The same reference characters are given to those components that are the same as the corresponding components of the first embodiment, and such components will not be described in detail.

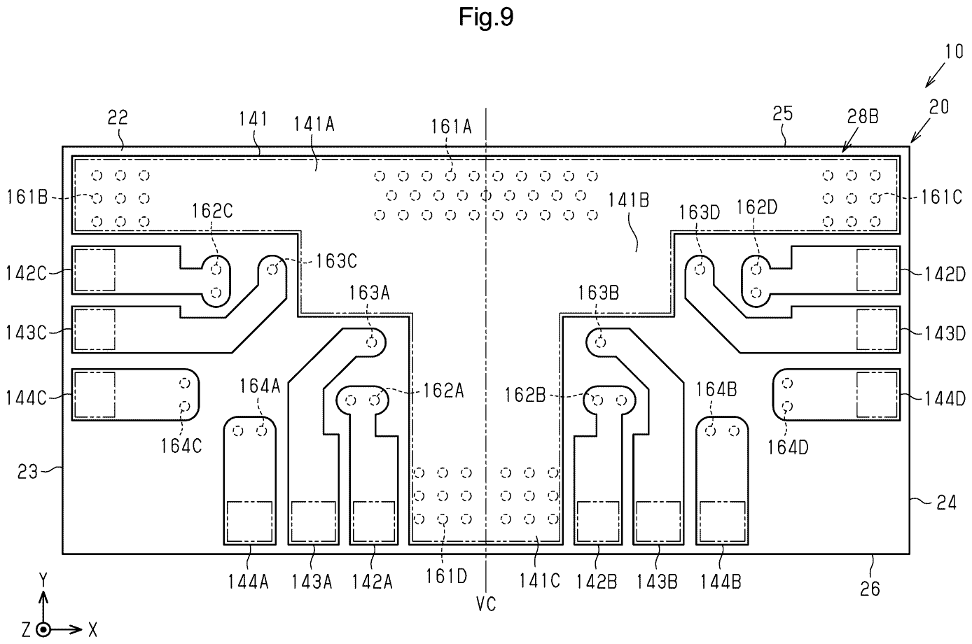

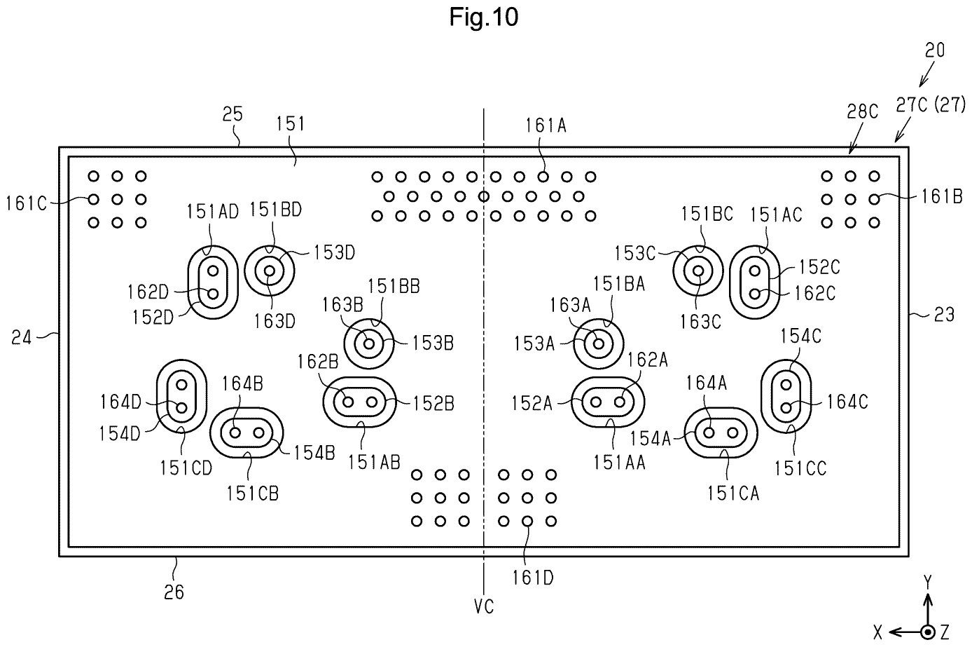

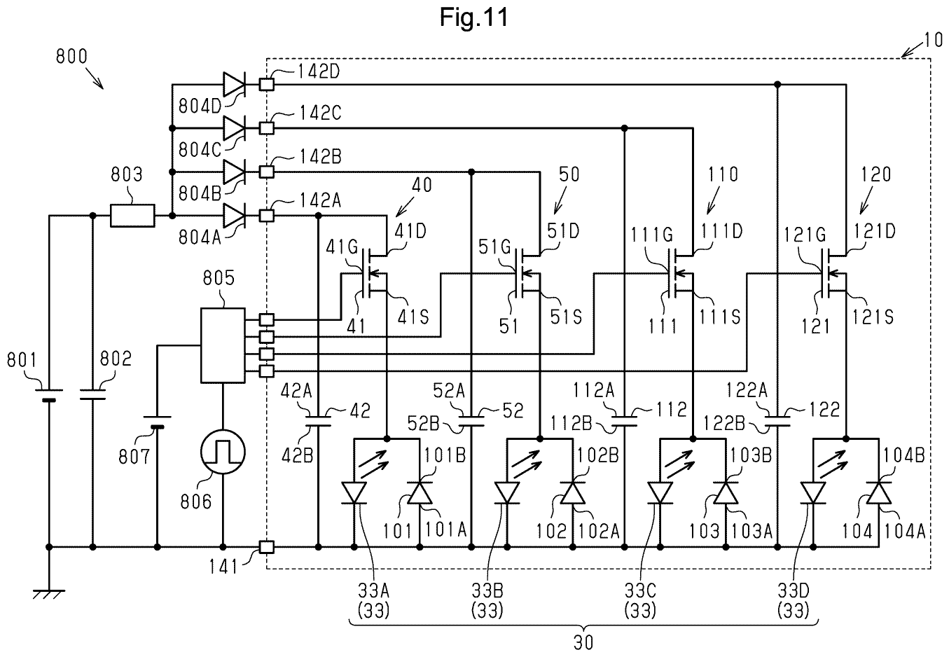

FIG. 8 shows a schematic planar structure of the semiconductor light-emitting device 10 in accordance with the second embodiment. FIG. 9 shows a schematic bottom structure of the semiconductor light-emitting device 10 shown in FIG. 8. FIG. 10 shows a schematic planar structure of the front-surface intermediate electrode 28C of the semiconductor light-emitting device 10 shown in FIG. 8. FIG. 11 shows a schematic circuit diagram of a light-emitting system 800 including the semiconductor light-emitting device 10 of the second embodiment.

As shown in FIG. 8, the semiconductor light-emitting element 30 in accordance with the second embodiment includes first to fourth light emitters 33A to 33D and first to fourth element front-surface electrodes 34A to 34D respectively provided for the first to fourth light emitters 33A to 33D. The first to fourth light emitters 33A to 33D each include two of the eight light emitters 33. The first element front-surface electrode 34A is included in the first light emitter 33A. The second element front-surface electrode 34B is included in the second light emitter 33B. The third element front-surface electrode 34C is included in the third light emitter 33C. The fourth element front-surface electrode 34D is included in the fourth light emitter 33D. The number of each of the first to fourth element front-surface electrodes 34A to 34D is determined in accordance with the number of a corresponding one of the first to fourth light emitters 33A to 33D. In the second embodiment, the number of each of the first to fourth light emitters 33A to 33D is two, and thus the number of each of the first to fourth element front-surface electrodes 34A to 34D is two. The first element front-surface electrode 34A is an example of “first anode electrode”. The second element front-surface electrode 34B is an example of “second anode electrode”. The third element front-surface electrode 34C is an example of “third anode electrode”. The fourth element front-surface electrode 34D is an example of “fourth anode electrode”.

The semiconductor light-emitting device 10 includes a configuration that controls driving of the first to fourth light emitters 33A to 33D separately. More specifically, the semiconductor light-emitting device 10 includes a first drive circuit 40 configured to drive the first light emitter 33A, a second drive circuit 50 configured to drive the second light emitter 33B, a third drive circuit 110 configured to drive the third light emitter 33C, and a fourth drive circuit 120 configured to drive the fourth light emitter 33D. The first drive circuit 40 is electrically connected to the first element front-surface electrode 34A of the first light emitter 33A. The second drive circuit 50 is electrically connected to the second element front-surface electrode 34B of the second light emitter 33B. The third drive circuit 110 is electrically connected to the third element front-surface electrode 34C of the third light emitter 33C. The fourth drive circuit 120 is electrically connected to the fourth element front-surface electrode 34D of the fourth light emitter 33D.

In the same manner as the first embodiment, the first drive circuit 40 includes the first switching element 41 and the first capacitor 42. In the same manner as the first embodiment, the second drive circuit 50 includes the second switching element 51 and the second capacitor 52.

The third drive circuit 110 includes a third switching element 111 configured to control driving of the third light emitter 33C, and a third capacitor 112 configured to supply electric current to the third light emitter 33C. The third switching element 111 and the third capacitor 112 are spaced apart from the semiconductor light-emitting element 30.

The fourth drive circuit 120 includes a fourth switching element 121 configured to control driving of the fourth light emitter 33D, and a fourth capacitor 122 configured to supply electric current to the fourth light emitter 33D. The fourth switching element 121 and the fourth capacitor 122 are spaced apart from the semiconductor light-emitting element 30.

Due to these modifications of the drive circuits, the configuration of the substrate 20 differs from that of the first embodiment. The configuration of the substrate 20 in accordance with the second embodiment will now be described.

The substrate 20 includes the front-surface electrodes 28A formed in the substrate front surface 21, namely, first front-surface electrodes 131A and 131B, second front-surface electrodes 132A to 132D, third front-surface electrodes 133A to 133D, and fourth front-surface electrodes 134A to 134D. The first front-surface electrodes 131A and 131B, the second front-surface electrodes 132A to 132D, the third front-surface electrodes 133A to 133D, and the fourth front-surface electrodes 134A to 134D are spaced apart from one another.

The semiconductor light-emitting element 30 is mounted on the first front-surface electrode 131A. In plan view, the first front-surface electrode 131A is disposed in a central part of the substrate front surface 21 in the X-direction and is located relatively close to the third substrate side surface 25 of the substrate front surface 21. The first front-surface electrode 131A is rectangular in plan view, with long sides extending in the X-direction and short sides extending in the Y-direction. In an example, the first front-surface electrode 131A is symmetric with respect to the imaginary centerline VC.

The first front-surface electrode 131B serves as ground wiring electrically connected to a ground terminal. The first front-surface electrode 131B is substantially U-shaped along the edges of the substrate front surface 21. The first front-surface electrode 131B includes a first wiring portion 131BA formed along the first substrate side surface 23, a second wiring portion 131BB formed along the second substrate side surface 24, and a third wiring portion 131BC formed along the fourth substrate side surface 26. In an example, the first wiring portion 131BA, the second wiring portion 131BB, and the third wiring portion 131BC are integrated with each other. In an example, the first front-surface electrode 131B is symmetric with respect to the imaginary centerline VC.

In plan view, the first front-surface electrode 131B surrounds the first front-surface electrode 131A, the second front-surface electrodes 132A to 132D, the third front-surface electrodes 133A to 133D, and the fourth front-surface electrodes 134A to 134D. The first front-surface electrode 131B has a greater area than each of the first front-surface electrode 131A, the second front-surface electrodes 132A to 132D, the third front-surface electrodes 133A to 133D, or the fourth front-surface electrodes 134A to 134D.

The second front-surface electrode 132A, the third front-surface electrode 133A, the fourth front-surface electrode 134A, and the first front-surface electrode 131B are for electrical connection of the first drive circuit 40. The second front-surface electrode 132B, the third front-surface electrode 133B, the fourth front-surface electrode 134B, and the first front-surface electrode 131B are for electrical connection of the second drive circuit 50. The second front-surface electrode 132C, the third front-surface electrode 133C, the fourth front-surface electrode 134C, and the first front-surface electrode 131B are for electrical connection of the third drive circuit 110. The second front-surface electrode 132D, the third front-surface electrode 133D, the fourth front-surface electrode 134D, and the first front-surface electrode 131B are for electrical connection of the fourth drive circuit 120.

The second front-surface electrode 132A and the second front-surface electrode 132B are adjacent to each other and are located at opposite sides of the imaginary centerline VC in the X-direction. In plan view, the second front-surface electrodes 132A and 132B are each substantially L-shaped. In an example, the second front-surface electrodes 132A and 132B are symmetric with respect to the imaginary centerline VC.

The second front-surface electrodes 132A and 132B are located between the first front-surface electrode 131A and the third wiring portion 131BC of the first front-surface electrode 131B in the Y-direction. Accordingly, as viewed in the Y-direction, the second front-surface electrodes 132A and 132B are located at a position that overlaps the first front-surface electrode 131A.

The second front-surface electrodes 132A and 132B each include a narrow section, a wide section, and a joining section. The narrow section and the wide section of the second front-surface electrode 132A, 132B are aligned with and spaced apart from each other in the Y-direction. The joining section is arranged between the narrow section and the wide section in the Y-direction and joins the narrow section to the wide section.

The wide section defines one of two opposite ends of the second front-surface electrodes 132A and 132B in the Y-direction that is located closer to the third wiring portion 131BC. The narrow section includes the other one of the two opposite ends of the second front-surface electrodes 132A and 132B in the Y-direction that is located closer to the first front-surface electrode 131A. In the example shown in FIG. 8, the dimension of the narrow section in the X-direction is approximately one-half of the dimension of the wide section in the X-direction. The dimension of the joining section in the X-direction is gradually increased from the narrow section toward the wide section.

The second front-surface electrode 132C and the second front-surface electrode 132D are separately disposed at opposite sides of the first front-surface electrode 131A in the X-direction. The second front-surface electrode 132C is located closer to the first substrate side surface 23 than the first front-surface electrode 131A is. The second front-surface electrode 132D is located closer to the second substrate side surface 24 than the first front-surface electrode 131A is. In an example, the second front-surface electrodes 132C and 132D are symmetric with respect to the imaginary centerline VC.

In an example, the second front-surface electrode 132C and the second front-surface electrode 132B are identical in size and shape. The second front-surface electrode 132C has a shape obtained by rotating the second front-surface electrode 132B counterclockwise by ninety degrees. Thus, the narrow section and the wide section of the second front-surface electrode 132C are aligned with and spaced apart from each other in the X-direction. The narrow section of the second front-surface electrode 132C is located near the first front-surface electrode 131A in the X-direction. The wide section of the second front-surface electrode 132C is located near the first wiring portion 131BA in the X-direction. The joining section of the second front-surface electrode 132C is arranged between the narrow section and the wide section in the X-direction and joins the narrow section to the wide section.

In an example, the second front-surface electrode 132D and the second front-surface electrode 132A are identical in size and shape. The second front-surface electrode 132D has a shape obtained by rotating the second front-surface electrode 132A clockwise by ninety degrees. Thus, the narrow section and the wide section of the second front-surface electrode 132D are aligned with and spaced apart from each other in the X-direction. The narrow section of the second front-surface electrode 132D is located near the first front-surface electrode 131A in the X-direction. The wide section of the second front-surface electrode 132D is located near the second wiring portion 131BB in the X-direction. The joining section of the second front-surface electrode 132D is arranged between the narrow section and the wide section in the X-direction and joins the narrow section to the wide section.

The third front-surface electrode 133A is located closer to the first substrate side surface 23 than the narrow section of the second front-surface electrode 132A is in the X-direction. The third front-surface electrode 133A is arranged between the first front-surface electrode 131A and the joining section of the second front-surface electrode 132A in the Y-direction.

The third front-surface electrode 133B is located closer to the second substrate side surface 24 than the narrow section of the second front-surface electrode 132B is in the X-direction. The third front-surface electrode 133B is arranged between the first front-surface electrode 131A and the joining section of the second front-surface electrode 132B in the Y-direction. In an example, the third front-surface electrodes 133A and 133B are symmetric with respect to the imaginary centerline VC.

The third front-surface electrode 133C is located closer to the fourth substrate side surface 26 than the narrow section of the second front-surface electrode 132C is in the Y-direction. The third front-surface electrode 133C is arranged between the first front-surface electrode 131A and the joining section of the second front-surface electrode 132C in the X-direction. In an example, the third front-surface electrode 133C is located closer to the fourth substrate side surface 26 than the first front-surface electrode 131A is in the Y-direction. In an example, the third front-surface electrode 133C and the third front-surface electrode 133B are identical in size and shape. The third front-surface electrode 133C has a shape obtained by rotating the third front-surface electrode 133B counterclockwise by ninety degrees.

The third front-surface electrode 133D is located closer to the fourth substrate side surface 26 than the narrow section of the second front-surface electrode 132D is in the Y-direction. The third front-surface electrode 133D is arranged between the first front-surface electrode 131A and the joining section of the second front-surface electrode 132D in the X-direction. In an example, the third front-surface electrode 133D is located closer to the fourth substrate side surface 26 than the first front-surface electrode 131A is in the Y-direction. In an example, the third front-surface electrode 133D and the third front-surface electrode 133A are identical in size and shape. The third front-surface electrode 133D has a shape obtained by rotating the third front-surface electrode 133A clockwise by ninety degrees.

The fourth front-surface electrode 134A is located closer to the first substrate side surface 23 than the second front-surface electrode 132A is in the X-direction. The fourth front-surface electrode 134A is arranged between the first front-surface electrode 131A and the third wiring portion 131BC in the Y-direction. The fourth front-surface electrode 134A includes a first opposing section opposing the narrow section of the second front-surface electrode 132A in the X-direction, and a second opposing section opposing the third wiring portion 131BC in the Y-direction. The fourth front-surface electrode 134A further includes a first joining section connected to the first opposing section, and a second joining section connected to the second opposing section. The first opposing section is arranged between the first front-surface electrode 131A and the third front-surface electrode 133A in the Y-direction. In other words, the third front-surface electrode 133A is arranged between the first opposing section and the joining section of the second front-surface electrode 132A in the Y-direction. The first joining section and the second joining section are continuous with each other. As the first joining section becomes closer to the second joining section, the first joining section diagonally extends toward the first substrate side surface 23 and the fourth substrate side surface 26. The dimension of the second joining section in the X-direction is gradually increased toward the second opposing section.

The fourth front-surface electrode 134B is located closer to the second substrate side surface 24 than the second front-surface electrode 132B is in the X-direction. The fourth front-surface electrode 134B is arranged between the first front-surface electrode 131A and the third wiring portion 131BC in the Y-direction. The fourth front-surface electrodes 134A and 134B are symmetric with respect to the imaginary centerline VC. Therefore, a first opposing section of the fourth front-surface electrode 134B is arranged between the first front-surface electrode 131A and the third front-surface electrode 133B in the Y-direction. In other words, the third front-surface electrode 133B is arranged between the first opposing section and the joining section of the second front-surface electrode 132B in the Y-direction.

The fourth front-surface electrode 134C is adjacent to the fourth front-surface electrode 134A in the X-direction and the Y-direction. The fourth front-surface electrode 134C is arranged between the second front-surface electrode 132C and the third wiring portion 131BC in the Y-direction. The fourth front-surface electrode 134C is arranged between the first front-surface electrode 131A and the first wiring portion 131BA in the X-direction. In an example, the fourth front-surface electrode 134C and the fourth front-surface electrode 134B are identical in size and shape. The fourth front-surface electrode 134C has a shape obtained by rotating the fourth front-surface electrode 134B counterclockwise by ninety degrees. Thus, a first opposing section of the fourth front-surface electrode 134C opposes the narrow section of the second front-surface electrode 132C in the Y-direction. A second opposing section of the fourth front-surface electrode 134C opposes the first wiring portion 131BA in the X-direction.

The fourth front-surface electrode 134D is adjacent to the fourth front-surface electrode 134B in the X-direction and the Y-direction. The fourth front-surface electrode 134D is arranged between the second front-surface electrode 132D and the third wiring portion 131BC in the Y-direction. The fourth front-surface electrode 134D is arranged between the first front-surface electrode 131A and the second wiring portion 131BB in the X-direction. In an example, the fourth front-surface electrode 134D and the fourth front-surface electrode 134A are identical in size and shape. The fourth front-surface electrode 134D has a shape obtained by rotating the fourth front-surface electrode 134A clockwise by ninety degrees. Thus, a first opposing section of the fourth front-surface electrode 134D opposes the narrow section of the second front-surface electrode 132D in the Y-direction. A second opposing section of the fourth front-surface electrode 134D opposes the second wiring portion 131BB in the X-direction.

As shown in FIG. 9, the back-surface electrodes 28B include a first back-surface electrode 141, second back-surface electrodes 142A to 142D, third back-surface electrodes 143A to 143D, and fourth back-surface electrodes 144A to 144D. The first back-surface electrode 141, the second back-surface electrodes 142A to 142D, the third back-surface electrodes 143A to 143D, and the fourth back-surface electrodes 144A to 144D are spaced apart from one another.

The first back-surface electrode 141 is substantially T-shaped in plan view. The first back-surface electrode 141 includes a first wide section 141A, a second wide section 141B, and a narrow section 141C. In an example, the first wide section 141A, the second wide section 141B, and the narrow section 141C are integrated with each other. In an example, the first back-surface electrode 141 is symmetric with respect to the imaginary centerline VC.

The first wide section 141A and the second wide section 141B are located closer to the third substrate side surface 25 than the center of the substrate back surface 22 in the Y-direction is. The first wide section 141A is located closer to the third substrate side surface 25 than the second wide section 141B is. The first wide section 141A is formed across substantially the entire the substrate back surface 22 in the X-direction. The second wide section 141B is smaller than the first wide section 141A in the X-direction. In an example, the second wide section 141B have the same dimension in the Y-direction as the first wide section 141A. The narrow section 141C extends in the Y-direction through the center of the substrate back surface 22 in the X-direction. The narrow section 141C has a distal end that is adjacent to the fourth substrate side surface 26 in the Y-direction in plan view.

In plan view, the first back-surface electrode 141 has a greater area than each of the second back-surface electrodes 142A to 142D, the third back-surface electrodes 143A to 143D, or the fourth back-surface electrodes 144A to 144D. In an example, the area of the first back-surface electrode 141 is greater than or equal to the combined total area of the second back-surface electrodes 142A to 142D, the third back-surface electrodes 143A to 143D, and the fourth back-surface electrodes 144A to 144D.

The first back-surface electrode 141, the second back-surface electrode 142A, the third back-surface electrode 143A, and the fourth back-surface electrode 144A are electrically connected to the first drive circuit 40 (refer to FIG. 8). The first back-surface electrode 141, the second back-surface electrode 142B, the third back-surface electrode 143B, and the fourth back-surface electrode 144B are electrically connected to the second drive circuit 50 (refer to FIG. 8). The first back-surface electrode 141, the second back-surface electrode 142C, the third back-surface electrode 143C, and the fourth back-surface electrode 144C are electrically connected to the third drive circuit 110 (refer to FIG. 8). The first back-surface electrode 141, the second back-surface electrode 142D, the third back-surface electrode 143D, and the fourth back-surface electrode 144D are electrically connected to the fourth drive circuit 120 (refer to FIG. 8).

The second back-surface electrode 142A and the second back-surface electrode 142B are separately disposed at opposite sides of the narrow section 141C of the first back-surface electrode 141 in the X-direction. The third back-surface electrode 143A and the third back-surface electrode 143B are separately disposed at opposite sides of the narrow section 141C of the first back-surface electrode 141 in the X-direction. The fourth back-surface electrode 144A and the fourth back-surface electrode 144B are separately disposed at opposite sides of the narrow section 141C of the first back-surface electrode 141 in the X-direction. The second back-surface electrode 142A, the third back-surface electrode 143A, and the fourth back-surface electrode 144A are located closer to the first substrate side surface 23 than the narrow section 141C is. The second back-surface electrode 142B, the third back-surface electrode 143B, and the fourth back-surface electrode 144B are located closer to the second substrate side surface 24 than the narrow section 141C is. The second back-surface electrode 142A is located closer to the narrow section 141C than the third back-surface electrode 143A and the fourth back-surface electrode 144A are in the X-direction. The fourth back-surface electrode 144A is located farther from the narrow section 141C than the second back-surface electrode 142A and the third back-surface electrode 143A are in the X-direction. The second back-surface electrode 142B is located closer to the narrow section 141C than the third back-surface electrode 143B and the fourth back-surface electrode 144B are in the X-direction. The fourth back-surface electrode 144B is located farther from the narrow section 141C than the second back-surface electrode 142B and the third back-surface electrode 143B are in the X-direction.

In an example, the second back-surface electrodes 142A and 142B are symmetric with respect to the imaginary centerline VC. The second back-surface electrodes 142A and 142B extend in the Y-direction.

In an example, the third back-surface electrodes 143A and 143B are symmetric with respect to the imaginary centerline VC. The third back-surface electrode 143A extends in the Y-direction and surrounds the second back-surface electrode 142A from the side of the first substrate side surface 23 in the X-direction and the side of the third substrate side surface 25 in the Y-direction. The third back-surface electrode 143B extends in the Y-direction and surrounds the second back-surface electrode 142B from the side of the second substrate side surface 24 in the X-direction and the side of the third substrate side surface 25 in the Y-direction. Thus, ends of the third back-surface electrodes 143A and 143B in the Y-direction that are located relatively close to the third substrate side surface 25 are adjacent to the second wide section 141B in the Y-direction.

In an example, the fourth back-surface electrodes 144A and 144B are symmetric with respect to the imaginary centerline VC. The fourth back-surface electrodes 144A and 144B extend in the Y-direction.

In the example shown in FIG. 9, the distal end of the narrow section 141C of the first back-surface electrode 141, ends of the second back-surface electrodes 142A and 142B that are located relatively close to the fourth substrate side surface 26 in the Y-direction, ends of the third back-surface electrodes 143A and 143B that are located relatively close to the fourth substrate side surface 26 in the Y-direction, and ends of the fourth back-surface electrodes 144A and 144B that are located relatively close to the fourth substrate side surface 26 in the Y-direction are located at the same position in the Y-direction and adjacent to the fourth substrate side surface 26.

The second back-surface electrode 142C and the second back-surface electrode 142D are separately disposed at opposite sides of the second wide section 141B of the first back-surface electrode 141 in the X-direction. The third back-surface electrode 143C and the third back-surface electrode 143D are separately disposed at opposite sides of the second wide section 141B of the first back-surface electrode 141 in the X-direction. The fourth back-surface electrode 144C and the fourth back-surface electrode 144D are separately disposed at opposite sides of the second wide section 141B of the first back-surface electrode 141 in the X-direction. The second back-surface electrode 142C, the third back-surface electrode 143C, and the fourth back-surface electrode 144C are located closer to the first substrate side surface 23 than the second wide section 141B is. The second back-surface electrode 142D, the third back-surface electrode 143D, and the fourth back-surface electrode 144D are located closer to the second substrate side surface 24 than the second wide section 141B is.

The second back-surface electrode 142C, the third back-surface electrode 143C, and the fourth back-surface electrode 144C are aligned with and spaced apart from each other in the Y-direction. The second back-surface electrode 142C is located closer to the first wide section 141A than the third back-surface electrode 143C and the fourth back-surface electrode 144C are in the Y-direction. The fourth back-surface electrode 144C is located farther from the first wide section 141A than the second back-surface electrode 142C and the third back-surface electrode 143C are in the Y-direction.

The second back-surface electrode 142D, the third back-surface electrode 143D, and the fourth back-surface electrode 144D are aligned with and spaced apart from each other in the Y-direction. The second back-surface electrode 142D is located closer to the first wide section 141A than the third back-surface electrode 143D and the fourth back-surface electrode 144D are in the Y-direction. The fourth back-surface electrode 144D is located farther from the first wide section 141A than the second back-surface electrode 142D and the third back-surface electrode 143D are in the Y-direction.

In an example, the second back-surface electrodes 142C and 142D are symmetric with respect to the imaginary centerline VC. The second back-surface electrodes 142C and 142D extend in the X-direction. The second back-surface electrode 142C has a shape obtained by rotating the second back-surface electrode 142B clockwise by ninety degrees. The second back-surface electrode 142D has a shape obtained by rotating the second back-surface electrode 142A counterclockwise by ninety degrees.

In an example, the third back-surface electrodes 143C and 143D are symmetric with respect to the imaginary centerline VC. The third back-surface electrode 143C extends in the Y-direction and surrounds the second back-surface electrode 142C from the side of the fourth substrate side surface 26 in the Y-direction and the side of the second wide section 141B in the X-direction. The third back-surface electrode 143D extends in the Y-direction and surrounds the second back-surface electrode 142D from the side of the fourth substrate side surface 26 in the Y-direction and the side of the second wide section 141B in the X-direction. Thus, ends of the third back-surface electrodes 143C and 143D that are located relatively close to the second wide section 141B are adjacent to the second wide section 141B in the X-direction.

In an example, the fourth back-surface electrodes 144C and 144D are symmetric with respect to the imaginary centerline VC. The fourth back-surface electrodes 144C and 144D extend in the X-direction.

In the example shown in FIG. 9, one of two opposite ends of the first wide section 141A of the first back-surface electrode 141 in the X-direction that is located closer to the first substrate side surface 23, an end of the second back-surface electrode 142C in the X-direction that is located relatively close to the first substrate side surface 23, an end of the third back-surface electrode 143C in the X-direction that is located relatively close to the first substrate side surface 23, and an end of the fourth back-surface electrode 144C in the X-direction that is located relatively close to the first substrate side surface 23 are located at the same position in the X-direction and adjacent to the first substrate side surface 23. Further, the other one of the two opposite ends of the first wide section 141A of the first back-surface electrode 141 in the X-direction that is located closer to the second substrate side surface 24, an end of the second back-surface electrode 142D in the X-direction that is located relatively close to the second substrate side surface 24, an end of the third back-surface electrode 143D in the X-direction that is located relatively close to the second substrate side surface 24, and an end of the fourth back-surface electrode 144D in the X-direction that is located relatively close to the second substrate side surface 24 are located at the same position in the X-direction and adjacent to the second substrate side surface 24.

As shown in FIG. 10, the front-surface intermediate electrodes 28C include a first intermediate electrode 151, second intermediate electrodes 152A to 152D, third intermediate electrodes 153A to 153D, and fourth intermediate electrodes 154A to 154D.

In plan view, the first intermediate electrode 151 has a greater area than each of the second intermediate electrodes 152A to 152D, the third intermediate electrodes 153A to 153D, or the fourth intermediate electrodes 154A to 154D. In plan view, the area of the first intermediate electrode 151 is greater than the combined total area of the second intermediate electrodes 152A to 152D, the third intermediate electrodes 153A to 153D, and the fourth intermediate electrodes 154A to 154D. In plan view, the area of the first intermediate electrode 151 is greater than one-half of the area of the base-member front surface of the intermediate base member 27C. In plan view, the area of the first intermediate electrode 151 is greater than two-thirds of the area of the base-member front surface of the intermediate base member 27C. In an example, the first intermediate electrode 151 is formed across substantially the entire base-member front surface of the intermediate base member 27C in plan view. The first intermediate electrode 151 includes first openings 151AA to 151AD, second openings 151BA to 151BD, and third openings 151CA to 151CD.

In an example, the first openings 151AA and 151AB are symmetric with respect to the imaginary centerline VC. In an example, the second openings 151BA and 151BB are symmetric with respect to the imaginary centerline VC. In an example, the third openings 151CA and 151CB are symmetric with respect to the imaginary centerline VC.

The first openings 151AA and 151AB are elliptic in plan view, with major axis extending in the X-direction and minor axis extending in the Y-direction. The second openings 151BA and 151BB are circular. The third openings 151CA and 151CB are elliptic in plan view, with major axis extending in the X-direction and minor axis extending in the Y-direction.

In an example, the first openings 151AC and 151AD are symmetric with respect to the imaginary centerline VC. In an example, the second openings 151BC and 151BD are symmetric with respect to the imaginary centerline VC. In an example, the third openings 151CC and 151CD are symmetric with respect to the imaginary centerline VC.

The first openings 151AC and 151AD are elliptic, with major axis extending in the Y-direction and minor axis extending in the X-direction. The second openings 151BC and 151BD are circular. The third openings 151CC and 151CD are elliptic, with major axis extending in the Y-direction and minor axis extending in the X-direction.

The second intermediate electrode 152A is disposed in the first opening 151AA. The second intermediate electrode 152B is disposed in the first opening 151AB. The second intermediate electrode 152C is disposed in the first opening 151AC. The second intermediate electrode 152D is disposed in the first opening 151AD. In plan view, the second intermediate electrodes 152A to 152D each have an elliptical shape that is slightly smaller than a corresponding one of the first openings 152AA to 152AD.

The third intermediate electrode 153A is disposed in the second opening 151BA. The third intermediate electrode 153B is disposed in the second opening 151BB. The third intermediate electrode 153C is disposed in the second opening 151BC. The third intermediate electrode 153D is disposed in the second opening 151BD. In plan view, the third intermediate electrodes 153A to 153D each have a circular shape that is slightly smaller than a corresponding one of the second openings 151BA to 151BD.

The fourth intermediate electrode 154A is disposed in the third opening 151CA. The fourth intermediate electrode 154B is disposed in the third opening 151CB. The fourth intermediate electrode 154C is disposed in the third opening 151CC. The fourth intermediate electrode 154D is disposed in the third opening 151CD. In plan view, the fourth intermediate electrodes 154A to 154D each have an elliptical shape that is slightly smaller than a corresponding one of the third openings 151CA to 151CD.

As shown in FIGS. 8 to 10, the substrate 20 includes first vias 161A to 161D, second vias 162A to 162D, third vias 163A to 163D, and fourth vias 164A to 164D. The first vias 161A to 161D, the second vias 162A to 162D, the third vias 163A to 163D, and the fourth vias 164A to 164D extend through the base members 27A, 27B, and 27C, the front-surface intermediate electrodes 28C, and the back-surface intermediate electrodes 28D in the Z-direction. The first vias 161A to 161D, the second vias 162A to 162D, the third vias 163A to 163D, and the fourth vias 164A to 164D are formed from, for example, a material containing one or more selected from Ti, TiN, Au, Ag, Cu, Al, and W.

The first via 161A is electrically connected to the first front-surface electrode 131A, the first intermediate electrode 151 of the front-surface intermediate electrode 28C, the first intermediate electrode 151 of the back-surface intermediate electrode 28D, and the first back-surface electrode 141. Therefore, the first front-surface electrode 131A, the first intermediate electrode 151 of the front-surface intermediate electrode 28C, the first intermediate electrode 151 of the back-surface intermediate electrode 28D, and the first back-surface electrode 141 are electrically connected to each other.

As shown in FIG. 8, multiple first vias 161A are provided. The first vias 161A are arranged in the first front-surface electrode 131A and are located relatively close to the third substrate side surface 25. Accordingly, in plan view, the first vias 161A are located at a position of the first front-surface electrode 131A that overlaps the semiconductor light-emitting element 30. The first vias 161A are aligned with and spaced apart from one another in the X-direction and the Y-direction. A greater number of first vias 161A are aligned in the X-direction than in the Y-direction. In plan view, the first vias 161A are formed in a region that is larger than the area of the semiconductor light-emitting element 30. Therefore, some of the first vias 161A are located outside the semiconductor light-emitting element 30 in plan view.

As shown in FIGS. 8 to 10, the first vias 161B to 161D are electrically connected to the first front-surface electrode 131B, the first intermediate electrode 151 of the front-surface intermediate electrode 28C, the first intermediate electrode 151 of the back-surface intermediate electrode 28D, and the first back-surface electrode 141. Therefore, the first front-surface electrode 131B, the first intermediate electrode 151 of the front-surface intermediate electrode 28C, the first intermediate electrode 151 of the back-surface intermediate electrode 28D, and the first back-surface electrode 141 are electrically connected to each other. In this manner, the first front-surface electrode 131A is electrically connected to the first front-surface electrode 131B through electrical connection of the electrodes by the first vias 161A to 161D.

Multiple first vias 161B, multiple first vias 161C, and multiple first vias 161D are provided. The first vias 161B to 161D are each less in number than the first vias 161A. The first vias 161B connect an end of the first wiring portion 131BA of the first front-surface electrode 131B that is located relatively close to both the third substrate side surface 25 and the first substrate side surface 23 to an end of the first wide section 141A of the first back-surface electrode 141 that is located relatively close to both the third substrate side surface 25 and the first substrate side surface 23. The first vias 161C connect an end of the second wiring portion 131BB of the first front-surface electrode 131B that is located relatively close to both the third substrate side surface 25 and the second substrate side surface 24 to an end of the first wide section 141A of the first back-surface electrode 141 that is located relatively close to both the third substrate side surface 25 and the second substrate side surface 24. The first vias 161D connect the central part of the third wiring portion 131BC of the first front-surface electrode 131B in the X-direction to the narrow section 141C of the first back-surface electrode 141.

As shown in FIGS. 8 to 10, multiple second vias 162A, multiple second vias 162B, multiple second vias 162C, and multiple second vias 162D are provided. The second via 162A to 162D are each less in number than any of the first vias 161A to 161D. The second vias 162A are electrically connected to the second front-surface electrode 132A, the second intermediate electrode 152A of the front-surface intermediate electrode 28C, the second intermediate electrode 152A of the back-surface intermediate electrode 28D, and the second back-surface electrode 142A. Therefore, the second front-surface electrode 132A, the second intermediate electrode 152A of the front-surface intermediate electrode 28C, the second intermediate electrode 152A of the back-surface intermediate electrode 28D, and the second back-surface electrode 142A are electrically connected to each other. The second vias 162B are electrically connected to the second front-surface electrode 132B, the second intermediate electrode 152B of the front-surface intermediate electrode 28C, the second intermediate electrode 152B of the back-surface intermediate electrode 28D, and the second back-surface electrode 142B. Therefore, the second front-surface electrode 132B, the second intermediate electrode 152B of the front-surface intermediate electrode 28C, the second intermediate electrode 152B of the back-surface intermediate electrode 28D, and the second back-surface electrode 142B are electrically connected to each other. The second vias 162C are electrically connected to the second front-surface electrode 132C, the second intermediate electrode 152C of the front-surface intermediate electrode 28C, the second intermediate electrode 152C of the back-surface intermediate electrode 28D, and the second back-surface electrode 142C. Therefore, the second front-surface electrode 132C, the second intermediate electrode 152C of the front-surface intermediate electrode 28C, the second intermediate electrode 152C of the back-surface intermediate electrode 28D, and the second back-surface electrode 142C are electrically connected to each other. The second vias 162D are electrically connected to the second front-surface electrode 132D, the second intermediate electrode 152D of the front-surface intermediate electrode 28C, the second intermediate electrode 152D of the back-surface intermediate electrode 28D, and the second back-surface electrode 142D. Therefore, the second front-surface electrode 132D, the second intermediate electrode 152D of the front-surface intermediate electrode 28C, the second intermediate electrode 152D of the back-surface intermediate electrode 28D, and the second back-surface electrode 142D are electrically connected to each other.

As shown in FIGS. 8 to 10, a single third via 163A, a single third via 163B, a single third via 163C, and a single third via 163D are provided. The third via 163A is electrically connected to the third front-surface electrode 133A, the third intermediate electrode 153A of the front-surface intermediate electrode 28C, the third intermediate electrode 153A of the back-surface intermediate electrode 28D, and the third back-surface electrode 143A. Therefore, the third front-surface electrode 133A, the third intermediate electrode 153A of the front-surface intermediate electrode 28C, the third intermediate electrode 153A of the back-surface intermediate electrode 28D, and the third back-surface electrode 143A are electrically connected to each other. The third via 163B is electrically connected to the third front-surface electrode 133B, the third intermediate electrode 153B of the front-surface intermediate electrode 28C, the third intermediate electrode 153B of the back-surface intermediate electrode 28D, and the third back-surface electrode 143B. Therefore, the third front-surface electrode 133B, the third intermediate electrode 153B of the front-surface intermediate electrode 28C, the third intermediate electrode 153B of the back-surface intermediate electrode 28D, and the third back-surface electrode 143B are electrically connected to each other. The third via 163C is electrically connected to the third front-surface electrode 133C, the third intermediate electrode 153C of the front-surface intermediate electrode 28C, the third intermediate electrode 153C of the back-surface intermediate electrode 28D, and the third back-surface electrode 143C. Therefore, the third front-surface electrode 133C, the third intermediate electrode 153C of the front-surface intermediate electrode 28C, the third intermediate electrode 153C of the back-surface intermediate electrode 28D, and the third back-surface electrodes 143C are electrically connected to each other. The third via 163D is electrically connected to the third front-surface electrode 133D, the third intermediate electrode 153D of the front-surface intermediate electrode 28C, the third intermediate electrode 153D of the back-surface intermediate electrode 28D, and the third back-surface electrode 143D. Therefore, the third front-surface electrode 133D, the third intermediate electrode 153D of the front-surface intermediate electrode 28C, the third intermediate electrode 153D of the back-surface intermediate electrode 28D, and the third back-surface electrode 143D are electrically connected to each other.

As shown in FIGS. 8 to 10, multiple fourth vias 164A, multiple fourth vias 164B, multiple fourth vias 164C, and multiple fourth vias 164D are provided. In an example, the fourth vias 164A to 164D are equal in number to the second vias 162A to 162D. The fourth vias 164A are electrically connected to the fourth front-surface electrode 134A, the fourth intermediate electrode 154A of the front-surface intermediate electrode 28C, the fourth intermediate electrode 154A of the back-surface intermediate electrode 28D, and the fourth back-surface electrode 144A. Therefore, the fourth front-surface electrode 134A, the fourth intermediate electrode 154A of the front-surface intermediate electrode 28C, the fourth intermediate electrode 154A of the back-surface intermediate electrode 28D, and the fourth back-surface electrode 144A are electrically connected to each other. The fourth vias 164B are electrically connected to the fourth front-surface electrode 134B, the fourth intermediate electrode 154B of the front-surface intermediate electrode 28C, the fourth intermediate electrode 154B of the back-surface intermediate electrode 28D, and the fourth back-surface electrode 144B. Therefore, the fourth front-surface electrode 134B, the fourth intermediate electrode 154B of the front-surface intermediate electrode 28C, the fourth intermediate electrode 154B of the back-surface intermediate electrode 28D, and the fourth back-surface electrode 144B are electrically connected to each other. The fourth vias 164C are electrically connected to the fourth front-surface electrode 134C, the fourth intermediate electrode 154C of the front-surface intermediate electrode 28C, the fourth intermediate electrode 154C of the back-surface intermediate electrode 28D, and the fourth back-surface electrode 144C. Therefore, the fourth front-surface electrode 134C, the fourth intermediate electrode 154C of the front-surface intermediate electrode 28C, the fourth intermediate electrode 154C of the back-surface intermediate electrode 28D, and the fourth back-surface electrode 144C are electrically connected to each other. The fourth vias 164D are electrically connected to the fourth front-surface electrode 134D, the fourth intermediate electrode 154D of the front-surface intermediate electrode 28C, the fourth intermediate electrode 154D of the back-surface intermediate electrode 28D, and the fourth back-surface electrode 144D. Therefore, the fourth front-surface electrode 134D, the fourth intermediate electrode 154D of the front-surface intermediate electrode 28C, the fourth intermediate electrode 154D of the back-surface intermediate electrode 28D, and the fourth back-surface electrode 144D are electrically connected to each other.

### Configuration and Layout of Semiconductor Light-Emitting Element and First to Fourth Drive Circuits

As shown in FIG. 8, the semiconductor light-emitting element 30, the first drive circuit 40, the second drive circuit 50, the third drive circuit 110, and the fourth drive circuit 120 are mounted on the front-surface electrodes 28A. The configuration and arrangement of the semiconductor light-emitting element 30 and the first to fourth drive circuits 40, 50, 110, and 120 will now be described in detail. The same reference characters are given to those components that are the same as the corresponding components of the first embodiment, and such components may not be described in detail.

The semiconductor light-emitting element 30 is mounted on the first front-surface electrode 131A. Specifically, the element back-surface electrode 35 (not shown in FIG. 8; refer to FIG. 3) of the semiconductor light-emitting element 30 is bonded to the first front-surface electrode 131A by the conductive bonding material SD (not shown in FIG. 8; refer to FIG. 3). Therefore, the element back-surface electrode 35 is electrically connected to the first front-surface electrode 131A. The semiconductor light-emitting element 30 is shifted toward the third substrate side surface 25 with respect to the center of the first front-surface electrode 131A in the Y-direction.

The semiconductor light-emitting element 30 of the second embodiment is identical to the semiconductor light-emitting element 30 of the first embodiment in size, shape, and configuration. As described above, in the semiconductor light-emitting element 30 of the second embodiment, the eight light emitters 33 are divided into pairs of light emitters 33, namely, the first to fourth light emitters 33A to 33D.

The first light emitter 33A includes two of the eight light emitters 33 that are disposed relatively close to the imaginary centerline VC and are located closer to the first substrate side surface 23 than the imaginary centerline VC is. The second light emitter 33B includes two of the eight light emitters 33 that are disposed relatively close to the imaginary centerline VC and are located closer to the second substrate side surface 24 than the imaginary centerline VC is. The third light emitter 33C includes two of the eight light emitters 33 that are located relatively close to the first substrate side surface 23 in the X-direction. The fourth light emitter 33D includes two of the eight light emitters 33 that are located relatively close to the second substrate side surface 24 in the X-direction.

In the first drive circuit 40, the first switching element 41 of the second embodiment includes a vertical transistor in the same manner as the first embodiment. However, the first switching element 41 of the second embodiment differs from that of the first embodiment in shape of the source electrode 41S and position of the gate electrode 41G. More specifically, the gate electrode 41G is disposed in one of four corners of the second element front surface 41A that is located relatively close to both the first substrate side surface 23 and the fourth substrate side surface 26. The source electrode 41S is formed in most of the second element front surface 41A, and includes a notch to avoid the gate electrode 41G.

The first switching element 41 is mounted on the second front-surface electrode 132A. That is, the drain electrode 41D (not shown in FIG. 8; refer to FIG. 3) of the first switching element 41 is bonded to the second front-surface electrode 132A by the conductive bonding material SD (not shown in FIG. 8; refer to FIG. 3). Therefore, the drain electrode 41D is electrically connected to the second front-surface electrode 132A. The first switching element 41 is disposed in the narrow section of the second front-surface electrode 132A.

The source electrode 41S of the first switching element 41 is electrically connected to the first element front-surface electrodes 34A, which correspond to the first light emitter 33A of the semiconductor light-emitting element 30, by the wires W1. The source electrode 41S of the first switching element 41 is electrically connected to the fourth front-surface electrode 134A by the wire W2. The gate electrode 41G of the first switching element 41 is electrically connected to the third front-surface electrode 133A by the wire W3.

In plan view, the semiconductor light-emitting element 30 and the first capacitor 42 are spaced apart from each other in the Y-direction. The first capacitor 42 is located at a side of the first switching element 41 opposite to the semiconductor light-emitting element 30 in the Y-direction. In other words, in plan view, the first switching element 41 is arranged between the semiconductor light-emitting element 30 and the first capacitor 42 in the Y-direction.

Multiple (in the second embodiment, four) first capacitors 42 are provided. The first capacitors 42 are connected in parallel to each other. The first capacitors 42 are aligned with and spaced apart from each other in the X-direction. Each of the first capacitors 42 extends over the second front-surface electrode 132A and the third wiring portion 131BC of the first front-surface electrode 131B in the Y-direction. The first capacitor 42 is mounted on the second front-surface electrode 132A and the third wiring portion 131BC. More specifically, the first capacitor 42 is separately bonded to the second front-surface electrode 132A and the third wiring portion 131BC by the conductive bonding material SD (not shown in FIG. 8; refer to FIG. 3). In the example shown in FIG. 8, the first electrode 42A is bonded to the second front-surface electrode 132A by the conductive bonding material SD. Therefore, the first electrode 42A is electrically connected to the second front-surface electrode 132A. The second electrode 42B is bonded to the third wiring portion 131BC by the conductive bonding material SD. Therefore, the second electrode 42B is electrically connected to the third wiring portion 131BC (first front-surface electrode 131B).

The first electrodes 42A of the first capacitors 42 are disposed in the wide section of the second front-surface electrode 132A. The first capacitors 42 are arranged side by side in the X-direction and disposed across the entire wide section in the X-direction. In other words, the dimension of the wide section in the X-direction is set to allow for the side-by-side arrangement of the first capacitors 42 in the X-direction.

The second electrodes 42B of the first capacitors 42 are disposed in one of two opposite ends of the third wiring portion 131BC in the Y-direction that is located closer to the second front-surface electrode 132A. That is, the second electrodes 42B of the first capacitors 42 are located closer to the second front-surface electrode 132A than the first vias 161D are in the Y-direction. As viewed in the Y-direction, some of the first capacitors 42 are located closer to the first substrate side surface 23 than the first switching element 41 is.

In the second drive circuit 50, the second switching element 51 of the second embodiment includes a vertical transistor in the same manner as the first embodiment. However, the second switching element 51 of the second embodiment differs from that of the first embodiment in shape of the source electrode 51S and position of the gate electrode 51G. More specifically, the gate electrode 51G is disposed in one of four corners of the second element front surface 51A that is located relatively close to both the second substrate side surface 24 and the fourth substrate side surface 26. The source electrode 51S is formed in most of the second element front surface 51A, and includes a notch to avoid the gate electrode 51G. In this manner, in the second embodiment, the configuration of the second switching element 51 differs from that of the first switching element 41.

The second switching element 51 is mounted on the second front-surface electrode 132B. That is, the drain electrode 51D (not shown in FIG. 8; refer to FIG. 11) of the second switching element 51 is bonded to the second front-surface electrode 132B by the conductive bonding material SD. Therefore, the drain electrode 51D is electrically connected to the second front-surface electrode 132B.

The second switching element 51 is disposed in the narrow section of the second front-surface electrode 132B. In plan view, the distance D1 between the semiconductor light-emitting element 30 and the first switching element 41 in the Y-direction is equal to the distance D2 between the semiconductor light-emitting element 30 and the second switching element 51 in the Y-direction. The distance D1 and the distance D2 may be considered to be the same as long as a difference of the distance D1 and the distance D2 is, for example, within 10% of the distance D1.

The source electrode 51S of the second switching element 51 is electrically connected to the second element front-surface electrodes 34B, which correspond to the second light emitter 33B of the semiconductor light-emitting element 30, by the wires W1. The source electrode 51S of the second switching element 51 is electrically connected to the fourth front-surface electrode 134B by the wire W2. The gate electrode 51G of the second switching element 51 is electrically connected to the third front-surface electrode 133B by the wire W3.

In an example, in plan view, the two wires W1 connecting the first element front-surface electrodes 34A and the source electrode 41S of the first switching element 41 have the same length. In an example, in plan view, the two wires W1 connecting the second element front-surface electrodes 34B and the source electrode 51S of the second switching element 51 have the same length.

Since the distance D1 is equal to the distance D2, the lengths of the wires W1 may be adjusted so that the total length of the two wires W1 connecting the first element front-surface electrodes 34A to the source electrode 41S of the first switching element 41 is equal to the total length of the two wires W1 connecting the second element front-surface electrodes 34B to the source electrode 51S of the second switching element 51 in plan view. It may be considered that the total length of the two wires W1 connecting the first element front-surface electrodes 34A to the source electrode 41S of the first switching element 41 is equal to the total length of the two wires W1 connecting the second element front-surface electrodes 34B to the source electrode 51S of the second switching element 51 in plan view as long as a difference in total length between the two wires W1 connecting the first element front-surface electrodes 34A to the source electrode 41S of the first switching element 41 and the two wires W1 connecting the second element front-surface electrodes 34B to the source electrode 51S of the second switching element 51 in plan view is, for example, within 10% of the total length of the two wires W1 connecting the first element front-surface electrodes 34A to the source electrode 41S of the first switching element 41 in plan view.

In plan view, the semiconductor light-emitting element 30 and the second capacitor 52 are spaced apart from each other in the Y-direction. The second capacitor 52 is located at a side of the second switching element 51 opposite to the semiconductor light-emitting element 30 in the Y-direction. In other words, in plan view, the second switching element 51 is arranged between the semiconductor light-emitting element 30 and the second capacitor 52 in the Y-direction.

Multiple (in the second embodiment, four) second capacitors 52 are provided. The second capacitors 52 are connected in parallel to each other. The second capacitors 52 are aligned with and spaced apart from each other in the X-direction. Each of the second capacitors 52 extends over the second front-surface electrode 132B and the third wiring portion 131BC of the first front-surface electrode 131B in the Y-direction. The second capacitor 52 is mounted on the second front-surface electrode 132B and the third wiring portion 131BC. More specifically, the second capacitor 52 is separately bonded to the second front-surface electrode 132B and the third wiring portion 131BC by the conductive bonding material SD (not shown). In the example shown in FIG. 8, the first electrode 52A is bonded to the second front-surface electrode 132B by the conductive bonding material SD. Therefore, the first electrode 52A is electrically connected to the second front-surface electrode 132B. The second electrode 52B is bonded to the third wiring portion 131BC by the conductive bonding material SD. Therefore, the second electrode 52B is electrically connected to the third wiring portion 131BC (first front-surface electrode 131B). Accordingly, the second electrode 52B of the second capacitor 52 is electrically connected to the second electrode 42B of the first capacitor 42.

The first electrodes 52A of the second capacitors 52 are disposed in the wide section of the second front-surface electrode 132B. The second capacitors 52 are arranged side by side in the X-direction and disposed across the entire wide section in the X-direction. In other words, the dimension of the wide section in the X-direction is set to allow for the side-by-side arrangement of the second capacitors 52 in the X-direction.

The second electrodes 52B of the second capacitors 52 are disposed in one of the two opposite ends of the third wiring portion 131BC in the Y-direction that is located closer to the second front-surface electrode 132B. That is, the second electrodes 52B of the second capacitors 52 are located closer to the second front-surface electrode 132B than the first vias 161D are in the Y-direction. As viewed in the Y-direction, some of the second capacitors 52 are located closer to the second substrate side surface 24 than the second switching element 51 is.

In the third drive circuit 110, the third switching element 111 includes a vertical transistor. The configuration and size of the third switching element 111 are the same as those of the second switching element 51 of the second embodiment. The third switching element 111 includes a second element front surface 111A and a second element back surface (not shown) facing away from each other in the Z-direction. A source electrode 111S and a gate electrode 111G are formed in the second element front surface 111A. A drain electrode 111D (not shown in FIG. 8; refer to FIG. 11) is formed in the second element back surface. The shape, configuration, and layout of the source electrode 111S and the gate electrode 111G are identical to those of the source electrode 51S and the gate electrode 51G.

The third switching element 111 is mounted on the second front-surface electrode 132C. Specifically, the drain electrode 111D of the third switching element 111 is bonded to the second front-surface electrode 132C by the conductive bonding material SD. Therefore, the drain electrode 111D is electrically connected to the second front-surface electrode 132C.

The third switching element 111 is disposed in the narrow section of the second front-surface electrode 132C. Therefore, the third switching element 111 is located closer to the first substrate side surface 23 than the semiconductor light-emitting element 30 is in the X-direction. As viewed in the X-direction, the third switching element 111 is located at a position that overlaps the semiconductor light-emitting element 30.

The source electrode 111S of the third switching element 111 is electrically connected to the third element front-surface electrodes 34C, which correspond to the third light emitter 33C of the semiconductor light-emitting element 30, by the wires W1. The source electrode 111S of the third switching element 111 is electrically connected to the fourth front-surface electrode 134C by the wire W2. The gate electrode 111G of the third switching element 111 is electrically connected to the third front-surface electrode 133C by the wire W3.

In plan view, the semiconductor light-emitting element 30 and the third capacitor 112 are spaced apart from each other in the X-direction. The third capacitor 112 is located at a side of the third switching element 111 opposite to the semiconductor light-emitting element 30 in the X-direction. In other words, in plan view, the third switching element 111 is arranged between the semiconductor light-emitting element 30 and the third capacitor 112 in the X-direction.

Multiple (in the second embodiment, four) third capacitors 112 are provided. The third capacitors 112 are connected in parallel to each other. The third capacitors 112 are aligned with and spaced apart from each other in the Y-direction. Each of the third capacitors 112 extends over the second front-surface electrode 132C and the first wiring portion 131BA of the first front-surface electrode 131B in the X-direction. The third capacitor 112 is mounted on the second front-surface electrode 132C and the first wiring portion 131BA. The third capacitor 112 is separately bonded to the second front-surface electrode 132C and the first wiring portion 131BA by the conductive bonding material SD (not shown). More specifically, the third capacitor 112 includes a first electrode 112A and a second electrode 112B. In the example shown in FIG. 8, the first electrode 112A is bonded to the second front-surface electrode 132C by the conductive bonding material SD. Therefore, the first electrode 112A is electrically connected to the second front-surface electrode 132C. The second electrode 112B is bonded to the first wiring portion 131BA by the conductive bonding material SD. Therefore, the second electrode 112B is electrically connected to the first wiring portion 131BA (first front-surface electrode 131B). Accordingly, the second electrode 112B of the third capacitor 112 is electrically connected to the second electrode 42B of the first capacitor 42.

The first electrodes 112A of the third capacitors 112 are disposed in the wide section of the second front-surface electrode 132C. The third capacitors 112 are arranged side by side in the Y-direction and disposed across the entire wide section in the Y-direction. In other words, the dimension of the wide section in the Y-direction is set to allow for the side-by-side arrangement of the third capacitors 112 in the Y-direction.

The second electrodes 112B of the third capacitors 112 are disposed in one of two opposite ends of the first wiring portion 131BA in the X-direction that is located closer to the second front-surface electrode 132C. That is, the second electrodes 112B of the third capacitors 112 are located closer to the second front-surface electrode 132C than the first vias 161B are in the X-direction. As viewed in the X-direction, some of the third capacitors 112 are located closer to the fourth substrate side surface 26 than the third switching element 111 is.

In the fourth drive circuit 120, the fourth switching element 121 includes a vertical transistor. The configuration and size of the fourth switching element 121 are the same as those of the first switching element 41 of the second embodiment. The fourth switching element 121 includes a second element front surface 121A and a second element back surface (not shown) facing away from each other in the Z-direction. A source electrode 121S and a gate electrode 121G are formed in the second element front surface 121A. A drain electrode 121D (not shown in FIG. 8; refer to FIG. 11) is formed in the second element back surface. The shape, configuration, and layout of the source electrode 121S and the gate electrode 121G are identical to those of the source electrode 41S and the gate electrode 41G.

The fourth switching element 121 is mounted on the second front-surface electrode 132D. Specifically, the drain electrode 121D of the fourth switching element 121 is bonded to the second front-surface electrode 132D by the conductive bonding material SD (not shown). Therefore, the drain electrode 121D is electrically connected to the second front-surface electrode 132D.

The fourth switching element 121 is disposed in the narrow section of the second front-surface electrode 132D. Therefore, the fourth switching element 121 is located closer to the second substrate side surface 24 than the semiconductor light-emitting element 30 is in the X-direction. As viewed in the X-direction, the fourth switching element 121 is located at a position that overlaps the semiconductor light-emitting element 30. In this manner, the third switching element 111 and the fourth switching element 121 are separately disposed at opposite sides of the semiconductor light-emitting element 30 in the X-direction. In plan view, a distance D3 between the semiconductor light-emitting element 30 and the third switching element 111 in the X-direction is equal to a distance D4 between the semiconductor light-emitting element 30 and the fourth switching element 121 in the X-direction. The distance D3 and the distance D4 may be considered to be the same as long as a difference of the distance D3 and the distance D4 is, for example, within 10% of the distance D3.

The source electrode 121S of the fourth switching element 121 is electrically connected to the fourth element front-surface electrodes 34D, which correspond to the fourth light emitter 33D of the semiconductor light-emitting element 30, by the wires W1. The source electrode 121S of the fourth switching element 121 is electrically connected to the fourth front-surface electrode 134D by the wire W2. The gate electrode 121G of the fourth switching element 121 is electrically connected to the third front-surface electrode 133D by the wire W3.

Since the distance D3 is equal to the distance D4, the lengths of the wires W1 may be adjusted so that the total length of the two wires W1 connecting the third element front-surface electrodes 34C to the source electrode 111S of the third switching element 111 is equal to the total length of the two wires W1 connecting the fourth element front-surface electrodes 34D to the source electrode 121S of the fourth switching element 121 in plan view. It may be considered that the total length of the two wires W1 connecting the third element front-surface electrodes 34C to the source electrode 111S of the third switching element 111 is equal to the total length of the two wires W1 connecting the fourth element front-surface electrodes 34D to the source electrode 121S of the fourth switching element 121 in plan view as long as a difference in total length between the two wires W1 connecting the third element front-surface electrodes 34C to the source electrode 111S of the third switching element 111 and the two wires W1 connecting the fourth element front-surface electrodes 34D to the source electrode 121S of the fourth switching element 121 in plan view is, for example, within 10% of the total length of the two wires W1 connecting the third element front-surface electrodes 34C to the source electrode 111S of the third switching element 111 in plan view.

In plan view, the semiconductor light-emitting element 30 and the fourth capacitor 122 are spaced apart from each other in the X-direction. The fourth capacitor 122 is located at a side of the fourth switching element 121 opposite to the semiconductor light-emitting element 30 in the X-direction. In other words, in plan view, the fourth switching element 121 is arranged between the semiconductor light-emitting element 30 and the fourth capacitor 122 in the X-direction. In this manner, the third capacitor 112 and the fourth capacitor 122 are separately disposed at opposite sides of the semiconductor light-emitting element 30 in the X-direction.

Multiple (in the second embodiment, four) fourth capacitors 122 are provided. The fourth capacitors 122 are connected in parallel to each other. The fourth capacitors 122 are aligned with and spaced apart from each other in the Y-direction. Each of the fourth capacitors 122 extends over the second front-surface electrode 132D and the second wiring portion 131BB of the first front-surface electrode 131B in the X-direction. The fourth capacitor 122 is mounted on the second front-surface electrode 132D and the second wiring portion 131BB. The fourth capacitor 122 is separately bonded to the second front-surface electrode 132D and the second wiring portion 131BB by the conductive bonding material SD (not shown). More specifically, the fourth capacitor 122 includes a first electrode 122A and a second electrode 122B. In the example shown in FIG. 8, the first electrode 122A is bonded to the second front-surface electrode 132D by the conductive bonding material SD. Therefore, the first electrode 122A is electrically connected to the second front-surface electrode 132D. The second electrode 122B is bonded to the second wiring portion 131BB by the conductive bonding material SD. Therefore, the second electrode 122B is electrically connected to the second wiring portion 131BB (first front-surface electrode 131B). Accordingly, the second electrode 122B of the fourth capacitor 122 is electrically connected to the second electrode 42B of the first capacitor 42. In other words, the second electrodes 42B, 52B, 112B, and 122B of the first to fourth capacitors 42, 52, 112, and 122 are electrically connected to one another through the first front-surface electrode 131B.

The first electrodes 122A of the fourth capacitors 122 are disposed in the wide section of the second front-surface electrode 132D. The fourth capacitors 122 are arranged side by side in the Y-direction and disposed across the entire wide section in the Y-direction. In other words, the dimension of the wide section in the Y-direction is set to allow for the side-by-side arrangement of the fourth capacitors 122 in the Y-direction.

The second electrodes 122B of the fourth capacitors 122 are disposed in one of two opposite ends of the second wiring portion 131BB in the X-direction that is located closer to the second front-surface electrode 132D. That is, the second electrodes 122B of the fourth capacitors 122 are located closer to the second front-surface electrode 132D than the first vias 161C are in the X-direction. As viewed in the X-direction, some of the fourth capacitors 122 are located closer to the fourth substrate side surface 26 than the fourth switching element 121 is.

The semiconductor light-emitting device 10 further includes first to fourth protection diodes 101 to 104.

The first protection diode 101 is configured to protect the first light emitter 33A of the semiconductor light-emitting element 30. The first protection diode 101 is located closer to the first substrate side surface 23 than the semiconductor light-emitting element 30, the first switching element 41, and the first capacitors 42 are in the X-direction. In an example, as viewed in the Y-direction, the first protection diode 101 is located at a position that overlaps the third switching element 111. The first protection diode 101 is located at a side of the first switching element 41 opposite to the semiconductor light-emitting element 30 in the Y-direction. The first protection diode 101 is located at the same position as the first capacitors 42 in the Y-direction. The first protection diode 101 extends over the fourth front-surface electrode 134A and the third wiring portion 131BC of the first front-surface electrode 131B in the Y-direction. The first protection diode 101 is arranged so that the first anode electrode 101A and the first cathode electrode 101B are located at the same position in the X-direction and are spaced apart from each other in the Y-direction. The first protection diode 101 is mounted on the fourth front-surface electrode 134A and the first front-surface electrode 131B. More specifically, the first protection diode 101 is separately bonded to the fourth front-surface electrode 134A and the first front-surface electrode 131B by the conductive bonding material SD.

The first protection diode 101 is connected in antiparallel to the first light emitter 33A. More specifically, the first anode electrode 101A is bonded to the first front-surface electrode 131B by the conductive bonding material SD. The first anode electrode 101A is disposed in the third wiring portion 131BC of the first front-surface electrode 131B. Therefore, the first anode electrode 101A is electrically connected to the element back-surface electrode 35 of the semiconductor light-emitting element 30 through the first front-surface electrode 131B. The first cathode electrode 101B is bonded to the fourth front-surface electrode 134A by the conductive bonding material SD. The first cathode electrode 101B is disposed in the second opposing section of the fourth front-surface electrode 134A. Therefore, the first cathode electrode 101B is electrically connected to the first element front-surface electrodes 34A, which correspond to the first light emitter 33A of the semiconductor light-emitting element 30, through the wire W2, the source electrode 41S of the first switching element 41, and the wires W1.

The second protection diode 102 is configured to protect the second light emitter 33B of the semiconductor light-emitting element 30. The second protection diode 102 is located closer to the second substrate side surface 24 than the semiconductor light-emitting element 30, the second switching element 51, and the second capacitors 52 are in the X-direction. In an example, as viewed in the Y-direction, the second protection diode 102 is located at a position that overlaps the fourth switching element 121. The second protection diode 102 is located at a side of the second switching element 51 opposite to the semiconductor light-emitting element 30 in the Y-direction. The second protection diode 102 is located at the same position as the second capacitors 52 in the Y-direction. The second protection diode 102 extends over the fourth front-surface electrode 134B and the third wiring portion 131BC of the first front-surface electrode 131B in the Y-direction. The second protection diode 102 is mounted on the fourth front-surface electrode 134B and the first front-surface electrode 131B. The second protection diode 102 is arranged in the same manner as the first protection diode 101.

The second protection diode 102 is connected in antiparallel to the second light emitter 33B. More specifically, the second anode electrode 102A is bonded to the third wiring portion 131BC of the first front-surface electrode 131B by the conductive bonding material SD. Therefore, the second anode electrode 102A is electrically connected to the element back-surface electrode 35 of the semiconductor light-emitting element 30 through the first front-surface electrode 131B. The second cathode electrode 102B is bonded to the second opposing section of the fourth front-surface electrode 134B by the conductive bonding material SD. Therefore, the second cathode electrode 102B is electrically connected to the second element front-surface electrodes 34B, which correspond to the second light emitter 33B of the semiconductor light-emitting element 30, through the wire W2, the source electrode 51S of the second switching element 51, and the wires W1.

The third protection diode 103 is configured to protect the third light emitter 33C of the semiconductor light-emitting element 30. The third protection diode 103 is located closer to the fourth substrate side surface 26 than the semiconductor light-emitting element 30, the third switching element 111, and the third capacitors 112 are in the Y-direction. In an example, as viewed in the X-direction, the third protection diode 103 is located at a position that overlaps the first switching element 41. The third protection diode 103 is located at a side of the third switching element 111 opposite to the semiconductor light-emitting element 30 in the X-direction. The third protection diode 103 is located at the same position as the third capacitors 112 in the X-direction. The third protection diode 103 extends over the fourth front-surface electrode 134C and the first wiring portion 131BA of the first front-surface electrode 131B in the Y-direction.

The third protection diode 103 includes a third anode electrode 103A and a third cathode electrode 103B. The third protection diode 103 is arranged so that the third anode electrode 103A and the third cathode electrode 103B are located at the same position in the Y-direction and are spaced apart from each other in the X-direction. The third protection diode 103 is mounted on the fourth front-surface electrode 134C and the first front-surface electrode 131B. More specifically, the third protection diode 103 is separately bonded to the fourth front-surface electrode 134C and the first front-surface electrode 131B by the conductive bonding material SD.

The third protection diode 103 is connected in antiparallel to the third light emitter 33C. More specifically, the third anode electrode 103A is bonded to the first front-surface electrode 131B by the conductive bonding material SD. The third anode electrode 103A is disposed in the first wiring portion 131BA of the first front-surface electrode 131B. Therefore, the third anode electrode 103A is electrically connected to the element back-surface electrode 35 of the semiconductor light-emitting element 30 through the first front-surface electrode 131B. The third cathode electrode 103B is bonded to the fourth front-surface electrode 134C by the conductive bonding material SD. The third cathode electrode 103B is disposed in the second opposing section of the fourth front-surface electrode 134C. Therefore, the third cathode electrode 103B is electrically connected to the third element front-surface electrodes 34C, which correspond to the third light emitter 33C of the semiconductor light-emitting element 30, through the wire W2, the source electrode 111S of the third switching element 111, and the wires W1.

The fourth protection diode 104 is configured to protect the fourth light emitter 33D of the semiconductor light-emitting element 30. The fourth protection diode 104 is located closer to the fourth substrate side surface 26 than the semiconductor light-emitting element 30, the fourth switching element 121, and the fourth capacitors 122 are in the Y-direction. In an example, as viewed in the X-direction, the fourth protection diode 104 is located at a position that overlaps the second switching element 51. The fourth protection diode 104 is located at a side of the fourth switching element 121 opposite to the semiconductor light-emitting element 30 in the X-direction. The fourth protection diode 104 is located at the same position as the fourth capacitors 122 in the X-direction. The fourth protection diode 104 extends over the fourth front-surface electrode 134D and the second wiring portion 131BB of the first front-surface electrode 131B in the Y-direction.

The fourth protection diode 104 includes a fourth anode electrode 104A and a fourth cathode electrode 104B. The fourth protection diode 104 is arranged so that the fourth anode electrode 104A and the fourth cathode electrode 104B are located at the same position in the Y-direction and are spaced apart from each other in the X-direction. The fourth protection diode 104 is mounted on the fourth front-surface electrode 134D and the first front-surface electrode 131B. More specifically, the fourth protection diode 104 is separately bonded to the fourth front-surface electrode 134D and the first front-surface electrode 131B by the conductive bonding material SD.

The fourth protection diode 104 is connected in antiparallel to the fourth light emitter 33D. More specifically, the fourth anode electrode 104A is bonded to the first front-surface electrode 131B by the conductive bonding material SD. The fourth anode electrode 104A is disposed in the second wiring portion 131BB of the first front-surface electrode 131B. Therefore, the fourth anode electrode 104A is electrically connected to the element back-surface electrode 35 of the semiconductor light-emitting element 30 through the first front-surface electrode 131B. The fourth cathode electrode 104B is bonded to the fourth front-surface electrode 134D by the conductive bonding material SD. The fourth cathode electrode 104B is disposed in the second opposing section of the fourth front-surface electrode 134D. Therefore, the fourth cathode electrode 104B is electrically connected to the fourth element front-surface electrodes 34D, which correspond to the fourth light emitter 33D of the semiconductor light-emitting element 30, through the wire W2, the source electrode 121S of the fourth switching element 121, and the wires W1. In this manner, the first to fourth anode electrodes 101A to 104A of the first to fourth protection diodes 101 to 104 are electrically connected to one another through the first front-surface electrode 131B.

### Circuitry of Semiconductor Light-Emitting Device

As shown in FIG. 11, the light-emitting system 800 includes the DC power supply 801, the capacitor 802, the current limiting resistor 803, the gate driver IC 805, the pulse generator 806, and the control power supply 807, in the same manner as the first embodiment. Unlike the first embodiment, the light-emitting system 800 further includes four reverse current protection diodes 804A to 804D. Hereinafter, the description will focus on the differences from the first embodiment, and the same configuration as the first embodiment will not be described.

Anodes of the reverse current protection diodes 804A to 804D are electrically connected to the current limiting resistor 803. A cathode of the reverse current protection diode 804A is electrically connected to the second back-surface electrode 142A. A cathode of the reverse current protection diode 804B is electrically connected to the second back-surface electrode 142B. A cathode of the reverse current protection diode 804C is electrically connected to the second back-surface electrode 142C. A cathode of the reverse current protection diode 804D is electrically connected to the second back-surface electrode 142D.

The drain electrode 41D of the first switching element 41 and the first electrode 42A of the first capacitor 42 are electrically connected to the cathode of the reverse current protection diode 804A through the second back-surface electrode 142A. The drain electrode 51D of the second switching element 51 and the first electrode 52A of the second capacitor 52 are electrically connected to the cathode of the reverse current protection diode 804B through the second back-surface electrode 142B. The drain electrode 111D of the third switching element 111 and the first electrode 112A of the third capacitor 112 are electrically connected to the cathode of the reverse current protection diode 804C through the second back-surface electrode 142C. The drain electrode 121D of the fourth switching element 121 and the first electrode 122A of the fourth capacitor 122 are electrically connected to the cathode of the reverse current protection diode 804D through the second back-surface electrode 142D.

The source electrode 41S of the first switching element 41 is electrically connected to the first element front-surface electrode 34A (refer to FIG. 8), which serves as the first anode electrode of the first light emitter 33A, and the first cathode electrode 101B of the first protection diode 101. The source electrode 51S of the second switching element 51 is electrically connected to the second element front-surface electrode 34B (refer to FIG. 8), which serves as the second anode electrode of the second light emitter 33B, and the second cathode electrode 102B of the second protection diode 102. The source electrode 111S of the third switching element 111 is electrically connected to the third element front-surface electrode 34C, which serves as the third anode electrode of the third light emitter 33C, and the third cathode electrode 103B of the third protection diode 103. The source electrode 121S of the fourth switching element 121 is electrically connected to the fourth element front-surface electrode 34D, which serves as the fourth anode electrode of the fourth light emitter 33D, and the fourth cathode electrode 104B of the fourth protection diode 104.

The first back-surface electrode 141 is electrically connected to the element back-surface electrode 35, which serves as the common cathode electrode of the first to fourth light emitters 33A to 33D, the first to fourth anode electrodes 101A to 104A of the first to fourth protection diodes 101 to 104, and the second electrodes 42B, 52B, 112B, and 122B of the first to fourth capacitors 42, 52, 112, and 122. Since the first back-surface electrode 141 is grounded, the element back-surface electrode 35, which serves as the cathode of the first to fourth light emitters 33A to 33D, the first to fourth anode electrodes 101A to 104A of the first to fourth protection diodes 101 to 104, and the second electrodes 42B, 52B, 112B, and 122B of the first to fourth capacitors 42, 52, 112, and 122 are grounded.

The gate driver IC 805 is separately electrically connected to the gate electrodes 41G, 51G, 111G, and 121G of the first to fourth switching elements 41, 51, 111, and 121. That is, the gate driver IC 805 is configured to control the first to fourth switching elements 41, 51, 111, and 121 separately. In the second embodiment, the first to fourth light emitters 33A to 33D of the semiconductor light-emitting device 10 are driven in the same manner as the first embodiment.

### Advantages

The semiconductor light-emitting device 10 of the second embodiment has the following advantages in addition to the advantages of the first embodiment.

(2-1) The third drive circuit 110 includes the third switching element 111 configured to control driving of the third light emitter 33C, and the third capacitor 112 configured to supply electric current to the third light emitter 33C. The fourth drive circuit 120 includes the fourth switching element 121 configured to control driving of the fourth light emitter 33D, and the fourth capacitor 122 configured to supply electric current to the fourth light emitter 33D.

With this configuration, the third light emitter 33C of the semiconductor light-emitting element 30, the third switching element 111, and the third capacitor 112 form a looped third current path inside the semiconductor light-emitting device 10. In this case, the third current path is relatively short, so that the inductance caused by the length of the third current path is decreased. Further, the fourth light emitter 33D of the semiconductor light-emitting element 30, the fourth switching element 121, and the fourth capacitor 122 form a looped fourth current path inside the semiconductor light-emitting device 10. In this case, the fourth current path is relatively short, so that the inductance caused by the length of the fourth current path is decreased. Since the third current path and the fourth current path are both relatively short, a difference in length between the third current path and the fourth current path may be relatively small. This reduces a difference in inductance between the third current path and the fourth current path.

(2-2) In plan view, the semiconductor light-emitting element 30 and the third capacitor 112 are spaced apart from each other in the X-direction. In plan view, the third switching element 111 is arranged between the semiconductor light-emitting element 30 and the third capacitor 112 in the X-direction. In plan view, the semiconductor light-emitting element 30 and the fourth capacitor 122 are spaced apart from each other in the X-direction. In plan view, the fourth switching element 121 is arranged between the semiconductor light-emitting element 30 and the fourth capacitor 122 in the Y-direction.

With this configuration, the looped third current path formed by the third light emitter 33C of the semiconductor light-emitting element 30, the third switching element 111, and the third capacitor 112 is shorter as compared to a configuration in which the third switching element 111 is located at a side of the third capacitor 112 opposite to the semiconductor light-emitting element 30 in the X-direction. Further, the looped fourth current path formed by the fourth light emitter 33D of the semiconductor light-emitting element 30, the fourth switching element 121, and the fourth capacitor 122 is shorter as compared to a configuration in which the fourth switching element 121 is located at a side of the fourth capacitor 122 opposite to the semiconductor light-emitting element 30 in the X-direction.

(2-3) The distance D3 between the semiconductor light-emitting element 30 and the third switching element 111 in the X-direction is equal to the distance D4 between the semiconductor light-emitting element 30 and the fourth switching element 121 in the X-direction.

With this configuration, the current path between the semiconductor light-emitting element 30 and the third switching element 111 is equal in length to the current path between the semiconductor light-emitting element 30 and the fourth switching element 121. This reduces a difference in length between the looped third current path formed by the third light emitter 33C of the semiconductor light-emitting element 30, the third switching element 111, and the third capacitor 112 and the looped fourth current path formed by the fourth light emitter 33D of the semiconductor light-emitting element 30, the fourth switching element 121, and the fourth capacitor 122.

(2-4) The third capacitor 112 is one of third capacitors 112, and the fourth capacitor 122 is one of fourth capacitors 122. The third capacitors 112 are connected in parallel to each other. The fourth capacitors 122 are connected in parallel to each other.

With this configuration, the third capacitors 112 are connected in parallel to each other, so that the total inductance of the third capacitors 112 is less than the inductance of each of the third capacitors 112. Further, the fourth capacitors 122 are connected in parallel to each other, so that the total inductance of the fourth capacitors 122 is less than the inductance of each of the fourth capacitors 122.

(2-5) The third capacitors 112 are aligned with and spaced apart from each other in the Y-direction. The fourth capacitors 122 are aligned with and spaced apart from each other in the Y-direction.

With this configuration, in plan view, the third capacitors 112 are aligned in a direction (Y-direction) orthogonal to the direction (X-direction) in which the semiconductor light-emitting element 30, the third switching element 111, and the third capacitor 112 are arranged. Therefore, the looped third current path formed by the third light emitter 33C of the semiconductor light-emitting element 30, the third switching element 111, and the third capacitor 112 is relatively short. In plan view, the fourth capacitors 122 are aligned in a direction (Y-direction) orthogonal to the direction (X-direction) in which the semiconductor light-emitting element 30, the fourth switching element 121, and the fourth capacitor 122 are arranged. Therefore, the looped fourth current path formed by the fourth light emitter 33D of the semiconductor light-emitting element 30, the fourth switching element 121, and the fourth capacitor 122 is relatively short.

(2-6) The semiconductor light-emitting device 10 further includes the third protection diode 103 connected in antiparallel to the third light emitter 33C, and the fourth protection diode 104 connected in antiparallel to the fourth light emitter 33D.

With this configuration, the third protection diode 103 and the fourth protection diode 104 protect the third light emitter 33C and the fourth light emitter 33D separately.

(2-7) The third protection diode 103 is located at a side of the third switching element 111 opposite to the semiconductor light-emitting element 30 in the X-direction. The fourth protection diode 104 is located at a side of the fourth switching element 121 opposite to the semiconductor light-emitting element 30 in the X-direction. The third protection diode 103 is spaced apart from the third capacitor 112 in the Y-direction. The fourth protection diode 104 is spaced apart from the fourth capacitor 122 in the Y-direction.

With this configuration, the looped third current path formed by the semiconductor light-emitting element 30, the third switching element 111, and the third capacitor 112 is shorter as compared to a configuration in which the third protection diode 103 is arranged between the semiconductor light-emitting element 30 and the third switching element 111 or between the third switching element 111 and the third capacitor 112. Further, the fourth current path formed by the semiconductor light-emitting element 30, the fourth switching element 121, and the fourth capacitor 122 is shorter as compared to a configuration in which the fourth protection diode 104 is arranged between the semiconductor light-emitting element 30 and the fourth switching element 121 or between the fourth switching element 121 and the fourth capacitor 122.

(2-8) As viewed in the X-direction, the first vias 161B are formed in a region that overlaps the region in which the first vias 161A are formed. As viewed in the X-direction, the first vias 161C are formed in a region that overlaps the region in which the first vias 161A are formed.

With this configuration, the first intermediate electrode 151 forms part of the loop of the third current path, in which electric current flows through the first electrode 112A of the third capacitor 112, the drain electrode 111D of the third switching element 111, the source electrode 111S, the third element front-surface electrode 34C of the semiconductor light-emitting element 30, the element back-surface electrode 35, and the second electrode 112B of the third capacitor 112 in this order. The part of the third current path formed by the first intermediate electrode 151 extends in the X-direction. This decreases the area of the loop of the third current path, thereby reducing the inductance of the third current path. Further, the first intermediate electrode 151 forms part of the loop of the fourth current path, in which electric current flows through the first electrode 122A of the fourth capacitor 122, the drain electrode 121D of the fourth switching element 121, the source electrode 121S, the fourth element front-surface electrode 34D of the semiconductor light-emitting element 30, the element back-surface electrode 35, and the second electrode 122B of the fourth capacitor 122 in this order. The part of the fourth current path formed by the first intermediate electrode 151 extends in the X-direction. This decreases the area of the loop of the fourth current path, thereby reducing the inductance of the fourth current path.

(2-9) As viewed in the X-direction, the third switching element 111 is located at a position that overlaps the third light emitter 33C of the semiconductor light-emitting element 30. As viewed in the X-direction, the fourth switching element 121 is located at a position that overlaps the fourth light emitter 33D of the semiconductor light-emitting element 30.

With this configuration, the distance between the third switching element 111 and the semiconductor light-emitting element 30 is shorter as compared to a configuration in which the third switching element 111 is shifted from the semiconductor light-emitting element 30 in the Y-direction. Therefore, when the source electrode 111S of the third switching element 111 is connected to the third element front-surface electrode 34C of the semiconductor light-emitting element 30 by the wires W1, the wires W1 are relatively short. The distance between the fourth switching element 121 and the semiconductor light-emitting element 30 is shorter as compared to a configuration in which the fourth switching element 121 is shifted from the semiconductor light-emitting element 30 in the Y-direction. Therefore, when the source electrode 121S of the fourth switching element 121 is connected to the fourth element front-surface electrode 34D of the semiconductor light-emitting element 30 by the wires W1, the wires W1 are relatively short.

### Third Embodiment

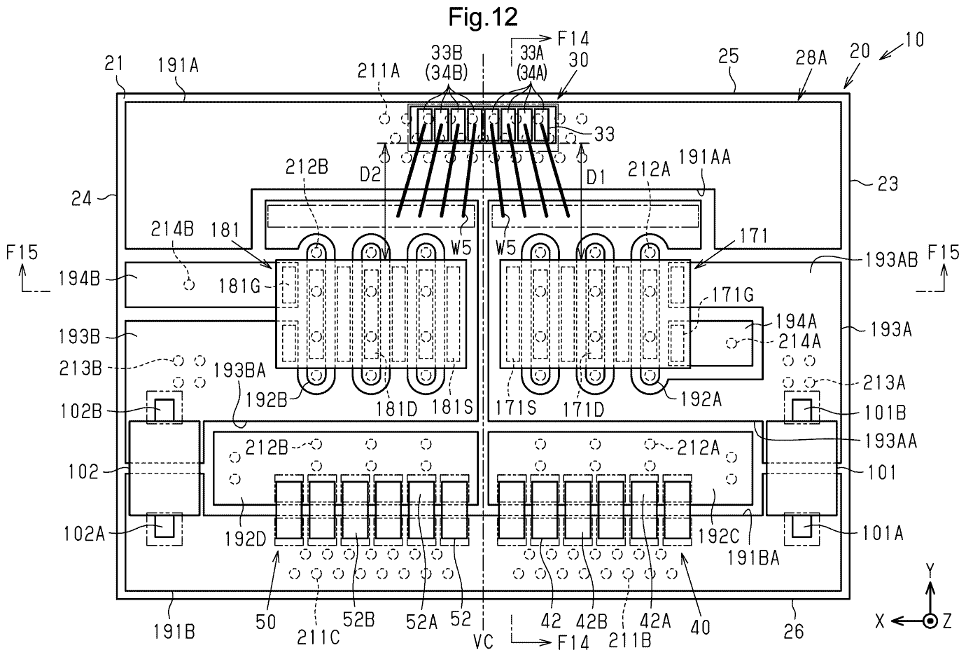

A semiconductor light-emitting device 10 in accordance with a third embodiment will now be described with reference to FIGS. 12 to 15. The semiconductor light-emitting device 10 of the third embodiment mainly differs from the semiconductor light-emitting device 10 of the first embodiment in that a first switching element 171 and a second switching element 181 are included instead of the first switching element 41 and the second switching element 51. Hereinafter, the description will focus on the differences from the first embodiment. The same reference characters are given to those components that are the same as the corresponding components of the first embodiment, and such components will not be described in detail.

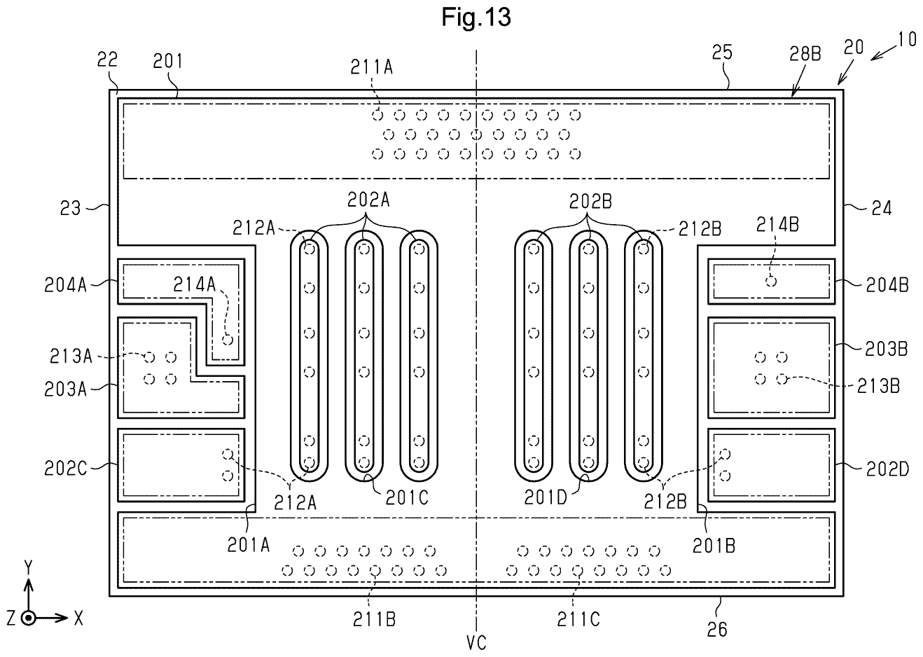

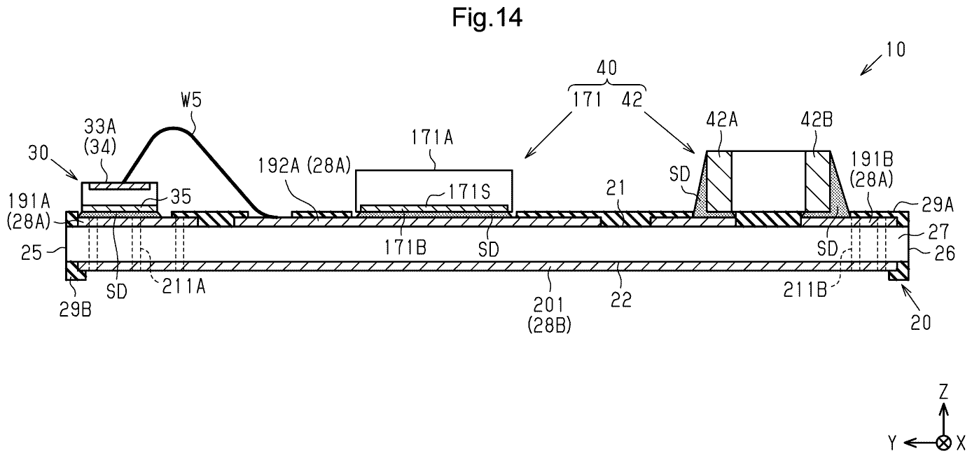

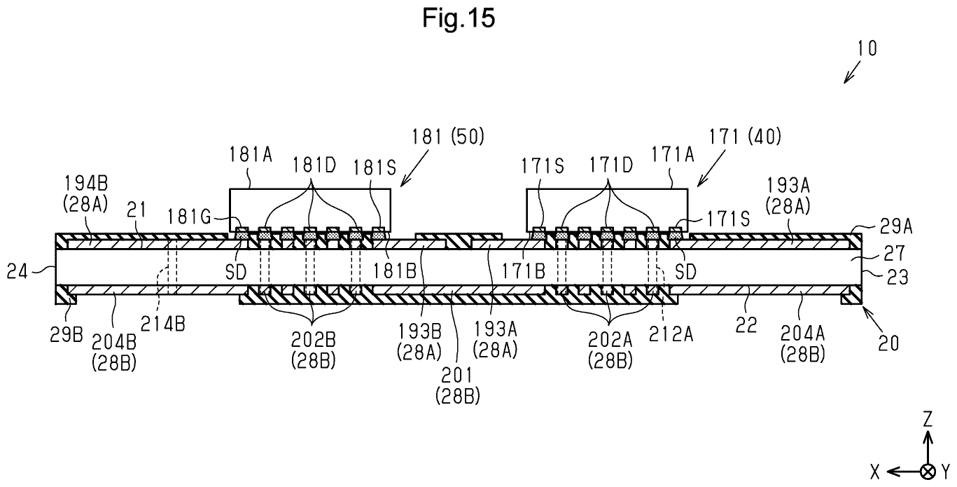

FIG. 12 shows a schematic planar structure of the semiconductor light-emitting device 10 in accordance with the third embodiment. FIG. 13 shows a schematic bottom structure of the semiconductor light-emitting device 10 shown in FIG. 12. FIG. 14 shows a schematic cross-sectional structure of the semiconductor light-emitting device 10 taken along line F14-F14 shown in FIG. 12. FIG. 15 shows a schematic cross-sectional structure of the semiconductor light-emitting device 10 taken along line F15-F15 shown in FIG. 12. In FIGS. 12 and 13, boxes defined by double-dashed lines indicate open portions formed in the front surface resist 29A and the back surface resist 29B (refer to FIG. 14).

As shown in FIG. 12, the semiconductor light-emitting device 10 of the third embodiment includes the first drive circuit 40 and the second drive circuit 50 in the same manner as the first embodiment. That is, the semiconductor light-emitting device 10 has the same circuitry as the first embodiment.

The first drive circuit 40 includes a first switching element 171 and multiple (in the third embodiment, six) first capacitors 42. The second drive circuit 50 includes a second switching element 181 and multiple (in the third embodiment, six) second capacitors 52. Unlike the first embodiment, the first switching element 171 and the second switching element 181 include a lateral transistor. In an example, the first switching element 171 and the second switching element 181 include a transistor formed from a nitride semiconductor (e.g., gallium nitride (GaN)). An example of such a transistor may be a high-electron-mobility transistor (HEMT) that uses a nitride semiconductor. As long as the first switching element 171 and the second switching element 181 include a lateral transistor, a MOSFET may be used.

As described above, the configurations of the first switching element 171 and the second switching element 181 differ from those of the first embodiment, such that the configuration of the substrate 20 is changed. More specifically, unlike the first embodiment, the substrate 20 does not include the front-surface intermediate electrodes 28C (refer to FIG. 4) or the back-surface intermediate electrodes 28D (refer to FIG. 3). That is, the substrate 20 includes a single base member 27, the front-surface electrodes 28A, and the back-surface electrodes 28B. The configurations of the front-surface electrodes 28A and the back-surface electrodes 28B differ from those of the first embodiment. The configurations of the front-surface electrodes 28A and the back-surface electrodes 28B will now be described in detail.

The front-surface electrodes 28A are formed in the base-member front surface (substrate front surface 21) of the single base member 27. The front-surface electrodes 28A include first front-surface electrodes 191A and 191B, second front-surface electrodes 192A, 192B, 192C, and 192D, third front-surface electrodes 193A and 193B, and fourth front-surface electrodes 194A and 194B.

The first front-surface electrode 191A and the first front-surface electrode 191B are located at two opposite ends of the substrate front surface 21 in the Y-direction. The semiconductor light-emitting element 30 is mounted on the first front-surface electrode 191A. The first front-surface electrode 191A is electrically connected to the element back-surface electrode 35 (refer to FIG. 14), which serves as the cathode of the semiconductor light-emitting element 30. The first front-surface electrode 191B is electrically connected to the first front-surface electrode 191A.

The first front-surface electrode 191A is adjacent to the third substrate side surface 25 in the Y-direction and extends in the X-direction. The first front-surface electrode 191A is formed across substantially the entire substrate front surface 21 in the X-direction. The first front-surface electrode 191A has a maximum dimension in the Y-direction that is greater than or equal to one-fourth of the dimension of the substrate front surface 21 in the Y-direction. The maximum dimension of the first front-surface electrode 191A in the Y-direction is less than one-third of the dimension of the substrate front surface 21 in the Y-direction.

In plan view, one of two opposite ends of the first front-surface electrode 191A in the Y-direction that is located closer to the fourth substrate side surface 26 includes a recess 191AA at a central part of the first front-surface electrode 191A in the X-direction. The recess 191AA is recessed toward the third substrate side surface 25 in the X-direction. In an example, the recess 191AA is rectangular in plan view. The length of the recess 191AA in the X-direction is greater than one-half of the dimension of the substrate front surface 21 in the X-direction. The length of the recess 191AA in the X-direction is less than three-fourths of the dimension of the substrate front surface 21 in the X-direction. The length of the recess 191AA in the X-direction may be defined by the distance between two opposite ends of the recess 191AA in the X-direction.

The first front-surface electrode 191B is adjacent to the fourth substrate side surface 26 in the Y-direction and extends in the X-direction. The first front-surface electrode 191B is formed across substantially the entire substrate front surface 21 in the X-direction. The first front-surface electrode 191B has a maximum dimension in the Y-direction that is less than the maximum dimension of the first front-surface electrode 191A in the Y-direction. The maximum dimension of the first front-surface electrode 191B in the Y-direction is greater than one-half of the maximum dimension of the first front-surface electrode 191A in the Y-direction.

In plan view, one of two opposite ends of the first front-surface electrode 191B in the Y-direction that is located closer to the third substrate side surface 25 includes a recess 191BA at a central part of the first front-surface electrode 191B in the X-direction. The recess 191BA is recessed toward the fourth substrate side surface 26. In an example, the recess 191BA is rectangular in plan view. The recess 191BA is larger than the recess 191AA in the X-direction. The length of the recess 191BA in the X-direction may be defined by the distance between two opposite ends of the recess 191BA in the X-direction.

The second front-surface electrode 192A, 192B, 192C, and 192D, the third front-surface electrodes 193A and 193B, and the fourth front-surface electrodes 194A and 194B are arranged between the first front-surface electrode 191A and the first front-surface electrode 191B in the Y-direction.

The second front-surface electrodes 192A and 192C, the third front-surface electrode 193A, the fourth front-surface electrode 194A, and the first front-surface electrode 191B are electrically connected to the first drive circuit 40. The second front-surface electrodes 192B and 192D, the third front-surface electrode 193B, the fourth front-surface electrode 194B, and the first front-surface electrode 191B are electrically connected to the second drive circuit 50.

The second front-surface electrodes 192A and 192C, the third front-surface electrode 193A, and the fourth front-surface electrode 194A are located closer to the first substrate side surface 23 than the imaginary centerline VC is. The second front-surface electrodes 192B and 192D, the third front-surface electrode 193B, and the fourth front-surface electrode 194B are located closer to the second substrate side surface 24 than the imaginary centerline VC is.

The second front-surface electrode 192A is electrically connected to a drain electrode 171D of the first switching element 171 of the first drive circuit 40. The second front-surface electrode 192C is electrically connected to the second front-surface electrode 192A. The second front-surface electrode 192B is electrically connected to a drain electrode 181D of the second switching element 181 of the second drive circuit 50. The second front-surface electrode 192D is electrically connected to the second front-surface electrode 192B.

Multiple (in the third embodiment, three) second front-surface electrodes 192A are provided. Each of the second front-surface electrodes 192A is elliptic and extends in the Y-direction. The second front-surface electrodes 192A are located at the same position in the Y-direction and are spaced apart from each other in the X-direction. The second front-surface electrodes 192A are arranged between the imaginary centerline VC and the first substrate side surface 23 and are located relatively close to the imaginary centerline VC in the X-direction.

Multiple (in the third embodiment, three) second front-surface electrodes 192B are provided. The second front-surface electrodes 192B and the second front-surface electrodes 192A are identical in shape and size. The second front-surface electrodes 192B and the second front-surface electrodes 192A are symmetric with respect to the imaginary centerline VC.

The second front-surface electrodes 192A and 192B are arranged between the first front-surface electrode 191A and the first front-surface electrode 191B and are located relatively close to the first front-surface electrode 191A in the Y-direction. Ends of the second front-surface electrodes 192A and 192B in the Y-direction that are located relatively close to the first front-surface electrode 191A are arranged in the recess 191AA in the Y-direction.

The second front-surface electrodes 192C and 192D are located closer to the fourth substrate side surface 26 than the second front-surface electrodes 192A and 192B are in the Y-direction.

The second front-surface electrode 192C is rectangular in plan view, with long sides extending in the X-direction and short sides extending in the Y-direction. The dimension of the second front-surface electrode 192C in the X-direction is greater than one-third of the dimension of the substrate front surface 21 in the X-direction and is less than one-half of the dimension of the substrate front surface 21 in the X-direction. One of two opposite ends of the second front-surface electrode 192C in the X-direction that is located closer to the first substrate side surface 23 is closer to the first substrate side surface 23 than one of the second front-surface electrodes 192A that is located closest to the first substrate side surface 23.

The second front-surface electrode 192D and the second front-surface electrode 192C are symmetric with respect to the imaginary centerline VC. One of two opposite ends of the second front-surface electrode 192D in the X-direction that is located closer to the second substrate side surface 24 is closer to the second substrate side surface 24 than one of the second front-surface electrodes 192B that is located closest to the second substrate side surface 24.

The second front-surface electrodes 192C and 192D are arranged in the recess 191BA in the X-direction. The second front-surface electrodes 192C and 192D are partially arranged in the recess 191BA in the Y-direction.

The third front-surface electrode 193A is electrically connected to a source electrode 171S of the first switching element 171. The third front-surface electrode 193B is electrically connected to a source electrode 181S of the second switching element 181. The fourth front-surface electrode 194A is electrically connected to a gate electrode 171G of the first switching element 171. The fourth front-surface electrode 194B is electrically connected to a gate electrode 181G of the second switching element 181.

The third front-surface electrodes 193A and 193B are arranged between the first front-surface electrode 191A and the second front-surface electrodes 192C and 192D in the Y-direction.

In plan view, the third front-surface electrode 193A surrounds the second front-surface electrodes 192A. One of two opposite ends of the third front-surface electrode 193A in the Y-direction that is located closer to the first front-surface electrode 191A is arranged in the recess 191AA. This end is located closer to the first front-surface electrode 191A than the second front-surface electrodes 192A are.

The other one of the two opposite ends of the third front-surface electrode 193A in the Y-direction that is located closer to the first front-surface electrode 191B includes an indent 193AA that opposes the recess 191BA. Part of the second front-surface electrode 192C in the Y-direction is located in the indent 193AA.

The third front-surface electrode 193A includes a detour section 193AB that surrounds the fourth front-surface electrode 194A. The detour section 193AB detours around the fourth front-surface electrode 194A and opposes the second front-surface electrode 192A in the X-direction at a position where the detour section 193AB is located closer to the first front-surface electrode 191A than the fourth front-surface electrode 194A is in the Y-direction.

The fourth front-surface electrode 194A is located closer to the first substrate side surface 23 than the second front-surface electrodes 192A are in the X-direction. The fourth front-surface electrode 194A opposes the second front-surface electrode 192A in the X-direction at a portion where the second front-surface electrode 192A is located relatively close to the third front-surface electrode 193A. The fourth front-surface electrode 194A is located in a region surrounded by the second front-surface electrode 192A and the detour section 193AB. The fourth front-surface electrode 194A is rectangular, with long sides extending in the X-direction and short sides extending in the Y-direction.

In plan view, the third front-surface electrode 193B surrounds the second front-surface electrodes 192B. The third front-surface electrode 193B and the third front-surface electrode 193A are not symmetric with respect to the imaginary centerline VC. One of two opposite ends of the third front-surface electrode 193B in the Y-direction that is located closer to the first front-surface electrode 191A is arranged in the recess 191AA. This end is located closer to the first front-surface electrode 191A than the second front-surface electrodes 192B are.

The other one of the two opposite ends of the third front-surface electrode 193B in the Y-direction that is located closer to the first front-surface electrode 191B includes an indent 193BA that opposes the recess 191BA. Part of the second front-surface electrode 192D in the Y-direction is located in the indent 193BA. In this manner, in plan view, the second front-surface electrodes 192C and 192D are located in a region defined by the recess 191BA, the indent 193AA, and the indent 193BA.

The fourth front-surface electrode 194B is located closer to the second substrate side surface 24 than the second front-surface electrodes 192B are in the X-direction. The fourth front-surface electrode 194B opposes the second front-surface electrode 192B in the X-direction at a portion where the second front-surface electrode 192B is located relatively close to the first front-surface electrode 191A. Specifically, the fourth front-surface electrode 194B is located closer to the first front-surface electrode 191A than the fourth front-surface electrode 194B is in the Y-direction, so that the fourth front-surface electrode 194B and the fourth front-surface electrode 194A are not symmetric with respect to the imaginary centerline VC. The fourth front-surface electrode 194B is rectangular, with long sides extending in the X-direction and short sides extending in the Y-direction. The fourth front-surface electrode 194B is larger than the fourth front-surface electrode 194A in the X-direction.

As shown in FIG. 13, the back-surface electrodes 28B are formed in the base-member back surface (substrate back surface 22) of the single base member 27. The back-surface electrodes 28B include a first back-surface electrode 201, second back-surface electrodes 202A, 202B, 202C, and 202D, third back-surface electrodes 203A and 203B, and fourth back-surface electrodes 204A and 204B.

The first back-surface electrode 201 is electrically connected to the first front-surface electrodes 191A and 191B (refer to FIG. 12). The first back-surface electrode 201 is located at a position that overlaps the first front-surface electrodes 191A and 191B in plan view. In plan view, the first back-surface electrode 201 has a greater area than each of the second back-surface electrodes 202A, 202B, 202C, and 202D, the third back-surface electrodes 203A and 203B, or the fourth back-surface electrodes 204A and 204B. The area of the first back-surface electrode 201 is greater than the combined total area of the third back-surface electrodes 203A and 203B and the fourth back-surface electrodes 204A and 204B. In an example, the first back-surface electrode 201 is formed across most of the substrate back surface 22.

The first back-surface electrode 201 includes two recesses 201A and 201B that are recessed in the X-direction. The recess 201A is arranged in one of two opposite ends of the first back-surface electrode 201 in the X-direction that is located closer to the first substrate side surface 23. The recess 201A is recessed from this end toward the second substrate side surface 24. The recess 201B is arranged in the other one of the two opposite ends of the first back-surface electrode 201 in the X-direction that is located closer to the second substrate side surface 24. The recess 201B is recessed from this end toward the first substrate side surface 23. In plan view, the recesses 201A and 201B are each rectangular, with long sides extending in the Y-direction and short sides extending in the X-direction. The recesses 201A and 201B are arranged between the third substrate side surface 25 and the fourth substrate side surface 26 and are located relatively close to the fourth substrate side surface 26 in the Y-direction. The length of the recess 201A, 201B in the Y-direction is approximately one-half of the dimension of the substrate back surface 22 in the Y-direction. The length of the recess 201A, 201B in the Y-direction may be defined by the distance between two opposite ends of the recess 201A, 201B in the Y-direction.

The first back-surface electrode 201 includes first openings 201C and second openings 201D. The first openings 201C and the second openings 201D are each elliptic in plan view, with major axis extending in the Y-direction and minor axis extending in the X-direction. The first openings 201C and the second openings 201D are identical in size. In an example, the first openings 201C and the second openings 201D are slightly smaller than the recesses 201A and 201B in the Y-direction.

The first openings 201C are located closer to the first substrate side surface 23 than the imaginary centerline VC is in the X-direction. The first openings 201C are located at the same position in the Y-direction and are spaced apart from each other in the X-direction.

The second openings 201D are located closer to the second substrate side surface 24 than the imaginary centerline VC is in the X-direction. The second openings 201D are located at the same position in the Y-direction and are spaced apart from each other in the X-direction. The second openings 201D are located at the same position as the first openings 201C in the Y-direction. In an example, the second openings 201D and the first openings 201C are symmetric with respect to the imaginary centerline VC.

The first openings 201C and the second openings 201D are arranged between the recesses 201A and 201B in the X-direction. The first openings 201C and the second openings 201D are located closer to the third substrate side surface 25 than the recesses 201A and 201B are in the Y-direction. Therefore, ends of the first openings 201C and the second openings 201D in the Y-direction that are located relatively close to the third substrate side surface 25 are closer to the third substrate side surface 25 than the recesses 201A and 201B are.

Multiple (in the third embodiment, three) second back-surface electrodes 202A are provided in accordance with the number of first openings 201C. The second back-surface electrodes 202A are separately electrically connected to the second front-surface electrodes 192A (refer to FIG. 12). The second back-surface electrodes 202A are electrically connected to the second front-surface electrode 192C (refer to FIG. 12). Thus, the second back-surface electrodes 202A are electrically connected to each other. In plan view, the second back-surface electrodes 202A separately overlap the second front-surface electrodes 192A.

The second back-surface electrodes 202A are each elliptic, with major axis extending in the Y-direction and minor axis extending in the X-direction. The second back-surface electrodes 202A are longer than the second front-surface electrodes 192A in the Y-direction. The second back-surface electrodes 202A extend in the Y-direction, so that the second back-surface electrodes 202A overlap the second front-surface electrode 192C in plan view. That is, the second back-surface electrodes 202A are dimensioned to overlap both the second front-surface electrodes 192A and the second front-surface electrode 192C in plan view.

Multiple (in the third embodiment, three) second back-surface electrodes 202B are provided in accordance with the number of second openings 201D. The second back-surface electrodes 202B are separately electrically connected to the second front-surface electrodes 192B (refer to FIG. 12). The second back-surface electrodes 202B are electrically connected to the second front-surface electrode 192D (refer to FIG. 12). Thus, the second back-surface electrodes 202B are electrically connected to each other. In plan view, the second back-surface electrodes 202B separately overlap the second front-surface electrodes 192B.

The second back-surface electrodes 202B are each elliptic, with major axis extending in the Y-direction and minor axis extending in the X-direction. The second back-surface electrodes 202B are longer than the second front-surface electrodes 192B in the Y-direction. The second back-surface electrodes 202B extend in the Y-direction, so that the second back-surface electrodes 202B overlap the second front-surface electrode 192D in plan view. That is, the second back-surface electrodes 202B are dimensioned to overlap both the second front-surface electrodes 192B and the second front-surface electrode 192D in plan view. The second back-surface electrodes 202B and the second back-surface electrodes 202A are identical in size.

The second back-surface electrode 202C, the third back-surface electrode 203A, and the fourth back-surface electrode 204A are located in the recess 201A. The second back-surface electrode 202D, the third back-surface electrode 203B, and the fourth back-surface electrode 204B are located in the recess 201B. The second back-surface electrodes 202A are respectively disposed in the first openings 201C. The second back-surface electrodes 202B are respectively disposed in the second openings 201D.

The second back-surface electrode 202C is electrically connected to the second front-surface electrode 192C (refer to FIG. 12). Therefore, the second back-surface electrode 202C is electrically connected to the second back-surface electrodes 202A. The second back-surface electrode 202C is located closer to the fourth substrate side surface 26 than the third back-surface electrode 203A and the fourth back-surface electrode 204A are. The second back-surface electrode 202C is located at a position that overlaps the second front-surface electrode 192C in plan view. The second back-surface electrode 202C is rectangular in plan view, with long sides extending in the X-direction and short sides extending in the Y-direction.

The third back-surface electrode 203A is electrically connected to the third front-surface electrode 193A (refer to FIG. 12). The third back-surface electrode 203A is arranged between the second back-surface electrode 202C and the fourth back-surface electrode 204A in the Y-direction. The third back-surface electrode 203A is located at a position that overlaps the third front-surface electrode 193A in plan view. The third back-surface electrode 203A includes an indent formed in one of four corners that is located relatively close to both the second substrate side surface 24 and the third substrate side surface 25.

The fourth back-surface electrode 204A is partially located in the indent. The fourth back-surface electrode 204A is electrically connected to the fourth front-surface electrode 194A. The fourth back-surface electrode 204A is located at a position that overlaps the fourth front-surface electrode 194A in plan view. The fourth back-surface electrode 204A is L-shaped in plan view.

The second back-surface electrode 202D is electrically connected to the second front-surface electrode 192D (refer to FIG. 12). Therefore, the second back-surface electrode 202D is electrically connected to the second back-surface electrodes 202B. The second back-surface electrode 202D is located at a position that overlaps the second front-surface electrode 192D in plan view. The second back-surface electrode 202D is located closer to the fourth substrate side surface 26 than the third back-surface electrode 203B and the fourth back-surface electrode 204B are. The second back-surface electrode 202D is rectangular in plan view, with long sides extending in the X-direction and short sides extending in the Y-direction. The second back-surface electrode 202D and the second back-surface electrode 202C are identical in size.

The third back-surface electrode 203B is electrically connected to the third front-surface electrode 193B (refer to FIG. 12). The third back-surface electrode 203B is arranged between the second back-surface electrode 202D and the fourth back-surface electrode 204B in the Y-direction. The third back-surface electrode 203B is located at a position that overlaps the third front-surface electrode 193B in plan view. The third back-surface electrode 203B is rectangular in plan view, with long sides extending in the X-direction and short sides extending in the Y-direction. The third back-surface electrode 203B is larger than the second back-surface electrode 202D in the Y-direction.

The fourth back-surface electrode 204B is electrically connected to the fourth front-surface electrode 194B (refer to FIG. 12). The fourth back-surface electrode 204B is located at a position that overlaps the fourth front-surface electrode 194B in plan view. The fourth back-surface electrode 204B is rectangular in plan view, with long sides extending in the X-direction and short sides extending in the Y-direction. The fourth back-surface electrode 204B is smaller than the second back-surface electrode 202D in the Y-direction.

As shown in FIGS. 12 and 13, the substrate 20 includes first vias 211A, 211B, and 211C, second vias 212A and 212B, third vias 213A and 213B, and fourth vias 214A and 214B. The first vias 211A, 211B, and 211C, the second vias 212A and 212B, the third vias 213A and 213B, and the fourth vias 214A and 214B extend through the base member 27 in the Z-direction. The first vias 211A, 211B, and 211C, the second vias 212A and 212B, the third vias 213A and 213B, and the fourth vias 214A and 214B are formed from, for example, a material containing one or more selected from Ti, TiN, Au, Ag, Cu, Al, and W.

Multiple first vias 211A, multiple first vias 211B, and multiple first vias 211C are provided. The first vias 211A are electrically connected to the first front-surface electrode 191A and the first back-surface electrode 201. Therefore, the first front-surface electrode 191A is electrically connected to the first back-surface electrode 201. The first vias 211B and 211C are electrically connected to the first front-surface electrode 191B and the first back-surface electrode 201. Therefore, the first front-surface electrode 191B is electrically connected to the first back-surface electrode 201. In this manner, the first front-surface electrode 191A is electrically connected to the first front-surface electrode 191B through the first vias 211A, the first back-surface electrode 201, and the first vias 211B and 211C.

The first vias 211A are disposed in a central part of the first front-surface electrode 191A in the X-direction and are located relatively close to the third substrate side surface 25 in the Y-direction. The first vias 211A are aligned with and spaced apart from one another in the X-direction and the Y-direction. A greater number of first vias 211A are aligned in the X-direction than in the Y-direction. In plan view, the first vias 211A are formed in a region that is larger than the area of the semiconductor light-emitting element 30. Therefore, some of the first vias 211A are located outside the semiconductor light-emitting element 30 in plan view.

The first vias 211B are arranged in the first front-surface electrode 191B and are located closer to the first substrate side surface 23 than the imaginary centerline VC is in the X-direction. The first vias 211B are arranged in the first front-surface electrode 191B and are located relatively close to the fourth substrate side surface 26 in the Y-direction. The first vias 211B are aligned with and spaced apart from one another in the X-direction and the Y-direction. A greater number of first vias 211B are aligned in the X-direction than in the Y-direction.

The first vias 211C are arranged in the first front-surface electrode 191B and are located closer to the second substrate side surface 24 than the imaginary centerline VC is in the X-direction. The first vias 211C are arranged in the first front-surface electrode 191B and are located relatively close to the fourth substrate side surface 26 in the Y-direction. The first vias 211C are aligned with and spaced apart from one another in the X-direction and the Y-direction. A greater number of first vias 211C are aligned in the X-direction than in the Y-direction. In an example, the first vias 211C and the first vias 211B are identical in number and layout.

Multiple second vias 212A are provided. Some of the second vias 212A are separately electrically connected to the second front-surface electrodes 192A and the second back-surface electrodes 202A. Therefore, the second front-surface electrodes 192A are separately electrically connected to the second back-surface electrodes 202A. Further, some of the second vias 212A are electrically connected to the second front-surface electrode 192C and the second back-surface electrodes 202A. Therefore, the second front-surface electrode 192C is electrically connected to the second back-surface electrodes 202A. In this manner, the second front-surface electrodes 192A are electrically connected to the second front-surface electrode 192C through the second vias 212A and the second back-surface electrodes 202A. Furthermore, some of the second vias 212A are electrically connected to the second front-surface electrode 192C and the second back-surface electrode 202C. Therefore, the second front-surface electrode 192C is electrically connected to the second back-surface electrode 202C.

Multiple second vias 212B are provided. Some of the second vias 212B are separately electrically connected to the second front-surface electrodes 192B and the second back-surface electrodes 202B. Therefore, the second front-surface electrodes 192B are separately electrically connected to the second back-surface electrodes 202B. Further, some of the second vias 212B are electrically connected to the second front-surface electrode 192D and the second back-surface electrodes 202B. Therefore, the second front-surface electrode 192D is electrically connected to the second back-surface electrodes 202B. In this manner, the second front-surface electrodes 192B are electrically connected to the second front-surface electrode 192D through the second vias 212B and the second back-surface electrodes 202B. Furthermore, some of the second vias 212B are electrically connected to the second front-surface electrode 192D and the second back-surface electrode 202D. Therefore, the second front-surface electrode 192D is electrically connected to the second back-surface electrode 202D.

Multiple third vias 213A are provided. The third vias 213A are electrically connected to the third front-surface electrode 193A and the third back-surface electrode 203A. Therefore, the third front-surface electrode 193A is electrically connected to the third back-surface electrode 203A.

Multiple third vias 213B are provided. The third vias 213B are electrically connected to the third front-surface electrode 193B and the third back-surface electrode 203B. Therefore, the third front-surface electrode 193B is electrically connected to the third back-surface electrode 203B.

A single fourth via 214A is provided. The fourth via 214A is electrically connected to the fourth front-surface electrode 194A and the fourth back-surface electrode 204A. Therefore, the fourth front-surface electrode 194A is electrically connected to the fourth back-surface electrode 204A.

A single fourth via 214B is provided. The fourth via 214B is electrically connected to the fourth front-surface electrode 194B and the fourth back-surface electrode 204B. Therefore, the fourth front-surface electrode 194B is electrically connected to the fourth back-surface electrode 204B.

### Configuration and Layout of Semiconductor Light-Emitting Element, First Drive Circuit, and Second Drive Circuit

As shown in FIG. 12, the semiconductor light-emitting element 30, the first drive circuit 40, and the second drive circuit 50 are mounted on the front-surface electrodes 28A. The configuration and arrangement of the semiconductor light-emitting element 30, the first drive circuit 40, and the second drive circuit 50 will now be described in detail. The same reference characters are given to those components that are the same as the corresponding components of the first embodiment, and such components may not be described in detail.

The semiconductor light-emitting element 30 is mounted on the first front-surface electrode 191A. More specifically, as shown in FIG. 14, the semiconductor light-emitting element 30 is bonded to the first front-surface electrode 191A by the conductive bonding material SD. As shown in FIG. 12, the semiconductor light-emitting element 30 is disposed in a central part of the first front-surface electrode 191A in the X-direction and is located relatively close to the third substrate side surface 25 in the Y-direction.

The semiconductor light-emitting element 30 includes multiple (in the third embodiment, eight) light emitters 33. The light emitters 33 are arranged side by side in the X-direction. More specifically, four light emitters 33 are arranged at each side of the imaginary centerline VC. The four light emitters 33 located closer to the first substrate side surface 23 than the imaginary centerline VC is will be referred to as “first light emitter 33A”. The four light emitters 33 located closer to the second substrate side surface 24 than the imaginary centerline VC is will be referred to as “second light emitter 33B”. The semiconductor light-emitting element 30 includes multiple (in the third embodiment, four) first element front-surface electrodes 34A corresponding to the first light emitter 33A, and multiple (in the third embodiment, four) second element front-surface electrodes 34B corresponding to the second light emitter 33B. The first element front-surface electrode 34A is an example of “the first anode electrode of the semiconductor light-emitting element”. The second element front-surface electrode 34B is an example of “the second anode electrode of the semiconductor light-emitting element”.

The first element front-surface electrodes 34A are electrically connected to the third front-surface electrode 193A by wires W5. The wires W5 are separately electrically connected to the first element front-surface electrodes 34A. The wires W5 are electrically connected to the third front-surface electrode 193A. Thus, the first element front-surface electrodes 34A are electrically connected to the third front-surface electrode 193A. The wires W5 are connected to a portion of the third front-surface electrode 193A that is located in the recess 191AA of the first front-surface electrode 191A. For example, the wires W5 separately connected to the first element front-surface electrodes 34A have substantially the same length in plan view.

The second element front-surface electrodes 34B are electrically connected to the third front-surface electrode 193B by the wires W5. The wires W5 are separately electrically connected to the second element front-surface electrodes 34B. The wires W5 are electrically connected to the third front-surface electrode 193B. Thus, the second element front-surface electrodes 34B are electrically connected to the third front-surface electrode 193B. The wires W5 are connected to a portion of the third front-surface electrode 193B that is located in the recess 191AA of the first front-surface electrode 191A. For example, the wires W5 which are separately connected to the second element front-surface electrodes 34B have substantially the same length in plan view.

In an example, in plan view, the total length of the wires W5 separately connected to the first element front-surface electrodes 34A is equal to the total length of the wires W5 separately connected to the second element front-surface electrodes 34B. It may be considered that the total length of the wires W5 separately connected to the first element front-surface electrodes 34A is equal to the total length of the wires W5 separately connected to the second element front-surface electrodes 34B in plan view as long as a difference in total length between the wires W5 separately connected to the first element front-surface electrodes 34A and the wires W5 separately connected to the second element front-surface electrodes 34B in plan view is, for example, within 10% of the total length of the wires W5 separately connected to the first element front-surface electrodes 34A.

In plan view, the first switching element 171 is located at a position that overlaps the second front-surface electrodes 192A, the third front-surface electrode 193A, and the fourth front-surface electrode 194A. The first switching element 171 is located closer to the fourth substrate side surface 26 than the wires W5 are in the Y-direction. The first switching element 171 is located closer to the third substrate side surface 25 than the second front-surface electrode 192C is in the Y-direction. The first switching element 171 is arranged between the imaginary centerline VC and the first substrate side surface 23 and is located relatively close to the imaginary centerline VC in the X-direction. The first switching element 171 includes a portion that overlaps the first light emitter 33A of the semiconductor light-emitting element 30 as viewed in the Y-direction. The first switching element 171 has a shape of a rectangular flat plate having a thickness-wise direction parallel to the Z-direction. The first switching element 171 is rectangular in plan view, with long sides extending in the X-direction and short sides extending in the Y-direction.

The first switching element 171 includes a second element front surface 171A and a second element back surface 171B facing away from each other in the Z-direction. The second element front surface 171A faces the same direction as the substrate front surface 21, and the second element back surface 171B faces the same direction as the substrate back surface 22. The first switching element 171 includes multiple (in the third embodiment, three) drain electrodes 171D, multiple (in the third embodiment, four) source electrodes 171S, and a gate electrode 171G. The drain electrodes 171D, the source electrodes 171S, and the gate electrode 171G are formed in the second element back surface 171B of the first switching element 171. The drain electrodes 171D, the source electrodes 171S, and the gate electrode 171G are each rectangular, with long sides extending in the Y-direction and short sides extending in the X-direction. The second element back surface is an example of “the element back surface of the first switching element”.

The drain electrodes 171D are aligned with and spaced apart from each other in the X-direction. The source electrodes 171S are aligned with and spaced apart from each other in the X-direction. One of the source electrodes 171S that is located closest to the first substrate side surface 23 is shorter than the other source electrodes 171S in the Y-direction. The other source electrodes 171S and the drain electrodes 171D have the same length in the Y-direction.

The drain electrodes 171D and the source electrodes 171S are alternately arranged in the X-direction. In the example shown in FIG. 12, the source electrode 171S, the drain electrode 171D, the source electrode 171S, the drain electrode 171D, the source electrode 171S, the drain electrode 171D, and the source electrode 171S are arranged in this order from an end of the second element back surface 171B that is located closer to the first substrate side surface 23 to another end of the second element back surface 171B that is located closer to the second substrate side surface 24. Accordingly, the source electrode 171S is arranged in both of the two opposite ends of the second element back surface 171B in the X-direction. The gate electrode 171G is arranged in an end of the second element back surface 171B that is located relatively close to the first substrate side surface 23. The gate electrode 171G is aligned with and spaced apart from one of the source electrodes 171S that is located closest to the first substrate side surface 23 in the Y-direction. The gate electrode 171G is located closer to the fourth substrate side surface 26 than the one of the source electrodes 171S that is located closest to the first substrate side surface 23 is. The gate electrode 171G is shorter than the drain electrodes 171D in the Y-direction. In an example, the gate electrode 171G and one of the source electrodes 171S that is located closest to the first substrate side surface 23 have the same length in the Y-direction.

In plan view, the drain electrodes 171D separately overlap the second front-surface electrodes 192A. As shown in FIG. 15, the drain electrodes 171D are separately bonded to the second front-surface electrodes 192A by the conductive bonding material SD. Therefore, the drain electrodes 171D are separately electrically connected to the second front-surface electrodes 192A.

Each of the source electrodes 171S is located at a position that overlaps the third front-surface electrode 193A. As shown in FIG. 15, the source electrodes 171S are bonded to the third front-surface electrode 193A by the conductive bonding material SD. Therefore, the source electrodes 171S are electrically connected to the third front-surface electrode 193A.

As shown in FIG. 12, the gate electrode 171G is located at a position that overlaps the fourth front-surface electrode 194A. The gate electrode 171G is bonded to the fourth front-surface electrode 194A by the conductive bonding material SD (not shown). Therefore, the gate electrode 171G is electrically connected to the fourth front-surface electrode 194A.

Multiple (in the third embodiment, six) first capacitors 42 are provided. The first capacitors 42 are connected in parallel to each other. The first capacitors 42 are aligned with and spaced apart from each other in the X-direction. Each of the first capacitors 42 extends over the second front-surface electrode 192C and the first front-surface electrode 191B in the Y-direction. The first capacitor 42 is mounted on the second front-surface electrode 192C and the first front-surface electrode 191B. More specifically, as shown in FIG. 14, the first capacitor 42 is separately bonded to the second front-surface electrode 192C and the first front-surface electrode 191B by the conductive bonding material SD. The first electrode 42A of the first capacitor 42 is bonded to the second front-surface electrode 192C. The second electrodes 42B of the first capacitor 42 are bonded to the first front-surface electrode 191B. Thus, the first electrode 42A is electrically connected to the second front-surface electrode 192C, the second electrode 42B is electrically connected to the first front-surface electrode 191B.

The first capacitors 42 are located at a side of the first switching element 171 opposite to the semiconductor light-emitting element 30 in the Y-direction. In other words, the first switching element 171 is arranged between the semiconductor light-emitting element 30 and the first capacitors 42 in the Y-direction. As viewed in the Y-direction, the first capacitors 42 are located at a position that overlaps the first switching element 171.

Since the second front-surface electrodes 192A are electrically connected to the second front-surface electrode 192C, the first electrodes 42A of the first capacitors 42 are electrically connected to the drain electrodes 171D of the first switching element 171. The source electrodes 171S of the first switching element 171 are electrically connected to the first element front-surface electrodes 34A through the third front-surface electrode 193A and the wires W5. Since the first element front-surface electrodes 34A each define the first anode electrode of the semiconductor light-emitting element 30, the first anode electrodes are electrically connected to the source electrodes 171S of the first switching element 171.

In plan view, the second switching element 181 is located at a position that overlaps the second front-surface electrodes 192B, the third front-surface electrode 193B, and the fourth front-surface electrode 194B. The second switching element 181 is located closer to the fourth substrate side surface 26 than the wires W5 are in the Y-direction. The second switching element 181 is located closer to the third substrate side surface 25 than the second front-surface electrode 192D is in the Y-direction. The second switching element 181 is arranged between the imaginary centerline VC and the second substrate side surface 24 and is located relatively close to the imaginary centerline VC in the X-direction. The second switching element 181 includes a portion that overlaps the second light emitter 33B as viewed in the Y-direction. The second switching element 181 has a shape of a rectangular flat plate having a thickness-wise direction parallel to the Z-direction. The second switching element 181 is rectangular in plan view, with long sides extending in the X-direction and short sides extending in the Y-direction. The second switching element 181 and the first switching element 171 are identical in shape and size.

The distance D1 between the semiconductor light-emitting element 30 and the first switching element 171 in the Y-direction is equal to the distance D2 between the semiconductor light-emitting element 30 and the second switching element 181 in the Y-direction. The distance D1 and the distance D2 may be considered to be the same as long as a difference of the distance D1 and the distance D2 is, for example, within 10% of the distance D1.

The second switching element 181 includes a second element front surface 181A and a second element back surface 181B facing away from each other in the Z-direction. The second element front surface 181A faces the same direction as the substrate front surface 21, and the second element back surface 181B faces the same direction as the substrate back surface 22. The second switching element 181 includes multiple (in the third embodiment, three) drain electrodes 181D, multiple (in the third embodiment, four) source electrodes 181S, and a gate electrode 181G. The drain electrodes 181D, the source electrodes 181S, and the gate electrode 181G are formed in the second element back surface 181B. The drain electrodes 181D, the source electrodes 181S, and the gate electrode 181G are each rectangular, with long sides extending in the Y-direction and short sides extending in the X-direction. The second element back surface 181B is an example of “the element back surface of the second switching element”.

The drain electrodes 181D are aligned with and spaced apart from each other in the X-direction. The source electrodes 181S are aligned with and spaced apart from each other in the X-direction. One of the source electrodes 181S that is located closest to the second substrate side surface 24 is shorter than the other source electrodes 181S in the Y-direction. The other source electrodes 181S and the drain electrodes 181D have the same length in the Y-direction.

The drain electrodes 181D and the source electrodes 181S are alternately arranged in the X-direction. In the example shown in FIG. 12, the source electrode 181S, the drain electrode 181D, the source electrode 181S, the drain electrode 181D, the source electrode 181S, the drain electrode 181D, and the source electrode 181S are arranged in this order from an end of the second element back surface 181B that is located closer to the second substrate side surface 24 to another end of the second element back surface 181B that is located closer to the first substrate side surface 23. Accordingly, the source electrode 181S is arranged in both of the two opposite ends of the second element back surface 181B in the X-direction. The gate electrode 181G is arranged in an end of the second element back surface 181B that is located relatively close to the second substrate side surface 24. The gate electrode 181G is aligned with and spaced apart from one of the source electrodes 181S that is located closest to the second substrate side surface 24 in the Y-direction. The gate electrode 181G is located closer to the third substrate side surface 25 than the one of the source electrodes 181S that is closest to the second substrate side surface 24 is. The gate electrode 181G is shorter than the drain electrodes 181D in the Y-direction. In an example, the gate electrode 181G and one of the source electrodes 181S that is located closest to the second substrate side surface 24 have the same length in the Y-direction.

In plan view, the drain electrodes 181D separately overlap the second front-surface electrodes 192B. As shown in FIG. 15, the drain electrodes 181D are separately bonded to the second front-surface electrodes 192B by the conductive bonding material SD. Therefore, the drain electrodes 181D are separately electrically connected to the second front-surface electrodes 192B.

Each of the source electrodes 181S is located at a position that overlaps the third front-surface electrode 193B. As shown in FIG. 15, the source electrodes 181S are bonded to the third front-surface electrode 193B by the conductive bonding material SD. Therefore, the source electrodes 181S are electrically connected to the third front-surface electrode 193B.

As shown in FIG. 12, the gate electrode 181G is located at a position that overlaps the fourth front-surface electrode 194B. The gate electrode 181G is bonded to the fourth front-surface electrode 194B by the conductive bonding material SD (not shown). Therefore, the gate electrode 181G is electrically connected to the fourth front-surface electrode 194B.

Multiple (in the third embodiment, six) second capacitors 52 are provided. The second capacitors 52 are aligned with and spaced apart from each other in the X-direction. Each of the first capacitors 52 extends over the second front-surface electrode 192D and the first front-surface electrode 191B in the Y-direction. The second capacitor 52 is mounted on the second front-surface electrode 192D and the first front-surface electrode 191B. More specifically, the second capacitor 52 is separately bonded to the second front-surface electrode 192D and the first front-surface electrode 191B by the conductive bonding material SD. The first electrode 52A of the second capacitor 52 is bonded to the second front-surface electrode 192D. The second electrode 52B of the second capacitor 52 is bonded to the first front-surface electrode 191B. Thus, the first electrode 52A is electrically connected to the second front-surface electrode 192D, and the second electrode 52B is electrically connected to the first front-surface electrode 191B.

The second capacitors 52 are located at a side of the second switching element 181 opposite to the semiconductor light-emitting element 30 in the Y-direction. In other words, the second switching element 181 is arranged between the semiconductor light-emitting element 30 and the second capacitors 52 in the Y-direction. As viewed in the Y-direction, the second capacitors 52 are located at a position that overlaps the second switching element 181.

Since the second front-surface electrodes 192B are electrically connected to the second front-surface electrode 192D, the first electrodes 52A of the second capacitors 52 are electrically connected to the drain electrodes 181D of the second switching element 181. The source electrodes 181S of the second switching element 181 are electrically connected to the second element front-surface electrodes 34B through the third front-surface electrode 193B and the wires W5. Since the second element front-surface electrodes 34B each define the second anode electrode of the semiconductor light-emitting element 30, the second anode electrodes are electrically connected to the source electrodes 181S of the second switching element 181.

The semiconductor light-emitting device 10 further includes the first protection diode 101 and the second protection diode 102.

The first protection diode 101 is configured to protect the first light emitter 33A of the semiconductor light-emitting element 30. The first protection diode 101 is located closer to the first substrate side surface 23 than the semiconductor light-emitting element 30, the first switching element 171, and the first capacitors 42 are in the X-direction. The first protection diode 101 is located at a side of the first switching element 171 opposite to the semiconductor light-emitting element 30 in the Y-direction. The first protection diode 101 is located at a position that overlaps the first capacitors 42 as viewed in the X-direction. The first protection diode 101 extends over the third front-surface electrode 193A and the first front-surface electrode 191B in the Y-direction. The first protection diode 101 is mounted on the third front-surface electrode 193A and the first front-surface electrode 191B. More specifically, the first protection diode 101 is separately bonded to the third front-surface electrode 193A and the first front-surface electrode 191B by the conductive bonding material SD.

The first protection diode 101 is arranged so that the first anode electrode 101A and the first cathode electrode 101B are located at the same position in the X-direction and are spaced apart from each other in the Y-direction. The first protection diode 101 is connected in antiparallel to the first light emitter 33A. More specifically, the first anode electrode 101A is bonded to the first front-surface electrode 191B by the conductive bonding material SD. The first anode electrode 101A is disposed in the first front-surface electrode 191B. Therefore, the first anode electrode 101A is electrically connected to the element back-surface electrode 35 of the semiconductor light-emitting element 30 through the first front-surface electrode 191B and the first front-surface electrode 191A. The first cathode electrode 101B is bonded to the third front-surface electrode 193A by the conductive bonding material SD. Therefore, the first cathode electrode 101B is electrically connected to the first element front-surface electrodes 34A, which correspond to the first light emitter 33A of the semiconductor light-emitting element 30, through the third front-surface electrode 193A and the wires W5.

The second protection diode 102 is configured to protect the second light emitter 33B of the semiconductor light-emitting element 30. The second protection diode 102 is located closer to the second substrate side surface 24 than the semiconductor light-emitting element 30, the second switching element 181, and the second capacitors 52 are in the X-direction. The second protection diode 102 is located at a side of the second switching element 181 opposite to the semiconductor light-emitting element 30 in the Y-direction. The second protection diode 102 is located at a position that overlaps the second capacitors 52 as viewed in the X-direction. The second protection diode 102 extends over the third front-surface electrode 193B and the first front-surface electrode 191B in the Y-direction. The second protection diode 102 is mounted on the third front-surface electrode 193B and the first front-surface electrode 191B. The second protection diode 102 is arranged in the same manner as the first protection diode 101.

The second protection diode 102 is connected in antiparallel to the second light emitter 33B. More specifically, the second anode electrode 102A of the second protection diode 102 is bonded to the first front-surface electrode 191B by the conductive bonding material SD. Therefore, the second anode electrode 102A is electrically connected to the element back-surface electrode 35 of the semiconductor light-emitting element 30 through the first front-surface electrode 191B and the first front-surface electrode 191A. The second cathode electrode 102B is bonded to the third front-surface electrode 193B by the conductive bonding material SD. Therefore, the second cathode electrode 102B is electrically connected to the second element front-surface electrodes 34B, which correspond to the second light emitter 33B of the semiconductor light-emitting element 30, through the third front-surface electrode 193B and the wires W5.

### Advantages

The semiconductor light-emitting device 10 of the third embodiment has the following advantages in addition to advantages (1-1) to (1-12), (1-16), (1-17), and (1-19) of the first embodiment.

(3-1) The first switching element 171 includes the source electrode 171S, the drain electrode 171D, and the gate electrode 171G that are formed in the second element back surface 171B. The second switching element 181 includes the source electrode 181S, the drain electrode 181D, and the gate electrode 181G that are formed in the second element back surface 181B. The source electrode 171S, the drain electrode 171D, and the gate electrode 171G of the first switching element 171 are mounted on the front-surface electrodes 28A. The source electrode 181S, the drain electrode 181D, and the gate electrode 181G of the second switching element 181 are mounted on the front-surface electrodes 28A.

With this configuration, no wire is used for electrical connection between the source electrode 171S, the drain electrode 171D, and the gate electrode 171G of the first switching element 171 and the front-surface electrodes 28A. This reduces the inductance of the looped first current path formed by the semiconductor light-emitting element 30, the first switching element 171, and the first capacitor 42. Further, no wire is used for electrical connection between the source electrode 181S, the drain electrode 181D, and the gate electrode 181G of the second switching element 181 and the front-surface electrodes 28A. This reduces the inductance of the looped second current path formed by the semiconductor light-emitting element 30, the second switching element 181, and the second capacitor 52.

(3-2) The first switching element 171 is rectangular in plan view, with long sides extending in the X-direction and short sides extending in the Y-direction. The second switching element 181 is rectangular in plan view, with long sides extending in the X-direction and short sides extending in the Y-direction.

With this configuration, the first switching element 171 is long in a direction (X-direction) orthogonal to an arrangement direction (Y-direction) in which the semiconductor light-emitting element 30, the first switching element 171, and the first capacitor 42 are arranged. Therefore, the distance between the semiconductor light-emitting element 30 and the first capacitor 42 in the Y-direction is shorter as compared to a configuration in which the first switching element 171 is relatively long in the arrangement direction. As a result, the looped first current path formed by the semiconductor light-emitting element 30, the first switching element 171, and the first capacitor 42 is relatively short. Further, the second switching element 181 is long in a direction (X-direction) orthogonal to an arrangement direction (Y-direction) in which the semiconductor light-emitting element 30, the second switching element 181, and the second capacitor 52 is arranged. Therefore, the distance between the semiconductor light-emitting element 30 and the second capacitor 52 in the Y-direction is shorter as compared to a configuration in which the second switching element 181 is relatively long in the arrangement direction. As a result, the looped second current path formed by the semiconductor light-emitting element 30, the second switching element 181, and the second capacitor 52 is relatively short.

(3-3) The semiconductor light-emitting device 10 includes the first vias 211A, 211B, and 211C, the second vias 212A and 212B, the third vias 213A and 213B, and the fourth vias 214A and 214B that are arranged in the substrate 20 to connect the back-surface electrodes 28B and the front-surface electrodes 28A. The first current path between the first light emitter 33A of the semiconductor light-emitting element 30 and the first drive circuit 40 is formed by the first front-surface electrodes 191A and 191B, the second front-surface electrode 192A, the third front-surface electrode 193A, the fourth front-surface electrode 194A, the first back-surface electrode 201, the second back-surface electrode 202A, the first vias 211A and 211B, and the second via 212A. The second current path between the second light emitter 33B of the semiconductor light-emitting element 30 and the second drive circuit 50 is formed by the first front-surface electrodes 191A and 191B, the second front-surface electrode 192B, the third front-surface electrode 193B, the fourth front-surface electrode 194B, the first back-surface electrode 201, the second back-surface electrode 202B, the first vias 211A and 211B, and the second via 212B.

With this configuration, the first back-surface electrode 201 forms part of the loop of the first current path, in which electric current flows through the first electrode 42A of the first capacitor 42, the drain electrode 171D of the first switching element 171, the source electrode 171S, the first element front-surface electrode 34A of the semiconductor light-emitting element 30, the element back-surface electrode 35, and the second electrode 42B of the first capacitor 42 in this order. This decreases the area of the loop of the first current path, thereby reducing the inductance of the first current path. Further, the first back-surface electrode 201 forms part of the loop of the second current path, in which electric current flows through the first electrode 52A of the second capacitor 52, the drain electrode 181D of the second switching element 181, the source electrode 181S, the second element front-surface electrode 34B of the semiconductor light-emitting element 30, the element back-surface electrode 35, and the second electrode 52B of the second capacitor 52 in this order. This decreases the area of the loop of the second current path, thereby reducing the inductance of the second current path.

(3-4) The substrate 20 includes a single base member 27. The front-surface electrodes 28A are formed in the base-member front surface (substrate front surface 21) of the base member 27, and the back-surface electrodes 28B are formed in the base-member back surface (substrate back surface 22) of the base member 27.

With this configuration, the front-surface electrodes 28A and the back-surface electrodes 28B are located closer to each other in the Z-direction as compared to a configuration in which the substrate 20 includes multiple base members 27. This facilitates transfer of heat from the semiconductor light-emitting element 30 through the front-surface electrode 28A and the back-surface electrode 28B to the outside of the semiconductor light-emitting device 10.

(3-5) The first switching element 171 and the second switching element 181 include lateral transistors having the same configuration.

With this configuration, the semiconductor light-emitting device 10 includes a single type of switching element. This reduces the manufacturing costs of the semiconductor light-emitting device 10 as compared to when two types of switching elements are included.

### Fourth Embodiment

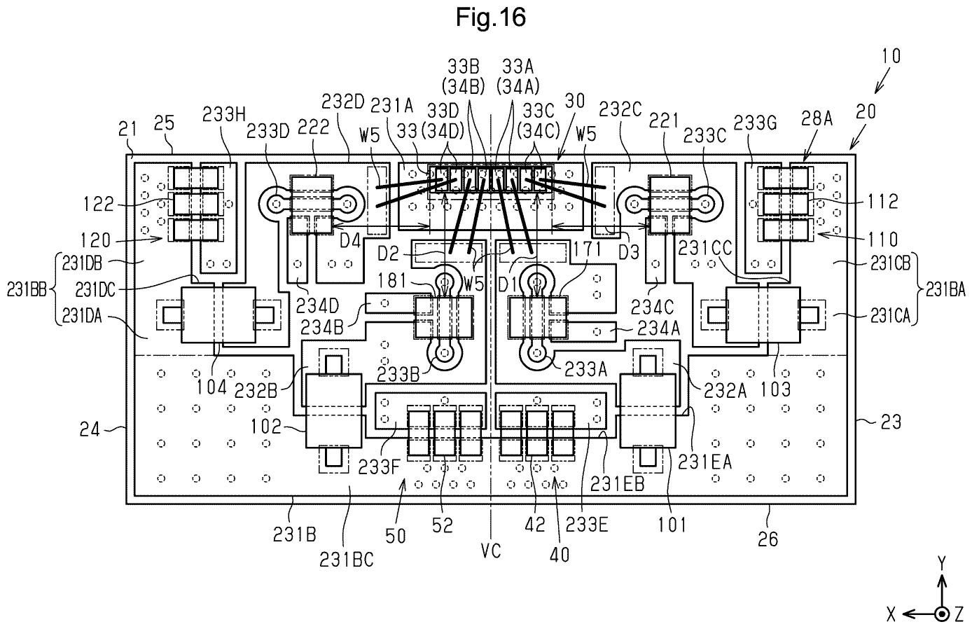

A semiconductor light-emitting device 10 in accordance with a fourth embodiment will now be described with reference to FIGS. 16 to 19. The semiconductor light-emitting device 10 of the fourth embodiment differs from the semiconductor light-emitting device 10 of the third embodiment in the number of light emitters that are separately controlled. Hereinafter, the description will focus on the differences from the third embodiment. The same reference characters are given to those components that are the same as the corresponding components of the third embodiment, and such components will not be described in detail.

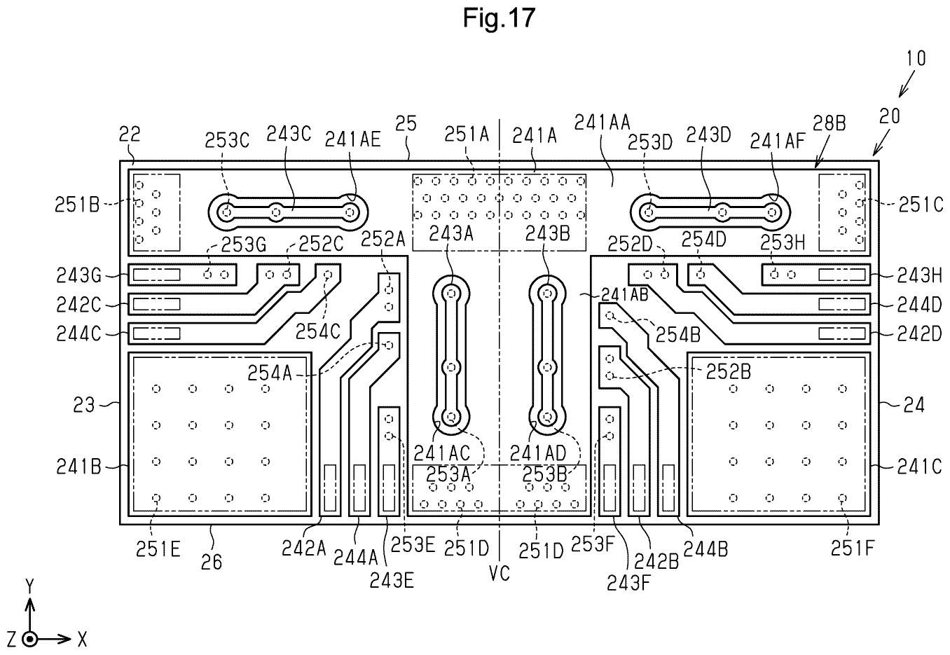

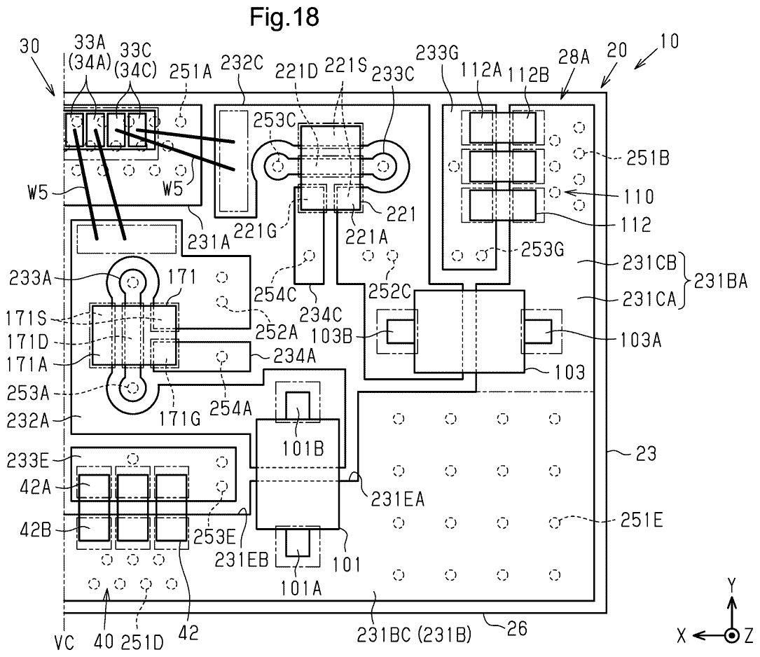

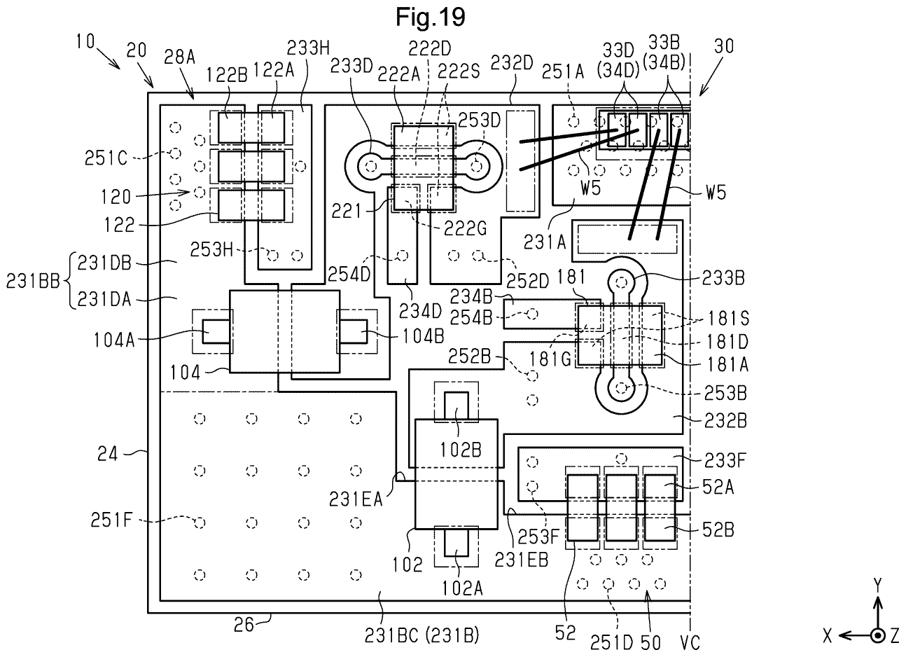

FIG. 16 shows a schematic planar structure of the semiconductor light-emitting device 10 in accordance with the fourth embodiment. FIG. 17 shows a schematic bottom structure of the semiconductor light-emitting device 10 shown in FIG. 16. FIG. 18 shows a schematic planar structure of the semiconductor light-emitting device 10 shown in FIG. 16 enlarging a region between the imaginary centerline VC and the first substrate side surface 23. FIG. 19 shows a schematic planar structure of the semiconductor light-emitting device 10 shown in FIG. 16 enlarging a region between the imaginary centerline VC and the second substrate side surface 24. In FIGS. 16, 18, and 19, rectangular boxes defined by double-dashed lines indicate open portions in the front surface resist 29A (refer to FIG. 3). In FIG. 17, rectangular boxes defined by double-dashed lines indicate open portions in the back surface resist 29B (refer to FIG. 3).

As shown in FIG. 16, the semiconductor light-emitting element 30 includes the first to fourth light emitters 33A to 33D, and the first to fourth element front-surface electrodes 34A to 34D respectively provided for the first to fourth light emitter 33A. The first to fourth light emitters 33A to 33D each include two of the eight light emitters 33. The first element front-surface electrode 34A is included in the first light emitter 33A. The second element front-surface electrode 34B is included in the second light emitter 33B. The third element front-surface electrode 34C is included in the third light emitter 33C. The fourth element front-surface electrode 34D is included in the fourth light emitter 33D. The number of each of the first to fourth element front-surface electrodes 34A to 34D is determined in accordance with the number of a corresponding one of the first to fourth light emitters 33A to 33D. In the fourth embodiment, the number of each of the first to fourth light emitters 33A to 33D is two, and thus the number of each of the first to fourth element front-surface electrodes 34A to 34D is two. The first element front-surface electrode 34A is an example of “first anode electrode”. The second element front-surface electrode 34B is an example of “second anode electrode”. The third element front-surface electrode 34C is an example of “third anode electrode”. The fourth element front-surface electrode 34D is an example of “fourth anode electrode”.

The semiconductor light-emitting device 10 includes a configuration that controls driving of the first to fourth light emitters 33A to 33D separately. Specifically, the semiconductor light-emitting device 10 includes a first drive circuit 40 configured to drive the first light emitter 33A, a second drive circuit 50 configured to drive the second light emitter 33B, a third drive circuit 110 configured to drive the third light emitter 33C, and a fourth drive circuit 120 configured to drive the fourth light emitter 33D.

In the same manner as the third embodiment, the first drive circuit 40 includes the first switching element 171 and the first capacitor 42. In the same manner as the third embodiment, the second drive circuit 50 includes the second switching element 181 and the second capacitor 52. Although the first switching element 171 and the second switching element 181 are lateral transistors in the same manner as the third embodiment, configurations of these transistors differ from those of the third embodiment. The configurations of the first switching element 171 and the second switching element 181 will be described later.

The third drive circuit 110 includes a third switching element 221 configured to control driving of the third light emitter 33C, and the third capacitor 112 configured to supply electric current to the third light emitter 33C. The third switching element 221 and the third capacitor 112 are spaced apart from the semiconductor light-emitting element 30.

The fourth drive circuit 120 includes a fourth switching element 222 configured to control driving of the fourth light emitter 33D, and the fourth capacitor 122 configured to supply electric current to the fourth light emitter 33D. The fourth switching element 222 and the fourth capacitor 122 are spaced apart from the semiconductor light-emitting element 30.

Due to such modifications on the drive circuits, the configuration of the substrate 20 differs from that of the third embodiment. The configuration of the substrate 20 in accordance with the fourth embodiment will now be described.

As shown in FIGS. 16, 18, and 19, the substrate 20 includes the front-surface electrodes 28A formed in the substrate front surface 21, namely, first front-surface electrodes 231A and 231B, second front-surface electrodes 232A and 232D, third front-surface electrodes 233A to 233H, and fourth front-surface electrodes 234A to 234D. The first front-surface electrodes 231A and 231B, the second front-surface electrodes 232A to 232D, the third front-surface electrodes 233A to 233H, and the fourth front-surface electrodes 234A to 234D are spaced apart from one another.

The semiconductor light-emitting element 30 is mounted on the first front-surface electrode 231A. In plan view, the first front-surface electrode 231A is disposed in a central part of the substrate front surface 21 in the X-direction and is located relatively close to the third substrate side surface 25 of the substrate front surface 21. The first front-surface electrode 231A is rectangular in plan view, with long sides extending in the X-direction and short sides extending in the Y-direction. The first front-surface electrode 231A is symmetric with respect to the imaginary centerline VC. The dimension of the first front-surface electrode 231A in the X-direction is greater than one-fourth of the dimension of the substrate front surface 21 in the X-direction and is less than one-third of the dimension of the substrate front surface 21 in the X-direction.

The first front-surface electrode 231B serves as ground wiring electrically connected to a ground terminal, which is electrically connected to the DC power supply 801 (refer to FIG. 5). The first front-surface electrode 231B is substantially U-shaped along the edges of the substrate front surface 21. The first front-surface electrode 231B includes a first wiring portion 231BA formed along the first substrate side surface 23, a second wiring portion 231BB formed along the second substrate side surface 24, and a third wiring portion 231BC formed along the fourth substrate side surface 26. In an example, the first wiring portion 231BA, the second wiring portion 231BB, and the third wiring portion 231BC are integrated with each other. The first front-surface electrode 231B is symmetric with respect to the imaginary centerline VC. In FIG. 16, boundaries of the first wiring portion 231BA, the second wiring portion 231BB, and the third wiring portion 231BC are indicated by single-dashed lines drawn in the first front-surface electrode 231B.

In plan view, the first front-surface electrode 231B surrounds the first front-surface electrode 231A, the second front-surface electrodes 232A to 232D, the third front-surface electrodes 233A to 233H, and the fourth front-surface electrodes 234A to 234D. The first front-surface electrode 231B has a greater area than each of the first front-surface electrode 231A, the second front-surface electrodes 232A to 232D, the third front-surface electrodes 233A to 233H, or the fourth front-surface electrodes 234A to 234D.

The first wiring portion 231BA includes a wide section 231CA and a narrow section 231CB. The wide section 231CA defines a portion of the first wiring portion 231BA that is continuous with the third wiring portion 231BC. The narrow section 231CB is located at a side of the wide section 231CA opposite to the third wiring portion 231BC. The wide section 231CA and the narrow section 231CB define an indent 231CC. The narrow section 231CB is longer than the wide section 231CA in the Y-direction.

The second wiring portion 231BB includes a wide section 231DA and a narrow section 231DB. The second wiring portion 231BB is arranged so that the second wiring portion 231BB and the first wiring portion 231BA are symmetric with respect to the imaginary centerline VC. The second wiring portion 231BB and the first wiring portion 231BA are symmetric with respect to the imaginary centerline VC. Accordingly, the wide section 231DA and the narrow section 231 DB define an indent 231DC.

The third wiring portion 231BC includes a first recess 231EA and a second recess 231EB. The first recess 231EA and the second recess 231EB are rectangular recesses formed in the third wiring portion 231BC toward the fourth substrate side surface 26. In other words, the first recess 231EA and the second recess 231EB are both open toward the third substrate side surface 25. The second recess 231EB is formed within the first recess 231EA. More specifically, the second recess 231EB is formed in the bottom of the first recess 231EA toward the fourth substrate side surface 26. The dimension of the first recess 231EA in the Y-direction, or the depth of the first recess 231EA, is greater than the dimension of the second recess 231EB in the Y-direction, or the depth of the second recess 231EB. The second recess 231EB is larger than the first front-surface electrode 231A in the X-direction. The first recess 231EA and the second recess 231EB are each symmetric with respect to the imaginary centerline VC.

The second front-surface electrodes 232A and 232B, the third front-surface electrodes 233A and 233B, 233E and 233F, and the fourth front-surface electrodes 234A and 234B are arranged between the first front-surface electrode 231A and the third wiring portion 231BC of the first front-surface electrode 231B in the Y-direction.

The second front-surface electrode 232A, the third front-surface electrodes 233A and 233E, and the fourth front-surface electrode 234A are electrically connected to the first drive circuit 40. The second front-surface electrode 232B, the third front-surface electrodes 233B and 233F, and the fourth front-surface electrode 234B are electrically connected to the second drive circuit 50.

The third front-surface electrode 233A is electrically connected to the drain electrode 171D of the first switching element 171. The third front-surface electrode 233A is arranged between the imaginary centerline VC and the first substrate side surface 23 in the X-direction and is located relatively close to the imaginary centerline VC. The third front-surface electrode 233A is elliptic in plan view, with major axis extending in the Y-direction and minor axis extending in the X-direction.

The second front-surface electrode 232A is electrically connected to the source electrode 171S of the first switching element 171. In plan view, the second front-surface electrode 232A surrounds the third front-surface electrode 233A. The second front-surface electrode 232A is arranged between the first front-surface electrode 231A and the third wiring portion 231BC of the first front-surface electrode 231B in the Y-direction. One of two opposite ends of the second front-surface electrode 232A in the Y-direction that is located closer to the third substrate side surface 25 is adjacent to the first front-surface electrode 231A in the Y-direction. The other end of the second front-surface electrode 232A that is located closer to the fourth substrate side surface 26 is adjacent to the third front-surface electrode 233E and the third wiring portion 231BC in the Y-direction. The end of the second front-surface electrode 232A located closer to the fourth substrate side surface 26 is disposed in the first recess 231EA of the third wiring portion 231BC. The end of the second front-surface electrode 232A located closer to the fourth substrate side surface 26 surrounds part of the third front-surface electrode 233E.

The third front-surface electrode 233E is electrically connected to the third front-surface electrode 233A. The third front-surface electrode 233E is located closer to the third wiring portion 231BC than the third front-surface electrode 233A is in the Y-direction. The third front-surface electrode 233E is partially located in the second recess 231EB of the third wiring portion 231BC. The third front-surface electrode 233E is adjacent to the imaginary centerline VC in the X-direction. The third front-surface electrode 233E is rectangular in plan view, with long sides extending in the X-direction and short sides extending in the Y-direction.

The fourth front-surface electrode 234A is electrically connected to the gate electrode 171G of the first switching element 171. The fourth front-surface electrode 234A is arranged between the first front-surface electrode 231A and the third front-surface electrode 233E and is located relatively close to the third front-surface electrode 233E in the Y-direction. The fourth front-surface electrode 234A is rectangular in plan view, with long sides extending in the X-direction and short sides extending in the Y-direction. Also, the fourth front-surface electrode 234A is surrounded by the second front-surface electrode 232A and the third front-surface electrode 233A.

The third front-surface electrode 233B is electrically connected to the drain electrode 181D of the second switching element 181. In an example, the third front-surface electrode 233B and the third front-surface electrode 233A are symmetric with respect to the imaginary centerline VC.

The second front-surface electrode 232B is electrically connected to the source electrode 181S of the second switching element 181. The second front-surface electrode 232B is located closer to the second substrate side surface 24 than the imaginary centerline VC is. The second front-surface electrode 232B and the second front-surface electrode 232A are not symmetric with respect to the imaginary centerline VC. The second front-surface electrode 232B surrounds the third front-surface electrode 233B. One of two opposite ends of the second front-surface electrode 232B in the Y-direction that is located closer to the third substrate side surface 25 is adjacent to the first front-surface electrode 231A in the Y-direction. The other end of the second front-surface electrode 232B that is located closer to the fourth substrate side surface 26 is adjacent to the third front-surface electrode 233F and the third wiring portion 231BC in the Y-direction. The end of the second front-surface electrode 232B located closer to the fourth substrate side surface 26 is disposed in the first recess 231EA of the third wiring portion 231BC. The end of the second front-surface electrode 232B located closer to the fourth substrate side surface 26 surrounds part of the third front-surface electrode 233F.

The third front-surface electrode 233F is electrically connected to the third front-surface electrode 233B. In an example, the third front-surface electrode 233F and the third front-surface electrode 233E are symmetric with respect to the imaginary centerline VC.

The fourth front-surface electrode 234B is electrically connected to the gate electrode 181G of the second switching element 181. The fourth front-surface electrode 234B is arranged between the first front-surface electrode 231A and the third front-surface electrode 233F and is located relatively close to the first front-surface electrode 231A in the Y-direction. The fourth front-surface electrode 234B is rectangular in plan view, with long sides extending in the X-direction and short sides extending in the Y-direction. Also, the fourth front-surface electrode 234B is surrounded by the second front-surface electrode 232B and the third front-surface electrode 233B.

The second front-surface electrode 232C, the third front-surface electrodes 233C and 233G, and the fourth front-surface electrode 234C are arranged between the first front-surface electrode 231A and the first wiring portion 231BA of the first front-surface electrode 231B in the X-direction. The second front-surface electrode 232C, the third front-surface electrodes 233C and 233G, and the fourth front-surface electrode 234C are electrically connected to the third drive circuit 110. The second front-surface electrode 232C is electrically connected to a source electrode 221S of the third switching element 221 of the third drive circuit 110, which will be described later. The third front-surface electrode 233C is electrically connected to a drain electrode 221D of the third switching element 221, which will be described later. The third front-surface electrode 233G is electrically connected to the third front-surface electrode 233C. The fourth front-surface electrode 234C is electrically connected to a gate electrode 221G of the third switching element 221, which will be described later.

The shape and size of the second front-surface electrode 232C, the third front-surface electrodes 233C and 233G, and the fourth front-surface electrode 234C are identical to those of the second front-surface electrode 232B, the third front-surface electrodes 233B and 233F, and the fourth front-surface electrode 234B. The layout of the second front-surface electrode 232C, the third front-surface electrodes 233C and 233G, and the fourth front-surface electrode 234C may be obtained by rotating the second front-surface electrode 232B, the third front-surface electrodes 233B and 233F, and the fourth front-surface electrode 234B counterclockwise by ninety degrees.

The third front-surface electrode 233G is partially located in the indent 231CC of the first wiring portion 231BA. Part of the second front-surface electrode 232C surrounds part of the third front-surface electrode 233G. The third front-surface electrode 233C includes a portion that opposes the wide section 231CA of the first wiring portion 231BA in the X-direction. The third front-surface electrode 233C includes a portion adjacent to one of two opposite ends of the first front-surface electrode 231A in the X-direction that is located closer to the first substrate side surface 23.

The second front-surface electrode 232D, the third front-surface electrodes 233D and 233H, and the fourth front-surface electrode 234D are arranged between the first front-surface electrode 231A and the second wiring portion 231BB of the first front-surface electrode 231B in the X-direction. The second front-surface electrode 232D, the third front-surface electrodes 233D and 233H, and the fourth front-surface electrode 234D are electrically connected to the fourth drive circuit 120. The second front-surface electrode 232D is electrically connected to a source electrode 222S of the fourth switching element 222 of the fourth drive circuit 120, which will be described later. The third front-surface electrode 233D is electrically connected to a drain electrode 222D of the fourth switching element 222, which will be described later. The third front-surface electrode 233H is electrically connected to the third front-surface electrode 233D. The fourth front-surface electrode 234D is electrically connected to a gate electrode 222G of the fourth switching element 222, which will be described later.

The shape and size of the second front-surface electrode 232D, the third front-surface electrodes 233D and 233H, and the fourth front-surface electrode 234D are identical to those of the second front-surface electrode 232A, the third front-surface electrodes 233A and 233E, and the fourth front-surface electrode 234A. The layout of the second front-surface electrode 232D, the third front-surface electrodes 233D and 233H, and the fourth front-surface electrode 234D may be obtained by rotating the second front-surface electrode 232A, the third front-surface electrodes 233A and 233E, and the fourth front-surface electrode 234A clockwise by ninety degrees.

The third front-surface electrode 233H is partially located in the indent 231DC of the second wiring portion 231BB. Part of the second front-surface electrode 232D surrounds part of the third front-surface electrode 233H. The third front-surface electrode 233D includes a portion that opposes the wide section 231DA of the second wiring portion 231BB in the X-direction. The third front-surface electrode 233D includes a portion adjacent to one of the two opposite ends of the first front-surface electrode 231A in the X-direction that is located closer to the second substrate side surface 24.

As shown in FIG. 17, the back-surface electrodes 28B include first back-surface electrodes 241A to 241C, second back-surface electrodes 242A to 242D, third back-surface electrodes 243A to 243H, and fourth back-surface electrodes 244A to 244D.

The first back-surface electrode 241A is electrically connected to the first front-surface electrode 231A and the first front-surface electrode 231B (refer to FIG. 16). The first back-surface electrode 241A serves as a ground terminal electrically connected to ground wiring. In plan view, the first back-surface electrode 241A has a greater area than each of the first back-surface electrode 241B to 241C, the second back-surface electrode 242A to 242D, the third back-surface electrode 243A to 243H, or the fourth back-surface electrode 244A to 244D.

The first back-surface electrode 241A is substantially T-shaped in plan view. The first back-surface electrode 241A includes a wide section 241AA and a narrow section 241AB. In an example, the wide section 241AA and the narrow section 241AB are integrated with each other. The first back-surface electrode 241A is symmetric with respect to the imaginary centerline VC.

In plan view, the wide section 241AA is adjacent to the third substrate side surface 25 in the Y-direction. The wide section 241AA is formed across substantially the entire substrate back surface 22 in the X-direction. The dimension of the wide section 241AA in the Y-direction is greater than one-fourth of the dimension of the substrate back surface 22 in the Y-direction and is less than one-third of the dimension of the substrate back surface 22 in the Y-direction.

The narrow section 241AB extends from a central part of the wide section 241AA in the X-direction toward the fourth substrate side surface 26. The narrow section 241AB has a distal end that is adjacent to the fourth substrate side surface 26 in the Y-direction in plan view. The dimension of the wide section 241AA in the X-direction is greater than one-fourth of the dimension of the substrate back surface 22 in the X-direction and is less than one-third of the dimension of the substrate back surface 22 in the X-direction.

The first back-surface electrode 241A includes first to fourth openings 241AC to 241AF.

The first opening 241AC and the second opening 241AD are formed in the narrow section 241AB. The first opening 241AC and the second opening 241AD are disposed at opposite sides of the imaginary centerline VC in the X-direction. The first opening 241AC is located closer to the first substrate side surface 23 than the imaginary centerline VC is. The second opening 241AD is located closer to the second substrate side surface 24 than the imaginary centerline VC is. The first opening 241AC and the second opening 241AD are each elliptic in plan view, with major axis extending in the Y-direction and minor axis extending in the X-direction. The first opening 241AC and the second opening 241AD are identical in shape and size. That is, the first opening 241AC and the second opening 241AD are symmetric with respect to the imaginary centerline VC.

The third opening 241AE and the fourth opening 241AF are formed in the wide section 241AA. The third opening 241AE and the fourth opening 241AF are separately disposed at opposite sides of the narrow section 241AB in the X-direction. The third opening 241AE is located closer to the first substrate side surface 23 than the narrow section 241AB is in the X-direction. The fourth opening 241AF is located closer to the second substrate side surface 24 than the narrow section 241AB is in the X-direction. The third opening 241AE and the fourth opening 241AF are each elliptic in plan view, with major axis extending in the X-direction and minor axis extending in the Y-direction. The third opening 241AE and the fourth opening 241AF are identical in shape and size. That is, the third opening 241AE and the fourth opening 241AF are symmetric with respect to the imaginary centerline VC.

The third back-surface electrodes 243A to 243D are disposed in the first to fourth openings 241AC to 241AF, respectively. More specifically, the third back-surface electrode 243A is disposed in the first opening 241AC, the third back-surface electrode 243B is disposed in the second opening 241AD, the third back-surface electrode 243C is disposed in the third opening 241AE, and the third back-surface electrode 243D is disposed in the fourth opening 241AF. The third back-surface electrode 243A and the third back-surface electrode 243B are each elliptic, with major axis extending in the Y-direction and minor axis extending in the X-direction. The third back-surface electrode 243C and the third back-surface electrode 243D are each elliptic, with major axis extending in the X-direction and minor axis extending in the Y-direction. The third back-surface electrode 243A is electrically connected to the third front-surface electrodes 233A and 233E (refer to FIG. 16). The third back-surface electrode 243B is electrically connected to the third front-surface electrodes 233B and 233F (refer to FIG. 16). The third back-surface electrode 243C is electrically connected to the third front-surface electrodes 233C and 233G (refer to FIG. 16). The third back-surface electrode 243D is electrically connected to the third front-surface electrodes 233D and 233H (refer to FIG. 16). In plan view, the third back-surface electrode 243A extends in the Y-direction and overlaps the third front-surface electrodes 233A and 233E. In plan view, the third back-surface electrode 243B extends in the Y-direction and overlaps the third front-surface electrodes 233B and 233F. In plan view, the third back-surface electrode 243C extends in the X-direction and overlaps the third front-surface electrodes 233C and 233G. In plan view, the third back-surface electrode 243D extends in the X-direction and overlaps the third back-surface electrodes 243D and 243H.

The first back-surface electrode 241B and the first back-surface electrode 241C are electrically connected to the first front-surface electrode 231B. Therefore, the first back-surface electrode 241B and the first back-surface electrode 241C are each electrically connected to the first back-surface electrode 241A through the first front-surface electrode 231B. The first back-surface electrode 241B and the first back-surface electrode 241C serve as a ground terminal in the same manner as the first back-surface electrode 241A.

The first back-surface electrode 241B is disposed in one of four corners of the substrate back surface 22 that is located between the first substrate side surface 23 and the fourth substrate side surface 26. The first back-surface electrode 241C is disposed in one of the four corners of the substrate back surface 22 that is located between the second substrate side surface 24 and the fourth substrate side surface 26. The first back-surface electrode 241B and the first back-surface electrode 241C are each rectangular in plan view, with long sides extending in the X-direction and short sides extending in the Y-direction. In the example shown in FIG. 17, the first back-surface electrode 241B and the first back-surface electrode 241C are each slightly larger in the X-direction than in the Y-direction. The first back-surface electrode 241B and the first back-surface electrode 241C are identical in shape and size. That is, the first back-surface electrode 241B and the first back-surface electrode 241C are symmetric with respect to the imaginary centerline VC.

The second back-surface electrode 242A, the third back-surface electrode 243E, and the fourth back-surface electrode 244A are arranged between the narrow section 241AB of the first back-surface electrode 241A and the first back-surface electrode 241B in the X-direction.

The third back-surface electrode 243E is electrically connected to the third front-surface electrode 233E. The third back-surface electrode 243E is adjacent to the narrow section 241AB in the X-direction. The third front-surface electrode 243E is rectangular in plan view, with long sides extending in the Y-direction and short sides extending in the X-direction.

The second back-surface electrode 242A is electrically connected to the second front-surface electrode 232A (refer to FIG. 16). The second back-surface electrode 242A is located closer to the first back-surface electrode 241B than the third back-surface electrode 243E and the fourth back-surface electrode 244A are. The third back-surface electrode 243A includes a first section, a second section, and a joining section. The first section is adjacent to the fourth back-surface electrode 244A in the X-direction. As viewed in the Y-direction, the second section is located at a position that overlaps the third back-surface electrode 243E. The second section is located closer to the wide section 241AA than the third back-surface electrode 243E and the fourth back-surface electrode 244A are. The joining section joins the first section and the second section.

The fourth back-surface electrode 244A is electrically connected to the fourth front-surface electrode 234A (refer to FIG. 16). The fourth back-surface electrode 244A includes a first section, a second section, and a joining section. The first section is located at a side of the third back-surface electrode 243E opposite to the narrow section 241AB in the X-direction. The first section is adjacent to the third back-surface electrode 243E. As viewed in the Y-direction, the second section is located at a position that overlaps the third back-surface electrode 243E. The second section is located closer to the wide section 241AA than the third back-surface electrode 243E is. The joining section joins the first section and the second section.

The third back-surface electrode 243F, the second back-surface electrode 242B, and the fourth back-surface electrode 244B are arranged between the narrow section 241AB of the first back-surface electrode 241A and the first back-surface electrode 241C in the X-direction.

The third back-surface electrode 243F is electrically connected to the third front-surface electrode 233F. The third back-surface electrode 243F is adjacent to the narrow section 241AB in the X-direction. The third front-surface electrode 243F is rectangular in plan view, with long sides extending in the Y-direction and short sides extending in the X-direction.

The second back-surface electrode 242B is electrically connected to the second front-surface electrode 232B (refer to FIG. 16). The second back-surface electrode 242B includes a first section, a second section, and a joining section. The first section is located at a side of the third back-surface electrode 243F opposite to the narrow section 241AB in the X-direction. The first section is adjacent to the third back-surface electrode 243F. As viewed in the Y-direction, the second section is located at a position that overlaps the third back-surface electrode 243F. The second section is located closer to the wide section 241AA than the third back-surface electrode 243F is. The joining section joins the first section and the second section.

The fourth back-surface electrode 244B is electrically connected to the fourth front-surface electrode 234B (refer to FIG. 16). The fourth back-surface electrode 244B is located closer to the first back-surface electrode 241C than the third back-surface electrode 243F and the second back-surface electrode 242B are. The fourth back-surface electrode 244B includes a first section, a second section, and a joining section. The first section is adjacent to the second back-surface electrode 242B in the X-direction. As viewed in the Y-direction, the second section is located at a position that overlaps the third back-surface electrode 243F. The second section is located closer to the wide section 241AA than the third back-surface electrode 243F and the second back-surface electrode 242B are. The joining section joins the first section and the second section.

The third back-surface electrode 243G, the second back-surface electrode 242C, and the fourth back-surface electrode 244C are arranged between the wide section 241AA of the first back-surface electrode 241A and the first back-surface electrode 241B in the Y-direction. The shape and size of the third back-surface electrode 243G, the second back-surface electrode 242C, and the fourth back-surface electrode 244C are identical to those of the third back-surface electrode 243E, the second back-surface electrode 242B, and the fourth back-surface electrode 244B. The configuration of the third back-surface electrode 243G, the second back-surface electrode 242C, and the fourth back-surface electrode 244C may be obtained by rotating the third back-surface electrode 243F, the second back-surface electrode 242B, and the fourth back-surface electrode 244B clockwise by ninety degrees.

The third back-surface electrode 243H, the second back-surface electrode 242D, and the fourth back-surface electrode 244D are arranged between the wide section 241AA of the first back-surface electrode 241A and the second back-surface electrode 242C in the Y-direction. The shape and size of the third back-surface electrode 243H, the second back-surface electrode 242D, and the fourth back-surface electrode 244D are identical to those of the third back-surface electrode 243E, the second back-surface electrode 242A, and the fourth back-surface electrode 244A. The configuration of the third back-surface electrode 243H, the second back-surface electrode 242D, and the fourth back-surface electrode 244D may be obtained by rotating the third back-surface electrode 243E, the second back-surface electrode 242A, and the fourth back-surface electrode 244A counterclockwise by ninety degrees.

As shown in FIGS. 17 to 19, the substrate 20 includes first vias 251A to 251F, second vias 252A to 252D, third vias 253A to 253H, and fourth vias 254A to 254D. The first vias 251A to 251F, the second vias 252A to 252D, the third vias 253A to 253H, and the fourth vias 254A to 254D extend through the base member 27 in the Z-direction. The first vias 251A to 251F, the second vias 252A to 252D, the third vias 253A to 253H, and the fourth vias 254A to 254D are formed from, for example, a material containing one or more selected from Ti, TiN, Au, Ag, Cu, Al, and W.

The first via 251A is electrically connected to the first front-surface electrode 231A and the first back-surface electrode 241A. Therefore, the first front-surface electrode 231A is electrically connected to the first back-surface electrode 241A.

As shown in FIGS. 18 and 19, multiple first vias 251A are provided. The first vias 251A are arranged in the first front-surface electrode 231A and are located relatively close to the third substrate side surface 25. Accordingly, in plan view, the first vias 251A are located at a position of the first front-surface electrode 231A that overlaps the semiconductor light-emitting element 30. The first vias 251A are aligned with and spaced apart from one another in the X-direction and the Y-direction. A greater number of first vias 251A are aligned in the X-direction than in the Y-direction. In plan view, the first vias 251A are formed in a region that is larger than the area of the semiconductor light-emitting element 30. Therefore, some of the first vias 251A are located outside the semiconductor light-emitting element 30 in plan view.

As shown in FIGS. 17 to 19, the first vias 251B to 251D are each electrically connected to the first front-surface electrode 231B and the first back-surface electrode 241A. Therefore, the first front-surface electrode 231B is electrically connected to the first back-surface electrode 241A. Accordingly, the first front-surface electrode 231A is electrically connected to the first front-surface electrode 231B through the first back-surface electrode 241A and the first vias 251B to 251D.

As shown in FIGS. 18 and 19, multiple first vias 251B, multiple first vias 251C, and multiple first vias 251D are provided. The first vias 251B are arranged in an end of the first wiring portion 231BA of the first front-surface electrode 231B that is located relatively close to the third substrate side surface 25. The first vias 251C are arranged in an end of the second wiring portion 231BB of the first front-surface electrode 231B that is located relatively close to the third substrate side surface 25. The first vias 251D are arranged in a central part of the third wiring portion 231BC of the first front-surface electrode 231B in the X-direction.

As shown in FIGS. 17 and 18, the first via 251E is electrically connected to the first front-surface electrode 231B and the first back-surface electrode 241B. Therefore, the first front-surface electrode 231B is electrically connected to the first back-surface electrode 241B. Multiple first vias 251E are provided. As shown in FIG. 18, the first vias 251E are arranged in an end of the third wiring portion 231BC of the first front-surface electrode 231B that is located relatively close to the first substrate side surface 23.

As shown in FIGS. 17 and 19, the first via 251F is electrically connected to the first front-surface electrode 231B and the first back-surface electrode 241C. Therefore, the first front-surface electrode 231B is electrically connected to the first back-surface electrode 241C. Multiple first vias 251F are provided. As shown in FIG. 19, the first vias 251F are arranged in an end of the third wiring portion 231BC of the first front-surface electrode 231B that is located relatively close to the second substrate side surface 24.

As shown in FIGS. 16 to 19, multiple third vias 253A, multiple third vias 253B, multiple third vias 253C, and multiple third vias 253D are provided. The third vias 253A to 253D are less in number than the first vias 251A to 251F. In an example, the number of each of the third vias 253A to 253D is three.

The third vias 253A are electrically connected to the third front-surface electrodes 233A and 233E and the third back-surface electrode 243A. Therefore, the third front-surface electrodes 233A and 233E are electrically connected to the third back-surface electrode 243A. That is, the third front-surface electrode 233A is electrically connected to the third front-surface electrode 233E through the third back-surface electrode 243A and the third vias 253A.

The third vias 253B are electrically connected to the third front-surface electrodes 233B and 233F and the third back-surface electrode 243B. Therefore, the third front-surface electrodes 233B and 233F are electrically connected to the third back-surface electrode 243B. That is, the third front-surface electrode 233B is electrically connected to the third front-surface electrode 233F through the third back-surface electrode 243B and the third vias 253B.

The third vias 253C are electrically connected to the third front-surface electrodes 233C and 233G and the third back-surface electrode 243C. Therefore, the third front-surface electrodes 233C and 233G are electrically connected to the third back-surface electrode 243C. That is, the third front-surface electrode 233C is electrically connected to the third front-surface electrode 233G through the third back-surface electrode 243C and the third vias 253C.

The third vias 253D are electrically connected to the third front-surface electrodes 233D and 233H and the third back-surface electrode 243D. Therefore, third front-surface electrodes 233D and 233H are electrically connected to the third back-surface electrode 243D. That is, the third front-surface electrode 233D is electrically connected to the third front-surface electrode 233H through the third back-surface electrode 243D and the third vias 253D.

Multiple third vias 253E, multiple third vias 253F, multiple third vias 253G, and multiple third vias 253H are provided. The third vias 253E to 253H are less in number than the third vias 253A to 253D. In an example, the number of each of the third vias 253E to 253H is two.

The third vias 253E are electrically connected to the third front-surface electrode 233E and the third back-surface electrode 243E. Therefore, the third front-surface electrode 233E is electrically connected to the third back-surface electrode 243E. Also, the third front-surface electrode 233A is electrically connected to the third back-surface electrode 243E through the third front-surface electrode 233E.

The third vias 253F are electrically connected to the third front-surface electrode 233F and the third back-surface electrode 243F. Therefore, the third front-surface electrode 233F is electrically connected to the third back-surface electrode 243F. Also, the third front-surface electrode 233B is electrically connected to the third back-surface electrode 243F through the third front-surface electrode 233F.

The third vias 253G are electrically connected to the third front-surface electrode 233G and the third back-surface electrode 243G. Therefore, the third front-surface electrode 233G is electrically connected to the third back-surface electrode 243G. Also, the third front-surface electrode 233C is electrically connected to the third back-surface electrode 243G through the third front-surface electrode 233G.

The third vias 253H are electrically connected to the third front-surface electrode 233H and the third back-surface electrode 243H. Therefore, the third front-surface electrode 233H is electrically connected to the third back-surface electrode 243H. Also, the third front-surface electrode 233D is electrically connected to the third back-surface electrode 243H through the third front-surface electrode 233H.

As shown in FIGS. 16 to 19, two second vias 252A, two second vias 252B, two second vias 252C, and two second vias 252D are provided. The second vias 252A are electrically connected to the second front-surface electrode 232A and the second back-surface electrode 242A. Therefore, the second front-surface electrode 232A is electrically connected to the second back-surface electrode 242A. The second vias 252B are electrically connected to the second front-surface electrode 232B and the second back-surface electrode 242B. Therefore, the second front-surface electrode 232B is electrically connected to the second back-surface electrode 242B. The second vias 252C are electrically connected to the second front-surface electrode 232C and the second back-surface electrode 242C. Therefore, the second front-surface electrode 232C is electrically connected to the second back-surface electrode 242C. The second vias 252D are electrically connected to the second front-surface electrode 232D and the second back-surface electrode 242D. Therefore, the second front-surface electrode 232D is electrically connected to the second back-surface electrode 242D.

As shown in FIGS. 16 and 17, a single fourth via 254A, a single fourth via 254B, a single fourth via 254C, and a single fourth via 254D are provided. The fourth via 254A is electrically connected to the fourth front-surface electrode 234A and the fourth back-surface electrode 244A. Therefore, the fourth front-surface electrode 234A is electrically connected to the fourth back-surface electrode 244A. The fourth via 254B is electrically connected to the fourth front-surface electrode 234B and the fourth back-surface electrode 244B. Therefore, the fourth front-surface electrode 234B is electrically connected to the fourth back-surface electrode 244B. The fourth via 254C is electrically connected to the fourth front-surface electrode 234C and the fourth back-surface electrode 244C. Therefore, the fourth front-surface electrode 234C is electrically connected to the fourth back-surface electrode 244C. The fourth via 254D is electrically connected to the fourth front-surface electrode 234D and the fourth back-surface electrode 244D. Therefore, the fourth front-surface electrode 234D is electrically connected to the fourth back-surface electrode 244D.

### Configuration and Layout of Semiconductor Light-Emitting Element and First to Fourth Drive Circuits

As shown in FIGS. 16, 18, and 19, the semiconductor light-emitting element 30, the first drive circuit 40, the second drive circuit 50, the third drive circuit 110, and the fourth drive circuit 120 are mounted on the front-surface electrodes 28A. The configuration and arrangement of the semiconductor light-emitting element 30 and the first to fourth drive circuits 40, 50, 110, and 120 will now be described in detail. The same reference characters are given to those components that are the same as the corresponding components of the third embodiment, and such components may not be described in detail.

The semiconductor light-emitting element 30 is mounted on the first front-surface electrode 231A. Specifically, the element back-surface electrode 35 (not shown in FIG. 16; refer to FIG. 3) of the semiconductor light-emitting element 30 is bonded to the first front-surface electrode 231A by the conductive bonding material SD (not shown). Therefore, the element back-surface electrode 35 is electrically connected to the first front-surface electrode 231A. The semiconductor light-emitting element 30 is shifted toward the third substrate side surface 25 with respect to the center of the first front-surface electrode 231A in the Y-direction.

The semiconductor light-emitting element 30 of the fourth embodiment is identical to the semiconductor light-emitting element 30 of the third embodiment in size, shape, and configuration. As described above, in the semiconductor light-emitting element 30 of the fourth embodiment, the eight light emitters 33 are divided into pairs of light emitters 33, namely, the first to fourth light emitters 33A to 33D. The first to fourth light emitters 33A to 33D are divided in the same manner as the second embodiment.

In the first drive circuit 40 of the fourth embodiment, the shapes and quantities of the drain electrode 171D, the source electrode 171S, and the gate electrode 171G of the first switching element 171 differ from those of the third embodiment. More specifically, a single drain electrode 171D is provided. The drain electrode 171D is rectangular in plan view, with long sides extending in the Y-direction and short sides extending in the X-direction. Multiple (in the fourth embodiment, two) source electrodes 171S are provided. The source electrodes 171S are separately disposed at opposite sides of the drain electrode 171D in the X-direction. One of the two source electrodes 171S that is located closer to the imaginary centerline VC than the drain electrode 171D is rectangular in plan view, with long sides extending in the Y-direction and short sides extending in the X-direction. The other source electrode 171S is substantially square in plan view. The gate electrode 171G is located at the same position as the other source electrode 171S in the X-direction. The gate electrode 171G is located closer to the fourth substrate side surface 26 than the other source electrode 171S is in the Y-direction. The gate electrode 171G is substantially square in plan view. The first switching element 171 is rectangular in plan view, with long sides extending in the X-direction and short sides extending in the Y-direction.

The first switching element 171 is mounted on the second front-surface electrode 232A, the third front-surface electrode 233A, and the fourth front-surface electrode 234A. More specifically, the drain electrode 171D of the first switching element 171 is bonded to the third front-surface electrode 233A by the conductive bonding material SD (not shown). The source electrodes 171S are each bonded to the second front-surface electrode 232A by the conductive bonding material SD (not shown). The gate electrode 171G is bonded to the fourth front-surface electrode 234A by the conductive bonding material SD (not shown). In this manner, the drain electrode 171D is electrically connected to the third front-surface electrode 233A, the source electrodes 171S are electrically connected to the second front-surface electrode 232A, and the gate electrode 171G is electrically connected to the fourth front-surface electrode 234A.

In plan view, the semiconductor light-emitting element 30 and the first capacitor 42 are spaced apart from each other in the Y-direction. The first capacitor 42 is located at a side of the first switching element 171 opposite to the semiconductor light-emitting element 30 in the Y-direction. In other words, in plan view, the first switching element 171 is arranged between the semiconductor light-emitting element 30 and the first capacitor 42 in the Y-direction. The first switching element 171 is located at a position that overlaps the first light emitter 33A and the third light emitter 33C as viewed in the Y-direction. The first capacitor 42 is located at a position that overlaps the first switching element 171 as viewed in the Y-direction.

Multiple (in the fourth embodiment, three) first capacitors 42 are provided. The first capacitors 42 are connected in parallel to each other. The first capacitors 42 are aligned with and spaced apart from each other in the X-direction. Each of the first capacitors 42 extends over the third front-surface electrode 233E and the third wiring portion 231BC of the first front-surface electrode 231B in the Y-direction. The first capacitor 42 is mounted on the third front-surface electrode 233E and the third wiring portion 231BC. More specifically, the first capacitor 42 is separately bonded to the third front-surface electrode 233E and the third wiring portion 231BC by the conductive bonding material SD. In the example shown in FIG. 16, the first electrode 42A is bonded to the third front-surface electrode 233E by the conductive bonding material SD. Therefore, the first electrode 42A is electrically connected to the third front-surface electrode 233E. The first electrode 42A is electrically connected to the drain electrode 171D of the first switching element 171 through the third front-surface electrode 233E and the third front-surface electrode 233A. The second electrode 42B is bonded to the third wiring portion 231BC by the conductive bonding material SD. Therefore, the second electrode 42B is electrically connected to the first front-surface electrode 231B. The first capacitors 42 are arranged in the third front-surface electrode 233E and are located relatively close to the imaginary centerline VC in the Y-direction.

As shown in FIG. 19, in the second drive circuit 50, the second switching element 181 of the second embodiment includes a lateral transistor in the same manner as the third embodiment. However, in the second switching element 181 of the fourth embodiment, the shapes and quantities of the drain electrode 181D, the source electrode 181S, and the gate electrode 181G differ from those of the third embodiment. More specifically, a single drain electrode 181D is provided. The drain electrode 181D is rectangular in plan view, with long sides extending in the Y-direction and short sides extending in the X-direction. Multiple (in the fourth embodiment, two) source electrodes 181S are provided. The source electrodes 181S are separately disposed at opposite sides of the drain electrode 181D in the X-direction. One of the two source electrodes 181S that is located relatively close to the imaginary centerline VC is rectangular in plan view, with long sides extending in the Y-direction and short sides extending in the X-direction. The other source electrode 181S is substantially square in plan view. The gate electrode 181G is located at the same position as the other source electrode 181S in the X-direction. The gate electrode 181G is located closer to the third substrate side surface 25 than the other source electrode 181S is in the Y-direction. The gate electrode 181G is substantially square in plan view. The second switching element 181 is rectangular in plan view, with long sides extending in the X-direction and short sides extending in the Y-direction.

The second switching element 181 is mounted on the second front-surface electrode 232B, the third front-surface electrode 233B, and the fourth front-surface electrode 234B. More specifically, the drain electrode 181D of the second switching element 181 is bonded to the third front-surface electrode 233B by the conductive bonding material SD (not shown). The source electrodes 181S are each bonded to the second front-surface electrode 232B by the conductive bonding material SD (not shown). The gate electrode 181G is bonded to the fourth front-surface electrode 234B by the conductive bonding material SD (not shown). In this manner, the drain electrode 181D is electrically connected to the second front-surface electrode 232B, the source electrodes 181S are electrically connected to the third front-surface electrode 233B, and the gate electrode 181G is electrically connected to the fourth front-surface electrode 234B.

In plan view, the semiconductor light-emitting element 30 and the second capacitor 52 are spaced apart from each other in the Y-direction. The second capacitor 52 is located at a side of the second switching element 181 opposite to the semiconductor light-emitting element 30 in the Y-direction. In other words, in plan view, the second switching element 181 is arranged between the semiconductor light-emitting element 30 and the second capacitor 52 in the Y-direction. The second switching element 181 is located at a position that overlaps the second light emitter 33B and the fourth light emitter 33D as viewed in the Y-direction. The second capacitor 52 is located at a position that overlaps the second switching element 181 as viewed in the Y-direction.

As shown in FIG. 16, in plan view, the distance D1 between the semiconductor light-emitting element 30 and the first switching element 171 in the Y-direction is equal to the distance D2 between the semiconductor light-emitting element 30 and the second switching element 181 in the Y-direction. The distance D1 and the distance D2 may be considered to be the same as long as a difference of the distance D1 and the distance D2 is, for example, within 10% of the distance D1.

Multiple (in the fourth embodiment, three) second capacitors 52 are provided. The second capacitors 52 are aligned with and spaced apart from each other in the X-direction. Each of the second capacitors 52 extends over the third front-surface electrode 233F and the third wiring portion 231BC of the first front-surface electrode 231B in the Y-direction. The second capacitor 52 is mounted on the third front-surface electrode 233F and the third wiring portion 231BC. More specifically, the second capacitor 52 is separately bonded to the third front-surface electrode 233F and the third wiring portion 231BC by the conductive bonding material SD (not shown). In the example shown in FIG. 18, the first electrode 52A is bonded to the third front-surface electrode 233F by the conductive bonding material SD (not shown). Therefore, the first electrode 52A is electrically connected to the third front-surface electrode 233F. The first electrode 52A is electrically connected to the drain electrode 181D of the second switching element 181 through the third front-surface electrode 233F and the third front-surface electrode 233B. The second electrode 52B is bonded to the third wiring portion 231BC by the conductive bonding material SD (not shown). Therefore, the second electrode 52B is electrically connected to the first front-surface electrode 231B. The second capacitors 52 are arranged in the third front-surface electrode 233F and are located relatively close to the imaginary centerline VC in the Y-direction.

In the third drive circuit 110, the third switching element 221 includes a lateral transistor. The third switching element 221 has the same configuration as the second switching element 181. The third switching element 221 includes a second element front surface 221A and a second element back surface (not shown) facing away from each other in the Z-direction. A drain electrode 221D, a source electrode 221S, and a gate electrode 221G are formed in the second element back surface. The quantities, shapes, and layout of the drain electrode 221D, the source electrode 221S, and the gate electrode 221G are identical to those of the drain electrode 181D, the source electrode 181S, and the gate electrode 181G of the second switching element 181. The third switching element 221 is rectangular, with long sides extending in the Y-direction and short sides extending in the X-direction.

The third switching element 221 is mounted on the second front-surface electrode 232C, the third front-surface electrode 233C, and the fourth front-surface electrode 234C. More specifically, the drain electrode 221D of the third switching element 221 is bonded to the third front-surface electrode 233C by the conductive bonding material SD (not shown). The source electrodes 221S are bonded to the second front-surface electrode 232C by the conductive bonding material SD (not shown). The gate electrode 221G is bonded to the fourth front-surface electrode 234C by the conductive bonding material SD (not shown). In this manner, the drain electrode 221D is electrically connected to the third front-surface electrode 233C, the source electrodes 221S are electrically connected to the second front-surface electrode 232C, and the gate electrode 221G is electrically connected to the fourth front-surface electrode 234C.

In plan view, the semiconductor light-emitting element 30 and the third switching element 221 are spaced apart from each other in the X-direction. The third switching element 221 is located closer to the first substrate side surface 23 than the semiconductor light-emitting element 30 is in the X-direction. As viewed in the X-direction, the third switching element 221 is located at a position that overlaps the semiconductor light-emitting element 30.

In plan view, the semiconductor light-emitting element 30 and the third capacitor 112 are spaced apart from each other in the X-direction. The third capacitor 112 is located at a side of the third switching element 221 opposite to the semiconductor light-emitting element 30 in the X-direction. In other words, in plan view, the third switching element 221 is arranged between the semiconductor light-emitting element 30 and the third capacitor 112 in the X-direction. As viewed in the X-direction, the third capacitor 112 is located at a position that overlaps the third switching element 221.

Multiple (in the fourth embodiment, three) third capacitors 112 are provided. The third capacitors 112 are connected in parallel to each other. The third capacitors 112 are aligned with and spaced apart from each other in the Y-direction. Each of the third capacitors 112 extends over the third front-surface electrode 233G and the first wiring portion 231BA of the first front-surface electrode 231B in the X-direction. The third capacitor 112 is mounted on the third front-surface electrode 233G and the first wiring portion 231BA. More specifically, the third capacitor 112 is separately bonded to the third front-surface electrode 233G and the first wiring portion 231BA by the conductive bonding material SD (not shown). In the example shown in FIG. 18, the first electrode 112A is bonded to the third front-surface electrode 233G by the conductive bonding material SD (not shown). Therefore, the first electrode 112A is electrically connected to the third front-surface electrode 233G. The first electrode 112A is electrically connected to the drain electrode 221D of the third switching element 221 through the third front-surface electrode 233G and the third front-surface electrode 233C. The second electrode 112B is bonded to the first wiring portion 231BA by the conductive bonding material SD (not shown). Therefore, the second electrode 112B is electrically connected to the first front-surface electrode 231B.

As shown in FIG. 19, in the fourth drive circuit 120, the third switching element 221 includes a lateral transistor. The fourth switching element 222 has the same configuration as the first switching element 171. The fourth switching element 222 includes a second element front surface 222A and a second element back surface (not shown) facing away from each other in the Z-direction. A drain electrode 222D, a source electrode 222S, and a gate electrode 222G are formed in the second element back surface. The quantities, shapes, and layout of the drain electrode 222D, the source electrode 222S, and the gate electrode 222G are identical to those of the drain electrode 171D, the source electrode 171S, and the gate electrode 171G of the first switching element 171. The fourth switching element 222 is rectangular, with long sides extending in the Y-direction and short sides extending in the X-direction.

The fourth switching element 222 is mounted on the second front-surface electrode 232D, the third front-surface electrode 233D, and the fourth front-surface electrode 234D. More specifically, the drain electrode 222D of the fourth switching element 222 is bonded to the third front-surface electrode 233D by the conductive bonding material SD (not shown). The source electrodes 222S are bonded to the second front-surface electrode 232D by the conductive bonding material SD (not shown). The gate electrode 222G is bonded to the fourth front-surface electrode 234D by the conductive bonding material SD (not shown). In this manner, the drain electrode 222D is electrically connected to the third front-surface electrode 233D, the source electrodes 222S are electrically connected to the second front-surface electrode 232D, and the gate electrode 222G is electrically connected to the fourth front-surface electrode 234D.

In plan view, the semiconductor light-emitting element 30 and the fourth switching element 222 are spaced apart from each other in the X-direction. The fourth switching element 222 is located closer to the second substrate side surface 24 than the semiconductor light-emitting element 30 is in the X-direction. As viewed in the X-direction, the fourth switching element 222 is located at a position that overlaps the semiconductor light-emitting element 30.

In plan view, the semiconductor light-emitting element 30 and the fourth capacitor 122 are spaced apart from each other in the X-direction. The fourth capacitor 122 is located at a side of the fourth switching element 222 opposite to the semiconductor light-emitting element 30 in the X-direction. In other words, in plan view, the fourth switching element 222 is arranged between the semiconductor light-emitting element 30 and the fourth capacitor 122 in the X-direction. As viewed in the X-direction, the fourth capacitor 122 is located at a position that overlaps the fourth switching element 222.

As shown in FIG. 16, in plan view, the distance D3 between the semiconductor light-emitting element 30 and the third switching element 221 in the X-direction is equal to the distance D4 between the semiconductor light-emitting element 30 and the fourth switching element 222 in the X-direction. The distance D3 and the distance D4 may be considered to be the same as long as a difference of the distance D3 and the distance D4 is, for example, within 10% of the distance D3.

As shown in FIG. 19, multiple (in the fourth embodiment, three) fourth capacitors 122 are provided. The fourth capacitors 122 are connected in parallel to each other. The fourth capacitors 122 are aligned with and spaced apart from each other in the Y-direction. Each of the fourth capacitors 122 extends over the third front-surface electrode 233H and the second wiring portion 231BB of the first front-surface electrode 231B in the X-direction. The fourth capacitor 122 is mounted on the third front-surface electrode 233H and the second wiring portion 231BB. More specifically, the fourth capacitor 122 is separately bonded to the third front-surface electrode 233H and the second wiring portion 231BB by the conductive bonding material SD (not shown). In the example shown in FIG. 19, the first electrode 122A is bonded to the third front-surface electrode 233H by the conductive bonding material SD (not shown). Therefore, the first electrode 122A is electrically connected to the third front-surface electrode 233H. The first electrode 122A is electrically connected to the drain electrode 222D of the fourth switching element 222 through the third front-surface electrode 233H and the third front-surface electrode 233D. The second electrode 122B is bonded to the second wiring portion 231BB by the conductive bonding material SD (not shown). Therefore, the second electrode 122B is electrically connected to the first front-surface electrode 231B.

As shown in FIGS. 18 and 19, the semiconductor light-emitting device 10 further includes the first to fourth protection diodes 101 to 104.

As shown in FIG. 18, the first protection diode 101 is configured to protect the first light emitter 33A of the semiconductor light-emitting element 30. The first protection diode 101 is located closer to the first substrate side surface 23 than the semiconductor light-emitting element 30, the first switching element 171, and the first capacitors 42 are in the X-direction. In an example, as viewed in the Y-direction, the first protection diode 101 is located at a position that overlaps the third switching element 221. The first protection diode 101 is located at a side of the first switching element 171 opposite to the semiconductor light-emitting element 30 in the Y-direction. The first protection diode 101 is located at a position that overlaps the first capacitors 42 as viewed in the X-direction. The first protection diode 101 extends over the second front-surface electrode 232A and the third wiring portion 231BC of the first front-surface electrode 231B in the Y-direction. The first protection diode 101 is arranged so that the first anode electrode 101A and the first cathode electrode 101B are located at the same position in the X-direction and are spaced apart from each other in the Y-direction. The first protection diode 101 is mounted on the second front-surface electrode 232A and the first front-surface electrode 231B. More specifically, the first protection diode 101 is separately bonded to the second front-surface electrode 232A and the first front-surface electrode 231B by the conductive bonding material SD (not shown).

The first protection diode 101 is connected in antiparallel to the first light emitter 33A. More specifically, the first anode electrode 101A is bonded to the first front-surface electrode 231B by the conductive bonding material SD (not shown). The first anode electrode 101A is disposed in the third wiring portion 231BC of the first front-surface electrode 231B. Therefore, the first anode electrode 101A is electrically connected to the element back-surface electrode 35 of the semiconductor light-emitting element 30 through the first front-surface electrode 231B. The first cathode electrode 101B is bonded to the second front-surface electrode 232A by the conductive bonding material SD (not shown). Therefore, the first cathode electrode 101B is electrically connected to the first element front-surface electrodes 34A, which correspond to the first light emitter 33A of the semiconductor light-emitting element 30, through the wires W5 and the second front-surface electrode 232A.

As shown in FIG. 19, the second protection diode 102 is configured to protect the second light emitter 33B of the semiconductor light-emitting element 30. The second protection diode 102 is located closer to the second substrate side surface 24 than the semiconductor light-emitting element 30, the second switching element 181, and the second capacitors 52 are in the X-direction. In an example, as viewed in the Y-direction, the second protection diode 102 is located at a position that overlaps the fourth switching element 222. The second protection diode 102 is located at a side of the second switching element 181 opposite to the semiconductor light-emitting element 30 in the Y-direction. The second protection diode 102 is located at a position that overlaps the second capacitors 52 as viewed in the X-direction. The second protection diode 102 extends over the second front-surface electrode 232B and the third wiring portion 231BC of the first front-surface electrode 231B in the Y-direction. The second protection diode 102 is mounted on the second front-surface electrode 232B and the first front-surface electrode 231B. The second protection diode 102 is arranged in the same manner as the first protection diode 101.

The second protection diode 102 is connected in antiparallel to the second light emitter 33B. More specifically, the second anode electrode 102A is bonded to the third wiring portion 231BC of the first front-surface electrode 231B by the conductive bonding material SD (not shown). Therefore, the second anode electrode 102A is electrically connected to the element back-surface electrode 35 of the semiconductor light-emitting element 30 through the first front-surface electrode 231B. The second cathode electrode 102B is bonded to the second front-surface electrode 232B by the conductive bonding material SD (not shown). Therefore, the second cathode electrode 102B is electrically connected to the second element front-surface electrodes 34B, which correspond to the second light emitter 33B of the semiconductor light-emitting element 30, through the wires W5 and the second front-surface electrode 232B.

As shown in FIG. 18, the third protection diode 103 is configured to protect the third light emitter 33C of the semiconductor light-emitting element 30. The third protection diode 103 is located closer to the fourth substrate side surface 26 than the semiconductor light-emitting element 30, the third switching element 221, and the third capacitors 112 are in the Y-direction. In an example, as viewed in the X-direction, the third protection diode 103 is located at a position that overlaps the first switching element 171. The third protection diode 103 is located at a side of the third switching element 221 opposite to the semiconductor light-emitting element 30 in the X-direction. The third protection diode 103 is located at a position that overlaps the third capacitors 112 as viewed in the Y-direction. The third protection diode 103 extends over the second front-surface electrode 232C and the first wiring portion 231BA of the first front-surface electrode 231B in the X-direction.

The third protection diode 103 is arranged so that the third anode electrode 103A and the third cathode electrode 103B are located at the same position in the Y-direction and are spaced apart from each other in the X-direction. The third protection diode 103 is mounted on the second front-surface electrode 232C and the first front-surface electrode 231B. More specifically, the third protection diode 103 is separately bonded to the second front-surface electrode 232C and the first front-surface electrode 231B by the conductive bonding material SD (not shown).

The third protection diode 103 is connected in antiparallel to the third light emitter 33C. More specifically, the third anode electrode 103A is bonded to the first front-surface electrode 231B by the conductive bonding material SD (not shown). The third anode electrode 103A is disposed in the first wiring portion 231BA of the first front-surface electrode 231B. Therefore, the third anode electrode 103A is electrically connected to the element back-surface electrode 35 of the semiconductor light-emitting element 30 through the first front-surface electrode 231B. The third cathode electrode 103B is bonded to the second front-surface electrode 232C by the conductive bonding material SD (not shown). Therefore, the third cathode electrode 103B is electrically connected to the third element front-surface electrodes 34C, which correspond to the third light emitter 33C of the semiconductor light-emitting element 30, through the wires W5 and the second front-surface electrode 232C.

As shown in FIG. 19, the fourth protection diode 104 is configured to protect the fourth light emitter 33D of the semiconductor light-emitting element 30. The fourth protection diode 104 is located closer to the fourth substrate side surface 26 than the semiconductor light-emitting element 30, the fourth switching element 222, and the fourth capacitors 122 are in the Y-direction. In an example, as viewed in the X-direction, the fourth protection diode 104 is located at a position that overlaps the second switching element 181. The fourth protection diode 104 is located at a side of the fourth switching element 222 opposite to the semiconductor light-emitting element 30 in the X-direction. The fourth protection diode 104 is located at a position that overlaps the fourth capacitors 122 as viewed in the Y-direction. The fourth protection diode 104 extends over the second front-surface electrode 232D and the second wiring portion 231BB of the first front-surface electrode 231B in the X-direction.

The fourth protection diode 104 is arranged so that the fourth anode electrode 104A and the fourth cathode electrode 104B are located at the same position in the Y-direction and are spaced apart from each other in the X-direction. The fourth protection diode 104 is mounted on the second front-surface electrode 232D and the first front-surface electrode 231B. More specifically, the fourth protection diode 104 is separately bonded to the second front-surface electrode 232D and the first front-surface electrode 231B by the conductive bonding material SD (not shown).

The fourth protection diode 104 is connected in antiparallel to the fourth light emitter 33D. More specifically, the fourth anode electrode 104A is bonded to the first front-surface electrode 231B by the conductive bonding material SD (not shown). The fourth anode electrode 104A is disposed in the second wiring portion 231BB of the first front-surface electrode 231B. Therefore, the fourth anode electrode 104A is electrically connected to the element back-surface electrode 35 of the semiconductor light-emitting element 30 through the first front-surface electrode 231B. The fourth cathode electrode 104B is bonded to the second front-surface electrode 232D by the conductive bonding material SD (not shown). Therefore, the fourth cathode electrode 104B is electrically connected to the fourth element front-surfaces electrodes 34D, which correspond to the fourth light emitter 33D of the semiconductor light-emitting element 30, by the wires W5 and the second front-surface electrode 232D. In this manner, the first to fourth anode electrodes 101A to 104A of the first to fourth protection diodes 101 to 104 are electrically connected to one another through the first front-surface electrode 231B.

### Advantages

The semiconductor light-emitting device 10 of the fourth embodiment has the following advantages in addition to advantages (2-1) to (2-7) of the second embodiment and advantages (3-1) to (3-4) of the third embodiment.

(4-1) The third switching element 221 includes the source electrode 221S, the drain electrode 221D, and the gate electrode 221G that are formed in the second element back surface. The fourth switching element 222 includes the source electrode 222S, the drain electrode 222D, and the gate electrode 222G that are formed in the second element back surface. The source electrode 221S, the drain electrode 221D, and the gate electrode 221G of the third switching element 221 are mounted on the front-surface electrodes 28A. The source electrode 222S, the drain electrode 222D, and the gate electrode 222G of the fourth switching element 222 are mounted on the front-surface electrodes 28A.

With this configuration, no wire is used for electrical connection between the source electrode 221S, the drain electrode 221D, and the gate electrode 221G of the third switching element 221 and the front-surface electrodes 28A. This reduces the inductance of the looped third current path formed by the semiconductor light-emitting element 30, the third switching element 221, and the third capacitor 112. Further, no wire is used for electrical connection between the source electrode 222S, the drain electrode 222D, and the gate electrode 222G of the fourth switching element 222 and the front-surface electrodes 28A. This reduces the inductance of the looped fourth current path formed by the semiconductor light-emitting element 30, the fourth switching element 222, and the fourth capacitor 122.

(4-2) The third switching element 221 is rectangular in plan view, with long sides extending in the Y-direction and short sides extending in the X-direction. The fourth switching element 222 is rectangular in plan view, with long sides extending in the Y-direction and short sides extending in the X-direction.

With this configuration, the third switching element 221 is long in a direction (Y-direction) orthogonal to an arrangement direction (X-direction) in which the semiconductor light-emitting element 30, the third switching element 221, and the third capacitor 112 are arranged. Therefore, the distance between the semiconductor light-emitting element 30 and the third capacitor 112 in the X-direction is shorter as compared to a configuration in which the third switching element 221 is relatively long in the arrangement direction. As a result, the looped third current path formed by the semiconductor light-emitting element 30, the third switching element 221, and the third capacitor 112 is relatively short. Further, the fourth switching element 222 is long in a direction (Y-direction) orthogonal to an arrangement direction (X-direction) in which the semiconductor light-emitting element 30, the fourth switching element 222, and the fourth capacitor 122 are arranged. Therefore, the distance between the semiconductor light-emitting element 30 and the fourth capacitor 122 in the X-direction is shorter as compared to a configuration in which the fourth switching element 222 is relatively long in the arrangement direction. As a result, the looped fourth current path formed by the semiconductor light-emitting element 30, the fourth switching element 222, and the fourth capacitor 122 is relatively short.

(4-3) The semiconductor light-emitting device 10 includes the first vias 251A to 251F, the second vias 252A to 252D, the third vias 253A to 253H, and the fourth vias 254A to 254D that are arranged in the substrate 20 to connect the back-surface electrodes 28B and the front-surface electrodes 28A. The third current path between the third light emitter 33C of the semiconductor light-emitting element 30 and the third drive circuit 110 is formed by the first front-surface electrodes 231A and 231B, the second front-surface electrode 232C, the third front-surface electrodes 233C and 233G, the fourth front-surface electrode 234C, the first back-surface electrode 241A, the first vias 251A and 251B, and the third via 253C. The fourth current path between the fourth light emitter 33D of the semiconductor light-emitting element 30 and the fourth drive circuit 120 is formed by the first front-surface electrodes 231A and 231B, the second front-surface electrode 232D, the third front-surface electrodes 233D and 233H, the fourth front-surface electrode 234D, the first back-surface electrode 241A, the first vias 251A and 251C, and the third via 253D.

With this configuration, the first back-surface electrode 241A forms part of the loop of the third current path, in which electric current flows through the first electrode 112A of the third capacitor 112, the drain electrode 221D of the third switching element 221, the source electrode 221S, the third element front-surface electrode 34C of the semiconductor light-emitting element 30, the element back-surface electrode 35, and the second electrode 112B of the third capacitor 112 in this order. This decreases the area of the loop of the third current path, thereby reducing the inductance of the third current path. Further, the first back-surface electrode 241A forms part of the loop of the fourth current path, in which electric current flows through the first electrode 122A of the fourth capacitor 122, the drain electrode 222D of the fourth switching element 222, the source electrode 222S, the fourth element front-surface electrode 34D of the semiconductor light-emitting element 30, the element back-surface electrode 35, and the second electrode 122B of the fourth capacitor 122 in this order. This decreases the area of the loop of the fourth current path, thereby reducing the inductance of the fourth current path.

(4-4) The first to fourth switching elements 171, 181, 221, and 222 include lateral transistors having the same configuration.

With this configuration, the semiconductor light-emitting device 10 includes a single type of switching element. This reduces the manufacturing costs of the semiconductor light-emitting device 10 as compared to when multiple types of switching elements are included.

### Fifth Embodiment

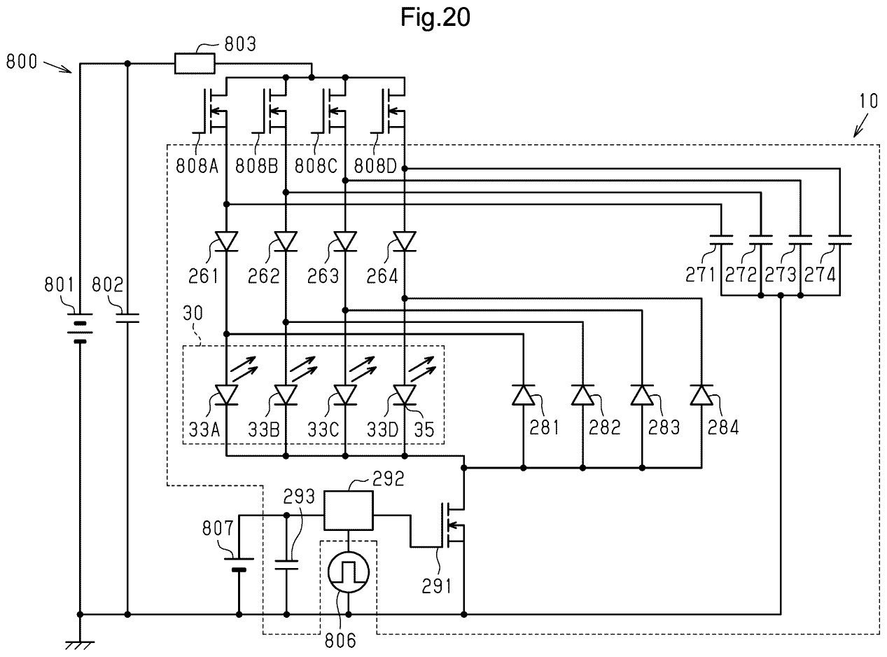

A semiconductor light-emitting device 10 in accordance with a fifth embodiment will now be described with reference to FIGS. 20 to 26.

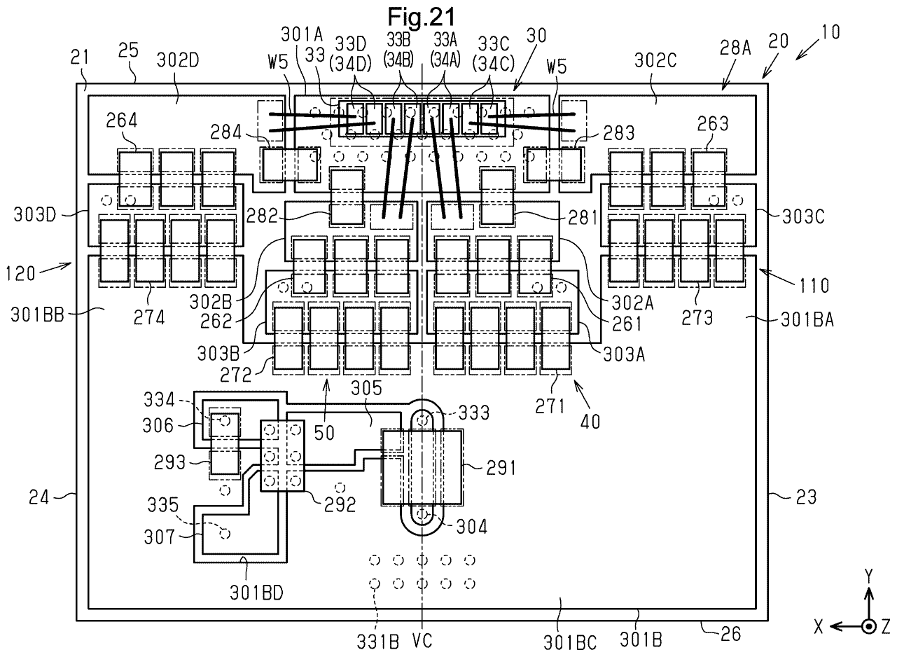

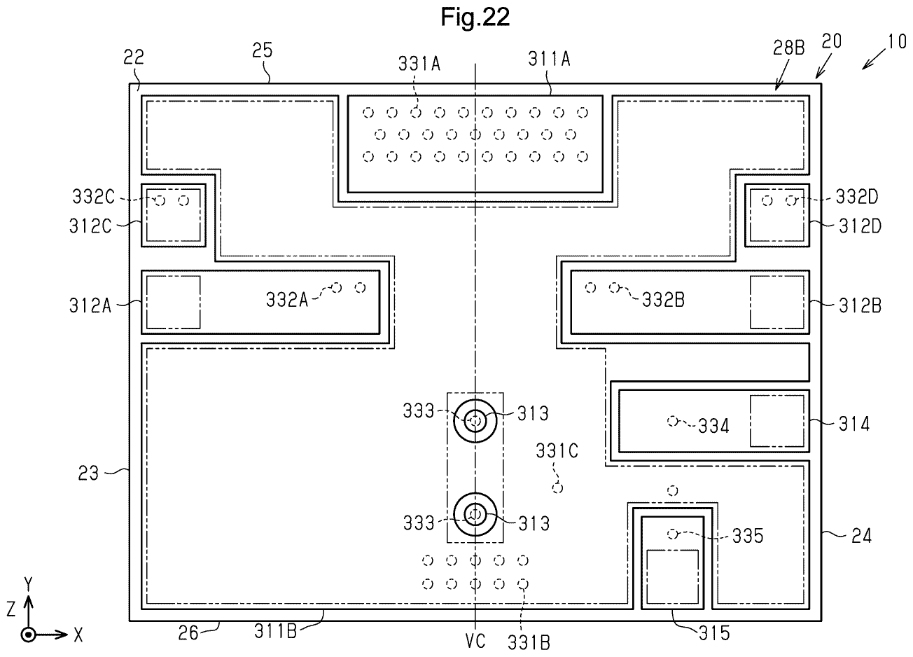

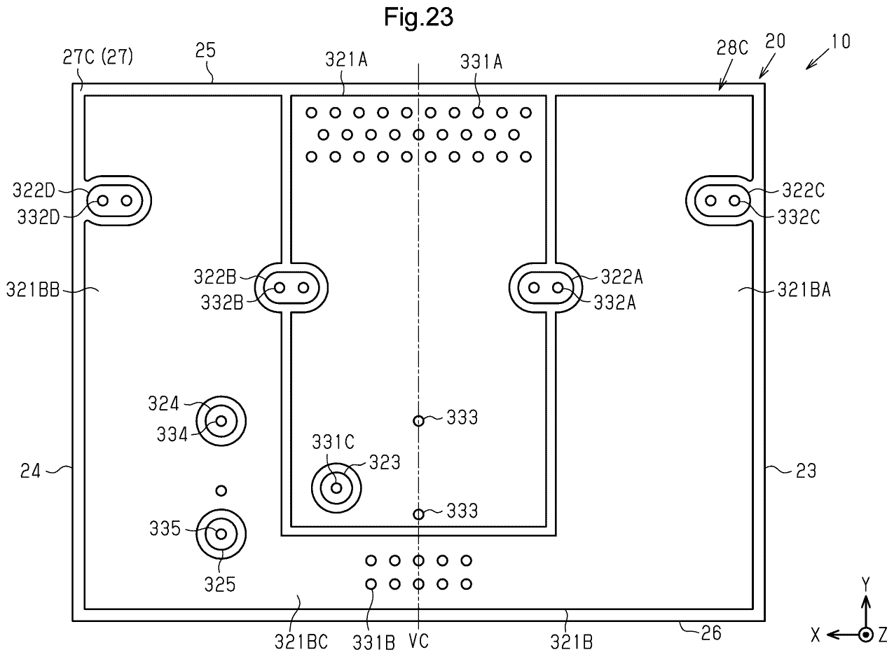

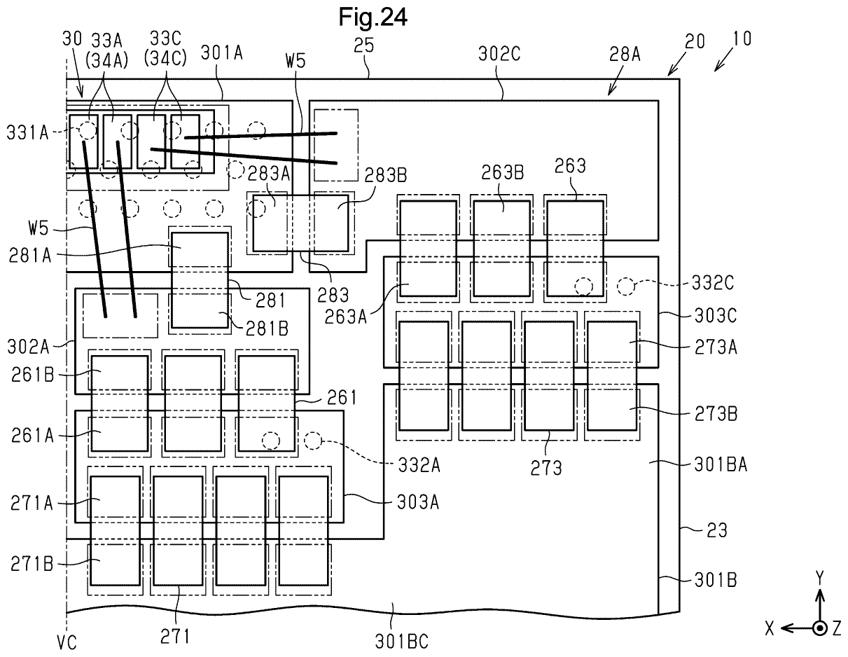

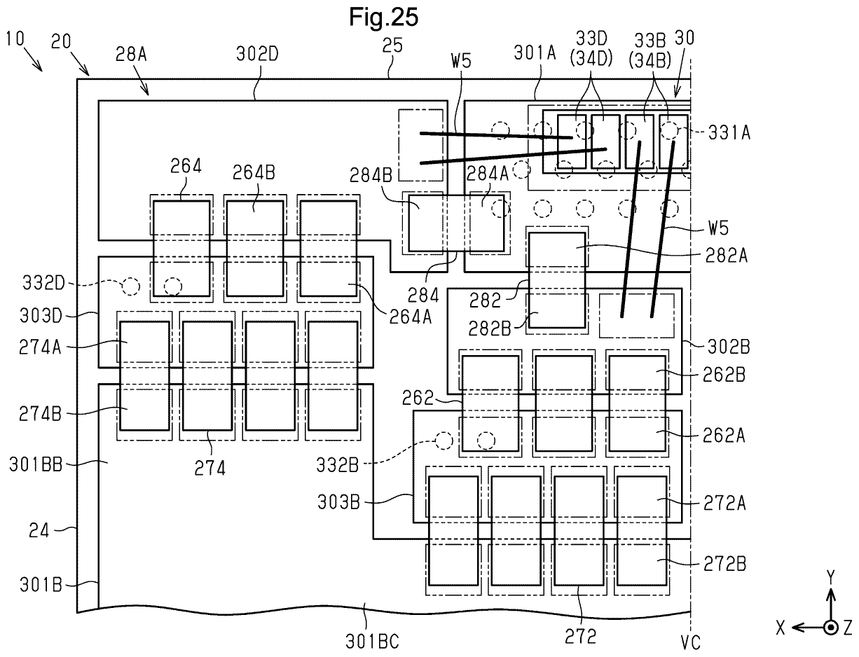

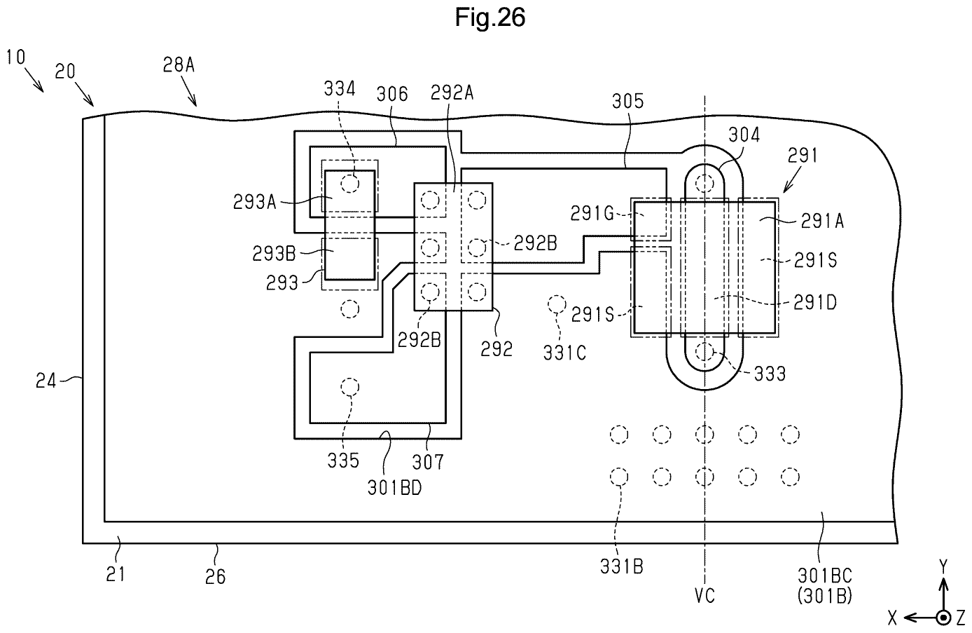

FIG. 20 shows a schematic circuit diagram of a light-emitting system 800 including the semiconductor light-emitting device 10 of the fifth embodiment. FIG. 21 shows a schematic planar structure of the semiconductor light-emitting device 10 in accordance with the fifth embodiment. FIG. 22 shows a schematic bottom structure of the semiconductor light-emitting device 10 shown in FIG. 21. FIG. 23 shows a schematic planar structure of the front-surface intermediate electrode 28C of the semiconductor light-emitting device 10 shown in FIG. 21. FIG. 24 shows a schematic planar structure of the semiconductor light-emitting device 10 shown in FIG. 21 enlarging a portion between the imaginary centerline VC and the first substrate side surface 23. FIG. 25 shows a schematic planar structure of the semiconductor light-emitting device 10 shown in FIG. 21 enlarging a portion between the imaginary centerline VC and the second substrate side surface 24. FIG. 26 shows a schematic planar structure of the semiconductor light-emitting device 10 shown in FIG. 21 enlarging a switching element for light emission 291, which will be described later.

### Circuitry of Light-Emitting System

As shown in FIG. 20, the light-emitting system 800 includes the DC power supply 801, the capacitor 802, and the current limiting resistor 803, in the same manner as the first embodiment. Instead of the gate driver IC 805, the pulse generator 806, and the control power supply 807 of the first embodiment (refer to FIG. 5), the light-emitting system 800 includes a gate driver IC 292. Further, the light-emitting system 800 includes first to fourth charging switching elements 808A to 808D.

The first to fourth charging switching elements 808A to 808D are configured to control electric currents supplied to the first to fourth light emitters 33A to 33D of the semiconductor light-emitting element 30 of the semiconductor light-emitting device 10. The first to fourth charging switching elements 808A to 808D are, for example, MOSFETs. Drain electrodes of the first to fourth charging switching elements 808A to 808D are electrically connected to one another and are electrically connected to the second terminal of the current limiting resistor 803. The first terminal of the current limiting resistor 803 is electrically connected to the positive electrode of the DC power supply 801.

The semiconductor light-emitting element 30 of the fifth embodiment includes the first to fourth light emitters 33A to 33D. In the same manner as the first embodiment, the semiconductor light-emitting element 30 includes eight light emitters 33 (refer to FIG. 21). The first to fourth light emitters 33A to 33D each include two light emitters 33. In the same manner as the first embodiment, the cathodes of the first to fourth light emitters 33A to 33D are electrically connected to each other. The semiconductor light-emitting element 30 includes the element back-surface electrode 35 that serves as a common cathode.

The semiconductor light-emitting device 10 includes first to fourth reverse current protection diodes 261 to 264, first to fourth capacitors 271 to 274, first to fourth protection diodes 281 to 284, a switching element for light emission 291, a gate driver IC 292, and a capacitor 293. The first to fourth reverse current protection diodes 261 to 264 and the first to fourth capacitors 271 to 274 are separately electrically connected to the first to fourth charging switching elements 808A to 808D.

The first to fourth reverse current protection diodes 261 to 264 are separately electrically connected to source electrodes of the first to fourth charging switching elements 808A to 808D. Also, the first to fourth reverse current protection diodes 261 to 264 are separately electrically connected to the first to fourth light emitters 33A to 33D. More specifically, the first reverse current protection diode 261 includes a first anode electrically connected to the source electrode of the first charging switching element 808A, and a first cathode electrically connected to the anode of the first light emitter 33A. The second reverse current protection diode 262 includes a second anode electrically connected to the source electrode of the second charging switching element 808B, and a second cathode electrically connected to the anode of the second light emitter 33B. The third reverse current protection diode 263 includes a third anode electrically connected to the source electrode of the third charging switching element 808C, and a third cathode electrically connected to the anode of the third light emitter 33C. The fourth reverse current protection diode 264 includes a fourth anode electrically connected to the source electrode of the fourth charging switching element 808D, and a fourth cathode electrically connected to the anode of the fourth light emitter 33D.

The first to fourth protection diodes 281 to 284 are separately connected in antiparallel to the first to fourth light emitters 33A to 33D. More specifically, the first protection diode 281 includes a first protection cathode electrically connected to the anode of the first light emitter 33A, the second protection diode 282 includes a second protection cathode electrically connected to the anode of the second light emitter 33B, the third protection diode 283 includes a third protection cathode electrically connected to the anode of the third light emitter 33C, and the fourth protection diode 284 includes a fourth protection cathode electrically connected to the anode of the fourth light emitter 33D. First to fourth protection anodes of the first to fourth protection diodes 281 to 284 are electrically connected to each other and are electrically connected to the common cathode of the first to fourth light emitters 33A to 33D. In other words, the first to fourth cathodes of the first to fourth protection diodes 281 are separately electrically connected to the first to fourth cathodes of the first to fourth reverse current protection diodes 261 to 264.

The cathodes (element back-surface electrode 35) of the first to fourth light emitters 33A to 33D are electrically connected to a drain electrode of the switching element for light emission 291. Accordingly, the first to fourth protection anodes, which serve as the common anode of the first to fourth protection diodes 281 to 284, are electrically connected to the drain electrode of the switching element for light emission 291. A source electrode of the switching element for light emission 291 is electrically connected to ground wiring. The ground wiring is, for example, electrically connected to the negative electrode of the DC power supply 801 and is also grounded.

The first to fourth capacitors 271 to 274 are configured to separately supply electric current to the first to fourth light emitters 33A to 33D. The first to fourth capacitors 271 to 274 are separately electrically connected to nodes between the source electrodes of the first to fourth charging switching elements 808A to 808D and the first to fourth anodes of the first to fourth reverse current protection diodes 261 to 264. Also, the first to fourth capacitors 271 to 274 are electrically connected to the ground wiring. More specifically, the first capacitor 271 includes a first electrode electrically connected to the node between the source electrode of the first charging switching element 808A and the first anode of the first reverse current protection diode 261. The second capacitor 272 includes a first electrode electrically connected to the node between the source electrode of the second charging switching element 808B and the second anode of the second reverse current protection diode 262. The third capacitor 273 includes a first electrode electrically connected to the node between the source electrode of the third charging switching element 808C and the third anode of the third reverse current protection diode 263. The fourth capacitor 274 includes a first electrode electrically connected to the node between the source electrode of the fourth charging switching element 808D and the fourth anode of the fourth reverse current protection diode 264. The first to fourth capacitors 271 to 274 include second electrodes electrically connected to each other and to the ground wiring. In other words, the second electrodes of the first to fourth capacitors 271 to 274 are electrically connected to the source electrode of the switching element for light emission 291.

The gate driver IC 292 is, for example, a semiconductor chip configured to control the switching element for light emission 291. The gate driver IC 292 is electrically connected to a gate electrode of the switching element for light emission 291. The gate driver IC 292 is configured to output a gate signal for controlling the switching element for light emission 291 to the gate electrode of the switching element for light emission 291.

The pulse generator 806 is electrically connected to the gate driver IC 292 and the ground wiring. Accordingly, the pulse generator 806 outputs a pulse signal to the gate driver IC 292. The control power supply 807 is electrically connected to the gate driver IC 292, the capacitor 293, and the ground wiring. Accordingly, the control power supply 807 supplies electric power to the gate driver IC 292. The control power supply 807 is disposed outside the semiconductor light-emitting device 10 in the same manner as the pulse generator 806. The control power supply 807 is electrically connected to an intermediate part between a fourth back-surface electrode 314 and a first back-surface electrode 311B shown in FIG. 22. The capacitor 293 is electrically connected to an intermediate part between a power supply terminal of the gate driver IC 292 and the ground wiring, that is, an intermediate part between a sixth front-surface electrode 306 and a second wiring portion 301BB of a first front-surface electrode 301B.

Although not shown in the drawings, the light-emitting system 800 further includes an external controller configured to separately control the first to fourth charging switching elements 808A to 808D. The external controller is separately electrically connected to gate electrodes of the first to fourth charging switching elements 808A to 808D. The external controller is configured to output a first gate signal for controlling the first charging switching element 808A to the gate electrode of the first charging switching element 808A. The external controller is configured to output a second gate signal for controlling the second charging switching element 808B to the gate electrode of the second charging switching element 808B. The external controller is configured to output a third gate signal for controlling the third charging switching element 808C to the gate electrode of the third charging switching element 808C. The external controller is configured to output a fourth gate signal for controlling the fourth charging switching element 808D to the gate electrode of the fourth charging switching element 808D.

In such a light-emitting system 800, for example, when the first charging switching element 808A is switched on and the switching element for light emission 291 is switched off, the first capacitor 271 is charged. Then, when the first charging switching element 808A is switched off and the switching element for light emission 291 is switched on, the first capacitor 271 supplies electric current through the first reverse current protection diode 261 to the first light emitter 33A. In the same manner as the first charging switching element 801A, the second to fourth capacitors 272 to 274 are charged and discharged in accordance with the on-off states of the second to fourth charging switching elements 808B to 808D. As a result, electric current is separately supplied through the second to fourth reverse current protection diodes 262 to 264 to the second to fourth light emitter 33B to 33D. In this manner, the first to fourth charging switching elements 808A to 808D, the first to fourth capacitors 271 to 274, and the switching element for light emission 291 allow the first to fourth light emitters 33A to 33D to emit light separately.

### Overall Configuration of Semiconductor Light-Emitting Device

The overall configuration of the semiconductor light-emitting device 10 will now be described with reference to FIGS. 21 to 26. The same reference characters are given to those components that are the same as the corresponding components of the first and second embodiments, and such components may not be described in detail. In FIG. 21, and 24 to 26, boxes defined by double-dashed lines indicate open portions in the front surface resist 29A (refer to FIG. 3). In FIG. 22, boxes defined by double-dashed lines indicate open portions in the back surface resist 29B (refer to FIG. 3).

As shown in FIG. 21, in the semiconductor light-emitting device 10, the first to fourth reverse current protection diodes 261 to 264, the first to fourth capacitors 271 to 274, the first to fourth protection diodes 281 to 284, the switching element for light emission 291, the gate driver IC 292, and the capacitor 293 are arranged on the substrate front surface 21. The first to fourth reverse current protection diodes 261 to 264, the first to fourth capacitors 271 to 274, the first to fourth protection diodes 281 to 284, the switching element for light emission 291, the gate driver IC 292, and the capacitor 293 are mounted on the front-surface electrodes 28A.

The semiconductor light-emitting device 10 of the fifth embodiment includes the first to fourth drive circuits 40, 50, 110, and 120. In the fifth embodiment, the first drive circuit 40 includes the first capacitor 271, the second drive circuit 50 includes the second capacitor 272, the third drive circuit 110 includes the third capacitor 273, and the fourth drive circuit 120 includes the fourth capacitor 274.

In the fifth embodiment, the front-surface electrodes 28A include first front-surface electrodes 301A and 301B, second front-surface electrodes 302A to 302D, third front-surface electrodes 303A to 303D, a fourth front-surface electrode 304, a fifth front-surface electrode 305, a sixth front-surface electrode 306, and a seventh front-surface electrode 307. The first front-surface electrodes 301A and 301B, the second front-surface electrodes 302A to 302D, the third front-surface electrodes 303A to 303D, the fourth front-surface electrode 304, the fifth front-surface electrode 305, the sixth front-surface electrode 306, and the seventh front-surface electrode 307 are spaced apart from one another.

The semiconductor light-emitting element 30 is mounted on the first front-surface electrode 301A. In plan view, the first front-surface electrode 301A is disposed in a central part of the substrate front surface 21 in the X-direction and is located relatively close to the third substrate side surface 25 of the substrate front surface 21. The first front-surface electrode 301A is rectangular in plan view, with long sides extending in the X-direction and short sides extending in the Y-direction. The first front-surface electrode 301A is symmetric with respect to the imaginary centerline VC.

The first front-surface electrode 301B serves as ground wiring. The first front-surface electrode 301B is substantially U-shaped along the edges of the substrate front surface 21. The first front-surface electrode 301B is spaced apart from the first front-surface electrode 301A and is located relatively close to the fourth substrate side surface 26 in the Y-direction. The first front-surface electrode 301B includes a first wiring portion 301BA formed along the first substrate side surface 23, a second wiring portion 301BB formed along the second substrate side surface 24, and a third wiring portion 301BC formed along the fourth substrate side surface 26. In an example, the first wiring portion 301BA, the second wiring portion 301BB, and the third wiring portion 301BC are integrated with each other. The first front-surface electrode 301B is symmetric with respect to the imaginary centerline VC. The first wiring portion 301BA and the second wiring portion 301BB each include a distal end that is located closer to the fourth substrate side surface 26 than the first front-surface electrode 301A is in the Y-direction.

In plan view, the first front-surface electrode 301B has a greater area than each of the first front-surface electrode 301A, the second front-surface electrodes 302A to 302D, the third front-surface electrodes 303A to 303D, the fourth front-surface electrode 304, the fifth front-surface electrode 305, the sixth front-surface electrode 306, or the seventh front-surface electrode 307. In the example shown in FIG. 21, the area of the first front-surface electrode 301B is greater than or equal to the combined total area of the first front-surface electrode 301A, the second front-surface electrodes 302A to 302D, the third front-surface electrodes 303A to 303D, the fourth front-surface electrode 304, the fifth front-surface electrode 305, the sixth front-surface electrode 306, and the seventh front-surface electrode 307.

The second front-surface electrodes 302A to 302D are arranged around the first front-surface electrode 301A. The second front-surface electrodes 302A to 302D are located closer to the third substrate side surface 25 than the first front-surface electrode 301B is in the Y-direction. The second front-surface electrodes 302A and 302B are located at a position that overlaps the first front-surface electrode 301A as viewed in the Y-direction, and are located closer to the fourth substrate side surface 26 than the first front-surface electrode 301A is in the Y-direction. The second front-surface electrodes 302A and 302B are adjacent to the first front-surface electrode 301A in the Y-direction. The second front-surface electrodes 302A and 302B are separately disposed at opposite sides of the imaginary centerline VC in the X-direction. The second front-surface electrodes 302A and 302B are arranged next to each other in the X-direction. The second front-surface electrode 302A is located closer to the first substrate side surface 23 than the imaginary centerline VC is. The second front-surface electrode 302B is located closer to the second substrate side surface 24 than the imaginary centerline VC is. The second front-surface electrodes 302A and 302B are arranged between the first wiring portion 301BA and the second wiring portion 301BB in the X-direction.

The second front-surface electrodes 302A and 302B are each rectangular in plan view, with long sides extending in the X-direction and short sides extending in the Y-direction. The second front-surface electrodes 302A and 302B are identical in size and shape. The second front-surface electrodes 302A and 302B are each smaller than the first front-surface electrode 301A in the Y-direction.

The second front-surface electrodes 302C and 302D are separately disposed at opposite sides of the first front-surface electrode 301A in the X-direction. As viewed in the X-direction, the second front-surface electrodes 302C and 302D are located at a position that overlaps the first front-surface electrode 301A. The second front-surface electrode 302C and the second front-surface electrode 302D are adjacent to the first front-surface electrode 301A in the X-direction. The second front-surface electrode 302C is located closer to the first substrate side surface 23 than the first front-surface electrode 301A is. The second front-surface electrode 302D is located closer to the second substrate side surface 24 than the first front-surface electrode 301A is.

The second front-surface electrodes 302C and 302D are each rectangular in plan view, with long sides extending in the X-direction and short sides extending in the Y-direction. The second front-surface electrodes 302C and 302D are identical in size. The second front-surface electrodes 302C and 302D are symmetric with respect to the imaginary centerline VC. The second front-surface electrodes 302C and 302D each include a projection at one of two opposite ends in the X-direction that is located closer to the first front-surface electrode 301A. The projection projects toward the fourth substrate side surface 26. In the example shown in FIG. 21, the distal edge of the projection of the second front-surface electrodes 302C and 302D is located at the same position as one of two edges of the first front-surface electrode 301A in the Y-direction that is located closer to the fourth substrate side surface 26 in the Y-direction. The second front-surface electrodes 302C and 302D are larger than the second front-surface electrodes 302A and 302B in the Y-direction. The second front-surface electrodes 302C and 302D are larger than the second front-surface electrodes 302A and 302B in the X-direction.

The third front-surface electrodes 303A to 303D are arranged between the second front-surface electrodes 302A to 302D and the first front-surface electrode 301B in the Y-direction.

The third front-surface electrodes 303A and 303B are separately disposed at opposite sides of the imaginary centerline VC in the X-direction. The third front-surface electrode 303A is arranged between the second front-surface electrode 302A and the third wiring portion 301BC of the first front-surface electrode 301B in the Y-direction and are located at a position that overlaps the second front-surface electrode 302A as viewed in the Y-direction. The third front-surface electrode 303B is arranged between the second front-surface electrode 302B and the third wiring portion 301BC in the Y-direction and are located at a position that overlaps the second front-surface electrode 302B as viewed in the Y-direction. The third front-surface electrodes 303A and 303B are located in a recess of the first front-surface electrode 301B.

The third front-surface electrodes 303A and 303B are each rectangular in plan view, with long sides extending in the X-direction and short sides extending in the Y-direction. The third front-surface electrodes 303A and 303B are identical in size. The third front-surface electrodes 303A and 303B are symmetric with respect to the imaginary centerline VC. The third front-surface electrodes 303A and 303B are larger than the second front-surface electrodes 302A and 302B in the X-direction.

The third front-surface electrodes 303C and 303D are disposed outside of the recess of the first front-surface electrode 301B in the X-direction. The third front-surface electrodes 303C and 303D are located closer to the third substrate side surface 25 than the third front-surface electrodes 303A and 303B are in the Y-direction.

The third front-surface electrode 303C is located at a position that overlaps the first wiring portion 301BA of the first front-surface electrode 301B as viewed in the Y-direction, and is located closer to the third substrate side surface 25 than the first wiring portion 301BA is in the Y-direction. The third front-surface electrode 303C is arranged between the first wiring portion 301BA and the second front-surface electrode 302C in the Y-direction.

The third front-surface electrode 303D is located at a position that overlaps the second wiring portion 301BB of the first front-surface electrode 301B as viewed in the Y-direction, and is located closer to the third substrate side surface 25 than the second wiring portion 301BB is in the Y-direction. The third front-surface electrode 303D is arranged between the second wiring portion 301BB and the second front-surface electrode 302D in the Y-direction.

In the example shown in FIG. 21, one of two opposite ends of the third front-surface electrodes 303C, 303D in the Y-direction that is located closer to the third substrate side surface 25 is disposed slightly closer to the third substrate side surface 25 than one of the two edges of the first front-surface electrode 301A in the Y-direction that is located closer to the fourth substrate side surface 26 in the Y-direction.

The third front-surface electrodes 303C and 303D are each rectangular in plan view, with long sides extending in the X-direction and short sides extending in the Y-direction. The third front-surface electrodes 303C and 303D are identical in size. The third front-surface electrodes 303C and 303D are symmetric with respect to the imaginary centerline VC. In the example shown in FIG. 21, the third front-surface electrodes 303C and 303D and the third front-surface electrodes 303A and 303B are identical in size.

The fourth to seventh front-surface electrodes 304 to 307 are located closer to the fourth substrate side surface 26 than the third front-surface electrodes 303A to 303D are in the Y-direction. More specifically, the third wiring portion 301BC of the first front-surface electrode 301B includes an open portion 301BD. The open portion 301BD is formed in the third wiring portion 301BC and is located relatively close to the second substrate side surface 24. The fourth to seventh front-surface electrodes 304 to 307 are arranged in the open portion 301BD.

The fourth front-surface electrode 304 is located closer to the first substrate side surface 23 than the fifth to seventh front-surface electrodes 305 to 307 are in the X-direction. The fourth front-surface electrode 304 is arranged on the imaginary centerline VC. The fourth front-surface electrode 304 is disposed in a central part of the third wiring portion 301BC in the Y-direction. The fourth front-surface electrode 304 is elliptic in plan view, with major axis extending in the Y-direction and minor axis extending in the X-direction.

The fifth front-surface electrode 305 includes a portion adjacent to the fourth front-surface electrode 304 in the X-direction. In plan view, the fourth front-surface electrode 304 is surrounded by the third wiring portion 301BC except for the portion adjacent to the fifth front-surface electrode 305. The fifth front-surface electrode 305 is located closer to the third substrate side surface 25 than the center of the fourth front-surface electrode 304 in the Y-direction is.

The fifth front-surface electrode 305 is substantially rectangular in plan view, with long sides extending in the X-direction and short sides extending in the Y-direction. The fifth front-surface electrode 305 includes an indent to avoid the third wiring portion 301BC. The indent is located relatively close to the fourth front-surface electrode 304 in the X-direction. The third wiring portion 301BC is disposed at two opposite sides of the fifth front-surface electrode 305 in the Y-direction.

The sixth front-surface electrode 306 and the seventh front-surface electrode 307 are located closer to the second substrate side surface 24 than the fifth front-surface electrode 305 is. The sixth front-surface electrode 306 is located at a position that overlaps the fifth front-surface electrode 305 as viewed in the X-direction. The seventh front-surface electrode 307 is located closer to the fourth substrate side surface 26 than the fifth front-surface electrode 305 is in the Y-direction. The seventh front-surface electrode 307 is located at a position that overlaps the sixth front-surface electrode 306 as viewed in the Y-direction. The seventh front-surface electrode 307 is spaced apart from the sixth front-surface electrode 306 in the Y-direction. Part of the third wiring portion 301BC is arranged between the seventh front-surface electrode 307 and the sixth front-surface electrode 306 in the Y-direction.

In plan view, the third wiring portion 301BC surrounds the sixth front-surface electrode 306 except for an end that opposes the fifth front-surface electrode 305 in the X-direction. The sixth front-surface electrode 306 is rectangular in plan view, with long sides extending in the X-direction and short sides extending in the Y-direction.

In plan view, the seventh front-surface electrode 307 is surrounded by the third wiring portion 301BC. Accordingly, part of the third wiring portion 301BC is disposed between the seventh front-surface electrode 307 and the sixth front-surface electrode 306 in the Y-direction. The seventh front-surface electrode 307 is substantially L-shaped in plan view. More specifically, the seventh front-surface electrode 307 includes a first section extending in the Y-direction, and a second section extending from the first section toward the second substrate side surface 24. The second section is located closer to the fourth substrate side surface 26 than the first section is.

As shown in FIG. 22, the back-surface electrodes 28B include first back-surface electrodes 311A and 311B, second back-surface electrodes 312A to 312D, a third back-surface electrode 313, a fourth back-surface electrode 314, and a fifth back-surface electrode 315. The first back-surface electrodes 311A and 311B, the second back-surface electrodes 312A to 312D, the third back-surface electrode 313, the fourth back-surface electrode 314, and the fifth back-surface electrode 315 are spaced apart from one another.

The first back-surface electrode 311A is electrically connected to the first front-surface electrode 301A (refer to FIG. 21). The first back-surface electrode 311A is disposed in a central part of the substrate back surface 22 in the X-direction and is adjacent to the third substrate side surface 25 in the Y-direction. That is, the first back-surface electrode 311A is located at a position that overlaps the first front-surface electrode 301A in plan view. The first back-surface electrode 311A is rectangular in plan view, with long sides extending in the X-direction and short sides extending in the Y-direction. In an example, the first back-surface electrode 311A and the first front-surface electrode 301A are identical in size.

The first back-surface electrode 311B is formed in most of the substrate back surface 22. In other words, the first back-surface electrode 311B is formed in the substrate back surface 22 except for regions in which the first back-surface electrode 311A, the second back-surface electrode 312A to 312D, the third back-surface electrode 313, the fourth back-surface electrode 314, and the fifth back-surface electrode 315 are formed. In plan view, the first back-surface electrode 311B includes a portion that surrounds the first back-surface electrode 311A from the sides of the first substrate side surface 23, the second substrate side surface 24, and the fourth substrate side surface 26. In plan view, the first back-surface electrode 311B has a greater area than the combined total area of the first back-surface electrode 311A, the second back-surface electrode 312A to 312D, the third back-surface electrode 313, the fourth back-surface electrode 314, and the fifth back-surface electrode 315.

The second back-surface electrode 312A is electrically connected to the third front-surface electrode 303A. The second back-surface electrode 312B is electrically connected to the third front-surface electrode 303B. The second back-surface electrode 312C is electrically connected to the third front-surface electrode 303C. The second back-surface electrode 312D is electrically connected to the third front-surface electrode 303D. The second back-surface electrodes 312A to 312D are located closer to the third substrate side surface 25 than the center of the substrate back surface 22 is in the Y-direction.

The second back-surface electrodes 312A to 312D are separately electrically connected to the sources of the first to fourth charging switching elements 808A to 808D (refer to FIG. 20). More specifically, the second back-surface electrode 312A is electrically connected to the source of the first charging switching element 808A, the second back-surface electrode 312B is electrically connected to the source of the second charging switching element 808B, the second back-surface electrode 312C is electrically connected to the source of the third charging switching element 808C, and the second back-surface electrode 312D is electrically connected to the source of the fourth charging switching element 808D.

The second back-surface electrodes 312A and 312B are located closer to the fourth substrate side surface 26 than the first back-surface electrode 311A is in the Y-direction. The second back-surface electrodes 312A and 312B are separately disposed at opposite sides of the imaginary centerline VC in the X-direction. One of two opposite ends of the second back-surface electrode 312A, 312B in the X-direction that is located closer to the imaginary centerline VC is disposed at a position that overlaps the first back-surface electrode 311A as viewed in the Y-direction. The one of the two opposite ends of the second back-surface electrode 312A in the X-direction that is located closer to the imaginary centerline VC is disposed at a position that overlaps the third front-surface electrode 303A in plan view. The one of the two opposite ends of the second back-surface electrode 312B in the X-direction that is located closer to the imaginary centerline VC is disposed at a position that overlaps the third front-surface electrode 303B in plan view.

The second back-surface electrodes 312A and 312B are each rectangular in plan view, with long sides extending in the X-direction and short sides extending in the Y-direction. The second back-surface electrodes 312A and 312B are identical in size. That is, the second back-surface electrodes 312A and 312B are symmetric with respect to the imaginary centerline VC.

The second back-surface electrodes 312C and 312D are located closer to the third substrate side surface 25 than the second back-surface electrodes 312A and 312B are in the Y-direction. One of two opposite ends of the second back-surface electrodes 312C, 312D in the X-direction that is located closer to the third substrate side surface 25 is disposed at a position that overlaps the first back-surface electrode 311A as viewed in the X-direction. The second back-surface electrodes 312C and 312D are separately disposed at opposite sides of the first back-surface electrode 311A in the X-direction. As viewed in the Y-direction, the second back-surface electrode 312C is located at a position that overlaps one of the two opposite ends of the second back-surface electrode 312A in the X-direction that is disposed closer to the first substrate side surface 23. As viewed in the Y-direction, the second back-surface electrode 312D is located at a position that overlaps one of the two opposite ends of the second back-surface electrode 312B in the X-direction that is disposed closer to the second substrate side surface 24. The second back-surface electrode 312C is disposed in an end of the substrate back surface 22 that is located relatively close to the first substrate side surface 23 in the X-direction. The second back-surface electrode 312D is disposed in another end of the substrate back surface 22 that is located relatively close to the second substrate side surface 24 in the X-direction. The second back-surface electrode 312C is located at a position that overlaps the third front-surface electrode 303C in plan view. The second back-surface electrode 312D is located at a position that overlaps the third front-surface electrode 303D in plan view.

The second back-surface electrodes 312C and 312D are each square in plan view. The second back-surface electrodes 312C and 312D are smaller than the second back-surface electrodes 312A and 312B in area. The second back-surface electrodes 312C and 312D are shorter than the second back-surface electrodes 312A and 312B in the X-direction.

The third to fifth back-surface electrodes 313 to 315 are located closer to the fourth substrate side surface 26 than the center of the substrate back surface 22 is in the Y-direction. The fourth back-surface electrode 314 and the fifth back-surface electrode 315 are located closer to the second substrate side surface 24 than the third back-surface electrode 313 is.

Multiple (in the fifth embodiment, two) third back-surface electrodes 313 are provided. The third back-surface electrodes 313 are located at the same position in the X-direction and are spaced apart from each other in the Y-direction. The third back-surface electrodes 313 are electrically connected to the fourth front-surface electrode 304. The third back-surface electrodes 313 are arranged on the imaginary centerline VC. That is, the third back-surface electrodes 313 are located at a position that overlaps the fourth front-surface electrode 304 in plan view. The first back-surface electrodes 313 are each circular in plan view.

One of the two third back-surface electrodes 313 that is located closer to the third substrate side surface 25 is disposed at the same position as the fourth back-surface electrode 314 in the Y-direction. The fourth back-surface electrode 314 is electrically connected to the sixth front-surface electrode 306. In plan view, the fourth back-surface electrode 314 is located at a position that overlaps the sixth front-surface electrode 306. The fourth back-surface electrode 314 is located at a position that overlaps the second back-surface electrode 312B as viewed in the Y-direction. Part of the first back-surface electrode 311B is located between the fourth back-surface electrode 314 and the second back-surface electrode 312B in the Y-direction.

The fourth back-surface electrode 314 is rectangular in plan view, with long sides extending in the X-direction and short sides extending in the Y-direction. The fourth back-surface electrode 314 is shorter than the second back-surface electrode 312C in the X-direction.

The fifth back-surface electrode 315 is electrically connected to the seventh front-surface electrode 307. The fifth back-surface electrode 315 is located closer to the fourth substrate side surface 26 than the fourth back-surface electrode 314 is in the Y-direction. The fifth back-surface electrode 315 is located at a position that overlaps the fourth back-surface electrode 314 as viewed in the Y-direction. One of the two third back-surface electrodes 313 that is located closer to the fourth substrate side surface 26 is disposed at a position that overlaps the fifth back-surface electrode 315 as viewed in the X-direction. The fifth back-surface electrode 315 is spaced apart from the second substrate side surface 24 in the X-direction. A distance between the fifth back-surface electrode 315 and the second substrate side surface 24 in the X-direction is, for example, greater than a distance between the second back-surface electrode 312D and the second substrate side surface 24 in the X-direction. Part of the first back-surface electrode 311B is located between the fifth back-surface electrode 315 and the second substrate side surface 24 in the X-direction and between the fifth back-surface electrode 315 and the fourth back-surface electrode 314 in the Y-direction.

The fifth front-surface electrode 315 is rectangular in plan view, with long sides extending in the Y-direction and short sides extending in the X-direction. The fifth back-surface electrode 315 is larger than the fourth back-surface electrode 314 in the Y-direction and smaller than the fourth back-surface electrode 314 in the X-direction.

As shown in FIG. 23, the front-surface intermediate electrodes 28C include first intermediate electrodes 321A and 321B, second intermediate electrodes 322A to 322D, a third intermediate electrode 323, a fourth intermediate electrode 324, and a fifth intermediate electrode 325. The first intermediate electrodes 321A and 321B, the second intermediate electrodes 322A to 322D, the third intermediate electrode 323, the fourth intermediate electrode 324, and the fifth intermediate electrode 325 are spaced apart from one another.

The first intermediate electrodes 321A and 321B are formed in most of the base-member front surface of the intermediate base member 27C. The first intermediate electrodes 321A and 321B include recesses and openings that are arranged to avoid the second intermediate electrodes 322A to 322D, the third intermediate electrode 323, the fourth intermediate electrode 324, and the fifth intermediate electrode 325.

The first intermediate electrode 321A electrically connects the first front-surface electrode 301A and the fourth front-surface electrode 304 (refer to FIG. 21). The first intermediate electrode 321A is disposed in a central part of the intermediate base member 27C in the X-direction. The second intermediate electrode 321A is rectangular in plan view, with long sides extending in the Y-direction and short sides extending in the X-direction. The first intermediate electrode 321A extends in the Y-direction from an end of the intermediate base member 27C that is located relatively close to the third substrate side surface 25 to a position of the intermediate base member 27C that overlaps both the fourth front-surface electrode 304 and the third back-surface electrodes 313 in plan view.

The first intermediate electrode 321B is electrically connected to the first front-surface electrode 301B (refer to FIG. 21). In plan view, the first intermediate electrode 321B is U-shaped and surrounds the first intermediate electrode 321A from the sides of the first, second, and fourth substrate side surfaces 23, 24, and 26. The first intermediate electrode 321B includes a first wiring portion 321BA extending along the first substrate side surface 23, a second wiring portion 321BB extending along the second substrate side surface 24, and a third wiring portion 321BC connecting the first wiring portion 321BA and the second wiring portion 321BB. In an example, the first wiring portion 321BA, the second wiring portion 321BB, and the third wiring portion 321BC are integrated with each other. The third wiring portion 321BC is adjacent to the fourth substrate side surface 26 in the Y-direction.

The second intermediate electrode 322A is electrically connected to both the third front-surface electrode 303A (refer to FIG. 21) and the second back-surface electrode 312A (refer to FIG. 22). The second intermediate electrode 322B is electrically connected to both the third front-surface electrode 303B (refer to FIG. 21) and the second back-surface electrode 312B (refer to FIG. 22). The second intermediate electrode 322C is electrically connected to both the third front-surface electrode 303C (refer to FIG. 21) and the second back-surface electrode 312C (refer to FIG. 22). The second intermediate electrode 322D is electrically connected to both the third front-surface electrode 303D (refer to FIG. 21) and the second back-surface electrode 312D (refer to FIG. 22).

The second intermediate electrodes 322A to 322D are located closer to the third substrate side surface 25 than the center of the intermediate base member 27C is in the Y-direction. The second intermediate electrode 322A is arranged between the first intermediate electrode 321A and the first wiring portion 321BA of the first intermediate electrode 321B in the X-direction. The second intermediate electrode 322B is arranged between the first intermediate electrode 321A and the second wiring portion 321BB of the first intermediate electrode 321B in the X-direction. The second intermediate electrode 322C is disposed in a substantially elliptic opening of the first wiring portion 321BA. The second intermediate electrode 322D is disposed in a substantially elliptic opening of the second wiring portion 321BB The second intermediate electrodes 322C and 322D are located closer to the third substrate side surface 25 than the second intermediate electrodes 322A and 322B are. The second intermediate electrode 322A is located at a position that overlaps both the third front-surface electrode 303A and the second back-surface electrode 312A in plan view. The second intermediate electrode 322B is located at a position that overlaps both the third front-surface electrode 303B and the second back-surface electrode 312B in plan view. The second intermediate electrode 322C is located at a position that overlaps both the third front-surface electrode 303C and the second back-surface electrode 312C in plan view. The second intermediate electrode 322D is located at a position that overlaps both the third front-surface electrode 303D and the second back-surface electrode 312D in plan view. The second intermediate electrodes 322A to 322D are each elliptic in plan view, with major axis extending in the X-direction and minor axis extending in the Y-direction.

The third intermediate electrode 323 is electrically connected to both the first front-surface electrode 301B and the first back-surface electrode 311B. The third intermediate electrode 323 is located at a position that overlaps both the first front-surface electrode 301B and the first back-surface electrode 311B in plan view. The third intermediate electrode 323 is disposed in a circular opening arranged in one of two opposite ends of the first intermediate electrode 321A in the Y-direction that is located closer to the fourth substrate side surface 26. The third intermediate electrode 323 is located closer to the second substrate side surface 24 than the imaginary centerline VC is. The third intermediate electrode 323 is circular in plan view.

The fourth intermediate electrode 324 is electrically connected to both the sixth front-surface electrode 306 (refer to FIG. 21) and the fourth back-surface electrode 314 (refer to FIG. 22). The fifth intermediate electrode 325 is electrically connected to both the seventh front-surface electrode 307 (refer to FIG. 21) and the fifth back-surface electrode 315 (refer to FIG. 22). The fourth intermediate electrode 324 is located at a position that overlaps both the sixth front-surface electrode 306 and the fourth back-surface electrode 314 in plan view. The fifth intermediate electrode 325 is located at a position that overlaps both the seventh front-surface electrode 307 and the fifth back-surface electrode 315 in plan view. The fourth intermediate electrode 324 and the fifth intermediate electrode 325 are respectively disposed in two circular openings arranged in the second wiring portion 321BB. The fourth intermediate electrode 324 and the fifth intermediate electrode 325 are located at the same position in the X-direction and are spaced apart from each other in the Y-direction. The fourth intermediate electrode 324 is located closer to the third substrate side surface 25 than the fifth intermediate electrode 325 is.

Although not shown in the drawings, the back-surface intermediate electrodes 28D include the first intermediate electrodes 321A and 321B, the second intermediate electrodes 322A to 322D, the third intermediate electrode 323, the fourth intermediate electrode 324, and the fifth intermediate electrode 325, in the same manner as the front-surface intermediate electrodes 28C. The shapes, sizes, and layout of the first intermediate electrodes 321A and 321B, the second intermediate electrodes 322A to 322D, the third intermediate electrode 323, the fourth intermediate electrode 324, and the fifth intermediate electrode 325 of the back-surface intermediate electrodes 28D are identical to those of the front-surface intermediate electrodes 28C.

As shown in FIGS. 21 to 26, the substrate 20 includes first vias 331A to 331C, second vias 332A to 332D, a third via 333, a fourth via 334, and a fifth via 335. The first vias 331A to 331C, the second vias 332A to 332D, the third via 333, the fourth via 334, and the fifth via 335 extend through the base members 27A, 27B, and 27C, the front-surface intermediate electrodes 28C, and the back-surface intermediate electrodes 28D in the Z-direction. The first vias 331A to 331C, the second vias 332A to 332D, the third via 333, the fourth via 334, and the fifth via 335 are formed from, for example, a material containing one or more selected from Ti, TiN, Au, Ag, Cu, Al, and W.

The first via 331A is electrically connected to the first front-surface electrode 301A, the first intermediate electrode 321A of the front-surface intermediate electrode 28C, the first intermediate electrode 321A of the back-surface intermediate electrode 28D, and the first back-surface electrode 311A. Therefore, the first front-surface electrode 301A, the first intermediate electrode 321A of the front-surface intermediate electrode 28C, the first intermediate electrode 321A of the back-surface intermediate electrode 28D, and the first back-surface electrode 311A are electrically connected to each other.

As shown in FIGS. 24 and 25, multiple first vias 331A are provided. The first vias 331A are arranged in the first front-surface electrode 301A and are located relatively close to the third substrate side surface 25. Accordingly, in plan view, the first vias 331A are located at a position of the first front-surface electrode 301A that overlaps the semiconductor light-emitting element 30. The first vias 331A are aligned with and spaced apart from one another in the X-direction and the Y-direction. A greater number of first vias 331A are aligned in the X-direction than in the Y-direction. In plan view, the first vias 331A are formed in a region that is larger than the area of the semiconductor light-emitting element 30. Therefore, some of the first vias 331A are located outside the semiconductor light-emitting element 30 in plan view.

As shown in FIGS. 22, 23, and 26, the first via 331B is electrically connected to the first front-surface electrode 301B, the first intermediate electrode 321B of the front-surface intermediate electrode 28C, the first intermediate electrode 321B of the back-surface intermediate electrode 28D, and the first back-surface electrode 311B. Therefore, the first front-surface electrode 301B, the first intermediate electrode 321B of the front-surface intermediate electrode 28C, the first intermediate electrode 321B of the back-surface intermediate electrode 28D, and the first back-surface electrode 311B are electrically connected to each other. The first via 331C is electrically connected to the first front-surface electrode 301B, the third intermediate electrode 323 of the front-surface intermediate electrode 28C, the third intermediate electrode 323 of the back-surface intermediate electrode 28D, and the first back-surface electrode 311B. Therefore, the first front-surface electrode 301B, the third intermediate electrode 323 of the front-surface intermediate electrode 28C, the third intermediate electrode 323 of the back-surface intermediate electrode 28D, and the first back-surface electrode 311B are electrically connected to each other.

Multiple first vias 331B are provided. The first vias 331B are arranged in a central part of the third wiring portion 301BC of the first front-surface electrode 301B in the X-direction. The first via 331C is located closer to both the second substrate side surface 24 and the third substrate side surface 25 than the first vias 331B are.

As shown in FIGS. 22 to 25, multiple second vias 332A, multiple second vias 332B, multiple second vias 332C, and multiple second vias 332D are provided. The second vias 332A to 332D are each less in number than the first vias 331A. The second vias 332A are electrically connected to the third front-surface electrode 303A, the second intermediate electrode 322A of the front-surface intermediate electrode 28C, the second intermediate electrode 322A of the back-surface intermediate electrode 28D, and the second back-surface electrode 312A. Therefore, the third front-surface electrode 303A, the second intermediate electrode 322A of the front-surface intermediate electrode 28C, the second intermediate electrode 322A of the back-surface intermediate electrode 28D, and the second back-surface electrode 312A are electrically connected to each other. The second vias 332B are electrically connected to the third front-surface electrode 303B, the second intermediate electrode 322B of the front-surface intermediate electrode 28C, the second intermediate electrode 322B of the back-surface intermediate electrode 28D, and the second back-surface electrode 312B. Therefore, the third front-surface electrode 303B, the second intermediate electrode 322B of the front-surface intermediate electrode 28C, the second intermediate electrode 322B of the back-surface intermediate electrode 28D, and the second back-surface electrode 312B are electrically connected to each other. The second vias 332C are electrically connected to the third front-surface electrode 303C, the second intermediate electrode 322C of the front-surface intermediate electrode 28C, the second intermediate electrode 322C of the back-surface intermediate electrode 28D, and the second back-surface electrode 312C. Therefore, the third front-surface electrode 303C, the second intermediate electrode 322C of the front-surface intermediate electrode 28C, the second intermediate electrode 322C of the back-surface intermediate electrode 28D, and the second back-surface electrode 312C are electrically connected to each other. The second vias 332D are electrically connected to the third front-surface electrode 303D, the second intermediate electrode 322D of the front-surface intermediate electrode 28C, the second intermediate electrode 322D of the back-surface intermediate electrode 28D, and the second back-surface electrode 312D. Therefore, the third front-surface electrode 303D, the second intermediate electrode 322D of the front-surface intermediate electrode 28C, the second intermediate electrode 322D of the back-surface intermediate electrode 28D, and the second back-surface electrode 312D are electrically connected to each other.

As shown in FIGS. 22 and 26, the third via 333 is electrically connected to the first front-surface electrode 304, the first intermediate electrode 321A of the front-surface intermediate electrode 28C, the first intermediate electrode 321A of the back-surface intermediate electrode 28D, and the third back-surface electrode 313. Therefore, the first front-surface electrode 304, the first intermediate electrode 321A of the front-surface intermediate electrode 28C, the first intermediate electrode 321A of the back-surface intermediate electrode 28D, and the third back-surface electrode 313 are electrically connected to each other.

The fourth via 334 is electrically connected to the sixth front-surface electrode 306, the fourth intermediate electrode 324 of the front-surface intermediate electrode 28C, the fourth intermediate electrode 324 of the back-surface intermediate electrode 28D, and the fourth back-surface electrode 314. Therefore, the sixth front-surface electrode 306, the fourth intermediate electrode 324 of the front-surface intermediate electrode 28C, the fourth intermediate electrode 324 of the back-surface intermediate electrode 28D, and the fourth back-surface electrode 314 are electrically connected to each other.

The fifth via 335 is electrically connected to the seventh front-surface electrode 307, the fifth intermediate electrode 325 of the front-surface intermediate electrode 28C, the fifth intermediate electrode 325 of the back-surface intermediate electrode 28D, and the fifth back-surface electrode 315. Therefore, the seventh front-surface electrode 307, the fifth intermediate electrode 325 of the front-surface intermediate electrode 28C, the fifth intermediate electrode 325 of the back-surface intermediate electrode 28D, and the fifth back-surface electrode 315 are electrically connected to each other.

### Configuration and Layout of Semiconductor Light-Emitting Element, Diodes, and Capacitors

As shown in FIGS. 24 and 25, the semiconductor light-emitting element 30 is mounted on the first front-surface electrode 301A. Specifically, the element back-surface electrode 35 (not shown in FIGS. 24 and 25; refer to FIG. 3) of the semiconductor light-emitting element 30 is bonded to the first front-surface electrode 301A by the conductive bonding material SD (not shown in FIGS. 24 and 25; refer to FIG. 3). Therefore, the element back-surface electrode 35 is electrically connected to the first front-surface electrode 301A. The semiconductor light-emitting element 30 is shifted toward the third substrate side surface 25 with respect to the center of the first front-surface electrode 301A in the Y-direction.

The semiconductor light-emitting element 30 of the fifth embodiment is identical to the semiconductor light-emitting element 30 of the second embodiment in size, shape, and configuration. In the semiconductor light-emitting element 30 of the fifth embodiment, the eight light emitters 33 are divided into pairs of light emitters 33, namely, the first to fourth light emitters 33A to 33D. The first to fourth light emitters 33A to 33D are divided in the same manner as the second embodiment. More specifically, the semiconductor light-emitting element 30 includes the first to fourth element front-surface electrodes 34A to 34D that correspond to the anodes of the first to fourth light emitters 33A to 33D, and the element back-surface electrode 35 that corresponds to the common cathode of the first to fourth light emitters 33A to 33D. The first element front-surface electrode 34A is an example of “first anode electrode for light emission”. The second element front-surface electrode 34B is an example of “second anode electrode for light emission”. The third element front-surface electrode 34C is an example of “third anode electrode for light emission”. The fourth element front-surface electrode 34D is an example of “fourth anode electrode for light emission”. The element back-surface electrode 35 is an example of “cathode electrode for light emission”.

The first element front-surface electrodes 34A, which correspond to the anode of the first light emitter 33A, are electrically connected to the second front-surface electrode 302A by the wires W5. The second element front-surface electrodes 34B, which correspond to the anode of the second light emitter 33B, are electrically connected to the second front-surface electrode 302B by the wires W5. The third element front-surface electrodes 34C, which correspond to the anode of the third light emitter 33C, are electrically connected to the second front-surface electrode 302C by the wires W5. The fourth element front-surface electrodes 34D, which correspond to the anode of the fourth light emitter 33D, are electrically connected to the second front-surface electrode 302D by the wires W5.

The first to fourth protection diodes 281 to 284 are separately mounted on the first front-surface electrode 301A and the second front-surface electrodes 302A to 302D. The first to fourth protection diodes 281 to 284 are arranged in a portion of the first front-surface electrode 301A that is located closer to the fourth substrate side surface 26 than the semiconductor light-emitting element 30 is.

As shown in FIG. 24, the first protection diode 281 extends over the first front-surface electrode 301A and the second front-surface electrode 302A in the Y-direction. The first protection diode 281 is arranged so that a first anode electrode 281A and a first cathode electrode 281B are spaced apart from each other in the Y-direction. The first protection diode 281 is located at a position that overlaps the third light emitter 33C as viewed in the Y-direction. In plan view, the first protection diode 281 is located closer to the first substrate side surface 23 than the wires W5 connected to the first light emitter 33A are. The first anode electrode 281A of the first protection diode 281 is bonded to the first front-surface electrode 301A by the conductive bonding material SD (not shown). Therefore, the first anode electrode 281A is electrically connected to the first front-surface electrode 301A. The first cathode electrode 281B of the first protection diode 281 is bonded to the second front-surface electrode 302A by the conductive bonding material SD (not shown). Therefore, the first cathode electrode 281B is electrically connected to the second front-surface electrode 302A. In this manner, the first protection diode 281 is connected in antiparallel to the first light emitter 33A. The first anode electrode 281A of the first protection diode 281 is an example of “first protection anode”. The first cathode electrode 281B is an example of “first protection cathode”.

As shown in FIG. 25, the second protection diode 282 extends over the first front-surface electrode 301A and the second front-surface electrode 302B in the Y-direction. The second protection diode 282 is arranged so that a second anode electrode 282A and a second cathode electrode 282B are spaced apart from each other in the Y-direction. The second protection diode 282 is located at a position that overlaps the fourth light emitter 33D as viewed in the Y-direction. In plan view, the second protection diode 282 is located closer to the second substrate side surface 24 than the wires W5 connected to the second light emitter 33B are. The second anode electrode 282A of the second protection diode 282 is bonded to the first front-surface electrode 301A by the conductive bonding material SD (not shown). Therefore, the second anode electrode 282A is electrically connected to the first front-surface electrode 301A. The second cathode electrode 282B of the second protection diode 282 is bonded to the second front-surface electrode 302B by the conductive bonding material SD (not shown). Therefore, the second cathode electrode 282B is electrically connected to the second front-surface electrode 302B. In this manner, the second protection diode 282 is connected in antiparallel to the second light emitter 33B. The second anode electrode 282A of the second protection diode 282 is an example of “second protection anode”. The second cathode electrode 282B is an example of “second protection cathode”.

As shown in FIG. 24, the third protection diode 283 extends over the first front-surface electrode 301A and the second front-surface electrode 302C in the X-direction. The third protection diode 283 is arranged so that a third anode electrode 283A and a third cathode electrode 283B are spaced apart from each other in the X-direction. The third protection diode 283 is located closer to the first substrate side surface 23 than the semiconductor light-emitting element 30 is in the X-direction. In plan view, the third protection diode 283 is located closer to the fourth substrate side surface 26 (refer to FIG. 21) than the wires W5 connected to the third light emitter 33C are. The third anode electrode 283A of the third protection diode 283 is bonded to the first front-surface electrode 301A by the conductive bonding material SD (not shown). Therefore, the third anode electrode 283A is electrically connected to the first front-surface electrode 301A. The third cathode electrode 283B of the third protection diode 283 is bonded to the second front-surface electrode 302C by the conductive bonding material SD (not shown). Therefore, the third cathode electrode 283B is electrically connected to the second front-surface electrode 302C. In this manner, the third protection diode 283 is connected in antiparallel to the third light emitter 33C. The third anode electrode 283A of the third protection diode 283 is an example of “third protection anode”. The third cathode electrode 283B is an example of “third protection cathode”.

As shown in FIG. 25, the fourth protection diode 284 extends over the first front-surface electrode 301A and the second front-surface electrode 302D in the X-direction. The fourth protection diode 284 is arranged so that a fourth anode electrode 284A and a fourth cathode electrode 284B are spaced apart from each other in the X-direction. The fourth protection diode 284 is located closer to the second substrate side surface 24 than the semiconductor light-emitting element 30 is in the X-direction. In plan view, the fourth protection diode 284 is located closer to the fourth substrate side surface 26 (refer to FIG. 21) than the wires W5 connected to the fourth light emitter 33D are. The fourth anode electrode 284A of the fourth protection diode 284 is bonded to the first front-surface electrode 301A by the conductive bonding material SD (not shown). Therefore, the fourth anode electrode 284A is electrically connected to the first front-surface electrode 301A. The fourth cathode electrode 284B of the fourth protection diode 284 is bonded to the second front-surface electrode 302D by the conductive bonding material SD (not shown). Therefore, the fourth cathode electrode 284B is electrically connected to the second front-surface electrode 302D. In this manner, the fourth protection diode 284 is connected in antiparallel to the third light emitter 33C. In addition, the first to fourth anode electrodes 281A to 284A are electrically connected to one another through the first front-surface electrode 301A. The fourth anode electrode 284A of the fourth protection diode 284 is an example of “fourth protection anode”. The fourth cathode electrode 284B is an example of “fourth protection cathode”.

The first to fourth reverse current protection diodes 261 to 264 are separately mounted on the second front-surface electrodes 302A to 302D and the third front-surface electrodes 303A to 303D. In plan view, the first to fourth reverse current protection diodes 261 to 264 are each spaced apart from the semiconductor light-emitting element 30. Multiple (in the fifth embodiment, three) first reverse current protection diodes 261, multiple (in the fifth embodiment, three) second reverse current protection diodes 262, multiple (in the fifth embodiment, three) third reverse current protection diodes 263, and multiple (in the fifth embodiment, three) fourth reverse current protection diodes 264 are provided.

As shown in FIG. 24, the first reverse current protection diodes 261 are located at a side of the first protection diode 281 opposite to the semiconductor light-emitting element 30 in the Y-direction. That is, the first protection diode 281 is arranged between the semiconductor light-emitting element 30 and the first reverse current protection diodes 261 in the Y-direction.

The first reverse current protection diodes 261 are connected in parallel to each other. The first reverse current protection diodes 261 each extend over the second front-surface electrode 302A and the third front-surface electrode 303A in the Y-direction. The first reverse current protection diodes 261 are located at the same position in the Y-direction and are spaced apart from each other in the X-direction. The dimension of the second front-surface electrode 302A in the X-direction is set to allow for the alignment of the first reverse current protection diodes 261 in the X-direction. Each of the first reverse current protection diodes 261 is arranged so that an anode electrode 261A and a cathode electrode 261B are spaced apart from each other in the Y-direction. The cathode electrode 261B of the first reverse current protection diode 261 is bonded to the second front-surface electrode 302A by the conductive bonding material SD (not shown), and the anode electrode 261A of the first reverse current protection diode 261 is bonded to the third front-surface electrode 303A by the conductive bonding material SD (not shown). Therefore, the cathode electrode 261B of the first reverse current protection diode 261 is electrically connected to the second front-surface electrode 302A, and the anode electrode 261A of the first reverse current protection diode 261 is electrically connected to the third front-surface electrode 303A. As a result, the cathode electrode 261B of the first reverse current protection diode 261 is electrically connected to the first cathode electrode 281B of the first protection diode 281 and the anode (first element electrode 34A) of the first light emitter 33A. The anode electrode 261A of the first reverse current protection diode 261 is an example of “the first anode of the first reverse current protection diode”. The cathode electrode 261B is an example of “the first cathode of the first reverse current protection diode”.

As shown in FIG. 25, the second reverse current protection diodes 262 are located at a side of the second protection diode 282 opposite to the semiconductor light-emitting element 30 in the Y-direction. That is, the second protection diode 282 is arranged between the semiconductor light-emitting element 30 and the second reverse current protection diodes 262 in the Y-direction.

The second reverse current protection diodes 262 are connected in parallel to each other. The second reverse current protection diodes 262 each extend over the second front-surface electrode 302B and the third front-surface electrode 303B in the Y-direction. The second reverse current protection diodes 262 are located at the same position in the Y-direction and are spaced apart from each other in the X-direction. The dimension of the second front-surface electrode 302B in the X-direction is set to allow for the alignment of the second reverse current protection diodes 262 in the X-direction. Each of the second reverse current protection diodes 262 is arranged so that an anode electrode 262A and a cathode electrode 262B are spaced apart from each other in the Y-direction. The cathode electrode 262B of the second reverse current protection diode 262 is bonded to the second front-surface electrode 302B by the conductive bonding material SD (not shown), and the anode electrode 262A of the second reverse current protection diode 262 is bonded to the third front-surface electrode 303B by the conductive bonding material SD (not shown). Therefore, the cathode electrode 262B of the second reverse current protection diode 262 is electrically connected to the second front-surface electrode 302B, and the anode electrode 262A of the second reverse current protection diode 262 is electrically connected to the third front-surface electrode 303B. As a result, the cathode electrode 262B of the second reverse current protection diode 262 is electrically connected to the second cathode electrode 282B of the second protection diode 282 and the anode (second element electrode 34B) of the second light emitter 33B. Furthermore, the second reverse current protection diodes 262 and the first reverse current protection diodes 261 (refer to FIG. 24) are symmetric with respect to the imaginary centerline VC. The anode electrode 262A of the second reverse current protection diode 262 is an example of “the second anode of the second reverse current protection diode”. The cathode electrode 262B is an example of “the second cathode of the second reverse current protection diode”.

As shown in FIG. 24, the third reverse current protection diodes 263 are located at a side of the third protection diode 283 opposite to the semiconductor light-emitting element 30 in the X-direction. That is, the third protection diode 283 is arranged between the semiconductor light-emitting element 30 and the third reverse current protection diodes 263 in the X-direction. The third reverse current protection diodes 263 are located closer to the fourth substrate side surface 26 than the semiconductor light-emitting element 30 is in the Y-direction. The third reverse current protection diodes 263 are located at a position that overlaps the third protection diode 283 as viewed in the X-direction. The third reverse current protection diodes 263 are located closer to both the first substrate side surface 23 and the third substrate side surface 25 than the first reverse current protection diodes 261 are.

The third reverse current protection diodes 263 are connected in parallel to each other. The third reverse current protection diodes 263 each extend over the second front-surface electrode 302C and the third front-surface electrode 303C in the Y-direction. The third reverse current protection diodes 263 are located at the same position in the Y-direction and are spaced apart from each other in the X-direction. Each of the third reverse current protection diodes 263 is arranged so that an anode electrode 263A and a cathode electrode 263B are spaced apart from each other in the Y-direction. The cathode electrode 263B of the third reverse current protection diode 263 is bonded to the second front-surface electrode 302C by the conductive bonding material SD (not shown), and the anode electrode 263A of the third reverse current protection diode 263 is bonded to the third front-surface electrode 303C by the conductive bonding material SD (not shown). Therefore, the cathode electrode 263B of the third reverse current protection diode 263 is electrically connected to the second front-surface electrode 302C, and the anode electrode 263A of the third reverse current protection diode 263 is electrically connected to the third front-surface electrode 303C. As a result, the cathode electrode 263B of the third reverse current protection diode 263 is electrically connected to the third cathode electrode 283B of the third protection diode 283 and the anode (third element electrode 34C) of the third light emitter 33C. The anode electrode 263A of the third reverse current protection diode 263 is an example of “the third anode of the third reverse current protection diode”. The cathode electrode 263B is an example of “the third cathode of the third reverse current protection diode”.

As shown in FIG. 25, the fourth reverse current protection diodes 264 are located at a side of the fourth protection diode 284 opposite to the semiconductor light-emitting element 30 in the X-direction. That is, the fourth protection diode 284 is arranged between the semiconductor light-emitting element 30 and the fourth reverse current protection diodes 264 in the X-direction. The fourth reverse current protection diodes 264 are located closer to the fourth substrate side surface 26 than the semiconductor light-emitting element 30 is in the Y-direction. The fourth reverse current protection diodes 264 are located at a position that overlaps the fourth protection diode 284 as viewed in the X-direction. The fourth reverse current protection diodes 264 are located closer to both the second substrate side surface 24 and the third substrate side surface 25 than the second reverse current protection diodes 262 are. The fourth reverse current protection diodes 264 and the third reverse current protection diodes 263 are symmetric with respect to the imaginary centerline VC.

The fourth reverse current protection diodes 264 are connected in parallel to each other. The fourth reverse current protection diodes 264 each extend over the second front-surface electrode 302D and the third front-surface electrode 303D in the Y-direction. The fourth reverse current protection diodes 264 are located at the same position in the Y-direction and are spaced apart from each other in the X-direction. Each of the fourth reverse current protection diodes 264 is arranged so that an anode electrode 264A and a cathode electrode 264B are spaced apart from each other in the Y-direction. The cathode electrode 264B of the fourth reverse current protection diode 264 is bonded to the second front-surface electrode 302D by the conductive bonding material SD (not shown), the anode electrode 264A of the fourth reverse current protection diode 264 is bonded to the third front-surface electrode 303D by the conductive bonding material SD (not shown). Therefore, the cathode electrode 264B of the fourth reverse current protection diode 264 is electrically connected to the second front-surface electrode 302D, and the anode electrode 264A of the fourth reverse current protection diode 264 is electrically connected to the third front-surface electrode 303D. As a result, the cathode electrode 264B of the fourth reverse current protection diode 264 is electrically connected to the fourth cathode electrode 284B of the fourth protection diode 284 and the anode (fourth element electrode 34D) of the fourth light emitter 33D. The anode electrode 264A of the fourth reverse current protection diode 264 is an example of “the fourth anode of the fourth reverse current protection diode”. The cathode electrode 264B is an example of “the fourth cathode of the fourth reverse current protection diode”.

As shown in FIGS. 24 and 25, the first to fourth capacitors 271 to 274 are separately mounted on the third front-surface electrodes 303A to 303D and the first front-surface electrode 301B. In plan view, the first to fourth capacitors 271 to 274 are each spaced apart from the semiconductor light-emitting element 30. Multiple (in the fifth embodiment, four) first capacitors 271, multiple (in the fifth embodiment, four) second capacitors 272, multiple (in the fifth embodiment, four) third capacitors 273, and multiple (in the fifth embodiment, four) fourth capacitors 274 are provided.

As shown in FIG. 24, the first capacitors 271 are located at a side of the first reverse current protection diodes 261 opposite to the first protection diode 281 (semiconductor light-emitting element 30) in the Y-direction. That is, the first reverse current protection diodes 261 are arranged between the first capacitors 271 and the first protection diode 281 (semiconductor light-emitting element 30) in the Y-direction.

The first capacitors 271 are connected in parallel to each other. The first capacitors 271 each extend over the third front-surface electrode 303A and the third wiring portion 301BC of the first front-surface electrode 301B in the Y-direction. The first capacitors 271 are located at the same position in the Y-direction and are spaced apart from each other in the X-direction. Each of the first capacitors 271 is arranged so that a first electrode 271A and a second electrode 271B are spaced apart from each other in the Y-direction. The first electrode 271A of the first capacitor 271 is bonded to the third front-surface electrode 303A by the conductive bonding material SD (not shown), and the second electrode 271B of the first capacitor 271 is bonded to the third wiring portion 301BC by the conductive bonding material SD (not shown). Therefore, the first electrode 271A of the first capacitor 271 is electrically connected to the third front-surface electrode 303A, and the second electrode 271B of the first capacitor 271 is electrically connected to the first front-surface electrode 301B. As a result, the first electrode 271A of the first capacitor 271 is electrically connected to the anode electrode 261A of the first reverse current protection diode 261.

As shown in FIG. 25, the second capacitors 272 are located at a side of the second reverse current protection diodes 262 opposite to the second protection diode 282 (semiconductor light-emitting element 30) in the Y-direction. That is, the second reverse current protection diodes 262 are arranged between the second capacitors 272 and the second protection diode 282 (semiconductor light-emitting element 30) in the Y-direction.

The second capacitors 272 are connected in parallel to each other. The second capacitors 272 each extend over the third front-surface electrode 303B and the third wiring portion 301BC of the first front-surface electrode 301B in the Y-direction. The second capacitors 272 are located at the same position in the Y-direction and are spaced apart from each other in the X-direction. Each of the second capacitors 272 is arranged so that a first electrode 272A and a second electrode 272B are spaced apart from each other in the Y-direction. The first electrode 272A of the second capacitor 272 is bonded to the third front-surface electrode 303B by the conductive bonding material SD (not shown), the second electrode 272B of the second capacitor 272 is bonded to the third wiring portion 301BC by the conductive bonding material SD (not shown). Therefore, the first electrode 272A of the second capacitor 272 is electrically connected to the third front-surface electrode 303B, and the second electrode 272B of the second capacitor 272 is electrically connected to the first front-surface electrode 301B. As a result, the first electrode 272A of the second capacitor 272 is electrically connected to the anode electrode 262A of the second reverse current protection diode 262.

As shown in FIG. 24, the third capacitors 273 are located at a side of the third reverse current protection diodes 263 opposite to the third substrate side surface 25 (semiconductor light-emitting element 30) in the Y-direction. As viewed in the Y-direction, the third capacitors 273 are located at a position that overlaps the third reverse current protection diodes 263. The third capacitors 273 are located closer to the first substrate side surface 23 than the first capacitors 271 are in the X-direction.

The third capacitors 273 are connected in parallel to each other. The third capacitors 273 each extend over the third front-surface electrode 303C and the first wiring portion 301BA of the first front-surface electrode 301B in the Y-direction. The third capacitors 273 are located at the same position in the Y-direction and are spaced apart from each other in the X-direction. Each of the third capacitors 273 is arranged so that a first electrode 273A and a second electrode 273B are spaced apart from each other in the Y-direction. The first electrode 273A of the third capacitor 273 is bonded to the third front-surface electrode 303C by the conductive bonding material SD (not shown), and the second electrode 273B of the third capacitor 273 is bonded to the first wiring portion 301BA by the conductive bonding material SD (not shown). Therefore, the first electrode 273A of the third capacitor 273 is electrically connected to the third front-surface electrode 303C, and the second electrode 273B of the third capacitor 273 is electrically connected to the first front-surface electrode 301B. As a result, the first electrode 273A of the third capacitor 273 is electrically connected to the anode electrode 263A of the third reverse current protection diode 263.

As shown in FIG. 25, the fourth capacitors 274 are located at a side of the fourth reverse current protection diodes 264 opposite to the third substrate side surface 25 (semiconductor light-emitting element 30) in the Y-direction. As viewed in the Y-direction, the fourth capacitors 274 are located at a position that overlaps the fourth reverse current protection diodes 264. The fourth capacitors 274 are located closer to the second substrate side surface 24 than the second capacitors 272 are in the X-direction.

The fourth capacitors 274 are connected in parallel to each other. The fourth capacitors 274 each extend over the third front-surface electrode 303D and the second wiring portion 301BB of the first front-surface electrode 301B in the Y-direction. The fourth capacitors 274 are located at the same position in the Y-direction and are spaced apart from each other in the X-direction. Each of the fourth capacitor 274 is arranged so that a first electrode 274A and a second electrode 274B are spaced apart from each other in the Y-direction. The first electrode 274A of the fourth capacitor 274 is bonded to the third front-surface electrode 303D by the conductive bonding material SD (not shown), and the second electrode 274B of the fourth capacitor 274 is bonded to the second wiring portion 301BB by the conductive bonding material SD (not shown). Therefore, the first electrode 274A of the fourth capacitor 274 is electrically connected to the third front-surface electrode 303D, and the second electrode 274B of the fourth capacitor 274 is electrically connected to the first front-surface electrode 301B. As a result, the first electrode 274A of the fourth capacitor 274 is electrically connected to the anode electrode 264A of the fourth reverse current protection diode 264. In this manner, the second electrodes 271B to 274B of the first to fourth capacitors 271 to 274 are electrically connected to one another through the first front-surface electrode 301B.

As shown in FIGS. 24 and 25, the fourth capacitors 274 and the third capacitors 273 are symmetric with respect to the imaginary centerline VC. The third capacitors 273 and the fourth capacitor 274 are located closer to the third substrate side surface 25 than the first capacitors 271 and the second capacitors 272 are in the Y-direction.

As shown in FIG. 21, the switching element for light emission 291 is located closer to the fourth substrate side surface 26 than the semiconductor light-emitting element 30, the first to fourth reverse current protection diodes 261A to 261D, the first to fourth capacitors 271 to 274, and the first to fourth protection diodes 281 to 284 are. In other words, the first to fourth reverse current protection diodes 261A to 261D, the first to fourth capacitors 271 to 274, and the first to fourth protection diodes 281 to 284 are arranged between the semiconductor light-emitting element 30 and the switching element for light emission 291 in the Y-direction.

As shown in FIG. 26, for example, the switching element for light emission 291 includes a lateral transistor. The switching element for light emission 291 has a shape of a rectangular flat plate having a thickness-wise direction parallel to the Z-direction. In the example shown in FIG. 26, the switching element for light emission 291 is rectangular in plan view, with long sides extending in the X-direction and short sides extending in the Y-direction. The switching element for light emission 291 includes a second element front surface 291A and a second element back surface (not shown) facing away from each other in the Z-direction. The second element front surface 291A faces the same direction as the substrate front surface 21, and the second element back surface faces the same direction as the substrate back surface 22 (refer to FIG. 3). The second element back surface faces the substrate front surface 21. A drain electrode 291D, a source electrode 291S, and a gate electrode 291G are formed in the second element back surface.

The switching element for light emission 291 includes a single drain electrode 291D arranged in a central part of switching element for light emission 291 in the X-direction. The drain electrode 291D is rectangular in plan view, with long sides extending in the Y-direction and short sides extending in the X-direction. Multiple (in the fifth embodiment, two) source electrodes 291S are provided. The source electrodes 291S are separately disposed at opposite sides of the drain electrode 291D in the X-direction. The source electrodes 291S are each rectangular in plan view, with long sides extending in the Y-direction and short sides extending in the X-direction. One of the source electrodes 291S that is located closer to the second substrate side surface 24 is smaller in the Y-direction than the other one of the source electrodes 291S that is located closer to the first substrate side surface 23. The gate electrode 291G is located closer to the second substrate side surface 24 than the drain electrode 291D is. As viewed in the Y-direction, the gate electrode 291G is located at a position that overlaps one of the source electrode 291S that is located relatively close to the second substrate side surface 24. Further, the gate electrode 291G is located closer to the third substrate side surface 25 than that source electrode 291S is in the Y-direction. The gate electrode 291G is rectangular in plan view.

The switching element for light emission 291 is mounted on the first front-surface electrode 301B, the fourth front-surface electrode 304, and the fifth front-surface electrode 305. More specifically, the drain electrode 291D of the switching element for light emission 291 is bonded to the fourth front-surface electrode 304B by the conductive bonding material SD (not shown). The source electrodes 291S are bonded to the first front-surface electrode 301B by the conductive bonding material SD (not shown). The gate electrode 291G is bonded to the fifth front-surface electrode 305 by the conductive bonding material SD (not shown). Thus, the drain electrode 291D is electrically connected to the fourth front-surface electrode 304, the source electrodes 291S are electrically connected to the first front-surface electrode 301B, and the gate electrode 291G is electrically connected to the fifth front-surface electrode 305.

As shown in FIG. 21, the gate driver IC 292 and the capacitor 293 are both located closer to the fourth substrate side surface 26 than the semiconductor light-emitting element 30, the first to fourth reverse current protection diodes 261A to 261D, the first to fourth capacitors 271 to 274, and the first to fourth protection diodes 281 to 284 are. As viewed in the X-direction, the gate driver IC 292 and the capacitor 293 are both located at a position that overlaps the switching element for light emission 291. The gate driver IC 292 and the capacitor 293 are both located closer to the second substrate side surface 24 than the switching element for light emission 291 is in the X-direction. The capacitor 293 is located closer to the second substrate side surface 24 than the gate driver IC 292 is in the X-direction. The capacitor 293 is adjacent to the gate driver IC 292 in the X-direction.

As shown in FIG. 26, the gate driver IC 292 has a shape of a rectangular flat plate having a thickness-wise direction parallel to the Z-direction. The gate driver IC 292 is rectangular in plan view, with long sides extending in the Y-direction and short sides extending in the X-direction. The gate driver IC 292 includes a chip front surface 292A and a chip back surface (not shown) facing away from each other in the Z-direction. The chip front surface 292A faces the same direction as the substrate front surface 21, and the chip back surface faces the same direction as the substrate back surface 22. The chip back surface faces the substrate front surface 21. Multiple (in the fifth embodiment, six) terminals 292B are included in the chip back surface. The terminals 292B are aligned with and spaced apart from one another in the X-direction and the Y-direction.

The gate driver IC 292 is mounted on each of the first front-surface electrode 301B and the fifth to seventh front-surface electrodes 305 to 307. More specifically, the terminals 292B of the gate driver IC 292 are bonded to the first front-surface electrode 301B and the fifth to seventh front-surface electrodes 305 to 307 by the conductive bonding material SD (not shown). Therefore, the gate driver IC 292 is electrically connected to each of the first front-surface electrode 301B and the fifth to seventh front-surface electrodes 305 to 307. In this manner, the gate driver IC 292 is electrically connected to the gate electrode 291G of the switching element for light emission 291 through the fifth front-surface electrode 305. Also, the gate driver IC 292 is electrically connected to the source electrodes 291S of the switching element for light emission 291 through the first front-surface electrode 301B.

The sixth front-surface electrode 306 is electrically connected to the control power supply 807 (refer to FIG. 20). Accordingly, the gate driver IC 292 receives the electric power supplied from the control power supply 807 through the sixth front-surface electrode 306. The seventh front-surface electrode 307 is electrically connected to the pulse generator 806 (refer to FIG. 20). Accordingly, the gate driver IC 292 receives the pulse signal of the pulse generator 806 through the seventh front-surface electrode 307.

The capacitor 293 is arranged so that a first electrode 293A and a second electrode 293B are aligned with and spaced apart from each other in the Y-direction. The capacitor 293 is mounted on the first front-surface electrode 301B and the sixth front-surface electrode 306. More specifically, the first electrode 293A of the capacitor 293 is bonded to the sixth front-surface electrode 306 by the conductive bonding material SD (not shown). The second electrode 293B of the capacitor 293 is bonded to the first front-surface electrode 301B by the conductive bonding material SD (not shown). Thus, the first electrode 293A of the capacitor 293 is electrically connected to the sixth front-surface electrode 306, and the second electrode 293B is electrically connected to the first front-surface electrode 301B.

### Advantages

The semiconductor light-emitting device 10 of the fifth embodiment has the following advantages.

(5-1) The semiconductor light-emitting device 10 includes the semiconductor light-emitting element 30, the first to fourth reverse current protection diodes 261 to 264, the first to fourth protection diodes 281 to 284, the switching element for light emission 291, and the first to fourth capacitors 271 to 274. The semiconductor light-emitting element 30 includes the first to fourth light emitters 33A to 33D, the first to fourth element front-surface electrodes 34A to 34D separately electrically connected to the first to fourth light emitters 33A to 33D, and the element back-surface electrode 35 electrically connected to the first to fourth light emitters 33A to 33D. The first to fourth reverse current protection diodes 261 to 264 include the cathode electrodes 261B separately electrically connected to the first to fourth element front-surface electrodes 34A to 34D, and the anode electrodes 261A separately electrically connected to the first to fourth charging switching elements 808A to 808D. The first to fourth protection diodes 281 to 284 includes the first cathode electrodes 281B separately electrically connected to the cathode electrodes 261B of the first to fourth reverse current protection diodes 261 and 264 and the first to fourth element front-surface electrodes 34A to 34D, and the first anode electrodes 281A electrically connected to the element back-surface electrode 35. The switching element for light emission 291 includes the drain electrode 291D electrically connected to the element back-surface electrode 35, and the source electrode 291S. The first to fourth capacitors 271 to 274 are separately electrically connected to the anode electrodes 261A of the first to fourth reverse current protection diodes 261 to 264 and the source electrode 291S of the switching element for light emission 291.

With this configuration, the first to fourth protection diodes 281 to 284 suppress an excessive reverse bias caused by a resonant current from being applied to the first to fourth light emitters 33A to 33D. As a result of such suppression, a peak light output of the semiconductor light-emitting element 30 may be increased.

In addition, the first to fourth reverse current protection diodes 261 to 264 restrict backflow of resonant currents flowing through the first to fourth protection diodes 281 to 284. Therefore, the resonant currents flowing through the first to fourth protection diodes 281 to 284 have limited effects on the other light emitters 33. This avoids interference between the first to fourth light emitters 33A to 33D of the semiconductor light-emitting element 30.

(5-2) The semiconductor light-emitting element 30 includes the element back-surface electrode 35 that serves as the common cathode electrode of the first to fourth light emitters 33A to 33D.

This configuration simplifies the electrical connection between the semiconductor light-emitting element 30 and the switching element for light emission 291.

(5-3) The first protection diode 281 is connected in antiparallel to the first light emitter 33A, the second protection diode 282 is connected in antiparallel to the second light emitter 33B, the third protection diode 283 is connected in antiparallel to the third light emitter 33C, and the fourth protection diode 284 is connected in antiparallel to the fourth light emitter 33D.

With this configuration, the first to fourth protection diodes 281 to 284 suppress an excessive reverse bias caused by a resonant current from being applied to the first to fourth light emitters 33A to 33D. As a result of such suppression, a peak light output of the semiconductor light-emitting element 30 may be increased.

(5-4) The first to fourth anode electrodes 281A to 284A of the first to fourth protection diodes 281 are electrically connected to the element back-surface electrode 35, which serves as the common cathode electrode of the semiconductor light-emitting element 30. This configuration simplifies the electrical connection between the semiconductor light-emitting element 30 and each of the first to fourth protection diodes 281 to 284.

(5-5) The semiconductor light-emitting device 10 includes the gate driver IC 292 configured to control the switching element for light emission 291.

With this configuration, the conductive path between the gate driver IC 292 and the switching element for light emission 291 is shorter as compared to a configuration in which the gate driver IC 292 is arranged outside the semiconductor light-emitting device 10. This reduces effect of noise on the gate electrode 291G of the switching element for light emission 291 caused by the conductive path.

(5-6) Multiple first to fourth capacitors 271 to 274 are provided. The first capacitors 271 are connected in parallel to each other. The second capacitors 272 are connected in parallel to each other. The third capacitors 273 are connected in parallel to each other. The fourth capacitors 274 are connected in parallel to each other.

With this configuration, the first capacitors 271 are connected in parallel to each other, so that the total inductance of the first capacitors 271 is less than the inductance of each of the first capacitors 271. Further, the total inductance of the second capacitors 272 is less than the inductance of each of the second capacitors 272. The total inductance of the third capacitors 273 is less than the inductance of each of the third capacitors 273. The total inductance of the fourth capacitors 274 is less than the inductance of each of the fourth capacitor 274.

(5-7) In plan view, the first back-surface electrode 311B has a greater area than each of the second back-surface electrodes 312A to 312D, the third back-surface electrode 313, the fourth back-surface electrode 314, or the fifth back-surface electrode 315.

With this configuration, the first back-surface electrode 311B has a relatively large heat capacity. Therefore, the heat of the semiconductor light-emitting element 30 is readily transferred to the first back-surface electrode 311B. In addition, when the semiconductor light-emitting device 10 is mounted on the circuit board 900, the first back-surface electrode 311B and the circuit board 900 are bonded to each other over a relatively large area. so that the heat of the semiconductor light-emitting element 30 is readily transferred through the first back-surface electrode 311B to the circuit board 900. Accordingly, the temperature of the semiconductor light-emitting element 30 will not become excessively high.

(5-8) In plan view, the area of the first back-surface electrode 311B is greater than the combined total area of the second back-surface electrode 312A to 312D, the third back-surface electrode 313, the fourth back-surface electrode 314, and the fifth back-surface electrode 315.

This configuration increases the heat capacity of the first back-surface electrode 311B, thereby further facilitating transfer of heat from the semiconductor light-emitting element 30 to the first back-surface electrode 311B. In addition, when the semiconductor light-emitting device 10 is mounted on the circuit board 900, the first back-surface electrode 311B and the circuit board 900 are bonded to each other over a relatively large area. so that the heat of the semiconductor light-emitting element 30 is more readily transferred through the first back-surface electrode 311B to the circuit board 900. Accordingly, the temperature of the semiconductor light-emitting element 30 will not become excessively high.

(5-9) The first vias 331A are located at a position that overlaps the semiconductor light-emitting element 30 in plan view.

With this configuration, the heat of the semiconductor light-emitting element 30 is readily transferred to the first intermediate electrode 321A and the first back-surface electrode 311A. Accordingly, the temperature of the semiconductor light-emitting element 30 will not become excessively high.

The fifth embodiment describes an example of the configuration of the semiconductor light-emitting device 10 in which the eight light emitters 33 of the semiconductor light-emitting element 30 are driven as the first to fourth light emitters 33A to 33D. However, a common switching element for light emission and a common reverse current protection diode may be provided to drive the eight light emitters 33 of the semiconductor light-emitting element 30 as the first light emitter 33A and the second light emitter 33B, in the same manner as the first embodiment. Such a semiconductor light-emitting device 10 also obtains the same advantages as the semiconductor light-emitting device 10 of the fifth embodiment.

### Sixth Embodiment

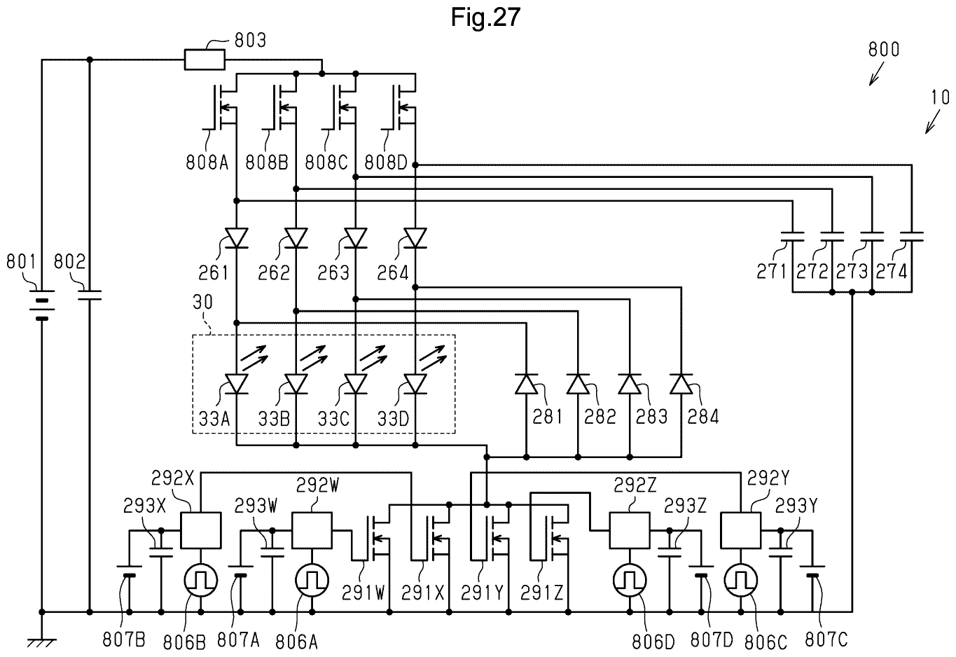

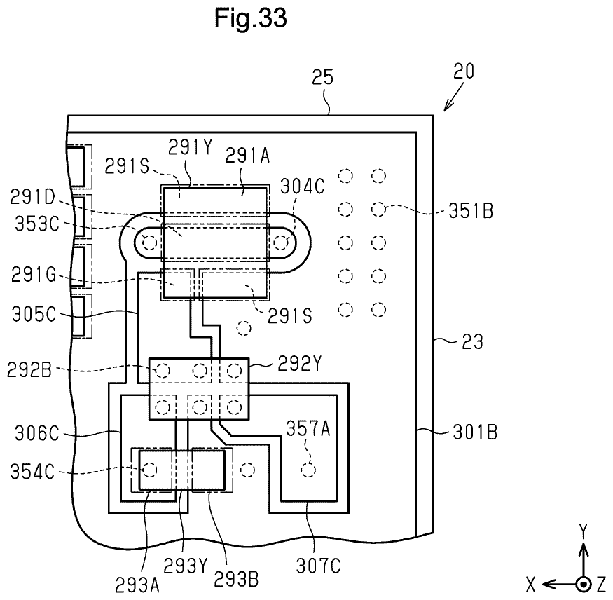

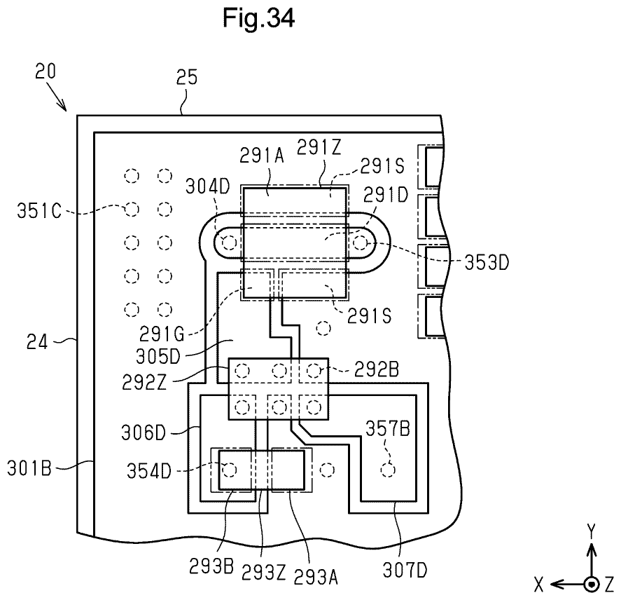

A semiconductor light-emitting device 10 in accordance with a sixth embodiment will now be described with reference to FIGS. 27 to 34.

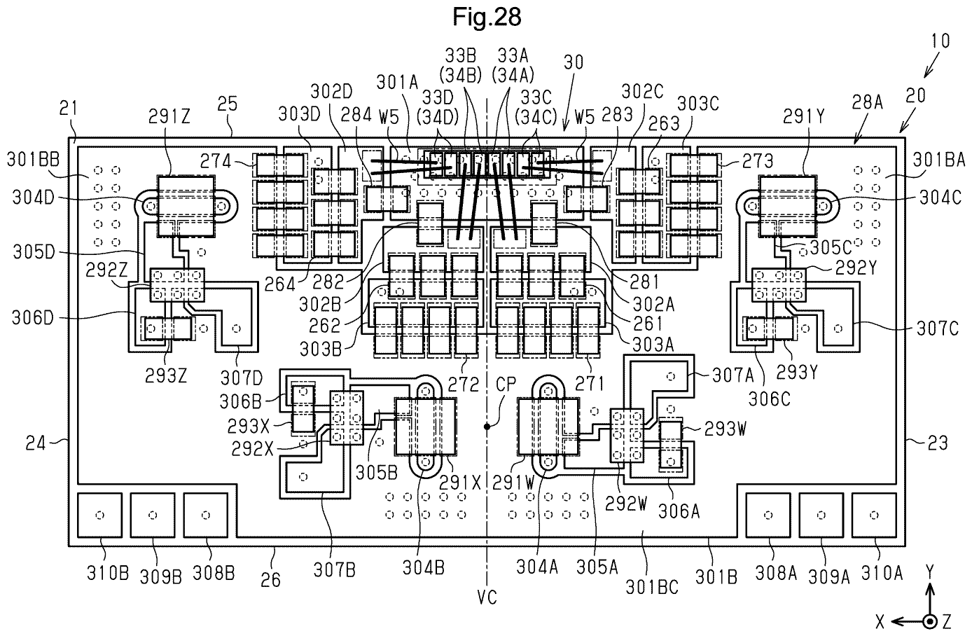

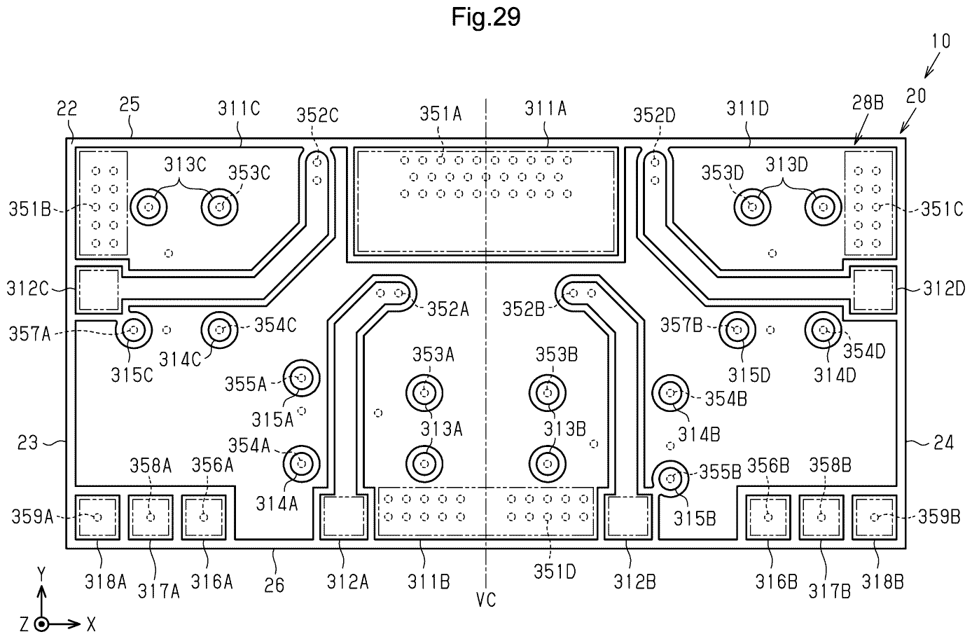

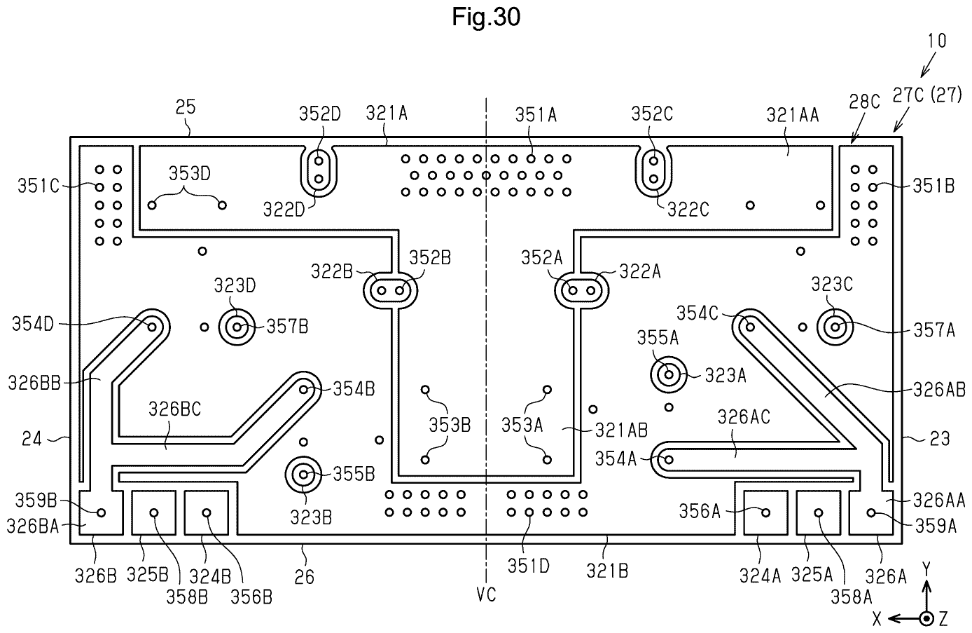

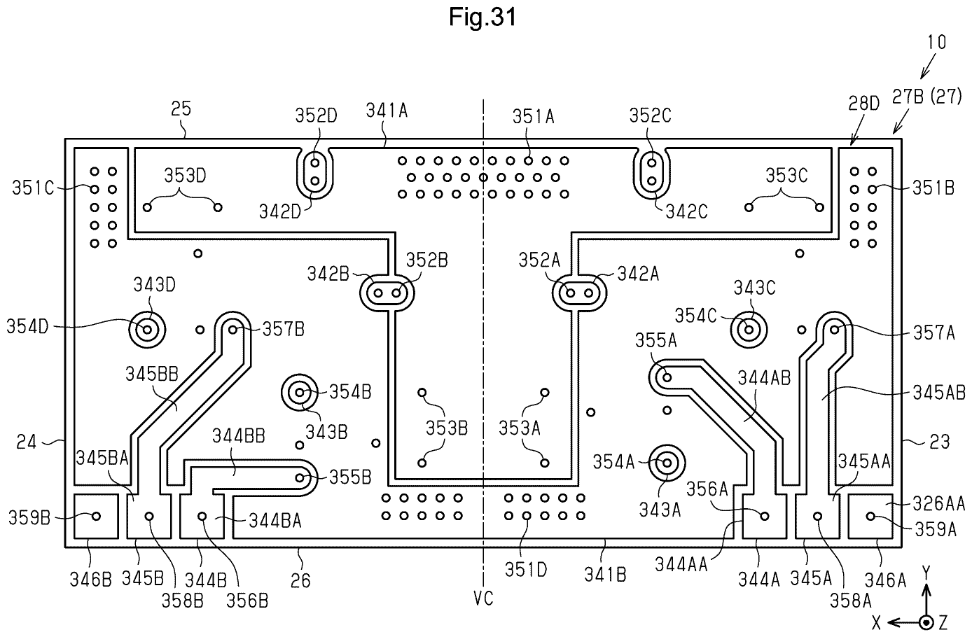

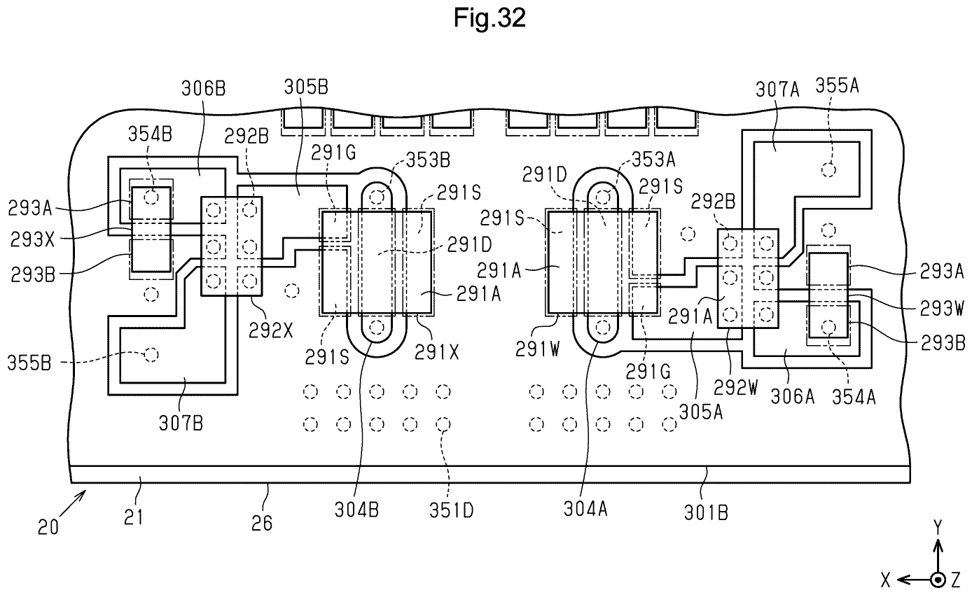

FIG. 27 shows a schematic circuit diagram of a light-emitting system 800 including the semiconductor light-emitting device 10 of the sixth embodiment. FIG. 28 shows a schematic planar structure of the semiconductor light-emitting device 10 in accordance with the sixth embodiment. FIG. 29 shows a schematic bottom structure of the semiconductor light-emitting device 10 shown in FIG. 28. FIG. 30 shows a schematic planar structure of the front-surface intermediate electrode 28C of the semiconductor light-emitting device 10 shown in FIG. 28. FIG. 31 shows a schematic planar structure of the back-surface intermediate electrode 28D of the semiconductor light-emitting device 10 shown in FIG. 28. FIGS. 32 to 34 show a schematic planar structure of the semiconductor light-emitting device 10 shown in FIG. 28 enlarging the switching element for light emission 291.

### Circuitry of Light-Emitting System

As shown in FIG. 27, the light-emitting system 800 of the sixth embodiment mainly differs from the light-emitting system 800 of the fifth embodiment in the quantities of switching elements for light emission, gate driver ICs, and capacitors. Hereinafter, the description will focus on the differences from the fifth embodiment. The same reference characters are given to those components that are the same as the corresponding components of the fifth embodiment, and such components will not be described in detail.

The semiconductor light-emitting device 10 includes first to fourth switching elements for light emission 291W to 291Z serving as multiple (in the sixth embodiment, four) switching elements for light emission, first to fourth gate driver ICs 292W to 292Z serving as multiple (in the sixth embodiment, four) gate driver ICs, and first to fourth capacitors 293W to 293Z serving as multiple (in the sixth embodiment, four) capacitors. The quantities of switching elements for light emission and gate driver ICs are determined, for example, in accordance with the number of light emitters 33 of the semiconductor light-emitting element 30. The number of capacitors electrically connected to the gate driver ICs is determined in accordance with the number of gate driver ICs.

The semiconductor light-emitting device 10 includes pulse generators 806A to 806D and control power supplies 807A to 807D that correspond to the first to fourth gate driver ICs 292W to 292Z. The quantities of pulse generators and control power supplies are determined, for example, in accordance with the number of gate driver ICs. The pulse generators 806A to 806D and the control power supplies 807A to 807D are arranged outside the semiconductor light-emitting device 10.

The first to fourth switching elements for light emission 291W to 291Z each include a drain electrode electrically connected to the element back-surface electrode 35, which serves as the common cathode electrode of the semiconductor light-emitting element 30. Therefore, the drain electrodes of the switching elements for light emission 291 are electrically connected to the first to fourth anode electrodes 281A to 284A of the first to fourth protection diodes 281 to 284. The first to fourth switching elements for light emission 291W to 291Z each include a source electrode electrically connected to ground wiring. Therefore, the source electrodes of the first to fourth switching elements for light emission 291W to 291Z are electrically connected to the second electrodes of the first to fourth capacitors 271 to 274.

The first to fourth gate driver ICs 292W to 292Z are separately electrically connected to the gate electrodes of the first to fourth switching elements for light emission 291W to 291Z. Specifically, the first gate driver IC 292W is configured to control the first switching element for light emission 291W, the second gate driver IC 292X is configured to control the second switching element for light emission 291X, the third gate driver IC 292Y is configured to control the third switching element for light emission 291Y, and the fourth gate driver IC 292Z is configured to control the fourth switching element for light emission 291Z.

The first to fourth capacitors 293W to 293Z are separately electrically connected to the first to fourth gate driver ICs 292W to 292Z. The first to fourth gate driver ICs 292W to 292Z and the first to fourth capacitors 293W to 293Z are electrically connected to the ground wiring.

The pulse generators 806A to 806D are separately electrically connected to the first to fourth gate driver ICs 292W to 292Z. Specifically, the pulse generator 806A is configured to output a pulse signal for controlling the first switching element for light emission 291W to the first gate driver IC 292W. The pulse generator 806B is configured to output a pulse signal for controlling the second switching element for light emission 291X to the second gate driver IC 292X. The pulse generator 806C is configured to output a pulse signal for controlling the third switching element for light emission 291Y to the third gate driver IC 292Y. The pulse generator 806D is configured to output a pulse signal for controlling the fourth switching element for light emission 291Z to the fourth gate driver IC 292Z.

The control power supplies 807A to 807D are separately electrically connected to the first to fourth gate driver ICs 292W to 292Z. The control power supplies 807A to 807D are separately electrically connected to the first to fourth capacitors 293W to 293Z. The control power supply 807A is configured to supply electric power to the first gate driver IC 292W. The control power supply 807B is configured to supply electric power to the second gate driver IC 292X. The control power supply 807C is configured to supply electric power to the third gate driver IC 292Y. The control power supply 807D is configured to supply electric power to the fourth gate driver IC 292Z.

### Overall Configuration of Semiconductor Light-Emitting Device

The overall configuration of the semiconductor light-emitting device 10 will now be described with reference to FIGS. 28 to 34. The same reference characters are given to those components that are the same as the corresponding components of the fifth embodiment, and such components may not be described in detail.

As shown in FIG. 28, the semiconductor light-emitting device 10 includes the first to fourth reverse current protection diodes 261 to 264, the first to fourth capacitors 271 to 274, the first to fourth protection diodes 281 to 284, the first to fourth switching elements for light emission 291W to 291Z, the first to fourth gate driver ICs 292W to 292Z, and the first to fourth capacitors 293W to 293Z that are arranged on the substrate front surface 21. The first to fourth reverse current protection diodes 261 to 264, the first to fourth capacitors 271 to 274, the first to fourth protection diodes 281 to 284, the first to fourth switching elements for light emission 291W to 291Z, the first to fourth gate driver ICs 292W to 292Z, and the first to fourth capacitors 293W to 293Z are mounted on the front-surface electrodes 28A.

The semiconductor light-emitting device 10 of the sixth embodiment includes the first to fourth drive circuits 40, 50, 110, and 120. The first drive circuit 40 includes the first capacitor 271 and the first switching element for light emission 291W. The second drive circuit 50 includes the second capacitor 272 and the second switching element for light emission 291X. The third drive circuit 110 includes the third capacitor 273 and the third switching element for light emission 291Y. The fourth drive circuit 120 includes the fourth capacitor 274 and the fourth switching element for light emission 291Z.

Due to the change in the quantities of switching elements for light emission, gate driver ICs, and capacitors electrically connected to the gate driver ICs, the front-surface electrodes 28A include different quantities of the fourth to seventh front-surface electrodes. More specifically, the front-surface electrodes 28A include fourth front-surface electrodes 304A to 304D, fifth front-surface electrodes 305A to 305D, sixth front-surface electrodes 306A to 306D, and seventh front-surface electrodes 307A to 307D in accordance with the first to fourth switching elements for light emission 291W to 291Z, the first to fourth gate driver ICs 292W to 292Z, and the first to fourth capacitors 293W to 293Z. The configurations of the first front-surface electrode 301A, the second front-surface electrodes 302A to 302D, and the third front-surface electrodes 303A to 303D are the same as those of the fifth embodiment. The first front-surface electrode 301B includes openings in which the fourth to seventh front-surface electrodes are arranged in accordance with the change in the quantities of the fourth to seventh front-surface electrodes.

The fourth front-surface electrodes 304A and 304B, the fifth front-surface electrodes 305A and 305B, the sixth front-surface electrodes 306A and 306B, and the seventh front-surface electrodes 307A and 307B are disposed in the openings formed in the third wiring portion 301BC of the first front-surface electrode 301B.

The shapes and layout of the fourth front-surface electrode 304B, the fifth front-surface electrode 305B, the sixth front-surface electrode 306B, and the seventh front-surface electrode 307B are the same as those of the fourth to seventh front-surface electrodes 304 to 307 of the fifth embodiment.

In an example, the fourth front-surface electrode 304A, the fifth front-surface electrode 305A, the sixth front-surface electrode 306A, and the seventh front-surface electrode 307A and the fourth front-surface electrode 304B, the fifth front-surface electrode 305B, the sixth front-surface electrode 306B, and the seventh front-surface electrode 307B are symmetric with respect to point CP on the imaginary centerline VC. The point CP is, for example, an intersection of the imaginary centerline VC and a straight line that extends in the X-direction through the center of the switching element for light emission 291 in the Y-direction.

The fourth front-surface electrode 304C, the fifth front-surface electrode 305C, the sixth front-surface electrode 306C, and the seventh front-surface electrode 307C are disposed in the openings formed in the first wiring portion 301BA of the first front-surface electrode 301B. In an example, the shapes and layout of the fourth front-surface electrode 304C, the fifth front-surface electrode 305C, the sixth front-surface electrode 306C, and the seventh front-surface electrode 307C may be obtained by rotating the fourth front-surface electrode 304B, the fifth front-surface electrode 305B, the sixth front-surface electrode 306B, and the seventh front-surface electrode 307B counterclockwise by ninety degrees.

The fourth front-surface electrode 304D, the fifth front-surface electrode 305D, the sixth front-surface electrode 306D, and the seventh front-surface electrode 307D are disposed in the openings formed in the second wiring portion 301BB of the first front-surface electrode 301B. In an example, the shapes and layout of the fourth front-surface electrode 304D, the fifth front-surface electrode 305D, the sixth front-surface electrode 306D, and the seventh front-surface electrode 307D may be obtained by rotating the fourth front-surface electrode 304A, the fifth front-surface electrode 305A, the sixth front-surface electrode 306A, and the seventh front-surface electrode 307A clockwise by ninety degrees.

The fourth front-surface electrodes 304C and 304D, the fifth front-surface electrodes 305C and 305D, the sixth front-surface electrodes 306C and 306D, and the seventh front-surface electrodes 307C and 307D are located closer to the third substrate side surface 25 than the fourth front-surface electrodes 304A and 304B, the fifth front-surface electrodes 305A and 305B, the sixth front-surface electrodes 306A and 306B, and the seventh front-surface electrodes 307A and 307B are in the Y-direction.

The front-surface electrodes 28A further include eighth front-surface electrodes 308A and 308B, ninth front-surface electrodes 309A and 309B, and tenth front-surface electrodes 310A and 310B.

The eighth front-surface electrodes 308A and 308B, the ninth front-surface electrodes 309A and 309B, and the tenth front-surface electrodes 310A and 310B are adjacent to the fourth substrate side surface 26 in the Y-direction. In an example, the eighth front-surface electrodes 308A and 308B, the ninth front-surface electrodes 309A and 309B, and the tenth front-surface electrodes 310A and 310B are each square in plan view.

The eighth front-surface electrode 308A, the ninth front-surface electrode 309A, and the tenth front-surface electrode 310A are located closer to the first substrate side surface 23 than the fourth front-surface electrode 304A, the fifth front-surface electrode 305A, the sixth front-surface electrode 306A, and the seventh front-surface electrode 307A are. The eighth front-surface electrode 308A, the ninth front-surface electrode 309A, and the tenth front-surface electrode 310A are located at the same position in the Y-direction and are spaced apart from each other in the X-direction. The eighth front-surface electrode 308A, the ninth front-surface electrode 309A, and the tenth front-surface electrode 310A are arranged in this order from the imaginary centerline VC toward the first substrate side surface 23.

The eighth front-surface electrode 308B, the ninth front-surface electrode 309B, and the tenth front-surface electrode 310B are located closer to the second substrate side surface 24 than the fourth front-surface electrode 304B, the fifth front-surface electrode 305B, the sixth front-surface electrode 306B, and the seventh front-surface electrode 307B are. The eighth front-surface electrode 308B, the ninth front-surface electrode 309B, and the tenth front-surface electrode 310B are located at the same position in the Y-direction and are spaced apart from each other in the X-direction. The eighth front-surface electrode 308B, the ninth front-surface electrode 309B, and the tenth front-surface electrode 310B are arranged in this order from the imaginary centerline VC toward the second substrate side surface 24.

As shown in FIG. 29, the back-surface electrodes 28B include first back-surface electrodes 311A to 311D, second back-surface electrodes 312A to 312D, third back-surface electrodes 313A to 313D, fourth back-surface electrodes 314A to 314D, fifth back-surface electrodes 315A to 315D, sixth back-surface electrodes 316A and 316B, seventh back-surface electrodes 317A and 317B, and eighth back-surface electrodes 318A and 318B. The first back-surface electrodes 311A to 311D, the second back-surface electrodes 312A to 312D, the third back-surface electrodes 313A to 313D, the fourth back-surface electrodes 314A to 314D, the fifth back-surface electrodes 315A to 315D, the sixth back-surface electrodes 316A and 316B, the seventh back-surface electrodes 317A and 317B, and the eighth back-surface electrodes 318A and 318B are spaced apart from one another.

The configuration and layout of the first back-surface electrode 311A are the same as those of the first back-surface electrode 311A of the fifth embodiment.

In plan view, the first back-surface electrode 311B has a greater area than each of the second back-surface electrodes 312A to 312D, the third back-surface electrodes 313A to 313D, the fourth back-surface electrodes 314A to 314D, the fifth back-surface electrodes 315A to 315D, the sixth back-surface electrodes 316A and 316B, the seventh back-surface electrodes 317A and 317B, or the eighth back-surface electrodes 318A and 318B. The area of the first back-surface electrode 311B is greater than the combined total area of the second back-surface electrodes 312A to 312D, the third back-surface electrodes 313A to 313D, the fourth back-surface electrodes 314A to 314D, the fifth back-surface electrodes 315A to 315D, the sixth back-surface electrodes 316A and 316B, the seventh back-surface electrodes 317A and 317B, and the eighth back-surface electrodes 318A and 318B. In an example, the first back-surface electrode 311B is formed across most of the substrate back surface 22. In other words, the first back-surface electrode 311B is formed in the substrate back surface 22 except for regions in which the first back-surface electrode 311A, the second back-surface electrodes 312A to 312D, the third back-surface electrodes 313A to 313D, the fourth back-surface electrodes 314A to 314D, the fifth back-surface electrodes 315A to 315D, the sixth back-surface electrodes 316A and 316B, the seventh back-surface electrodes 317A and 317B, and the eighth back-surface electrodes 318A and 318B are arranged.

The first back-surface electrode 311C and the first back-surface electrode 311D are separately disposed at opposite sides of the first back-surface electrode 311A in the X-direction. The first back-surface electrode 311C and the first back-surface electrode 311D are both electrically connected to the first front-surface electrode 301B (refer to FIG. 28). The first back-surface electrode 311C is located at a position that overlaps the first wiring portion 301BA (refer to FIG. 28) of the first front-surface electrode 301B in plan view. The first back-surface electrode 311D is located at a position that overlaps the second wiring portion 301BB (refer to FIG. 28) of the first front-surface electrode 301B in plan view.

The second back-surface electrode 312A is electrically connected to the third front-surface electrode 303A. The second back-surface electrode 312B is electrically connected to the third front-surface electrode 303B. The second back-surface electrode 312C is electrically connected to the third front-surface electrode 303C. The second back-surface electrode 312D is electrically connected to the third front-surface electrode 303D.

The second back-surface electrodes 312A to 312D are separately electrically connected to the sources of the first to fourth charging switching elements 808A to 808D (refer to FIG. 27). More specifically, the second back-surface electrode 312A is electrically connected to the source of the first charging switching element 808A, the second back-surface electrode 312B is electrically connected to the source of the second charging switching element 808B, the second back-surface electrode 312C is electrically connected to the source of the third charging switching element 808C, and the second back-surface electrode 312D is electrically connected to the source of the fourth charging switching element 808D.

The second back-surface electrodes 312A and 312B each extend from a position of the substrate back surface 22 that is adjacent to the fourth substrate side surface 26 to a position of the substrate back surface 22 that is adjacent to the first back-surface electrode 311A in the Y-direction. The second back-surface electrodes 312A and 312B are separately disposed at opposite sides of the imaginary centerline VC in the X-direction. The second back-surface electrode 312A is located closer to the first substrate side surface 23 than the imaginary centerline VC is. The second back-surface electrode 312B is located closer to the second substrate side surface 24 than the imaginary centerline VC is. In an example, the second back-surface electrode 312A and the second back-surface electrode 312B are symmetric with respect to the imaginary centerline VC.

The second back-surface electrode 312C is located closer to the first substrate side surface 23 than the first back-surface electrode 311A and the second back-surface electrode 312A are in the X-direction. The second back-surface electrode 312C extends from a position of the substrate back surface 22 that is adjacent to the first substrate side surface 23 to a position of the substrate back surface 22 that is adjacent to the first back-surface electrode 311A in the X-direction. In plan view, the second back-surface electrode 312C surrounds the first back-surface electrode 311C from the sides of the second substrate side surface 24 and the fourth substrate side surface 26. The second back-surface electrode 312D is located closer to the second substrate side surface 24 than the first back-surface electrode 311A and the second back-surface electrode 312B are in the X-direction. The second back-surface electrode 312D extends from a position of the substrate back surface 22 that is adjacent to the second substrate side surface 24 to a position of the substrate back surface 22 that is adjacent to the first back-surface electrode 311A in the X-direction. In plan view, the second back-surface electrode 312D surrounds the first back-surface electrode 311D from the sides of the first substrate side surface 23 and the fourth substrate side surface 26. In an example, the second back-surface electrode 312C and the second back-surface electrode 312D are symmetric with respect to the imaginary centerline VC.

The third back-surface electrode 313A is electrically connected to the fourth front-surface electrode 304A (refer to FIG. 23). The third back-surface electrode 313B is electrically connected to the fourth front-surface electrode 304B (refer to FIG. 23). The third back-surface electrode 313C is electrically connected to the fourth front-surface electrode 304C (refer to FIG. 23). The third back-surface electrode 313D is electrically connected to the fourth front-surface electrode 304D (refer to FIG. 23).

Multiple (in the sixth embodiment, two) third back-surface electrodes 313A, multiple (in the sixth embodiment, two) third back-surface electrodes 313B, multiple (in the sixth embodiment, two) third back-surface electrodes 313C, and multiple (in the sixth embodiment, two) third back-surface electrodes 313D are provided. The third back-surface electrodes 313A to 313D are each circular in plan view.

The third back-surface electrodes 313A to 313D are separately disposed at opposite sides of the imaginary centerline VC in the X-direction. The third back-surface electrodes 313A and 313C are located closer to the first substrate side surface 23 than the imaginary centerline VC is. The third back-surface electrodes 313B and 313D are located closer to the second substrate side surface 24 than the imaginary centerline VC is. The third back-surface electrodes 313C are located closer to the first substrate side surface 23 than the third back-surface electrodes 313A are. The third back-surface electrodes 313D are located closer to the second substrate side surface 24 than the third back-surface electrodes 313B are. The third back-surface electrodes 313C and 313D are located closer to the third substrate side surface 25 than the third back-surface electrodes 313A and 313B are in the Y-direction. As viewed in the X-direction, the third back-surface electrodes 313C and 313D are located at a position that overlaps the first back-surface electrode 311A.

The third back-surface electrodes 313A are located at the same position in the X-direction and are spaced apart from each other in the Y-direction. The third back-surface electrodes 313B are located at the same position in the X-direction and are spaced apart from each other in the Y-direction. The third back-surface electrodes 313C are located at the same position in the Y-direction and are spaced apart from each other in the X-direction. The third back-surface electrodes 313D are located at the same position in the Y-direction and are spaced apart from each other in the X-direction.

The fourth back-surface electrode 314A is electrically connected to the sixth front-surface electrode 306A (refer to FIG. 23). The fourth back-surface electrode 314B is electrically connected to the sixth front-surface electrode 306B (refer to FIG. 23). The fourth back-surface electrode 314C is electrically connected to the sixth front-surface electrode 306C (refer to FIG. 23). The fourth back-surface electrode 314D is electrically connected to the sixth front-surface electrode 306D (refer to FIG. 23). The fourth back-surface electrodes 314A to 314D are each circular in plan view. In an example, the fourth back-surface electrodes 314A to 314D are identical to the third back-surface electrodes 313A to 313D in size.

The fifth back-surface electrode 315A is electrically connected to the seventh front-surface electrode 307A (refer to FIG. 23). The fifth back-surface electrode 315B is electrically connected to the seventh front-surface electrode 307B (refer to FIG. 23). The fifth back-surface electrode 315C is electrically connected to the seventh front-surface electrode 307C (refer to FIG. 23). The fifth back-surface electrode 315D is electrically connected to the seventh front-surface electrode 307D (refer to FIG. 23). The fifth back-surface electrodes 315A to 315D are each circular in plan view. In an example, the fifth back-surface electrodes 315A to 315D are identical to the fourth back-surface electrodes 314A to 314D in size.

The fourth back-surface electrode 314A and the fifth back-surface electrode 315A are located closer to the first substrate side surface 23 than the third back-surface electrodes 313A are in the X-direction. The fourth back-surface electrode 314A and the fifth back-surface electrode 315A are located at the same position in the X-direction and are spaced apart from each other in the Y-direction. The fourth back-surface electrode 314A is located closer to the fourth substrate side surface 26 than the fifth back-surface electrode 315A is.

The fourth back-surface electrode 314B and the fifth back-surface electrode 315B are located closer to the second substrate side surface 24 than the third back-surface electrodes 313B are in the X-direction. The fourth back-surface electrode 314B and the fifth back-surface electrode 315B are located at the same position in the X-direction and are spaced apart from each other in the Y-direction. The fourth back-surface electrode 314B is located closer to the third substrate side surface 25 than the fifth back-surface electrode 315B is.

The fourth back-surface electrodes 314C and 314D and the fifth back-surface electrodes 315C and 315D are located closer to the third substrate side surface 25 than the fourth back-surface electrodes 314A and 314B and the fifth back-surface electrodes 315A and 315B are in the Y-direction. The fourth back-surface electrodes 314C and 314D and the fifth back-surface electrodes 315C and 315D are located closer to the fourth substrate side surface 26 than the third back-surface electrodes 313A and 313B are in the Y-direction. The fourth back-surface electrode 314C and the fifth back-surface electrode 315C are located closer to the first substrate side surface 23 than the fourth back-surface electrode 314A and the fifth back-surface electrode 315A are in the X-direction. The fifth back-surface electrode 315C is located closer to the first substrate side surface 23 than the fourth back-surface electrode 314C is. The fourth back-surface electrode 314D and the fifth back-surface electrode 315D are located closer to the second substrate side surface 24 than the fourth back-surface electrode 314B and the fifth back-surface electrode 315B are in the X-direction. The fourth back-surface electrode 314D is located closer to the second substrate side surface 24 than the fifth back-surface electrode 315D is.

The sixth back-surface electrodes 316A and 316B, the seventh back-surface electrodes 317A and 317B, and the eighth back-surface electrodes 318A and 318B are adjacent to the fourth substrate side surface 26 in the Y-direction. In an example, the sixth back-surface electrodes 316A and 316B, the seventh back-surface electrodes 317A and 317B, and the eighth back-surface electrodes 318A and 318B are each square in plan view.

The sixth back-surface electrode 316A, the seventh back-surface electrode 317A, the eighth back-surface electrode 318A are located closer to the first substrate side surface 23 than the fourth back-surface electrode 314A and the fifth back-surface electrode 315A are. The sixth back-surface electrode 316A, the seventh back-surface electrode 317A, and the eighth back-surface electrode 318A are located at the same position in the Y-direction and are spaced apart from each other in the X-direction. The sixth back-surface electrode 316A, the seventh back-surface electrode 317A, and the eighth back-surface electrode 318A are arranged in this order from the imaginary centerline VC toward the first substrate side surface 23.

The sixth back-surface electrode 316B, the seventh back-surface electrode 317B, and the eighth back-surface electrode 318B are located closer to the second substrate side surface 24 than the fourth back-surface electrode 314B and the fifth back-surface electrode 315B are. The sixth back-surface electrode 316B, the seventh back-surface electrode 317B, and the eighth back-surface electrode 318B are located at the same position in the Y-direction and are spaced apart from each other in the X-direction. The sixth back-surface electrode 316B, the seventh back-surface electrode 317B, and the eighth back-surface electrode 318B are arranged in that order from the imaginary centerline VC toward the second substrate side surface 24.

As shown in FIG. 30, the front-surface intermediate electrodes 28C include first intermediate electrodes 321A and 321B, second intermediate electrodes 322A to 322D, third intermediate electrodes 323A to 323D, fourth intermediate electrodes 324A and 324B, fifth intermediate electrodes 325A and 325B, and sixth intermediate electrodes 326A and 326B. The first intermediate electrodes 321A and 321B, the second intermediate electrodes 322A to 322D, the third intermediate electrodes 323A to 323D, the fourth intermediate electrodes 324A and 324B, the fifth intermediate electrodes 325A and 325B, and the sixth intermediate electrodes 326A and 326B are spaced apart from one another.

The first intermediate electrodes 321A and 321B are formed in most of the base-member front surface of the intermediate base member 27C. The first intermediate electrodes 321A and 321B include recesses and openings that are arranged to avoid the second intermediate electrodes 322A to 322D, the third intermediate electrodes 323A to 323D, the fourth intermediate electrodes 324A and 324B, the fifth intermediate electrodes 325A and 325B, and the sixth intermediate electrodes 326A and 326B.

The first intermediate electrode 321A electrically connects the first front-surface electrode 301A and the fourth front-surface electrodes 304A and 304B (refer to FIG. 28). The first intermediate electrode 321A is substantially T-shaped in plan view. The first intermediate electrode 321A includes a wide section 321AA and a narrow section 321AB. In an example, the wide section 321AA and the narrow section 321AB are integrated with each other. In plan view, the wide section 321AA is disposed at a position of the base-member front surface of the intermediate base member 27C that is adjacent to the third substrate side surface 25. The wide section 321AA is formed in most of the base-member front surface of the intermediate base member 27C in the X-direction. The narrow section 321AB extends from the center of the wide section 321AA in the X-direction toward the fourth substrate side surface 26. The narrow section 321AB includes a distal end that is located closer to the fourth substrate side surface 26 than the center of the intermediate base member 27C in the Y-direction is. The distal end is spaced apart from the fourth substrate side surface 26 in the Y-direction. The first intermediate electrode 321A extends from the first front-surface electrode 301A to the third front-surface electrodes 303A and 303B in the Y-direction. The first intermediate electrode 321A is symmetric with respect to the imaginary centerline VC.

The first intermediate electrode 321B is electrically connected to the first front-surface electrode 301B (refer to FIG. 28) and the first back-surface electrodes 311B to 311D (refer to FIG. 29). The first intermediate electrode 321B surrounds the first intermediate electrode 321A from the sides of the first substrate side surface 23, the second substrate side surface 24, and the fourth substrate side surface 26.

The second intermediate electrode 322A is electrically connected to both the third front-surface electrode 303A (refer to FIG. 28) and the second back-surface electrode 312A (refer to FIG. 29). The second intermediate electrode 322B is electrically connected to both the third front-surface electrode 303B (refer to FIG. 28) and the second back-surface electrode 312B (refer to FIG. 29). The second intermediate electrode 322C is electrically connected to both the third front-surface electrode 303C (refer to FIG. 28) and the second back-surface electrode 312C (refer to FIG. 29). The second intermediate electrode 322D is electrically connected to both the third front-surface electrode 303D (refer to FIG. 28) and the second back-surface electrode 312D (refer to FIG. 29).

The second intermediate electrodes 322A to 322D are located closer to the third substrate side surface 25 than the center of the intermediate base member 27C is in the Y-direction. The second intermediate electrode 322A is arranged between the first intermediate electrode 321B and an end of the narrow section 321AB of the first intermediate electrode 321A that is located relatively close to the first substrate side surface 23 in the X-direction. The second intermediate electrode 322B is arranged between the first intermediate electrode 321B and an end of the narrow section 321AB of the first intermediate electrode 321A that is located relatively close to the second substrate side surface 24 in the X-direction. The second intermediate electrode 322C is disposed in an opening that is formed in the wide section 321AA of the first intermediate electrode 321A. The opening is located closer to the first substrate side surface 23 than the narrow section 321AB is. The second intermediate electrode 322D is disposed in an opening that is formed in the wide section 321AA. The opening is located closer to the second substrate side surface 24 than the narrow section 321AB is. The second intermediate electrodes 322A and 322B are each elliptic in plan view, with major axis extending in the X-direction and minor axis extending in the Y-direction. The second intermediate electrodes 322C and 322D are each elliptic in plan view, with major axis extending in the Y-direction and minor axis extending in the X-direction.

The third intermediate electrode 323A is electrically connected to both the seventh front-surface electrode 307A (refer to FIG. 28) and the fifth back-surface electrode 315A (refer to FIG. 29). The third intermediate electrode 323B is electrically connected to both the seventh front-surface electrode 307B (refer to FIG. 28) and the fifth back-surface electrode 315B (refer to FIG. 29). The third intermediate electrode 323C is electrically connected to both the seventh front-surface electrode 307C (refer to FIG. 28) and the fifth back-surface electrode 315C (refer to FIG. 29). The third intermediate electrode 323D is electrically connected to both the seventh front-surface electrode 307D (refer to FIG. 28) and the fifth back-surface electrode 315D (refer to FIG. 29).

The third intermediate electrodes 323A to 323D are each circular in plan view. The third intermediate electrodes 323A and 323C are located closer to the first substrate side surface 23 than the narrow section 321AB of the first intermediate electrode 321A is in the X-direction. The third intermediate electrode 323C is located closer to the first substrate side surface 23 than the third intermediate electrode 323A is. The third intermediate electrodes 323B and 323D are located closer to the second substrate side surface 24 than the narrow section 321AB is in the X-direction. The third intermediate electrode 323D is located closer to the second substrate side surface 24 than the third intermediate electrode 323B is.

The fourth intermediate electrode 324A is electrically connected to both the eighth front-surface electrode 308A (refer to FIG. 28) and the sixth back-surface electrode 316A (refer to FIG. 29). The fourth intermediate electrode 324B is electrically connected to both the eighth front-surface electrode 308B (refer to FIG. 28) and the sixth back-surface electrode 316B (refer to FIG. 29). The fifth intermediate electrode 325A is electrically connected to both the ninth front-surface electrode 309A (refer to FIG. 28) and the seventh back-surface electrode 317A (refer to FIG. 29). The fifth intermediate electrode 325B is electrically connected to both the ninth front-surface electrode 309B (refer to FIG. 28) and the seventh back-surface electrode 317B (refer to FIG. 29).

In plan view, the fourth intermediate electrodes 324A and 324B and the fifth intermediate electrodes 325A and 325B are each located at a position of the intermediate base member 27C that is adjacent to the fourth substrate side surface 26. The fourth intermediate electrodes 324A and 324B and the fifth intermediate electrodes 325A and 325B are separately disposed at two opposite ends of the intermediate base member 27C in the X-direction. The fourth intermediate electrode 324A and the fifth intermediate electrode 325A are located at an end of the intermediate base member 27C that is located relatively close to the first substrate side surface 23. The fourth intermediate electrode 324B and the fifth intermediate electrode 325B are located at an end of the base member 27 that is located relatively close to the second substrate side surface 24. The fourth intermediate electrode 324A and the fifth intermediate electrode 325A are located at the same position in the Y-direction and are spaced apart from each other in the X-direction. The fourth intermediate electrode 324B and the fifth intermediate electrode 325B are located at the same position in the Y-direction and are spaced apart from each other in the X-direction. The fifth intermediate electrode 325A is located closer to the first substrate side surface 23 than the fourth intermediate electrode 324A is. The fifth intermediate electrode 325B is located closer to the second substrate side surface 24 than the fourth intermediate electrode 324B is.

The sixth intermediate electrode 326A is electrically connected to each of the sixth front-surface electrodes 306A and 306C, the tenth front-surface electrode 310A (refer to FIG. 28), the fourth back-surface electrodes 314A and 314C, and the eighth back-surface electrode 318A (refer to FIG. 29). The sixth intermediate electrode 326B is electrically connected to each of the sixth front-surface electrodes 306B and 306D, the tenth front-surface electrode 310B (refer to FIG. 28), the fourth back-surface electrodes 314B and 314D, and the eighth back-surface electrode 318B (refer to FIG. 29).

The sixth intermediate electrode 326A includes a base section 326AA, a first extension 326AB, and a second extension 326AC. The base section 326AA is adjacent to the fifth intermediate electrode 325A. The base section 326AA is located at a side of the fifth intermediate electrode 325A opposite to the fourth intermediate electrode 324A in the X-direction. The first extension 326AB extends from the base section 326AA. The second extension 326AC branches from the first extension 326AB. The base section 326AA is square in plan view. The first extension 326AB extends toward the sixth front-surface electrode 306C (fourth back-surface electrode 314C). The sixth intermediate electrode 326A is electrically connected to both the sixth front-surface electrode 306C and the fourth back-surface electrode 314C at the distal end of the first extension 326AB. The second extension 326AC extends toward the sixth front-surface electrode 306A (fourth back-surface electrode 314A). The sixth intermediate electrode 326A is electrically connected to both the sixth front-surface electrode 306A and the fourth back-surface electrode 314A at the distal end of the second extension 326AC. The sixth intermediate electrode 326A is electrically connected to the tenth front-surface electrode 310A (eighth back-surface electrode 318A) at the base section 326AA.

The sixth intermediate electrode 326B includes a base section 326BA, a first extension 326BB, and a second extension 326BC. The base section 326BA is adjacent to the fifth intermediate electrode 325B. The base section 326BA is located at a side of the fifth intermediate electrode 325B opposite to the fourth intermediate electrode 324B in the X-direction. The first extension 326BB extends from the base section 326BA. The second extension 326BC branches from the first extension 326BB. The base section 326BA is square in plan view. The first extension 326BB extends toward the sixth front-surface electrode 306D (fourth back-surface electrode 314D). The sixth intermediate electrode 326B is electrically connected to both the sixth front-surface electrode 306D and the fourth back-surface electrode 314D at the distal end of the first extension 326BB. The second extension 326BC extends toward the sixth front-surface electrode 306B (fourth back-surface electrode 314B). The sixth intermediate electrode 326B is electrically connected to both the sixth front-surface electrode 306B and the fourth back-surface electrode 314B at the distal end of the second extension 326BC. The sixth intermediate electrode 326B is electrically connected to the tenth front-surface electrode 310B (eighth back-surface electrode 318B) at the base section 326BA.

As shown in FIG. 31, the back-surface intermediate electrodes 28D include first intermediate electrodes 341A and 341B, second intermediate electrodes 342A to 342D, third intermediate electrodes 343A to 343D, fourth intermediate electrodes 344A and 344B, fifth intermediate electrodes 345A and 345B, and sixth intermediate electrodes 346A and 346B. The first intermediate electrodes 341A and 341B, the second intermediate electrodes 342A to 342D, the third intermediate electrodes 343A to 343D, the fourth intermediate electrodes 344A and 344B, the fifth intermediate electrodes 345A and 345B, and the sixth intermediate electrodes 346A and 346B are spaced apart from one another.

The first intermediate electrodes 341A and 341B are formed in most of the base-member front surface of the back-surface base member 27B. The first intermediate electrodes 341A and 341B include recesses and openings that are arranged to avoid the second intermediate electrodes 342A to 342D, the third intermediate electrodes 343A to 343D, the fourth intermediate electrodes 344A and 344B, the fifth intermediate electrodes 345A and 345B, and the sixth intermediate electrodes 346A and 346B.

The first intermediate electrode 341A electrically connects the first front-surface electrode 301A and the fourth front-surface electrodes 304A to 304D (refer to FIG. 28). In an example, in plan view, the first intermediate electrode 341A has the same shape as the first intermediate electrode 321A of the front-surface intermediate electrode 28C (refer to FIG. 30).

The first intermediate electrode 341B is electrically connected to the first front-surface electrode 301B (refer to FIG. 28) and the first back-surface electrodes 311B to 311D (refer to FIG. 29). The first intermediate electrode 341B is electrically connected to the first intermediate electrode 321B. The first intermediate electrode 341B surrounds the first intermediate electrode 341A from the sides of the first substrate side surface 23, the second substrate side surface 24, and the fourth substrate side surface 26.

The second intermediate electrode 342A is electrically connected to both the third front-surface electrode 303A (refer to FIG. 28) and the second back-surface electrode 312A (refer to FIG. 29). The second intermediate electrode 342B is electrically connected to both the third front-surface electrode 303B (refer to FIG. 28) and the second back-surface electrode 312B (refer to FIG. 29). The second intermediate electrode 342C is electrically connected to both the third front-surface electrode 303C (refer to FIG. 28) and the second back-surface electrode 312C (refer to FIG. 29). The second intermediate electrode 342D is electrically connected to both the third front-surface electrode 303D (refer to FIG. 28) and the second back-surface electrode 312D (refer to FIG. 29). The second intermediate electrodes 342A to 342D are separately electrically connected to the second intermediate electrodes 322A to 322D (refer to FIG. 30). The shapes, sizes, and layout of the second intermediate electrodes 342A to 342D are identical to those of the second intermediate electrodes 322A to 322D.

The third intermediate electrode 343A is electrically connected to both the sixth front-surface electrode 306A (refer to FIG. 28) and the fourth back-surface electrode 314A (refer to FIG. 29). The third intermediate electrode 343B is electrically connected to both the sixth front-surface electrode 306B (refer to FIG. 28) and the fourth back-surface electrode 314B (refer to FIG. 29). The third intermediate electrode 343C is electrically connected to both the sixth front-surface electrode 306C (refer to FIG. 28) and the fourth back-surface electrode 314C (refer to FIG. 29). The third intermediate electrode 343D is electrically connected to both the sixth front-surface electrode 306D (refer to FIG. 28) and the fourth back-surface electrode 314D (refer to FIG. 29). The third intermediate electrodes 343A and 343C are electrically connected to the sixth intermediate electrode 326A. The third intermediate electrodes 343B and 343D are electrically connected to the sixth intermediate electrode 326B.

The third intermediate electrodes 343A to 343D are each circular in plan view. The third intermediate electrodes 343A and 343C are located closer to the first substrate side surface 23 than the imaginary centerline VC is in the X-direction. The third intermediate electrode 343C is located closer to the first substrate side surface 23 than the third intermediate electrode 343A is. The third intermediate electrodes 343B and 343D are located closer to the second substrate side surface 24 than the imaginary centerline VC is in the X-direction. The third intermediate electrode 343D is located closer to the second substrate side surface 24 than the third intermediate electrode 343B is.

The fourth intermediate electrode 344A is electrically connected to each of the seventh front-surface electrode 307A, the eighth front-surface electrode 308A (refer to FIG. 28), the fifth back-surface electrode 315A, and the sixth back-surface electrode 316A (refer to FIG. 29). The fourth intermediate electrode 344B is electrically connected to each of the seventh front-surface electrode 307B, the eighth front-surface electrode 308B (refer to FIG. 28), the fifth back-surface electrode 315B, and the sixth back-surface electrode 316B (refer to FIG. 29). The fourth intermediate electrode 344A is electrically connected to the third intermediate electrode 323A and the fourth intermediate electrode 324A (refer to FIG. 30). The fourth intermediate electrode 344B is electrically connected to the third intermediate electrode 323B and the fourth intermediate electrode 324B (refer to FIG. 30).

The fourth intermediate electrode 344A includes a base section 344AA, and an extension 344AB extending from the base section 344AA. The base section 344AA is square in plan view. The fourth intermediate electrode 344A is electrically connected to the eighth front-surface electrode 308A (sixth back-surface electrode 316A) at the base section 344AA. The extension 344AB extends toward the seventh front-surface electrode 307A (fifth back-surface electrode 315A). The fourth intermediate electrode 344A is electrically connected to the seventh front-surface electrode 307A (fifth back-surface electrode 315A) at the distal end of the extension 344AB.

The fourth intermediate electrode 344B includes a base section 344BA, and an extension 344BB extending from the base section 344BA. The base section 344BA is square in plan view. The fourth intermediate electrode 344B is electrically connected to the eighth front-surface electrode 308B (sixth back-surface electrode 316B) at the base section 344BA. The extension 344BB extends toward the seventh front-surface electrode 307B (fifth back-surface electrode 315B). The fourth intermediate electrode 344B is electrically connected to the seventh front-surface electrode 307B (fifth back-surface electrode 315B) at the distal end of the extension 344BB.

The fifth intermediate electrode 345A is electrically connected to each of the seventh front-surface electrode 307C, the ninth front-surface electrode 309A (refer to FIG. 28), the fifth back-surface electrode 315C, and the seventh back-surface electrode 317A (refer to FIG. 29). The fifth intermediate electrode 345B is electrically connected to each of the seventh front-surface electrode 307D, the ninth front-surface electrode 309B (refer to FIG. 28), the fifth back-surface electrode 315D, and the seventh back-surface electrode 317B (refer to FIG. 29). The fifth intermediate electrode 345A is electrically connected to the third intermediate electrode 323C and the fifth intermediate electrode 325A (refer to FIG. 30). The fifth intermediate electrode 345B is electrically connected to the third intermediate electrode 323D and the fifth intermediate electrode 325B (refer to FIG. 30).

The fifth intermediate electrode 345A includes a base section 345AA, and an extension 345AB extending from the base section 345AA. The base section 345AA is square in plan view. The fifth intermediate electrode 345A is electrically connected to the ninth front-surface electrode 309A (seventh back-surface electrode 317A) at the base section 345AA. The extension 345AB extends toward the seventh front-surface electrode 307C (fifth back-surface electrode 315C). The fifth intermediate electrode 345A is electrically connected to the seventh front-surface electrode 307C (fifth back-surface electrode 315C) at the distal end of the extension 345AB.

The fifth intermediate electrode 345B includes a base section 345BA, and an extension 345BB extending from the base section 345BA. The base section 345BA is square in plan view. The fifth intermediate electrode 345B is electrically connected to the ninth front-surface electrode 309B (seventh back-surface electrode 317B) at the base section 345BA. The extension 345BB extends toward the seventh front-surface electrode 307D (fifth back-surface electrode 315D). The fifth intermediate electrode 345B is electrically connected to the seventh front-surface electrode 307D (fifth back-surface electrode 315D) at the distal end of the extension 345BB.

The sixth intermediate electrode 346A is electrically connected to both the tenth front-surface electrode 310A (refer to FIG. 28) and the eighth back-surface electrode 318A (refer to FIG. 29). The sixth intermediate electrode 346B is electrically connected to both the tenth front-surface electrode 310B (refer to FIG. 28) and the eighth back-surface electrode 318B (refer to FIG. 29). The sixth intermediate electrode 346A is electrically connected to the sixth intermediate electrode 326A (refer to FIG. 30). The sixth intermediate electrode 346B is electrically connected to the sixth intermediate electrode 326B (refer to FIG. 30). The sixth intermediate electrodes 346A and 346B are each square in plan view.

The base sections 344AA and 344BA of the fourth intermediate electrodes 344A and 344B, the base sections 345AA and 345BA of the fifth intermediate electrodes 345A and 345B, and the sixth intermediate electrodes 346A and 346B are each located at a position of the back-surface base member 27B that is adjacent to the fourth substrate side surface 26 in the Y-direction.

The base section 344AA of the fourth intermediate electrode 344A, the base section 345AA of the fifth intermediate electrode 345A, and the sixth intermediate electrode 346A are arranged at an end of the back-surface base member 27B that is relatively close to the first substrate side surface 23 in the X-direction. The base sections 344AA and 345AA and the sixth intermediate electrode 346A are located at the same position in the Y-direction and are spaced apart from each other in the X-direction. The base sections 344AA and 345AA, and the sixth intermediate electrode 346A are arranged in this order from the imaginary centerline VC toward the first substrate side surface 23.

The base section 344BA of the fourth intermediate electrode 344B, the base section 345BA of the fifth intermediate electrode 345B, and the sixth intermediate electrode 346B are arranged at an end of the back-surface base member 27B that is located relatively close to the second substrate side surface 24 in the X-direction. The base sections 344BA and 345BA and the sixth intermediate electrode 346B are located at the same position in the Y-direction and are spaced apart from each other in the X-direction. The base sections 344BA and 345BA and the sixth intermediate electrode 346B are arranged in this order from the imaginary centerline VC toward the first substrate side surface 23.

As shown in FIGS. 29 to 34, the substrate 20 includes first vias 351A to 351D, second vias 352A to 352D, third vias 353A to 353D, fourth vias 354A to 354D, fifth vias 355A and 355B, sixth vias 356A and 356B, seventh vias 357A and 357B, eighth vias 358A and 358B, and ninth vias 359A and 359B. The first vias 351A to 351D, the second vias 352A to 352D, the third vias 353A to 353D, the fourth vias 354A to 354D, the fifth vias 355A and 355B, the sixth vias 356A and 356B, the seventh vias 357A and 357B, the eighth vias 358A and 358B, and the ninth vias 359A and 359B extend through the base members 27A, 27B and 27C, the front-surface intermediate electrode 28C, and the back-surface intermediate electrode 28D in the Z-direction. The first vias 351A to 351D, the second vias 352A to 352D, the third vias 353A to 353D, the fourth vias 354A to 354D, the fifth vias 355A and 355B, the sixth vias 356A and 356B, the seventh vias 357A and 357B, the eighth vias 358A and 358B, and the ninth vias 359A and 359B are formed from, for example, a material containing one or more selected from Ti, Tin, Au, Ag, Cu, Al, and W.

The first via 351A is electrically connected to the first front-surface electrode 301A, the first intermediate electrode 321A of the front-surface intermediate electrode 28C, the first intermediate electrode 341A of the back-surface intermediate electrode 28D, and the first back-surface electrode 311A. Therefore, the first front-surface electrode 301A, the first intermediate electrode 321A, the first intermediate electrode 341A, and the first back-surface electrode 311A are electrically connected to each other.

As shown in FIG. 29, multiple first vias 351A are provided. The layout of the first vias 351A with respect to the first front-surface electrode 301A (refer to FIG. 28) is identical to that of the first vias 331A with respect to the first front-surface electrode 301A in the fifth embodiment.

As shown in FIGS. 29 to 34, the first vias 351B to 351D are electrically connected to the first front-surface electrode 301B, the first intermediate electrode 321B of the front-surface intermediate electrode 28C, the first intermediate electrode 341B of the back-surface intermediate electrode 28D, and the first back-surface electrodes 311B to 311D. Therefore, the first front-surface electrode 301B, the first intermediate electrode 321B, the first intermediate electrode 341B, and the first back-surface electrodes 311B to 311D are electrically connected to each other. The first vias 351B are arranged in an end of the first front-surface electrode 301B that is located relatively close to both the first substrate side surface 23 and the third substrate side surface 25. The first vias 351C are arranged in an end of the first front-surface electrode 301B that is located relatively close to both the second substrate side surface 24 and the third substrate side surface 25. The first vias 351D are arranged in an end of the first front-surface electrode 301B that is located relatively close to the fourth substrate side surface 26. The first vias 351D are arranged in a central part of the first front-surface electrode 301B in the X-direction.

The second vias 352A to 352D are arranged around the first front-surface electrode 301A. Multiple (in the sixth embodiment, two) second vias 352A, multiple (in the sixth embodiment, two) second vias 352B, multiple (in the sixth embodiment, two) second vias 352C, multiple (in the sixth embodiment, two) second vias 352D are provided. The second vias 352A are electrically connected to the third front-surface electrode 303A, the second intermediate electrode 322A of the front-surface intermediate electrode 28C, the second intermediate electrode 342A of the back-surface intermediate electrode 28D, and the second back-surface electrode 312A. Therefore, the third front-surface electrode 303A, the second intermediate electrode 322A, the second intermediate electrode 342A, and the second back-surface electrode 312A are electrically connected to each other. The second vias 352B are electrically connected to the third front-surface electrode 303B, the second intermediate electrode 322B of the front-surface intermediate electrode 28C, the second intermediate electrode 342B of the back-surface intermediate electrode 28D, and the second back-surface electrode 312B. Therefore, the third front-surface electrode 303B, the second intermediate electrode 322B, the second intermediate electrode 342B, and the second back-surface electrode 312B are electrically connected to each other. The second vias 352C are electrically connected to the third front-surface electrode 303C, the second intermediate electrode 322C of the front-surface intermediate electrode 28C, the second intermediate electrode 342C of the back-surface intermediate electrode 28D, and the second back-surface electrode 312C. Therefore, the third front-surface electrode 303C, the second intermediate electrode 322C, the second intermediate electrode 342C, and the second back-surface electrode 312C are electrically connected to each other. The second vias 352D are electrically connected to the third front-surface electrode 303D, the second intermediate electrode 322D of the front-surface intermediate electrode 28C, the second intermediate electrode 342D of the back-surface intermediate electrode 28D, and the second back-surface electrode 312D. Therefore, the third front-surface electrode 303D, the second intermediate electrode 322D, the second intermediate electrode 342D, and the second back-surface electrode 312D are electrically connected to each other.

The third via 353A is electrically connected to the fourth front-surface electrode 304A, the first intermediate electrode 321A of the front-surface intermediate electrode 28C, the first intermediate electrode 341A of the back-surface intermediate electrode 28D, and the third back-surface electrode 313A. Therefore, the fourth front-surface electrode 304A, the first intermediate electrode 321A, the first intermediate electrode 341A, and the third back-surface electrode 313A are electrically connected to each other. The third via 353B is electrically connected to the fourth front-surface electrode 304B, the first intermediate electrode 321A of the front-surface intermediate electrode 28C, the first intermediate electrode 341A of the back-surface intermediate electrode 28D, and the third back-surface electrode 313B. Therefore, the fourth front-surface electrode 304B, the first intermediate electrode 321A, the first intermediate electrode 341A, and the third back-surface electrode 313B are electrically connected to each other. The third via 353C is electrically connected to the fourth front-surface electrode 304C, the first intermediate electrode 321A of the front-surface intermediate electrode 28C, the first intermediate electrode 341A of the back-surface intermediate electrode 28D, and the third back-surface electrode 313C. Therefore, the fourth front-surface electrode 304C, the first intermediate electrode 321A, the first intermediate electrode 341A, and the third back-surface electrode 313C are electrically connected to each other. The third via 353D is electrically connected to the fourth front-surface electrode 304D, the first intermediate electrode 321A of the front-surface intermediate electrode 28C, the first intermediate electrode 341A of the back-surface intermediate electrode 28D, and the third back-surface electrode 313D. Therefore, the fourth front-surface electrode 304D, the first intermediate electrode 321A, the first intermediate electrode 341A, and the third back-surface electrode 313D are electrically connected to each other. In this manner, the fourth front-surface electrodes 304A to 304D are electrically connected to each other through the first intermediate electrode 321A.

The fourth via 354A is electrically connected to the sixth front-surface electrode 306A, the sixth intermediate electrode 326A of the front-surface intermediate electrode 28C, the third intermediate electrode 343A of the back-surface intermediate electrode 28D, and the fourth back-surface electrode 314A. Therefore, the sixth front-surface electrode 306A, the sixth intermediate electrode 326A, the third intermediate electrode 343A, and the fourth back-surface electrode 314A are electrically connected to each other. The fourth via 354B is electrically connected to the sixth front-surface electrode 306B, the sixth intermediate electrode 326B of the front-surface intermediate electrode 28C, the third intermediate electrode 343B of the back-surface intermediate electrode 28D, and the fourth back-surface electrode 314B. Therefore, the sixth front-surface electrode 306B, the sixth intermediate electrode 326B, the third intermediate electrode 343B, and the fourth back-surface electrode 314B are electrically connected to each other. The fourth via 354C is electrically connected to the sixth front-surface electrode 306C, the sixth intermediate electrode 326A of the front-surface intermediate electrode 28C, the third intermediate electrode 343C of the back-surface intermediate electrode 28D, and the fourth back-surface electrode 314C. Therefore, the sixth front-surface electrode 306C, the sixth intermediate electrode 326A, the third intermediate electrode 343C, and the fourth back-surface electrode 314C are electrically connected to each other. The fourth via 354D is electrically connected to the sixth front-surface electrode 306D, the sixth intermediate electrode 326B of the front-surface intermediate electrode 28C, the third intermediate electrode 343D of the back-surface intermediate electrode 28D, and the fourth back-surface electrode 314D. Therefore, the sixth front-surface electrode 306D, the sixth intermediate electrode 326B, the third intermediate electrode 343D, and the fourth back-surface electrode 314D are electrically connected to each other.

The fifth via 355A is electrically connected to the seventh front-surface electrode 307A, the third intermediate electrode 323A of the front-surface intermediate electrode 28C, the fourth intermediate electrode 344A of the back-surface intermediate electrode 28D, and the fifth back-surface electrode 315A. Therefore, the seventh front-surface electrode 307A, the third intermediate electrode 323A, the fourth intermediate electrode 344A, and the fifth back-surface electrode 315A are electrically connected to each other. The fifth via 355B is electrically connected to the seventh front-surface electrode 307B, the third intermediate electrode 323B of the front-surface intermediate electrode 28C, the fourth intermediate electrode 344B of the back-surface intermediate electrode 28D, and the fifth back-surface electrode 315B. Therefore, the seventh front-surface electrode 307B, the third intermediate electrode 323B, the fourth intermediate electrode 344B, and the fifth back-surface electrode 315B are electrically connected to each other.

The sixth via 356A is electrically connected to the eighth front-surface electrode 308A, the fourth intermediate electrode 324A of the front-surface intermediate electrode 28C, the fourth intermediate electrode 344A of the back-surface intermediate electrode 28D, and the sixth back-surface electrode 316A. Therefore, the eighth front-surface electrode 308A, the fourth intermediate electrode 324A, the fourth intermediate electrode 344A, and the sixth back-surface electrode 316A are electrically connected to each other. The sixth via 356B is electrically connected to the eighth front-surface electrode 308B, the fourth intermediate electrode 324B of the front-surface intermediate electrode 28C, the fourth intermediate electrode 344B of the back-surface intermediate electrode 28D, and the sixth back-surface electrode 316B. Therefore, the eighth front-surface electrode 308B, the fourth intermediate electrode 324B, the fourth intermediate electrode 344B, and the sixth back-surface electrode 316B are electrically connected to each other.

The seventh via 357A is electrically connected to the seventh front-surface electrode 307C, the third intermediate electrode 323C of the front-surface intermediate electrode 28C, the fifth intermediate electrode 345A of the back-surface intermediate electrode 28D, and the fifth back-surface electrode 315C. Therefore, the seventh front-surface electrode 307C, the third intermediate electrode 323C, the fifth intermediate electrode 345A, and the fifth back-surface electrode 315C are electrically connected to each other. The seventh via 357B is electrically connected to the seventh front-surface electrode 307D, the third intermediate electrode 323D of the front-surface intermediate electrode 28C, the fifth intermediate electrode 345B of the back-surface intermediate electrode 28D, and the fifth back-surface electrode 315D. Therefore, the seventh front-surface electrode 307D, the third intermediate electrode 323D, the fifth intermediate electrode 345B, and the fifth back-surface electrode 315D are electrically connected to each other.

The eighth via 358A is electrically connected to the ninth front-surface electrode 309A, the fifth intermediate electrode 325A of the front-surface intermediate electrode 28C, the fifth intermediate electrode 345A of the back-surface intermediate electrode 28D, and the seventh back-surface electrode 317A. Therefore, the ninth front-surface electrode 309A, the fifth intermediate electrode 325A, the fifth intermediate electrode 345A, and the seventh back-surface electrode 317A are electrically connected to each other. The eighth via 358B is electrically connected to the ninth front-surface electrode 309B, the fifth intermediate electrode 325B of the front-surface intermediate electrode 28C, the fifth intermediate electrode 345B of the back-surface intermediate electrode 28D, and the seventh back-surface electrode 317B. Therefore, the ninth front-surface electrode 309B, the fifth intermediate electrode 325B, the fifth intermediate electrode 345B, and the seventh back-surface electrode 317B are electrically connected to each other.

The ninth via 359A is electrically connected to the tenth front-surface electrode 310A, the sixth intermediate electrode 326A of the front-surface intermediate electrode 28C, the sixth intermediate electrode 346A of the back-surface intermediate electrode 28D, and the eighth back-surface electrode 318A. Therefore, the tenth front-surface electrode 310A, the sixth intermediate electrode 326A, the sixth intermediate electrode 346A, and the eighth back-surface electrode 318A are electrically connected to each other. The ninth via 359B is electrically connected to the tenth front-surface electrode 310B, the sixth intermediate electrode 326B of the front-surface intermediate electrode 28C, the sixth intermediate electrode 346B of the back-surface intermediate electrode 28D, and the eighth back-surface electrode 318B. Therefore, the tenth front-surface electrode 310B, the sixth intermediate electrode 326B, the sixth intermediate electrode 346B, and the eighth back-surface electrode 318B are electrically connected to each other.

In this manner, the first front-surface electrode 301A and the fourth front-surface electrodes 304A to 304D are electrically connected to the first back-surface electrode 311A, and the first front-surface electrode 301B is electrically connected to the first back-surface electrodes 311B to 311D. The third front-surface electrodes 303A to 303D are separately electrically connected to the second back-surface electrodes 312A to 312D. The sixth front-surface electrodes 306A and 306C are electrically connected to the eighth back-surface electrode 318A, and the sixth front-surface electrodes 306B and 306D are electrically connected to the eighth back-surface electrode 318B. The seventh front-surface electrode 307A is electrically connected to the sixth back-surface electrode 316A, the seventh front-surface electrode 307B is electrically connected to the sixth back-surface electrode 316B, the seventh front-surface electrode 307C is electrically connected to the seventh back-surface electrode 317A, and the seventh front-surface electrode 307D is electrically connected to the seventh back-surface electrode 317B.

### Configuration and Layout of Semiconductor Light-Emitting Element, Diodes, and Capacitors

As shown in FIG. 28, the semiconductor light-emitting element 30, the first to fourth protection diodes 101 to 104, the first to fourth reverse current protection diodes 261 to 264, and the first to fourth capacitors 271 to 274 are arranged in the same manner as those in the fifth embodiment. Thus, such layout will not be described in detail. The layout of the first to fourth switching elements for light emission 291W to 291Z, the first to fourth gate driver ICs 292W to 292Z, and the first to fourth capacitors 293W to 293Z differs from that of the fifth embodiment. The layout of the first to fourth switching elements for light emission 291W to 291Z, the first to fourth gate driver ICs 292W to 292Z, and the first to fourth capacitors 293W to 293Z will now be described.

As shown in FIGS. 32 to 34, the first to fourth switching elements for light emission 291W to 291Z are mounted on the fourth front-surface electrodes 304A to 304D, the fifth front-surface electrodes 305A to 305D, and the first front-surface electrode 301B. More specifically, the drain electrodes 291D of the first to fourth switching elements for light emission 291W to 291Z are separately bonded to the fourth front-surface electrodes 304A to 304D by the conductive bonding material SD. The gate electrodes 291G of the first to fourth switching elements for light emission 291W to 291Z are separately bonded to the fifth front-surface electrodes 305A to 305D by the conductive bonding material SD. The source electrodes 291S of the first to fourth switching elements for light emission 291W to 291Z are bonded to the first front-surface electrode 301B. Accordingly, the drain electrodes 291D of the first to fourth switching elements for light emission 291W to 291Z are separately electrically connected to the fourth front-surface electrodes 304A to 304D. The gate electrodes 291G of the first to fourth switching elements for light emission 291W to 291Z are separately electrically connected to the fifth front-surface electrodes 305A to 305D. The source electrodes 291S of the first to fourth switching elements for light emission 291W to 291Z are electrically connected to the first front-surface electrode 301B. Therefore, the source electrodes 291S of the first to fourth switching elements for light emission 291W to 291Z are electrically connected by the first front-surface electrode 301B.

As shown in FIG. 28, the first switching element for light emission 291W and the second switching element for light emission 291X are located at a position that overlaps the semiconductor light-emitting element 30 as viewed in the Y-direction. The first switching element for light emission 291W and the second switching element for light emission 291X are located at a side of the first and second capacitors 271 and 272 opposite to the semiconductor light-emitting element 30 in the Y-direction. Accordingly, the first and second protection diodes 101 and 102, the first and second reverse current protection diodes 261 and 262, and the first and second capacitors 271 and 272 are arranged between the semiconductor light-emitting element 30 and the first switching element for light emission 291W and the second switching element for light emission 291X in the Y-direction.

The third switching element for light emission 291Y and the fourth switching element for light emission 291Z are located at a position that partially overlaps the semiconductor light-emitting element 30 as viewed in the X-direction. The third switching element for light emission 291Y and the fourth switching element for light emission 291Z are separately disposed at opposite sides of the semiconductor light-emitting element 30 in the X-direction. The third switching element for light emission 291Y is located at a side of the third capacitor 273 opposite to the semiconductor light-emitting element 30 in the X-direction. Accordingly, the third protection diode 103, the third reverse current protection diode 263, and the third capacitor 273 are arranged between the third switching element for light emission 291Y and the semiconductor light-emitting element 30 in the X-direction. The fourth switching element for light emission 291Z is located at a side of the fourth capacitor 274 opposite to the semiconductor light-emitting element 30 in the X-direction. Accordingly, the fourth protection diode 104, the fourth reverse current protection diode 264, and the fourth capacitor 274 are arranged between the fourth switching element for light emission 291Z and the semiconductor light-emitting element 30 in the X-direction.

The first to fourth gate driver ICs 292W to 292Z are mounted on the fifth front-surface electrodes 305A to 305D, the sixth front-surface electrodes 306A to 306D, the seventh front-surface electrodes 307A to 307D, and the first front-surface electrode 301B. The first to fourth gate driver ICs 292W to 292Z are arranged on the front-surface electrodes 28A in the same manner as those of the fifth embodiment. The first gate driver IC 292W is adjacent to the first switching element for light emission 291W. The second gate driver IC 292X is adjacent to the second switching element for light emission 291X. The third gate driver IC 292Y is adjacent to the third switching element for light emission 291Y. The fourth gate driver IC 292Z is adjacent to the fourth switching element for light emission 291Z.

The first gate driver IC 292W is electrically connected to the gate electrode of the first switching element for light emission 291W through the fifth front-surface electrode 305A. The sixth front-surface electrode 306A is electrically connected to the control power supply 807A (refer to FIG. 27). Thus, the first gate driver IC 292W receives the electric power supplied from the control power supply 807A through the sixth front-surface electrode 306A. The seventh front-surface electrode 307A is electrically connected to the pulse generator 806A (refer to FIG. 27). Therefore, the first gate driver IC 292W receives the pulse signal of the pulse generator 806A through the seventh front-surface electrode 307A. In the same manner, the second to fourth gate driver ICs 292X to 292Z are separately electrically connected to the gate electrodes of the second to fourth switching elements for light emission 291X to 291W through the fifth front-surface electrodes 305B to 305D. The second to fourth gate driver ICs 292X to 292Z receive the electric power supplied from the control power supplies 807B to 807D (refer to FIG. 27) through the sixth front-surface electrodes 306B to 306D, respectively. The second to fourth gate driver ICs 292X to 292Z receive the pulse signals from the pulse generators 806B to 806D (refer to FIG. 27) through the seventh front-surface electrodes 307B to 307D, respectively.

The first to fourth capacitors 293W to 293Z are mounted on the sixth front-surface electrodes 306A to 306D and the first front-surface electrode 301B. The first to fourth capacitors 293W to 293Z are arranged on the front-surface electrodes 28A in the same manner as those of the fifth embodiment. The first capacitor 293W is adjacent to the first gate driver IC 292W in the X-direction. The first capacitor 293W is located at a side of the first gate driver IC 292W opposite to the first switching element for light emission 291W in the X-direction. The second capacitor 293X is adjacent to the second gate driver IC 292X in the X-direction. The second capacitor 293X is located at a side of the second gate driver IC 292X opposite to the second switching element for light emission 291X in the X-direction. The third capacitor 293Y is adjacent to the third gate driver IC 292Y in the Y-direction. The third capacitor 293Y is located at a side of the third gate driver IC 292Y opposite to the third switching element for light emission 291Y in the Y-direction. The fourth capacitor 293Z is adjacent to the fourth gate driver IC 292Z in the Y-direction. The fourth capacitor 293Z is located at a side of the fourth gate driver IC 292Z opposite to the fourth switching element for light emission 291Z in the Y-direction.

### Advantages

The semiconductor light-emitting device 10 of the sixth embodiment has the following advantages in addition to advantages (5-1) to (5-9) of the fifth embodiment.

(6-1) The semiconductor light-emitting device 10 includes the first to fourth switching elements for light emission 291W to 291Z that are arranged in accordance with the first to fourth light emitters 33A to 33D.

With this configuration, the distance between the first light emitter 33A and the first switching element for light emission 291W, the distance between the second light emitter 33B and the second switching element for light emission 291X, the distance between the third light emitter 33C and the third switching element for light emission 291Y, and the distance between the fourth light emitter 33D and the fourth switching element for light emission 291Z may be adjusted to be the same. Accordingly, the current path between the first light emitter 33A and the first switching element for light emission 291W, the current path between the second light emitter 33B and the second switching element for light emission 291X, the current path between the third light emitter 33C and the third switching element for light emission 291Y, and the current path between the fourth light emitter 33D and the fourth switching element for light emission 291Z may be adjusted to have the same length. This reduces differences in inductance between the current paths extending from the first to fourth light emitters 33A to 33D to the first to fourth switching elements for light emission 291W to 291Z.

(6-2) The semiconductor light-emitting device 10 includes the first gate driver IC 292W configured to control the first switching element for light emission 291W, the second gate driver IC 292X configured to control the second switching element for light emission 291X, the third gate driver IC 292Y configured to control the third switching element for light emission 291Y, and the fourth gate driver IC 292Z configured to control the fourth switching element for light emission 291Z.

With this configuration, the conductive path between the first gate driver IC 292W and the first switching element for light emission 291W, the conductive path between the second gate driver IC 292X and the second switching element for light emission 291X, the conductive path between the third gate driver IC 292Y and the third switching element for light emission 291Y, and the conductive path between the fourth gate driver IC 292Z and the fourth switching element for light emission 291Z are shorter as compared to a configuration in which the first to fourth gate driver ICs 292W to 292Z are arranged outside the semiconductor light-emitting device 10. This reduces effect of noise on the gate electrodes 291G of the first to fourth switching element for light emission 291W to 291Z caused by these conductive paths.

The sixth embodiment describes an example of the configuration of the semiconductor light-emitting device 10 in which the eight light emitters 33 of the semiconductor light-emitting element 30 are driven as the first to fourth light emitters 33A to 33D. However, a first switching element for light emission and a first reverse current protection diode may be provided for the first light emitter 33A of the eight light emitters 33 of the semiconductor light-emitting element 30, and a second switching element for light emission and a second reverse current protection diode may be provided for the second light emitter 33B, in the same manner as the first embodiment. Such a semiconductor light-emitting device 10 also obtains the same advantages as the semiconductor light-emitting device 10 of the sixth embodiment.

### Modified Examples

The above-described embodiments may be modified as follows. The embodiments described above and the modified examples described below may be combined as long as there is no technical contradiction. In the modified examples described hereafter, same reference characters are given to those components that are the same as the corresponding components of the above embodiments. Such components will not be described in detail.

In the first embodiment, the first switching element 41 and the second switching element 51 may include vertical transistors having different configurations.

In the third embodiment, the first switching element 171 and the second switching element 181 may include lateral transistors having different configurations.

In the first and second embodiments, at least one of the front-surface intermediate electrode 28C and the back-surface intermediate electrode 28D may be omitted.

In the first to fourth embodiments, the distance D1 between the semiconductor light-emitting element 30 and the first switching element 41 (171) in the Y-direction may differ from the distance D2 between the semiconductor light-emitting element 30 and the second switching element 51 (181) in the Y-direction.

In the second and fourth embodiments, the distance D3 between the semiconductor light-emitting element 30 and the third switching element 111 (221) in the X-direction may differ from the distance D4 between the semiconductor light-emitting element 30 and the fourth switching element 121 (222) in the X-direction.

In the first and third embodiments, the semiconductor light-emitting device 10 may further include a gate driver IC configured to control the first switching element 41 (171) of the first drive circuit 40 and the second switching element 51 (181) of the second drive circuit 50. These switching elements may be controlled by different gate driver ICs or the same gate driver IC.

In the second and fourth embodiments, the semiconductor light-emitting device 10 may further include a gate driver IC configured to control the first switching element 41 (171) of the first drive circuit 40, the second switching element 51 (181) of the second drive circuit 50, the third switching element 111 (221) of the third drive circuit 110, and the fourth switching element 121 (222) of the fourth drive circuit 120. These switching elements may be controlled by different gate driver ICs or the same gate driver IC.

In the first embodiment, the layout of the first switching element 41, the first capacitor 42, the first protection diode 101, the second switching element 51, the second capacitor 52, and the second protection diode 102 may be changed.

In the second embodiment, the layout of the first to fourth switching elements 41, 51, 111, and 121, the first to fourth capacitors 42, 52, 112, and 122, and the first to fourth protection diodes 101 to 104 may be changed.

In the third embodiment, the layout of the first switching element 171, the first capacitor 42, the first protection diode 101, the second switching element 181, the second capacitor 52, and the second protection diode 102 may be changed.

In the fourth embodiment, the layout of the first to fourth switching elements 171, 181, 221, and 222, the first to fourth capacitors 42, 52, 112, and 122, and the first to fourth protection diodes 101 to 104 may be changed.

In the fifth and sixth embodiments, the semiconductor light-emitting device 10 may include the first to fourth charging switching elements 808A to 808D. In this case, the first drive circuit 40 includes the first charging switching element 808A and the first capacitor 271. The second drive circuit 50 includes the second charging switching element 808B and the second capacitor 272. The third drive circuit 110 includes the third charging switching element 808C and the third capacitor 273. The fourth drive circuit 120 includes the fourth charging switching element 808D and the fourth capacitor 274.

In the fifth and sixth embodiments, the layout of the first to fourth reverse current protection diodes 261 to 264, the first to fourth capacitors 271 to 274, and the first to fourth protection diodes 281 to 284 may be changed.

In the fifth embodiment, the layout of the gate driver IC 292 and the capacitor 293 may be changed.

In the sixth embodiment, the layout of the first to fourth gate driver ICs 292W to 292Z and the first to fourth capacitors 293W to 293Z may be changed.

In the fifth embodiment, the gate driver IC 292 may be omitted from the semiconductor light-emitting device 10. The capacitor 293 may be omitted from the semiconductor light-emitting device 10.

In the sixth embodiment, the first to fourth gate driver ICs 292W to 292Z may be omitted from the semiconductor light-emitting device 10. The first to fourth capacitors 293W to 293Z may be omitted from the semiconductor light-emitting device 10.

In the first to fourth embodiments, one of the first capacitor 42 and the first switching element 41 (171) may be omitted from the first drive circuit 40. One of the second capacitor 52 and the second switching element 51 (181) may be omitted from the second drive circuit 50.

In the second and fourth embodiments, one of the third capacitor 112 and the third switching element 111 (221) may be omitted from the third drive circuit 110. One of the fourth capacitor 122 and the fourth switching element 121 (222) may be omitted from the fourth drive circuit 120.

In the first to fourth embodiments, the first protection diode 101 and the second protection diode 102 may be omitted from the semiconductor light-emitting device 10.

In the second and fourth embodiments, the third protection diode 103 and the fourth protection diode 104 may be omitted from the semiconductor light-emitting device 10.

In the first to fourth embodiments, the first capacitors 42 do not have to be aligned with and spaced apart from each other in the X-direction. The first capacitors 42 may be arranged in any manner. The second capacitors 52 do not have to be aligned with and spaced apart from each other in the X-direction. The second capacitors 52 may be arranged in any manner.

In the second and fourth embodiments, the third capacitors 112 do not have to be aligned with and spaced apart from each other in the Y-direction. The third capacitors 112 may be arranged in any manner. The fourth capacitors 122 do not have to be aligned with and spaced apart from each other in the Y-direction. The fourth capacitors 122 may be arranged in any manner.

In the first to fourth embodiments, the number of first capacitors 42 may be one. The number of second capacitors 52 may be one.

In the second and fourth embodiments, the number of third capacitors 112 may be one. The number of fourth capacitors 122 may be one.

In each embodiment, the number of light emitters 33 of the semiconductor light-emitting element 30 may be changed. For example, in the first embodiment, when the semiconductor light-emitting element 30 includes four light emitters 33, the semiconductor light-emitting device 10 may be configured to drive the first light emitter 33A and the second light emitter 33B, each including two light emitters 33. In the second embodiment, when the semiconductor light-emitting element 30 includes four light emitters 33, the semiconductor light-emitting device 10 may be configured to drive the first to fourth light emitters 33A to 33D, each including a single light emitter 33.

In each embodiment, the semiconductor light-emitting element 30 is not limited to an edge-emitting laser element. In an example, the semiconductor light-emitting element 30 may include a light-emitting diode (LED), a vertical-cavity surface-emitting laser (VCSEL), or the like.

Various examples described in this specification may be combined as long as there is no technical contradiction.

Terms such as “first”, “second”, or “third” in this disclosure are used to distinguish subjects and are not used for ordinal purposes.

In this specification, “at least one of A and B” should be understood to mean “only A, only B, or both A and B.”

In the present disclosure, the term “on” includes the meaning of “above” in addition to the meaning of “on” unless otherwise clearly described in the context. Accordingly, for example, a phrase such as “first element arranged on second element” may mean that the first element is directly located on the second element in one embodiment and that the first element is located above the second element without contacting the second element in another embodiment. Thus, the term “on” does not exclude a structure in which another component is formed between the first element and the second element.

The Z-direction as referred to in this disclosure does not necessarily have to be the vertical direction, and does not necessarily have to exactly coincide with the vertical direction. Accordingly, in the structures of the present disclosure, “up” and “down” with respect to the Z-direction as referred to in this specification are not limited to “up” and “down” with respect to the vertical direction. For example, the X-direction may be the vertical direction. Alternatively, the Y-direction may be the vertical direction.

### Clauses

Technical concepts that can be understood from the present disclosure will now be described. Reference characters used in the described embodiment are added to corresponding elements in the clauses to aid understanding without any intention to impose limitations on these elements. The reference characters are given as examples to aid understanding and are not intended to limit elements to the elements denoted by the reference characters.

### Clause A1

A semiconductor light-emitting device (10), including:
a substrate (20) including a substrate front surface (21), and a substrate back surface (22) facing away from the substrate front surface (21);
front-surface electrodes (28A) formed in the substrate front surface (21);
back-surface electrodes (28B) formed in the substrate back surface (22) and configured for mounting the semiconductor light-emitting device (10);
a semiconductor light-emitting element (30) including a first light emitter (33A), a second light emitter (33B), a first element front-surface electrode (34A) electrically connected to the first light emitter (33A), a second element front-surface electrode (34B) electrically connected to the second light emitter (33B), and an element back-surface electrode (35) electrically connected to both the first light emitter (33A) and the second light emitter (33B);
a first drive circuit (40) electrically connected to the first element front-surface electrode (34A) and configured to drive the first light emitter (33A); and
a second drive circuit (50) electrically connected to the second element front-surface electrode (34B) and configured to drive the second light emitter (33B),
in which the element back-surface electrode (35) of the semiconductor light-emitting element (30), the first drive circuit (40), and the second drive circuit (50) are mounted on the front-surface electrodes (28A).

### Clause A2

The semiconductor light-emitting device according to clause A1, in which
the first drive circuit (40) includes a first switching element (41) configured to control driving of the first light emitter (33A), and a first capacitor (42) configured to supply electric current to the first light emitter (33A), and
the second drive circuit (50) includes a second switching element (51) configured to control driving of the second light emitter (33B), and a second capacitor (52) configured to supply electric current to the second light emitter (33B).

### Clause A3

The semiconductor light-emitting device according to clause A2, in which
the first switching element (41) and the second switching element (51) each include a source electrode (41S/51S) and a gate electrode (41G/51G) that are formed in an element front surface (41A/51A), and a drain electrode (41D/51D) formed in an element back surface (41B/51B), and
the drain electrode (41D/51D) is mounted on the front-surface electrodes (28A).

### Clause A4

The semiconductor light-emitting device according to clause A2, in which
the first switching element (171) and the second switching element (181) each include a source electrode (171S/181S), a drain electrode (171D/181D), and a gate electrode (171G/181G) that are formed in an element back surface, and
the source electrode (171S/181S), the drain electrode (171D/181D), and the gate electrode (171G/181G) are mounted on the front-surface electrodes (28A).

### Clause A5

The semiconductor light-emitting device according to clause A2, in which
the first switching element (41) and the second switching element (51) each include a drain electrode (41D/51D), a source electrode (41S/51S), and a gate electrode (41G/51G),
the first capacitor (42) and the second capacitor (52) each include a first electrode (42A/52A) and a second electrode (42B/52B),
the first element front-surface electrode (34A) defines a first anode electrode,
the second element front-surface electrode (34B) defines a second anode electrode,
the element back-surface electrode (35) defines a cathode electrode,
the source electrode (41S) of the first switching element (41) is electrically connected to the first anode electrode (34A),
the drain electrode (41D) of the first switching element (41) is electrically connected to the first electrode (42A) of the first capacitor (42),
the source electrode (51S) of the second switching element (51) is electrically connected to the second anode electrode (34B), and
the cathode electrode (35) is electrically connected to the second electrode (42B) of the first capacitor (42) and the second electrode (52B) of the second capacitor (52).

### Clause A6

The semiconductor light-emitting device according to clause A5, in which
as viewed in a thickness-wise direction (Z-direction) of the substrate (20), the semiconductor light-emitting element (30) and the first capacitor (42) are spaced apart from each other in a first direction (Y-direction),
as viewed in the thickness-wise direction (Z-direction), the first switching element (41) is arranged between the semiconductor light-emitting element (30) and the first capacitor (42) in the first direction (Y-direction),
as viewed in the thickness-wise direction (Z-direction), the semiconductor light-emitting element (30) and the second capacitor (52) are spaced apart from each other in the first direction (Y-direction), and
as viewed in the thickness-wise direction (Z-direction), the second switching element (51) is arranged between the semiconductor light-emitting element (30) and the second capacitor (52) in the first direction (Y-direction).

### Clause A7

The semiconductor light-emitting device according to clause A6, in which a distance (D1) between the semiconductor light-emitting element (30) and the first switching element (41) in the first direction (Y-direction) is equal to a distance (D2) between the semiconductor light-emitting element (30) and the second switching element (51) in the first direction (Y-direction).

### Clause A8

The semiconductor light-emitting device according to clause A6, in which
the first capacitor (42) is one of first capacitors,
the second capacitor (52) is one of second capacitors,
the first capacitors (42) are connected in parallel to each other, and
the second capacitors (52) are connected in parallel to each other.

### Clause A9

The semiconductor light-emitting device according to clause A8, in which
a direction orthogonal to the first direction (Y-direction) as viewed in the thickness-wise direction (Z-direction) is a second direction (X-direction),
the first capacitors (42) are aligned with and spaced apart from each other in the second direction (X-direction), and
the second capacitors (52) are aligned with and spaced apart from each other in the second direction (X-direction).

### Clause A10

The semiconductor light-emitting device according to clause A1, further including:
a first protection diode (101) connected in antiparallel to the first light emitter (33A); and
a second protection diode (102) connected in antiparallel to the second light emitter (33B).

### Clause A11

The semiconductor light-emitting device according to clause A10, in which
the first drive circuit (40) includes a first switching element (41) configured to control driving of the first light emitter (33A), and a first capacitor (42) configured to supply electric current to the first light emitter (33A),
the second drive circuit (50) includes a second switching element (51) configured to control driving of the second light emitter (33B), and a second capacitor (52) configured to supply electric current to the second light emitter (33B),
as viewed in a thickness-wise direction (Z-direction) of the substrate (20), the semiconductor light-emitting element (30) and the first capacitor (42) are spaced apart from each other in a first direction (Y-direction),
as viewed in the thickness-wise direction (Z-direction), the first switching element (41) is arranged between the semiconductor light-emitting element (30) and the first capacitor (42) in the first direction (Y-direction),
as viewed in the thickness-wise direction (Z-direction), the semiconductor light-emitting element (30) and the second capacitor (52) are spaced apart from each other in the first direction (Y-direction),
as viewed in the thickness-wise direction (Z-direction), the second switching element (51) is arranged between the semiconductor light-emitting element (30) and the second capacitor (52) in the first direction (Y-direction),
a direction orthogonal to the first direction (Y-direction) as viewed in the thickness-wise direction (Z-direction) is a second direction (X-direction),
the first protection diode (101) is located at a side of the first switching element (41) opposite to the semiconductor light-emitting element (30) in the first direction (Y-direction), the first protection diode (101) being spaced apart from the first capacitor (42) in the second direction (X-direction), and
the second protection diode (102) is located at a side of the second switching element (51) opposite to the semiconductor light-emitting element (30) in the first direction (Y-direction), the second protection diode (102) being spaced apart from the second capacitor (52) in the second direction (X-direction).

### Clause A12

The semiconductor light-emitting device according to clause A1, in which
the semiconductor light-emitting element (30) includes a third light emitter (33C), a fourth light emitter (33D), a third element front-surface electrode (34C) electrically connected to the third light emitter (33C), and a fourth element front-surface electrode (34D) electrically connected to the fourth light emitter (33D),
the semiconductor light-emitting device further includes
   a third drive circuit (110) electrically connected to the third element front-surface electrode (34C) and configured to drive the third light emitter (33C); and
   a fourth drive circuit (120) electrically connected to the fourth element front-surface electrode (34D) and configured to drive the fourth light emitter (33D), and
   the third drive circuit (110) and the fourth drive circuit (120) are mounted on the front-surface electrodes (28A).

### Clause A13

The semiconductor light-emitting device according to clause A12, in which
as viewed in a thickness-wise direction (Z-direction) of the substrate (20), the first drive circuit (40) and the second drive circuit (50) are spaced apart from the semiconductor light-emitting element (30) in a first direction (Y-direction),
a direction orthogonal to the first direction (Y-direction) as viewed in the thickness-wise direction (Z-direction) is a second direction (X-direction), and
the third drive circuit (110) and the fourth drive circuit (120) are separately disposed at opposite sides of the semiconductor light-emitting element (30) in the second direction (X-direction).

### Clause A14

The semiconductor light-emitting device according to clause A12, in which
the third drive circuit (110) includes a third switching element (111) configured to control driving of the third light emitter (33C), and a third capacitor (112) configured to supply electric current to the third light emitter (33C), and
the fourth drive circuit (120) includes a fourth switching element (121) configured to control driving of the fourth light emitter (33D), and a fourth capacitor (122) configured to supply electric current to the fourth light emitter (33D).

### Clause A15

The semiconductor light-emitting device according to clause A14, in which
as viewed in a thickness-wise direction (Z-direction) of the substrate (20), the semiconductor light-emitting element (30) and the third capacitor (112) are spaced apart from each other in a second direction (X-direction),
as viewed in the thickness-wise direction (Z-direction), the third switching element (111) is arranged between the semiconductor light-emitting element (30) and the third capacitor (112) in the second direction (X-direction),
as viewed in the thickness-wise direction (Z-direction), the semiconductor light-emitting element (30) and the fourth capacitor (122) are spaced apart from each other in the second direction (X-direction), and
as viewed in the thickness-wise direction (Z-direction), the fourth switching element (121) is arranged between the semiconductor light-emitting element (30) and the fourth capacitor (122) in the second direction (X-direction).

### Clause A16

The semiconductor light-emitting device according to clause A15, in which a distance (D3) between the semiconductor light-emitting element (30) and the third switching element (111) in the second direction (X-direction) is equal to a distance (D4) between the semiconductor light-emitting element (30) and the fourth switching element (122) in the second direction (X-direction).

### Clause A17

The semiconductor light-emitting device according to clause A1, further including:
vias (91A, 91B) arranged in the substrate (20) and connecting the back-surface electrodes (28B) and the front-surface electrodes (28A), in which
a first current path between the first light emitter (33A) of the semiconductor light-emitting element (30) and the first drive circuit (40) includes the front-surface electrodes (28A), the back-surface electrodes (28B), and the vias (91A, 91B), and
a second current path between the second light emitter (33B) of the semiconductor light-emitting element (30) and the second drive circuit (50) includes the front-surface electrodes (28A), the back-surface electrodes (28B), and the vias (91A, 91B).

### Clause A18

The semiconductor light-emitting device according to clause A1, further including:
intermediate electrodes (28C, 28D) arranged between the front-surface electrodes (28A) and the back-surface electrodes (28B) in a thickness-wise direction (Z-direction) of the substrate (20); and
vias (91A, 91B) arranged in the substrate (20) and connecting the back-surface electrodes (28B), the front-surface electrodes (28A), and the intermediate electrodes (28C, 28D), in which
a first current path between the first light emitter of (33A) of the semiconductor light-emitting element (30) and the first drive circuit (40) includes the front-surface electrodes (28A), the intermediate electrodes (28C), and the vias (91A, 91B), and
a second current path between the second light emitter (33B) of the semiconductor light-emitting element (30) and the second drive circuit (50) includes the front-surface electrodes (28A), the intermediate electrodes (28C), and the vias (91A, 91B).

### Clause A19

The semiconductor light-emitting device according to clause A1, further including:
a first protection diode (281);
a second protection diode (282);
a first reverse current protection diode (261);
a second reverse current protection diode (262); and
a switching element for light emission (291), in which
the switching element for light emission (291) includes a drain electrode (291D) and a source electrode (291S),
the first drive circuit (40) includes a first capacitor (271),
the second drive circuit (50) includes a second capacitor (272),
the first capacitor (271) and the second capacitor (272) each include a first electrode (271A/272A) and a second electrode (271B/272B),
the first element front-surface electrode (34A) defines a first anode electrode,
the second element front-surface electrode (34B) defines a second anode electrode,
the element back-surface electrode (35) defines a cathode electrode,
an anode of the first reverse current protection diode (261) is electrically connected to the first electrode (271A) of the first capacitor (271),
a cathode of the first reverse current protection diode (261) is electrically connected to a cathode of the first protection diode (281) and the first anode electrode (34A),
an anode of the second reverse current protection diode (262) is electrically connected to the first electrode (272A) of the second capacitor (272),
a cathode of the second reverse current protection diode (262) is electrically connected to a cathode of the second protection diode (282) and the second anode electrode (34B), and
an anode of the first protection diode (281) and an anode of the second protection diode (282) are electrically connected to the drain electrode (291D) of the switching element for light emission (291) and the cathode electrode (35).

### Clause A20

The semiconductor light-emitting device according to clause A19, in which the switching element for light emission (291) includes a first switching element for light emission (291W) and a second switching element for light emission (291X) connected in parallel to each other.

### Clause A21

The semiconductor light-emitting device according to clause A1, in which
the first switching element (41) and the second switching element (51) each include a drain electrode (41D/51D), a source electrode (41S/51S), and a gate electrode (41G/51G), and
the semiconductor light-emitting device further includes a gate driver IC (292) electrically connected to the gate electrode (41G) of the first switching element (41) and the gate electrode (51G) of the second switching element (51), the gate driver IC (292) being configured to drive the first switching element (41) and the second switching element (51).

### Clause A22

The semiconductor light-emitting device according to clause A1, in which the substrate (20) is formed from any one of glass epoxy resin, ceramic, or silicon.

### Clause A23

The semiconductor light-emitting device according to clause A1, in which the semiconductor light-emitting element (30) includes an edge-emitting laser element.

### Clause B1

A semiconductor light-emitting device (10), including:
a semiconductor light-emitting element including a first light emitter (33A), a second light emitter (33B), a first anode electrode for light emission (34A) electrically connected to the first light emitter (33A), a second anode electrode for light emission (34B) electrically connected to the second light emitter (33B), and a cathode electrode for light emission (35) electrically connected to both the first light emitter (33A) and the second light emitter (33B);
a first reverse current protection diode (261) including a first cathode (261B) electrically connected to the first anode electrode for light emission (34A), and a first anode (261A) electrically connected to a first charging switching element (808A);
a second reverse current protection diode (262) including a second cathode (262B) electrically connected to the second anode electrode for light emission (34B), and a second anode (262A) electrically connected to a second charging switching element (808B);
a first protection diode (281) including a first protection anode (281A) electrically connected to the first cathode (261B) of the first reverse current protection diode (261) and the first anode electrode for light emission (34A), and a first protection cathode (281B) electrically connected to the cathode electrode for light emission (35);
a second protection diode (282) including a second protection anode (282A) electrically connected to the second cathode (262B) of the second reverse current protection diode (262) and the second anode electrode for light emission (34B), and a second protection cathode (282B) electrically connected to the cathode electrode for light emission (35);
a switching element for light emission (291) including a drain electrode (291D) electrically connected to the cathode electrode for light emission (35), and a source electrode (291S);
a first capacitor (271) electrically connected to the first anode (261A) of the first reverse current protection diode (261) and the source electrode (291S) of the switching element for light emission (291); and
a second capacitor (272) electrically connected to the second anode (262A) of the second reverse current protection diode (262) and the source electrode (291S) of the switching element for light emission (291).

The above descriptions are merely exemplary. One skilled in the art may recognize further possible combinations and replacements of the elements and methods (manufacturing processes) in addition to those listed for purposes of describing the techniques of the present disclosure. All replacements, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor light-emitting device, comprising:
a substrate including a substrate front surface, and a substrate back surface facing away from the substrate front surface;
front-surface electrodes formed in the substrate front surface;
back-surface electrodes formed in the substrate back surface and configured for mounting the semiconductor light-emitting device;
a semiconductor light-emitting element including a first light emitter, a second light emitter, a first element front-surface electrode electrically connected to the first light emitter, a second element front-surface electrode electrically connected to the second light emitter, and an element back-surface electrode electrically connected to both the first light emitter and the second light emitter;
a first drive circuit electrically connected to the first element front-surface electrode and configured to drive the first light emitter; and
a second drive circuit electrically connected to the second element front-surface electrode and configured to drive the second light emitter,
wherein the element back-surface electrode of the semiconductor light-emitting element, the first drive circuit, and the second drive circuit are mounted on the front-surface electrodes.

2. The semiconductor light-emitting device according to claim 1, wherein
the first drive circuit includes a first switching element configured to control driving of the first light emitter, and a first capacitor configured to supply electric current to the first light emitter, and
the second drive circuit includes a second switching element configured to control driving of the second light emitter, and a second capacitor configured to supply electric current to the second light emitter.

3. The semiconductor light-emitting device according to claim 2, wherein
the first switching element and the second switching element each include a source electrode and a gate electrode that are formed in an element front surface, and a drain electrode formed in an element back surface, and
the drain electrode is mounted on the front-surface electrodes.

4. The semiconductor light-emitting device according to claim 2, wherein
the first switching element and the second switching element each include a source electrode, a drain electrode, and a gate electrode that are formed in an element back surface, and
the source electrode, the drain electrode, and the gate electrode are mounted on the front-surface electrodes.

5. The semiconductor light-emitting device according to claim 2, wherein
the first switching element and the second switching element each include a drain electrode, a source electrode, and a gate electrode,
the first capacitor and the second capacitor each include a first electrode and a second electrode,
the first element front-surface electrode defines a first anode electrode,
the second element front-surface electrode defines a second anode electrode,
the element back-surface electrode defines a cathode electrode,
the source electrode of the first switching element is electrically connected to the first anode electrode,
the drain electrode of the first switching element is electrically connected to the first electrode of the first capacitor,
the source electrode of the second switching element is electrically connected to the second anode electrode, and
the cathode electrode is electrically connected to the second electrode of the first capacitor and the second electrode of the second capacitor.

6. The semiconductor light-emitting device according to claim 5, wherein
as viewed in a thickness-wise direction of the substrate, the semiconductor light-emitting element and the first capacitor are spaced apart from each other in a first direction,
as viewed in the thickness-wise direction, the first switching element is arranged between the semiconductor light-emitting element and the first capacitor in the first direction,
as viewed in the thickness-wise direction, the semiconductor light-emitting element and the second capacitor are spaced apart from each other in the first direction, and
as viewed in the thickness-wise direction, the second switching element is arranged between the semiconductor light-emitting element and the second capacitor in the first direction.

7. The semiconductor light-emitting device according to claim 6, wherein a distance between the semiconductor light-emitting element and the first switching element in the first direction is equal to a distance between the semiconductor light-emitting element and the second switching element in the first direction.

8. The semiconductor light-emitting device according to claim 6, wherein
the first capacitor is one of first capacitors,
the second capacitor is one of second capacitors,
the first capacitors are connected in parallel to each other, and
the second capacitors are connected in parallel to each other.

9. The semiconductor light-emitting device according to claim 8, wherein
a direction orthogonal to the first direction as viewed in the thickness-wise direction is a second direction,
the first capacitors are aligned with and spaced apart from each other in the second direction, and
the second capacitors are aligned with and spaced apart from each other in the second direction.

10. The semiconductor light-emitting device according to claim 1, further comprising:
a first protection diode connected in antiparallel to the first light emitter; and
a second protection diode connected in antiparallel to the second light emitter.

11. The semiconductor light-emitting device according to claim 10, wherein
the first drive circuit includes a first switching element configured to control driving of the first light emitter, and a first capacitor configured to supply electric current to the first light emitter,
the second drive circuit includes a second switching element configured to control driving of the second light emitter, and a second capacitor configured to supply electric current to the second light emitter,
as viewed in a thickness-wise direction of the substrate, the semiconductor light-emitting element and the first capacitor are spaced apart from each other in a first direction,
as viewed in the thickness-wise direction, the first switching element is arranged between the semiconductor light-emitting element and the first capacitor in the first direction,
as viewed in the thickness-wise direction, the semiconductor light-emitting element and the second capacitor are spaced apart from each other in the first direction,
as viewed in the thickness-wise direction, the second switching element is arranged between the semiconductor light-emitting element and the second capacitor in the first direction,
a direction orthogonal to the first direction as viewed in the thickness-wise direction is a second direction,
the first protection diode is located at a side of the first switching element opposite to the semiconductor light-emitting element in the first direction, the first protection diode being spaced apart from the first capacitor in the second direction, and
the second protection diode is located at a side of the second switching element opposite to the semiconductor light-emitting element in the first direction, the second protection diode being spaced apart from the second capacitor in the second direction.

12. The semiconductor light-emitting device according to claim 1, wherein
the semiconductor light-emitting element includes a third light emitter, a fourth light emitter, a third element front-surface electrode electrically connected to the third light emitter, and a fourth element front-surface electrode electrically connected to the fourth light emitter,
the semiconductor light-emitting device further comprises:
a third drive circuit electrically connected to the third element front-surface electrode and configured to drive the third light emitter; and
a fourth drive circuit electrically connected to the fourth element front-surface electrode and configured to drive the fourth light emitter, and
the third drive circuit and the fourth drive circuit are mounted on the front-surface electrodes.

13. The semiconductor light-emitting device according to claim 12, wherein
as viewed in a thickness-wise direction of the substrate, the first drive circuit and the second drive circuit are spaced apart from the semiconductor light-emitting element in a first direction,
a direction orthogonal to the first direction as viewed in the thickness-wise direction is a second direction, and
the third drive circuit and the fourth drive circuit are separately disposed at opposite sides of the semiconductor light-emitting element in the second direction.

14. The semiconductor light-emitting device according to claim 12, wherein
the third drive circuit includes a third switching element configured to control driving of the third light emitter, and a third capacitor configured to supply electric current to the third light emitter, and
the fourth drive circuit includes a fourth switching element configured to control driving of the fourth light emitter, and a fourth capacitor configured to supply electric current to the fourth light emitter.

15. The semiconductor light-emitting device according to claim 14, wherein
as viewed in a thickness-wise direction of the substrate, the semiconductor light-emitting element and the third capacitor are spaced apart from each other in a second direction,
as viewed in the thickness-wise direction, the third switching element is arranged between the semiconductor light-emitting element and the third capacitor in the second direction,
as viewed in the thickness-wise direction, the semiconductor light-emitting element and the fourth capacitor are spaced apart from each other in the second direction, and
as viewed in the thickness-wise direction, the fourth switching element is arranged between the semiconductor light-emitting element and the fourth capacitor in the second direction.

16. The semiconductor light-emitting device according to claim 15, wherein a distance between the semiconductor light-emitting element and the third switching element in the second direction is equal to a distance between the semiconductor light-emitting element and the fourth switching element in the second direction.

17. The semiconductor light-emitting device according to claim 1, further comprising:
vias arranged in the substrate and connecting the back-surface electrodes and the front-surface electrodes, wherein
a first current path between the first light emitter of the semiconductor light-emitting element and the first drive circuit includes the front-surface electrodes, the back-surface electrodes, and the vias, and
a second current path between the second light emitter of the semiconductor light-emitting element and the second drive circuit includes the front-surface electrodes, the back-surface electrodes, and the vias.

18. The semiconductor light-emitting device according to claim 1, further comprising:
intermediate electrodes arranged between the front-surface electrodes and the back-surface electrodes in a thickness-wise direction of the substrate; and
vias arranged in the substrate and connecting the back-surface electrodes, the front-surface electrodes, and the intermediate electrodes, wherein
a first current path between the first light emitter of the semiconductor light-emitting element and the first drive circuit includes the front-surface electrodes, the intermediate electrodes, and the vias, and
a second current path between the second light emitter of the semiconductor light-emitting element and the second drive circuit includes the front-surface electrodes, the intermediate electrodes, and the vias.

19. The semiconductor light-emitting device according to claim 1, further comprising:
a first protection diode;
a second protection diode;
a first reverse current protection diode;
a second reverse current protection diode; and
a switching element for light emission, wherein
the switching element for light emission includes a drain electrode and a source electrode,
the first drive circuit includes a first capacitor,
the second drive circuit includes a second capacitor,
the first capacitor and the second capacitor each include a first electrode and a second electrode,
the first element front-surface electrode defines a first anode electrode,
the second element front-surface electrode defines a second anode electrode,
the element back-surface electrode defines a cathode electrode,
an anode of the first reverse current protection diode is electrically connected to the first electrode of the first capacitor,
a cathode of the first reverse current protection diode is electrically connected to a cathode of the first protection diode and the first anode electrode,
an anode of the second reverse current protection diode is electrically connected to the first electrode of the second capacitor,
a cathode of the second reverse current protection diode is electrically connected to a cathode of the second protection diode and the second anode electrode, and
an anode of the first protection diode and an anode of the second protection diode are electrically connected to the drain electrode of the switching element for light emission and the cathode electrode.

20. The semiconductor light-emitting device according to claim 19, wherein the switching element for light emission includes a first switching element for light emission and a second switching element for light emission connected in parallel to each other.
